(19) United States
(12) Patent Application Publication
(10) Pub. No.: US 2024/0341183 A1
(43) Pub. Date: Oct. 10, 2024

(54) ORGANIC COMPOUNDS, LIGHT-EMITTING ELEMENTS, AND DISPLAY PANELS

(71) Applicant: SHENZHEN CHINA STAR OPTOELECTRONICS SEMICONDUCTOR DISPLAY TECHNOLOGY CO., LTD., Shenzhen (CN)

(72) Inventors: Zeming XIA, Shenzhen (CN); Zeguan XIAO, Shenzhen (CN); Ruifeng HE, Shenzhen (CN); Jingyao SONG, Shenzhen (CN)

(21) Appl. No.: 18/215,904

(22) Filed: Jun. 29, 2023

(30) Foreign Application Priority Data
Apr. 6, 2023 (CN) 202310406306.6

(51) Int. Cl. H10K 85/60; C07F 5/02; C09K 11/06

(52) U.S. Cl. CPC H10K 85/658; C07F 5/027; C09K 11/06; C09K 2211/1018; H10K 50/121; H10K 2101/30

(57) ABSTRACT

The present disclosure provides an organic compound, a light-emitting element, and a display panel. The organic compound has a structure represented by formula (1), wherein Ar₁ is selected from the group consisting of a substituted or unsubstituted aromatic group having 6 to 60 ring atoms, and a substituted or unsubstituted heteroaromatic group having 5 to 60 ring atoms; X and Y are each independently selected from the group consisting of O, S, CR₅R₆, and NR₇; W is selected from the group consisting of O, S, CR₈R₉, and NR₁₀; and R₁, R₂, R₃, R₄, R₅, R₆, R₇, R₈, R₉, and R₁₀, at each occurrence, are each independently selected from the group consisting of —H, a linear alkyl group having 1 to 20 carbon atoms, a branched alkyl group having 3 to 20 carbon atoms, and a substituted or unsubstituted aromatic group having 6 to 30 ring atoms.

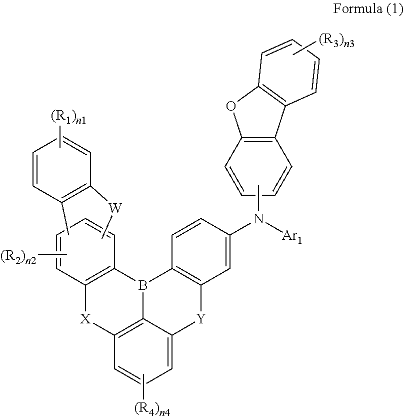

### CROSS-REFERENCE TO RELATED APPLICATIONS

This application claims priority to Chinese Patent Application No. 202310406306.6, filed on Apr. 6, 2023, the content of which is incorporated herein by reference in its entirety.

### TECHNICAL FIELD

The present disclosure relates to displays, and in particular, to an organic compound, a light-emitting element, and a display panel.

### BACKGROUND

At present, organic electroluminescent elements generally comprise a positive electrode, a negative electrode, and an organic layer therebetween. An organic substance of the organic layer can be used to convert electric energy into light energy, achieving organic electroluminescence. In order to improve luminous efficiency and prolong service life of the organic electroluminescent element, the organic layer is usually implemented as a multilayer structure, each layer of which has a different organic substance. Specifically, the organic layer mainly includes a hole injection layer, a hole transport layer, a light-emitting layer, an electron transport layer, an electron injection layer, and the like. When a voltage is applied between the positive electrode and the negative electrode of the organic electroluminescent element, holes are injected into the organic layer from the positive electrode, electrons are injected into the organic layer from the negative electrode, and the injected holes and electrons are combined to form excitons. When excitons transition back to the ground state, light is emitted, thereby realizing light emission of the organic electroluminescent element. The organic electroluminescent element has characteristics such as self-luminous, high brightness, high efficiency, low voltage driving, wide viewing angle, high contrast, and high response. Therefore, the organic electroluminescent device has a wide application prospect.

In order to improve the luminous efficiency of the organic electroluminescent element, various light-emitting material systems based on fluorescence and phosphorescence have been developed. Although the organic electroluminescent element taking advantage of a fluorescent material has a high reliability, the internal electroluminescent quantum efficiency thereof may be limited to 25% due to 1:3 of a branching ratio of the singlet excited state to the triplet excited state of the excitons under an electric excited condition. The organic electroluminescent element having a phosphorescent material achieves almost 100% of internal electroluminescent quantum efficiency. However, the phosphorescent material typically includes a metal complex containing iridium or platinum, which is expensive and complex to synthesize; and the phosphor-based organic electroluminescent element may produce a roll-off effect, i.e., the luminous efficiency decreases rapidly with the increase of current or brightness, which limits its application at high luminance levels.

In order to overcome the above defects, a thermally activated delayed fluorescence (TADF) material is generally applied in the prior art. The TADF material allows the complete separation of the electron cloud distribution of the highest occupied molecular orbital (HOMO) from the lowest unoccupied molecular orbital (LUMO), and the reduction of the difference (AEST) between the first excited singlet state (S1) and the first excited triplet state (T1) of the organic compound, by connecting electron-donating groups and electron-withdrawing groups. However, the conventional TADF organic compound has limited improvement of performance in terms of both efficiency and lifetime, which makes it difficult to improve luminous efficiency and service life of the organic electroluminescent element having the TADF organic compound.

Accordingly, there is a need for an organic compound, a light-emitting element, and a display panel to solve the above problems.

### SUMMARY

An embodiment of the present disclosure provides an organic compound, a light-emitting element, and a display panel, which can address a problem that it is difficult to improve luminous efficiency and service life of an organic electroluminescent element having a TADF organic compound.

An embodiment of the present disclosure provides an organic compound having a structure represented by formula (1):

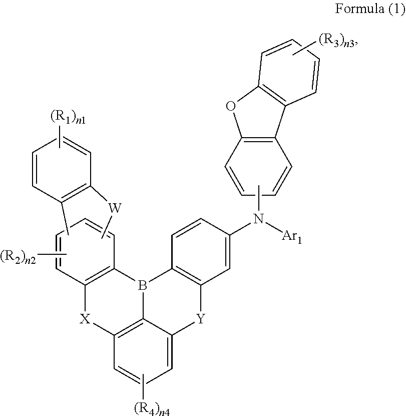

wherein Ar₁ is selected from the group consisting of a substituted or unsubstituted aromatic group having 6 to 60 ring atoms, and a substituted or unsubstituted heteroaromatic group having 5 to 60 ring atoms;
X and Y are each independently selected from the group consisting of O, S, CR₅R₆, and NR₇;
W is selected from the group consisting of O, S, CR₈R₉, and NR₁₀;
R₁, R₂, R₃, R₄, R₅, R₆, R₇, R₈, R₉ and R₁₀, at each occurrence, are each independently selected from the group consisting of —H, a linear alkyl group having 1 to 20 carbon atoms, a branched alkyl group having 3 to 20 carbon atoms, and a substituted or unsubstituted aromatic group having 6 to 30 ring atoms; and
n1 is selected from 0, 1, 2, 3 or 4; n2 is selected from 0, 1 or 2; n3 is selected from 0, 1, 2, 3 or 4; n4 is selected from 0, 1, 2 or 3.

An embodiment of the present disclosure provides a light-emitting element including:
a first electrode and a second electrode; and
an organic functional layer between the first electrode and the second electrode;
wherein materials of the organic functional layer include an organic compound having a structure represented by formula (1):

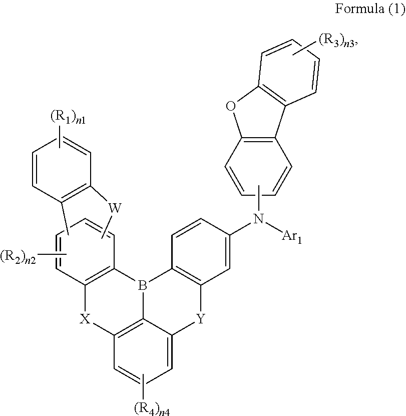

wherein Ar₁ is selected from the group consisting of a substituted or unsubstituted aromatic group having 6 to 60 ring atoms, and a substituted or unsubstituted heteroaromatic group having 5 to 60 ring atoms;
X and Y are each independently selected from the group consisting of O, S, CR₅R₆, and NR₇;
W is selected from the group consisting of O, S, CR₈R₉, and NR₁₀;
R₁, R₂, R₃, R₄, R₅, R₆, R₇, R₈, R₉, and R₁₀, at each occurrence, are each independently selected from the group consisting of —H, a linear alkyl group having 1 to 20 carbon atoms, a branched alkyl group having 3 to 20 carbon atoms, and a substituted or unsubstituted aromatic group having 6 to 30 ring atoms; and
n1 is selected from 0, 1, 2, 3, or 4; n2 is selected from 0, 1, or 2; n3 is selected from 0, 1, 2, 3, or 4; n4 is selected from 0, 1, 2, or 3.

An embodiment of the present disclosure provides a display panel including a light-emitting element, wherein the light-emitting element includes an organic compound having a structure represented by formula (1):

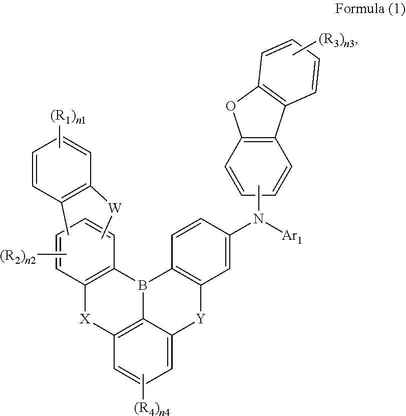

wherein Ar₁ is selected from the group consisting of a substituted or unsubstituted aromatic group having 6 to 60 ring atoms, and a substituted or unsubstituted heteroaromatic group having 5 to 60 ring atoms;
X and Y are each independently selected from the group consisting of O, S, CR₅R₆, and NR₇;
W is selected from the group consisting of O, S, CR₈R₉, and NR₁₀;
R₁, R₂, R₃, R₄, R₅, R₆, R₇, R₈, R₉, and R₁₀, at each occurrence, are each independently selected from the group consisting of —H, a linear alkyl group having 1 to 20 carbon atoms, a branched alkyl group having 3 to 20 carbon atoms, and a substituted or unsubstituted aromatic group having 6 to 30 ring atoms; and
n1 is selected from 0, 1, 2, 3, or 4; n2 is selected from 0, 1, or 2; n3 is selected from 0, 1, 2, 3, or 4; n4 is selected from 0, 1, 2, or 3.

According to the present disclosure, introduction of an aromatic or heteroaromatic group into a boron-containing organic compound enhances conjugation of the molecule, and introduction of an aliphatic group into the boron-containing organic compound enhances solubility of the molecule, thereby improving the material performance in terms of purity of the boron-containing organic compound in the light-emitting element, improving luminous efficiency, and prolonging service life of the light-emitting element.

### BRIEF DESCRIPTION OF THE DRAWINGS

In order to illustrate the embodiments of the present disclosure, the following accompanying drawings to be used in the description of the embodiments are briefly described. It is apparent that the described accompanying drawings are only part of embodiments of the present disclosure, and for those skilled in the art, other accompanying drawings may be obtained on the basis of these accompanying drawings without any creative effort.

FIG. 1 is a schematic diagram of a first structure of a light-emitting element according to an embodiment of the present disclosure.

FIG. 2 is a schematic diagram of a second structure of a light-emitting element according to an embodiment of the present disclosure.

### DETAILED DESCRIPTION

Embodiments of the present disclosure will be described below in conjunction with the accompanying drawings of the present disclosure. It is apparent that the described embodiments are only a part of embodiments of the present disclosure, rather than all the embodiments. Based on the embodiments in the present disclosure, all other embodiments obtained by those skilled in the art without creative effort fall within the protection scope of the present disclosure. In addition, it should be understood that the embodiments described herein are merely illustrative and explanatory of the present disclosure and are not intended to limit the present disclosure. In the present disclosure, in the absence of any indication to the contrary, orientation terms, such as “upper”, “lower”, “inner” or “outer”, usually refer to the top or bottom of a device in its actual use or working state, specifically the direction of the drawing in the accompanying drawings, or with regard to the outline of the device. In the present disclosure, a term “optionally” and “optional” means either with or without, i.e. any one selected from “having” or “not”. If the term “optional (optionally)” appears in a technical solution more than one time, each “optional (optionally)” is independent of the other if not specifically stated and there is no contradictions or mutual constraints. In the present disclosure, the technical features described in an open-ended manner include closed technical solutions consisting of the listed features, as well as open technical solutions containing the listed features.

In the present disclosure, an aromatic group, an aryl group and an aromatic ring system have the same meaning and are interchangeable.

In the present disclosure, a heteroaromatic group, a heteroaryl group and a heteroaromatic ring system have the same meaning and are interchangeable.

In the present disclosure, “substituted” means that a hydrogen atom in a group to be substituted is replaced by a substituent.

In the present disclosure, when a same substituent occurs several times in a structure formula of a compound, the substituent, at each occurrence, may be independently selected from a same moiety or different moieties in a moiety set. For example, when the formula contains a plurality of R, the plurality of R can be independently different moieties or the same moiety.

In the present disclosure, “substituted or unsubstituted” means that a defined group may or may not be substituted. When the defined group is substituted, it is to be understood that the defined group may be substituted with one or more substituents, and each of the substituents may be selected from, but not limited to, a deuterium atom, a cyano group, an isocyano group, a nitro group or halogen (for example, F, Cl, Br, or I), an alkyl group having 1 to 20 carbon atoms, a heterocyclyl group having 3 to 20 ring atoms, an aromatic group having 6 to 20 ring atoms, a heteroaromatic group having 5 to 20 ring atoms, —NR′R″, a silanyl group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, or a trifluoromethyl group, wherein the above groups may be further substituted with an substituent accepted in the art. It is to be understood that R′ and R″ in —NR′R″ are each independently selected from, but not limited to, H, a deuterium atom, a cyano group, an isocyano group, a nitro group or halogen (for example, F, Cl, Br, or I), an alkyl group having 1 to 10 carbon atoms, a heterocyclyl group having 3 to 20 ring atoms, an aromatic group having 6 to 20 ring atoms, or a heteroaromatic group having 5 to 20 ring atoms. For example, the substituent is selected from, but not limited to, a deuterium atom, a cyano group, an isocyano group, a nitro group or halogen (for example, F, Cl, Br, or I), an alkyl group having 1 to 10 carbon atoms, a heterocyclyl group having 3 to 10 ring atoms, an aromatic group having 6 to 20 ring atoms, a heteroaromatic group having 5 to 20 ring atoms, a silanyl group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, or a trifluoromethyl group, and the above groups may be further substituted with a substituent accepted in the art.

In the present disclosure, “the number of ring atoms” denotes the total number of atoms that constitute, by atomic bonding, a ring structure of a compound (e.g., a monocyclic compound, a fused ring compound, a cross-linking compound, a carbocyclic compound, or a heterocyclic compound). It is to be noted that when the ring is substituted with a substituent, the atoms in the substituent are not the ring-forming atoms. The definition of “the number of ring atoms” also may be applied to the following description, unless otherwise specified. For example, the number of ring atoms in benzene is 6, the number of ring atoms in naphthalene is 10, and the number of ring atoms in a thiophenyl group is 5.

In the present disclosure, “aryl or aromatic group” means an aromatic hydrocarbon group that is derived by removing a hydrogen atom from an aromatic ring compound wherein all of ring atoms are carbon. The aryl may be a monocyclic, a fused-ring, or a polycyclic aryl group. In the polycyclic aryl group, at least one ring is an aromatic ring system. For example, “a substituted or unsubstituted aromatic group having 6 to 40 ring atoms” refers to an aromatic group having 6 to 40 ring atoms, preferably a substituted or unsubstituted aromatic group having 6 to 30 ring atoms, more preferably a substituted or unsubstituted aromatic group having 6 to 18 ring atoms, particularly preferably a substituted or unsubstituted aromatic group having 6 to 14 ring atoms. Suitable examples include, but are not limited to, phenyl, biphenyl, terphenyl, naphthyl, anthracenyl, phenanthrenyl, fluoranthenyl, triphenylenyl, pyrenyl, perylenyl, tetraphenyl, fluorenyl, acenaphthylenyl, and derivatives thereof. It is to be understood that a plurality of aryl groups may be connected by an intervening short non-aromatic unit (e.g., the non-aromatic unit preferably contain less than 10% of non-H atoms, such as C, N or O atoms, based on the total number of atoms in the system), for example, acenaphthylene, fluorene, 9,9-diarylfluorene, triarylamine, diaryl ether, which should also be encompassed in the definition of 6-the aromatic group.

In the present disclosure, “heteroaryl or heteroaromatic group” means that at least one carbon atom of ring atoms on an aromatic group is replaced by a non-carbon atom such as an N atom, an O atom, or an S atom. That is, the ring atoms of heteroaryl include one or more non-carbon atoms. For example, “substituted or unsubstituted heteroaromatic group having 5 to 40 ring atoms” refers to a heteroaromatic group having 5 to 40 ring atoms, preferably a substituted or unsubstituted heteroaromatic group having 6 to 30 ring atoms, more preferably a substituted or unsubstituted heteroaromatic group having 6 to 18 ring atoms, particularly preferably a substituted or unsubstituted heteroaromatic group having 6 to 14 ring atoms. Suitable examples include, but are not limited to: thienyl, furanyl, pyrrolyl, imidazolyl, diazolyl, triazolyl, pyridyl, bipyridyl, pyrimidinyl, triazinyl, acridinyl, pyridazinyl, pyrazinyl, quinolinyl, isoquinolinyl, quinazolinyl, quinoxalinyl, phthalazinyl, pyridopyrimidinyl, pyridopyrazinyl, benzothienyl, benzofuranyl, indolyl, pyrroloimidazolyl, pyrrolopyrrolyl, thienopyrrolyl, thienothiophenyl, furopyrrolyl, furofuranyl, thienofuranyl, benzoisoxazolyl, benzoisothiazolyl, benzimidazolyl, cinnolinyl, phenanthridinyl, perimidinyl, quinazolinonyl, dibenzothiophenyl, dibenzofuranyl, carbazolyl, and derivatives thereof.

The term “heterocyclyl,” “heterocyclic” or “heterocyclo” refers to fully saturated or partially unsaturated, but non-aromatic cyclic groups, which have one or more oxygen, sulfur, silicon or nitrogen heteroatoms in ring. The nitrogen and sulfur heteroatoms may optionally be oxidized and the nitrogen heteroatoms may optionally be quaternized. The heterocyclic group may be attached at any heteroatom or carbon atom of the ring or ring system and may be unsubstituted or substituted by one or more moieties as described for aryl groups above.

In the present disclosure, “alkyl group” may represent a linear, branched and/or cyclic alkyl group. The number of carbon atoms in an alkyl group may be 1 to 50, 1 to 30, 1 to 20, 1 to 10, or 1 to 6. The phrase containing the term, for example, “C₁₋₉ alkyl”, refers to an alkyl group having 1 to 9 carbon atoms, which at each occurrence may each independently be, a C₁ alkyl group, a C₂ alkyl group, a C₃ alkyl group, a C₄ alkyl group, a C₅ alkyl group, a C₆ alkyl group, a C₇ alkyl group, a C₈ alkyl group, or a C₉ alkyl group. Non-limiting examples of the alkyl group include methyl, ethyl, n-propyl, isopropyl, n-butyl, sec-butyl, tert-butyl, isobutyl, 2-ethylbutyl, 3,3-dimethylbutyl, n-pentyl, isopentyl, neopentyl, tert-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-tert-butylcyclohexyl, n-heptyl, 1-methylheptyl, 2,2-dimethylheptyl, 2-ethylheptyl, 2-butylheptyl, n-octyl, tert-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-heneicosyl, n-docosyl, n-tricosyl, n-tetracosanyl, n-pentacosanyl, n-hexacosanyl, n-heptacosanyl, n-octacosanyl, n-nonacosanyl, n-triacontanyl, or the like.

In the present disclosure, abbreviations for substituents are as follows: n—normal, sec—secondary, i—iso, ter—tertiary, o—ortho, m—meta, p—para, Me—methyl, Et—ethyl, Pr—propyl, Bu—butyl, Am—amyl (pentyl), Hx—hexyl, Cy—cyclohexyl.

In the present disclosure, “amino group” refers to a derivative of an amine that has a structure of formula —N(X)₂, wherein each “X” is independently H, a substituted or unsubstituted alkyl group, a substituted or unsubstituted cycloalkyl group, a substituted or unsubstituted heterocyclyl group, or the like. Non-limiting types of an amino group include —NH₂, —N(alkyl)₂, —NH(alkyl), —N(cycloalkyl)₂, —NH(cycloalkyl), —N(heterocyclyl)₂, —NH(heterocyclyl), —N(aryl)₂, —NH(aryl), —N(alkyl)(aryl), —N(alkyl)(heterocyclyl), —N(cycloalkyl)(heterocyclyl), —N(aryl)(heteroaryl), —N(alkyl)(heteroaryl), or the like.

In the present disclosure, unless specifically defined, hydroxyl refers to —OH, carboxyl refers to —COOH, carbonyl refers to —C(═O)—, amino refers to —NH₂, formyl refers to —C(═O)H, haloformyl refers to —C(═O)Z (where Z denotes halogen (for example, F, Cl, Br, or I)), carbamoyl refers to —C(═O)NH₂, isocyanate refers to —NCO and isothiocyanate refers to —NCS.

In the present disclosure, the term “alkoxy” refers to a group having a structure “—O-alkyl”, i.e., a group obtained by connecting an alkyl group as defined above to the remaining groups via an oxygen atom. Suitable examples of a phrase containing the term include, but are not limited to, methoxy (—O—CH₃ or —OMe), ethoxy (—O—CH₂CH₃ or —OEt), and tert-butoxy (—O—C(CH₃)₃ or —OtBu).

In the present disclosure, “*” attached to a single bond denotes a linkage site or a fused site.

In the present disclosure, when no linkage site is specified in a moiety, it means that one or more linkage sites in the moiety can be optionally selected as the linkage site.

In the present disclosure, when no fused site is denoted in a moiety, it means that one or more fused sites in the moiety can be optionally selected as the fused site, preferably two or more sites in adjacent positions in the moiety as the fused sites.

In the present disclosure, when a moiety has a plurality of substituents represented by a same symbol, each of the substituents may be the same as or different from others. For example, in

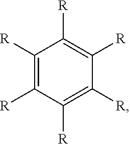

six Rs on the phenyl ring may be the same as or different from each other.

In the present disclosure, when a single bond to which a substituent is attached extends through a corresponding ring, it means that the substituent may be attached to any position of the ring. For example, in

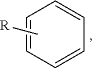

is attached to any substitutable position of the phenyl ring, and in

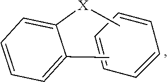

it means that

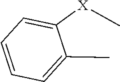

may be connected to any position of

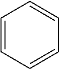

to form a fused rings.

In the present disclosure, the cyclic alkyl and cycloalkyl have the same meaning and are interchangeable.

In the present disclosure, “ortho group” refers to a group that is adjacent to another group on the main ring or chain such that there is no additional substitutable site between the group and the adjacent substituent.

In the present disclosure, “any adjacent two of R₁, R₂, R₃ and R₄ form a ring with each other” denotes adjacent two of R₁, R₂, R₃ and R₄ are connected to each other to form a ring system, which may be selected from the group consisting of an aliphatic hydrocarbon ring, an aliphatic heterocyclic ring, an aromatic hydrocarbon ring or an aromatic heterocyclic ring, preferably,

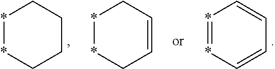

At present, the improvement of performance of conventional organic compounds with TADF is limited in terms of both efficiency and lifetime, and therefore there is the problem of difficulty in improving the luminescence efficiency as well as the lifetime of organic electroluminescent elements.

An embodiment of the present disclosure provides an organic compound having a structure represented by the following formula (1):

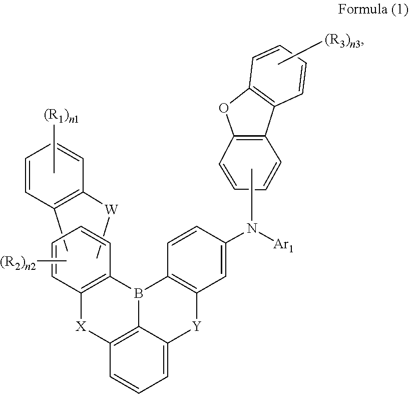

wherein Ar₁ is selected from the group consisting of a substituted or unsubstituted aromatic group having 6 to 60 ring atoms, and a substituted or unsubstituted heteroaromatic group having 5 to 60 ring atoms;
X and Y are each independently selected from the group consisting of O, S, CR₅R₆, and NR₇;
W is selected from the group consisting of O, S, CR₈R₉, and NR₁₀;
R₁, R₂, R₃, R₄, R₅, R₆, R₇, R₈, R₉, and R₁₀, at each occurrence, are each independently selected from the group consisting of —H, a linear alkyl group having 1 to 20 carbon atoms, a branched alkyl group having 3 to 20 carbon atoms, and a substituted or unsubstituted aromatic group having 6 to 30 ring atoms;
n1 is selected from 0, 1, 2, 3 or 4; n2 is selected from 0, 1 or 2; n3 is selected from 0, 1, 2, 3 or 4; n4 is selected from 0, 1, 2 or 3.

According to the present disclosure, a boron-containing organic compound is selected, wherein an aromatic group or a heteroaromatic group is incorporated to enhance overall conjugation of the boron-containing organic compound, and an aliphatic hydrocarbon group is incorporated to enhance solubility of the boron-containing organic compound, thereby improving the material performance in terms of luminous efficiency, service life, purity of the boron-containing organic compound in the light-emitting element, and the like, for example, increasing the luminous efficiency, and prolonging the service life of the light-emitting element.

In some embodiments, R₁, R₂, R₃, R₄, R₅, R₆, R₇, R₈, R₉, and R₁₀, at each occurrence, may also be each independently selected from the group consisting of -D (deuterium group), a linear alkoxy group having 1 to 20 carbon atoms, a linear thioalkoxy group having 1 to 20 carbon atoms, a cyclic alkyl group having 3 to 20 carbon atoms, a branched alkoxy group having 3 to 20 carbon atoms, a cyclic alkoxy group having 3 to 20 carbon atoms, a branched thioalkoxy group having 3 to 20 carbon atoms, a cyclic thioalkoxy group having 3 to 20 carbon atoms, a silyl group, a ketone group having 1 to 20 carbon atoms, an alkoxycarbonyl group having 2 to 20 carbon atoms, an aryloxycarbonyl group having 7 to 20 carbon atoms, an alkenyl group having 1 to 20 carbon atoms, —CN, carbamoyl, haloformyl, formyl, isocyano, isocyanate, thiocyanate, isothiocyanate, hydroxyl, nitro, —CF₃, —Cl, —Br, —F, a substituted or unsubstituted heteroaromatic group having 5 to 30 ring atoms.

The substituted or unsubstituted heteroaromatic group having 5 to 30 ring atoms may be a substituted or unsubstituted aryloxy group having 6 to 30 ring atoms, or a substituted or unsubstituted heteroaryloxy group having 5 to 30 ring atoms.

In some embodiments, when n1 is greater than or equal to 2, two adjacent R₁ groups form a ring or not. When n2 is greater than or equal to 2, two adjacent R₂ groups form a ring or not. When n3 is greater than or equal to 2, two adjacent R₃ groups form a ring or not. When n4 is greater than or equal to 2, two adjacent R₄ groups form a ring or not.

In some embodiments, the organic compound has a structure represented by any one of formulae (2-1) to (2-6):

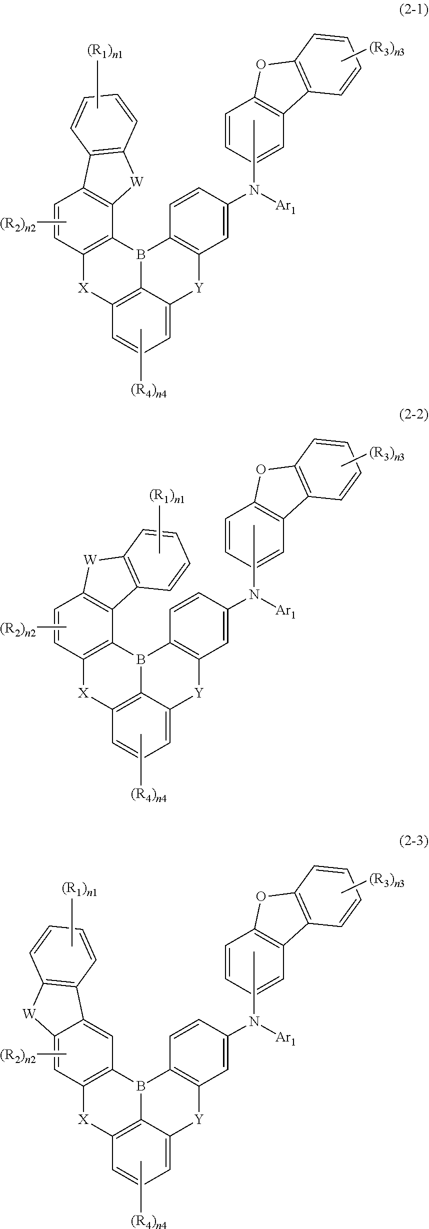

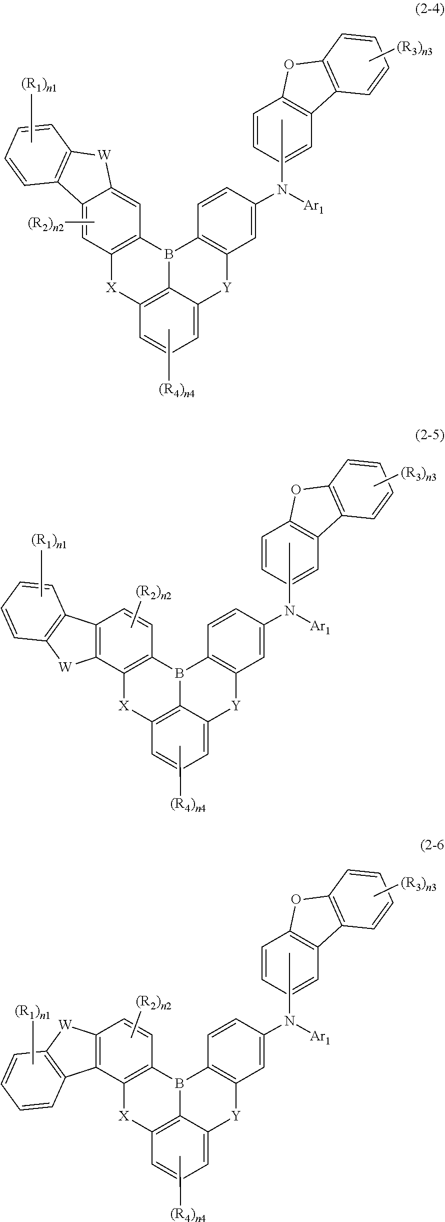

In some embodiments, the organic compound has a structure represented by any one of formulae (3-1) to (3-6):

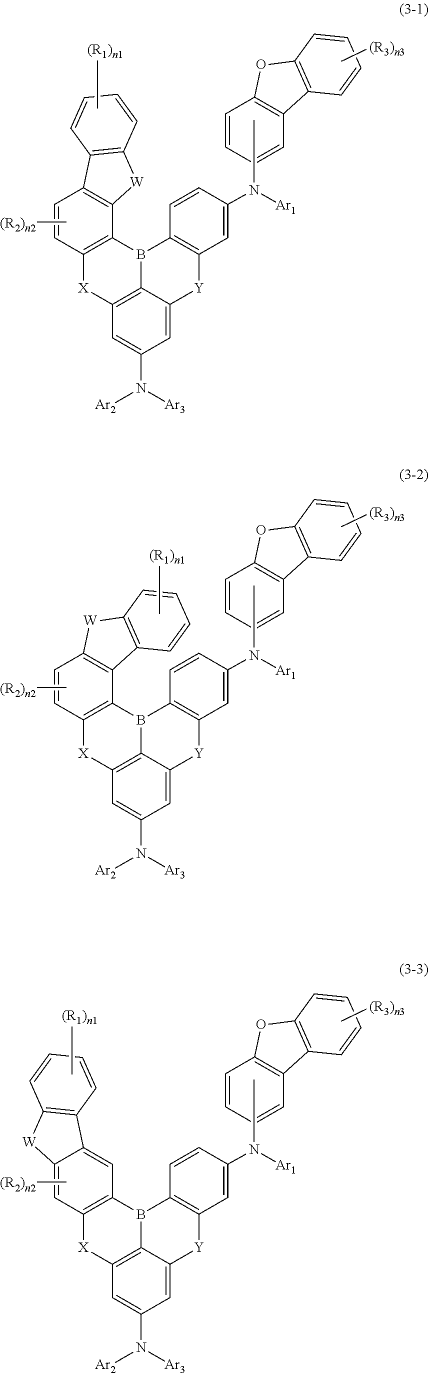

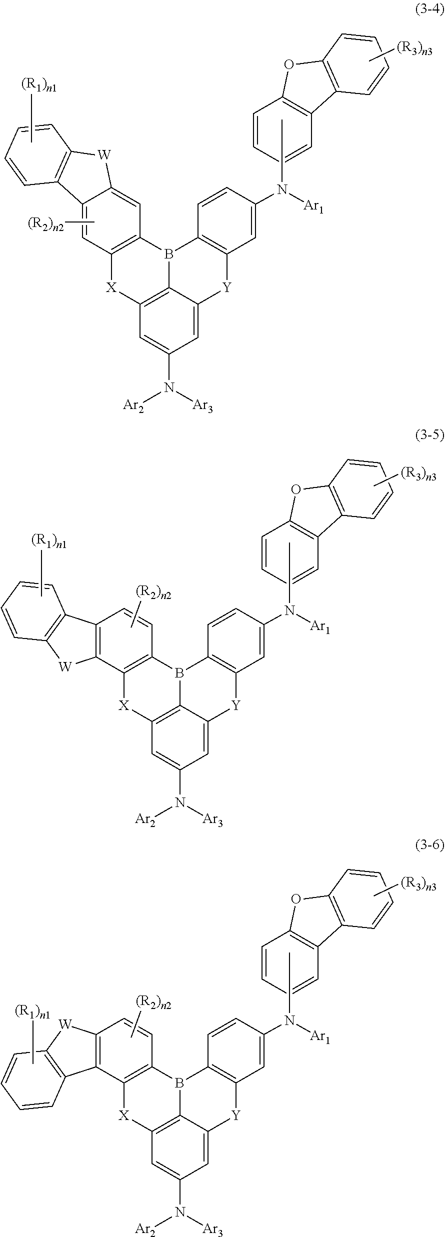

wherein Ar₂ and Ar₃ are each independently selected from the group consisting of a substituted or unsubstituted aromatic group having 6 to 60 ring atoms, and a substituted or unsubstituted heteroaromatic group having 5 to 60 ring atoms.

In the structure represented by any one of the formulae (3-1) to (3-6), Ar₂ and Ar₁ are each independently selected from the group consisting of a substituted or unsubstituted aromatic group having 6 to 24 carbon atoms, and a substituted or unsubstituted heteroaromatic group having 5 to 24 carbon atoms.

In the structure represented by any one of the formulae (1), and (2-1) to (2-6), An is selected from the group consisting of a substituted or unsubstituted aromatic group having 6 to 24 carbon atoms, and a substituted or unsubstituted heteroaromatic group having 5 to 24 carbon atoms.

In the structure represented by any one of the formulae (1), (2-1) to (2-6), and (3-1) to (3-6), Ar₁, Ar₂, and Arₙ are each independently selected from a structure represented by any one of the following:

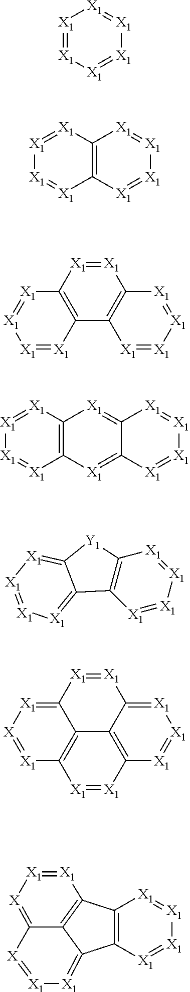

X₁, at each occurrence, is independently selected from CR₁₁ or N.

Y₁ is selected from the group consisting of NR₁₂, CR₁₃R₁₄, SiR₁₃R₁₄, O, S, S═O and SO₂.

R₁₁, R₁₂, R₁₃, and R₁₄, at each occurrence, are each independently selected from the group consisting of —H, a linear alkyl group having 1 to 20 carbon atoms, a branched alkyl group having 3 to 20 carbon atoms, a substituted or unsubstituted aromatic group having 6 to 30 ring atoms. Preferably, R₁₁, R₁₂, R₁₃ and R₁₄, at each occurrence, are each independently selected from —H, methyl, tert-butyl, or phenyl. More preferably, R₁₁, R₁₂, R₁₃, and R₁₄, at each occurrence, are independently selected from —H, tert-butyl, or phenyl.

In the structure represented by any one of the formulae (1) and (2-1) to (2-6), R₁, R₂, R₃, and R₄, at each occurrence, are each independently selected from the group consisting of —H, methyl,

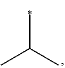

tert-butyl,

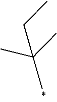

phenyl,

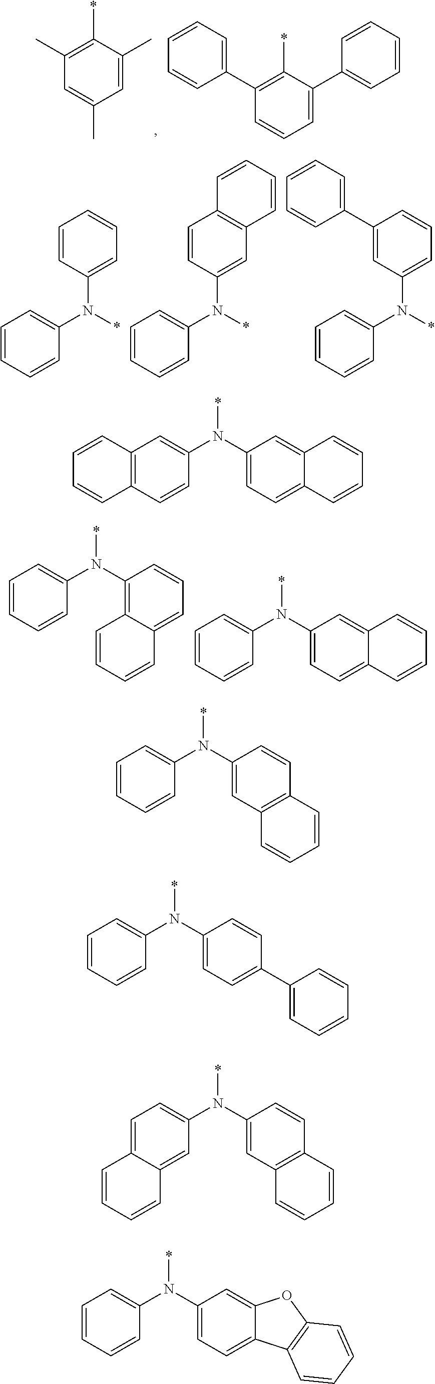

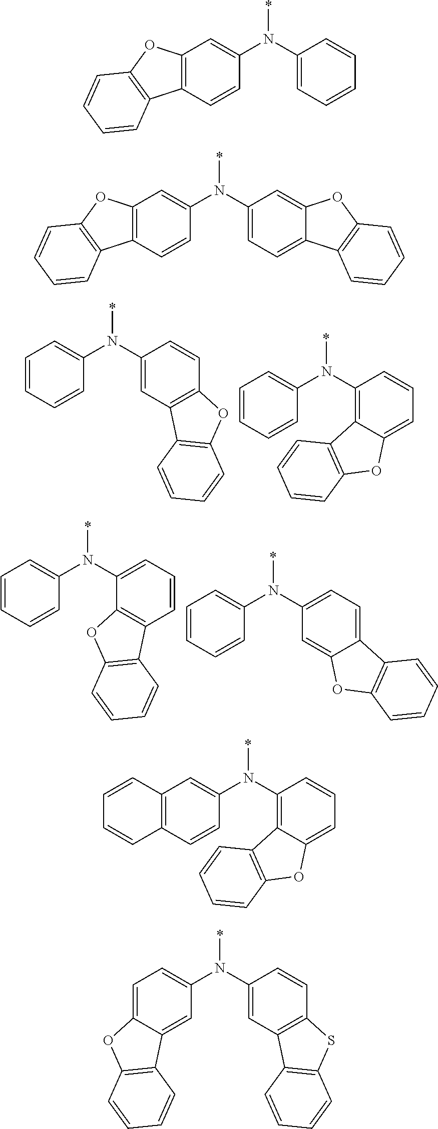

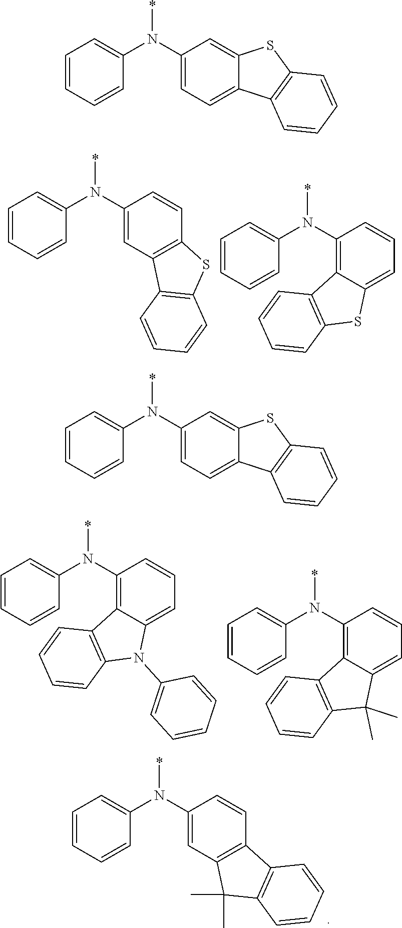

In the structure represented by any one of the formulae (1) and (2-1) to (2-6), R₅, R₆, R₇, R₈, R₉, and R₁₀, at each occurrence, are each independently selected from the group consisting of —H, methyl, tert-butyl, phenyl,

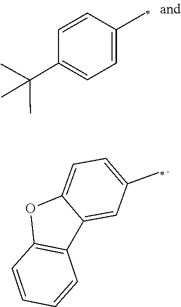

In the structure represented by any one of the formulae (1) and (2-1) to (2-6), R₁, R₂, R₃, R₄, R₅, R₆, R₇, R₈, R₉, R₁₀, R₁₁, R₁₂, R₁₃, and R₁₄ are each preferably tert-butyl, phenyl, and other groups having a relatively large steric hindrance, thereby reducing intermolecular π-π stacking of the organic compound, increasing solubility of the organic compound in the process for manufacturing the light-emitting element, improving efficiency of the light-emitting element to which the organic compound is applied, and prolonging lifetime of the light-emitting element.

In some embodiments, the organic compound is selected from any one of the following compounds:

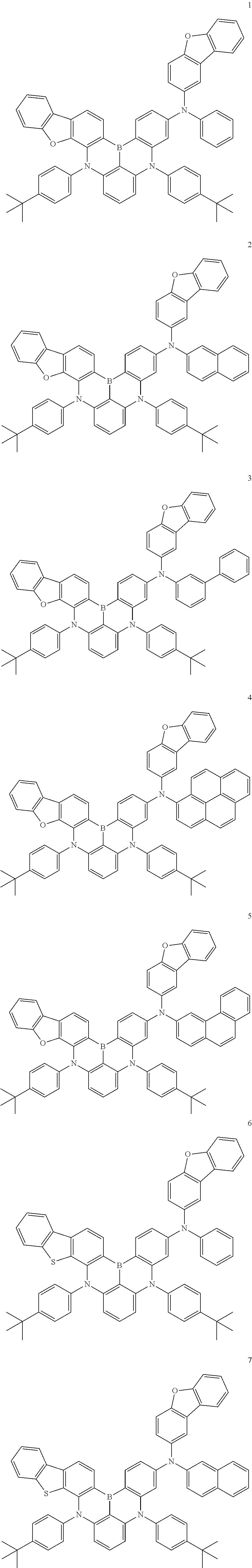

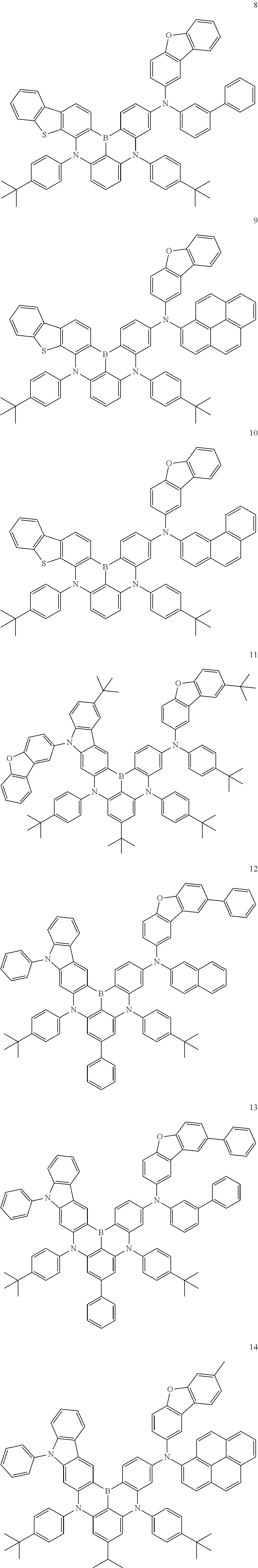

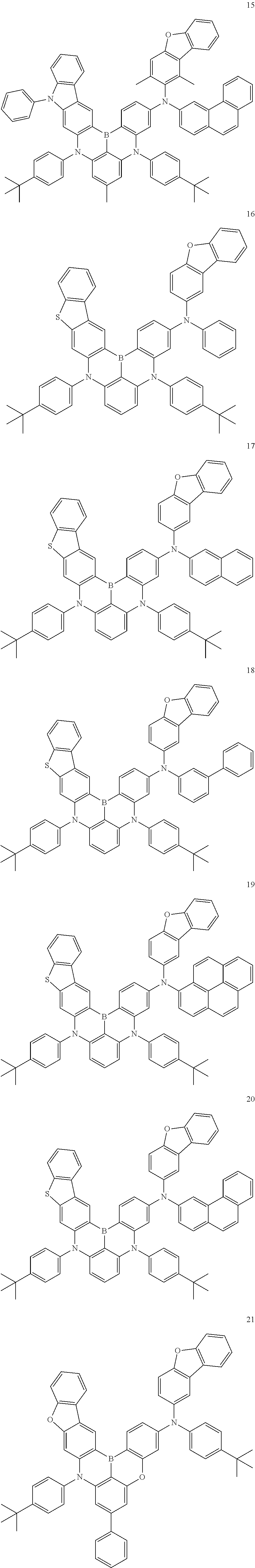

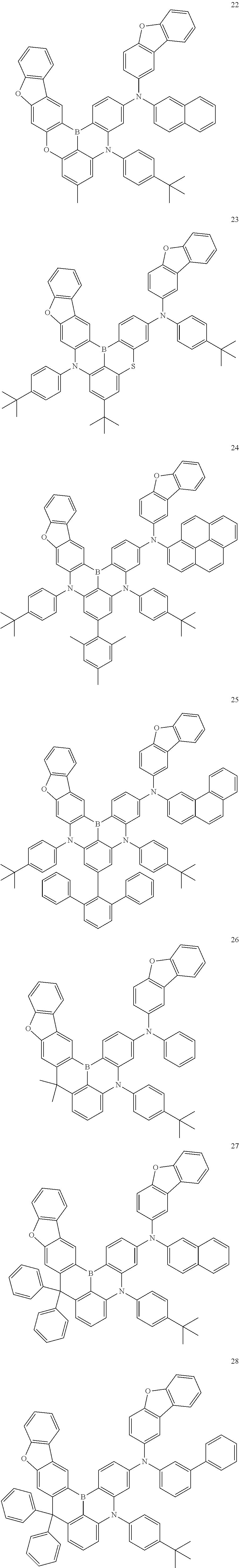

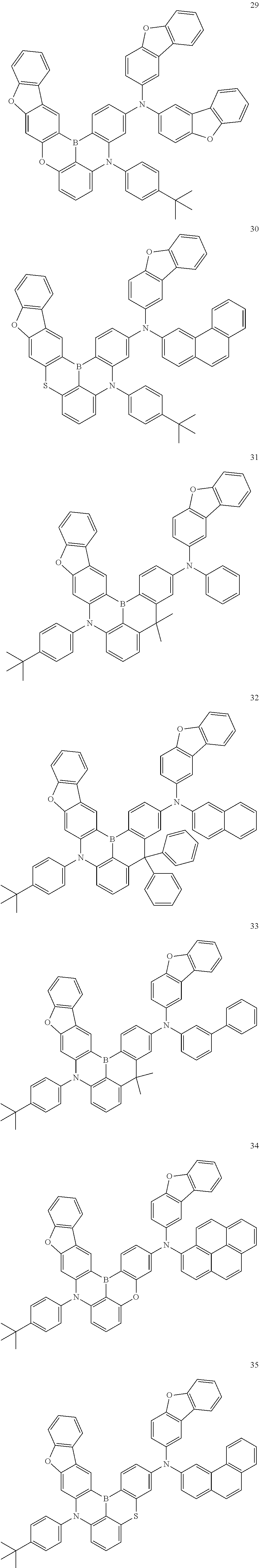

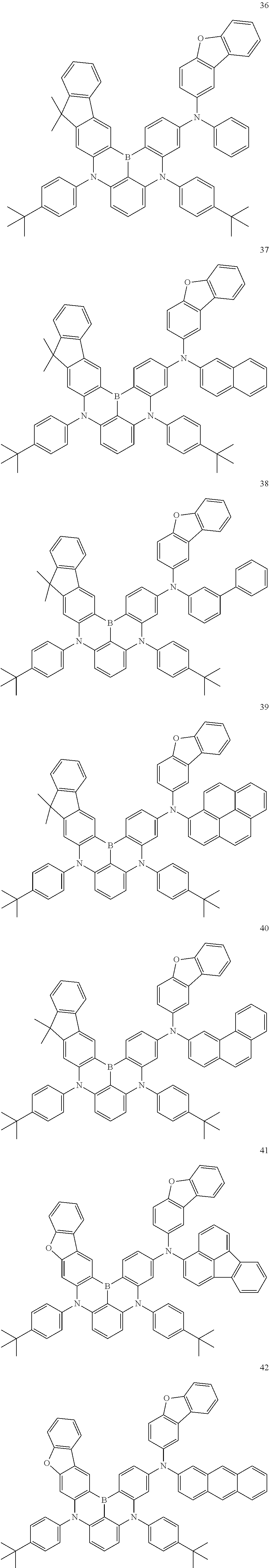

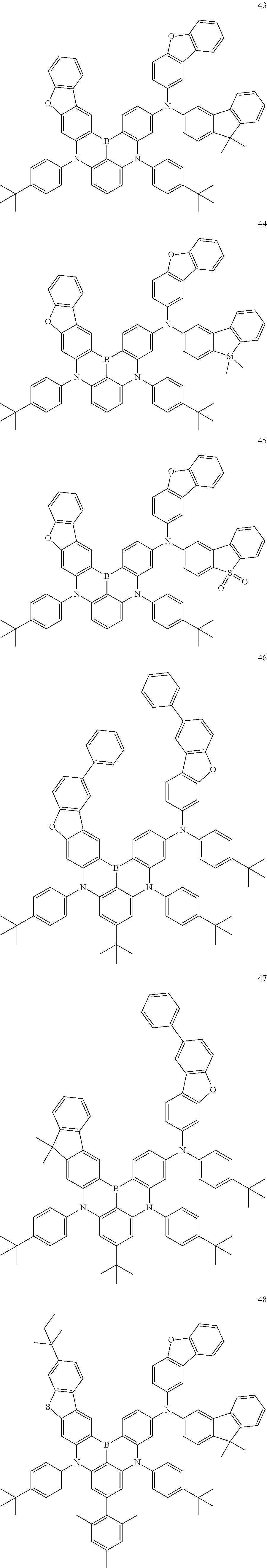

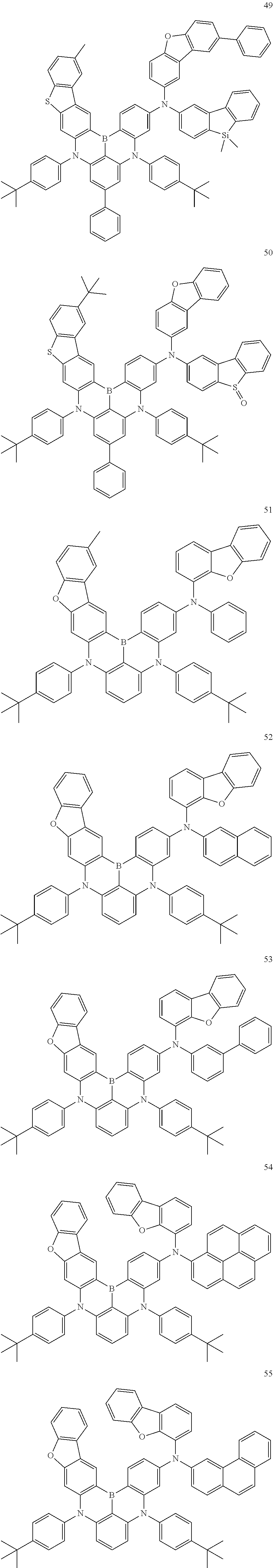

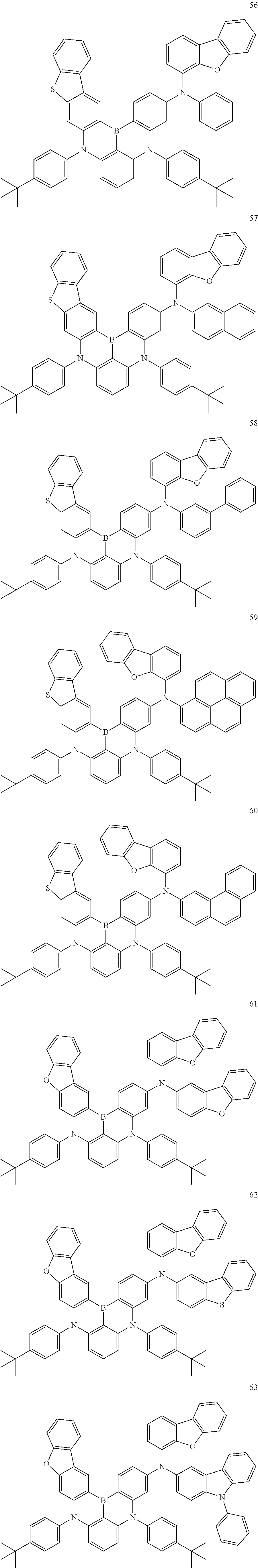

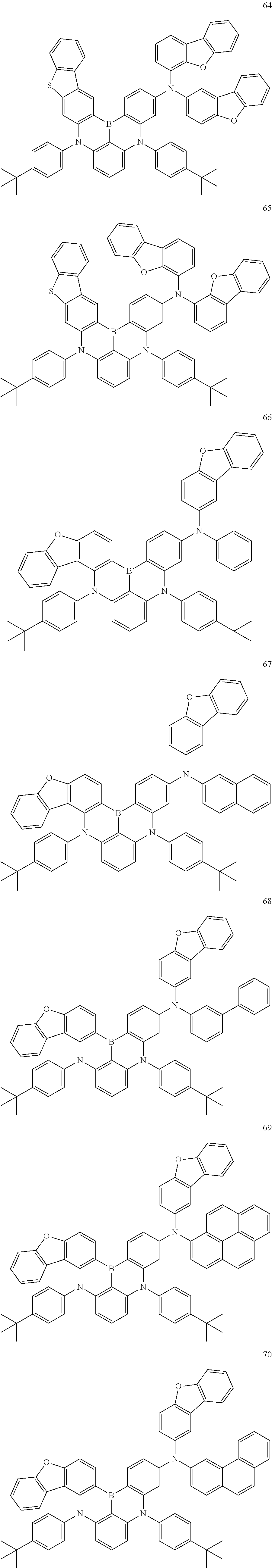

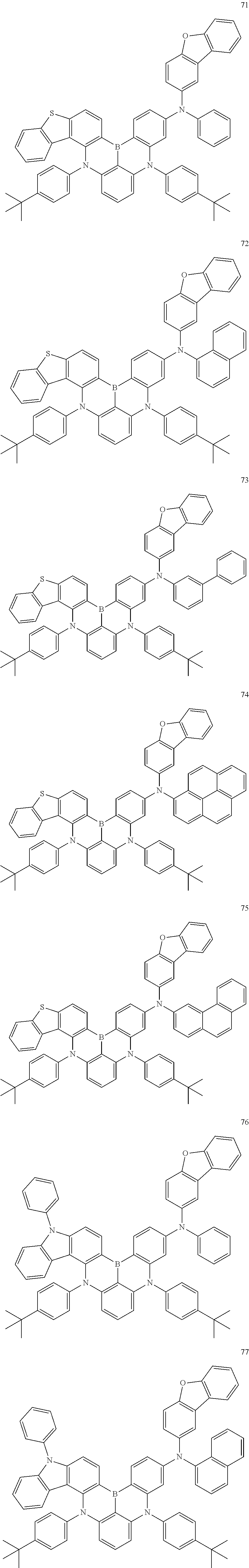

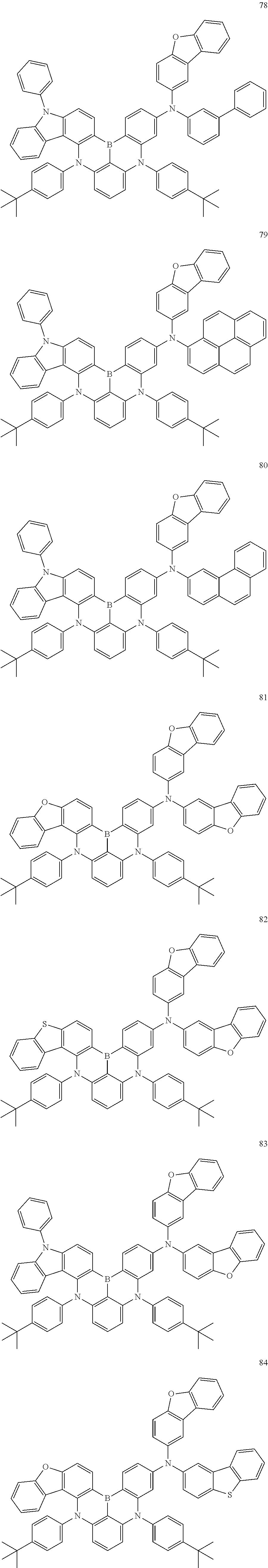

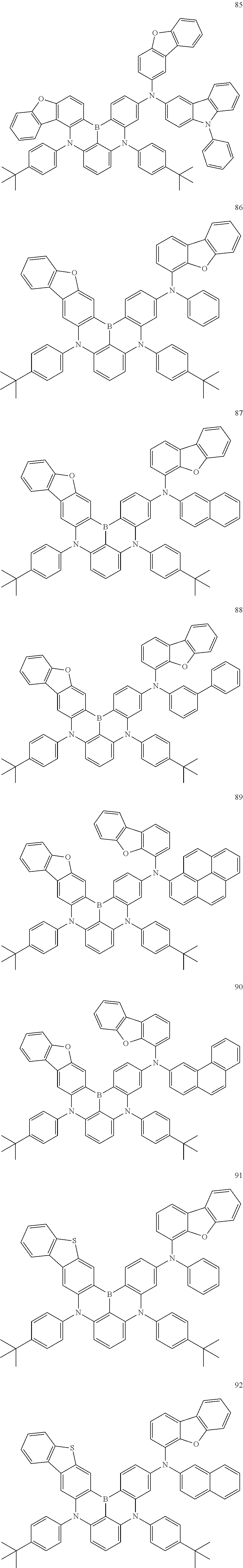

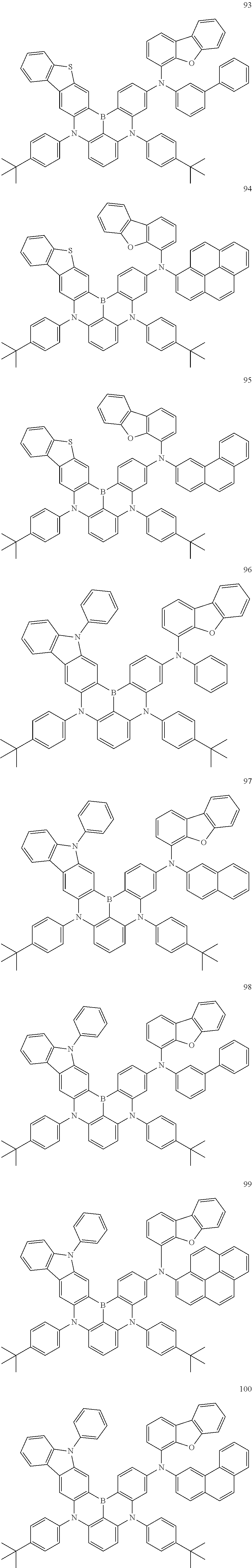

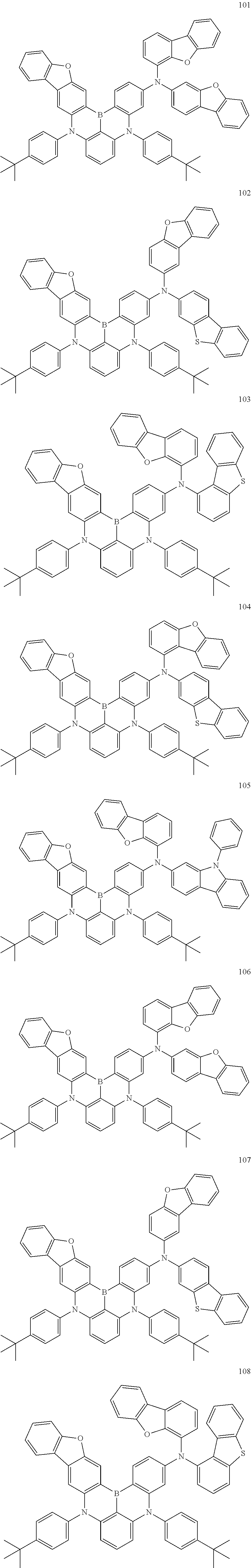

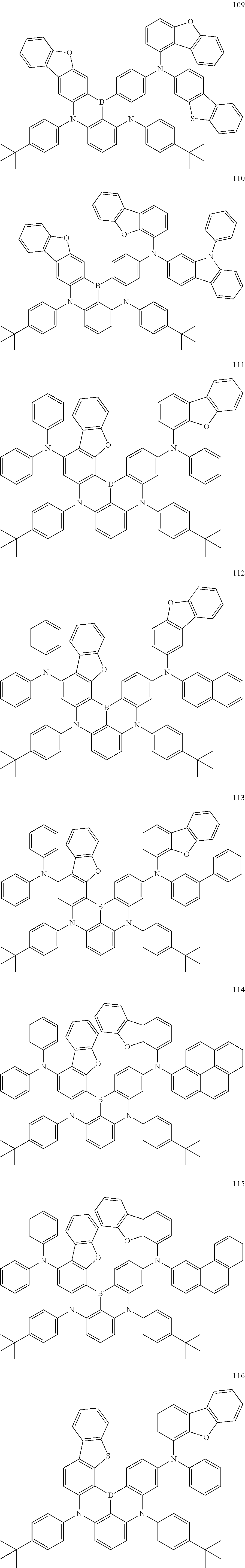

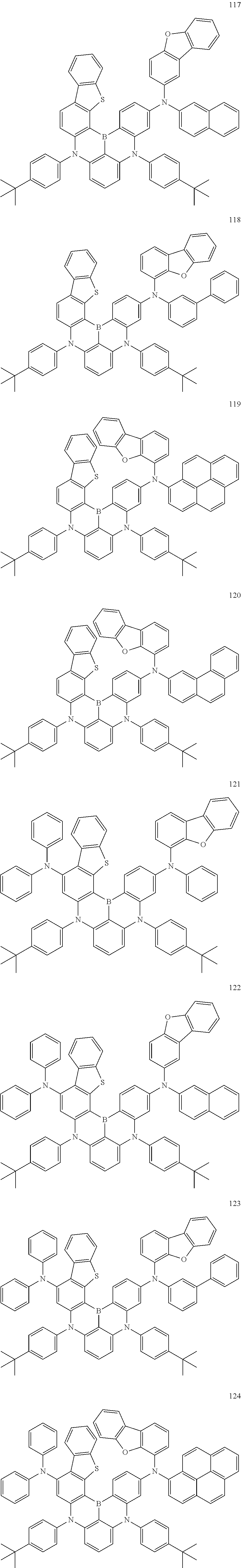

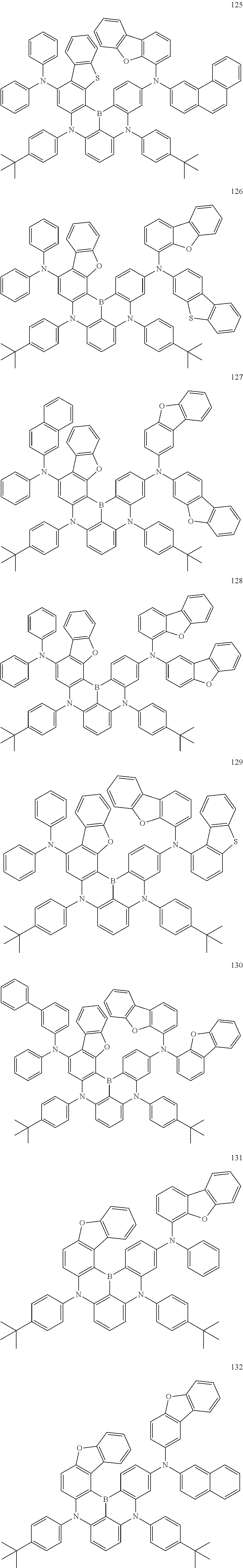

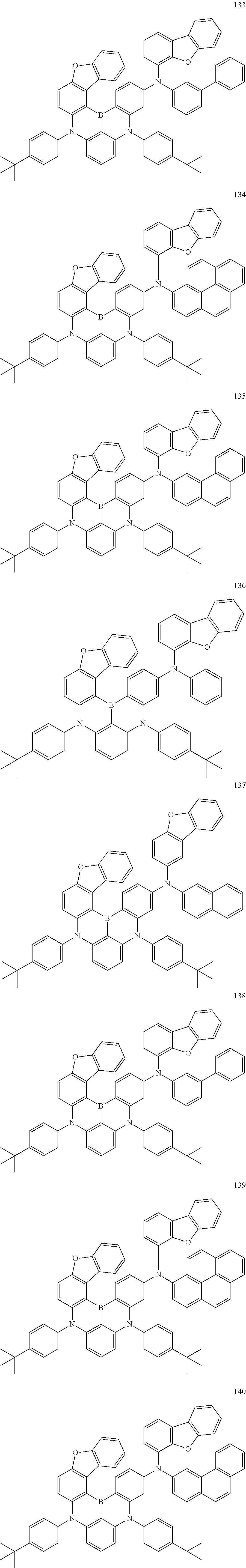

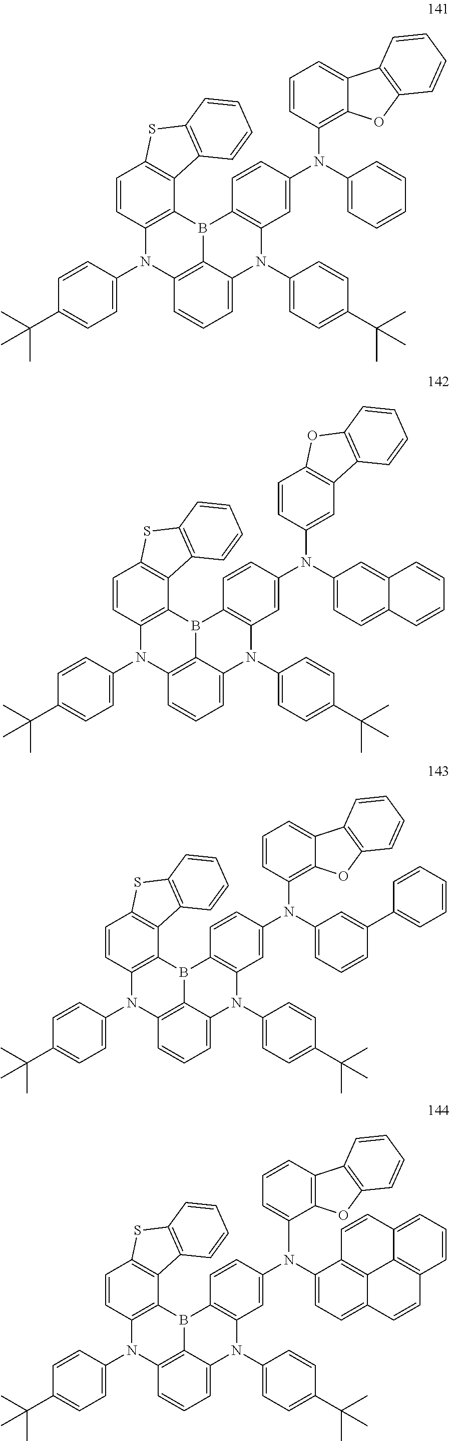 [SMILES: CC(C)(C)c1ccc(N2c3cc(N(c4ccccc4)c4cccc5c4oc4ccccc45)ccc3B3c4c2cccc4N(c2ccc(C(C)(C)C)cc2)c2ccc4sc5ccccc5c4c23)cc1 ; CC(C)(C)c1ccc(N2c3cc(N(c4ccc5ccccc5c4)c4ccc5oc6ccccc6c5c4)ccc3B3c4c2cccc4N(c2ccc(C(C)(C)C)cc2)c2ccc4sc5ccccc5c4c23)cc1 ; CC(C)(C)c1ccc(N2c3cc(N(c4cccc(-c5ccccc5)c4)c4cccc5c4oc4ccccc45)ccc3B3c4c2cccc4N(c2ccc(C(C)(C)C)cc2)c2ccc4sc5ccccc5c4c23)cc1 ; CC(C)(C)c1ccc(N2c3cc(N(c4ccc5ccc6cccc7ccc4c5c67)c4cccc5c4oc4ccccc45)ccc3B3c4c2cccc4N(c2ccc(C(C)(C)C)cc2)c2ccc4sc5ccccc5c4c23)cc1]

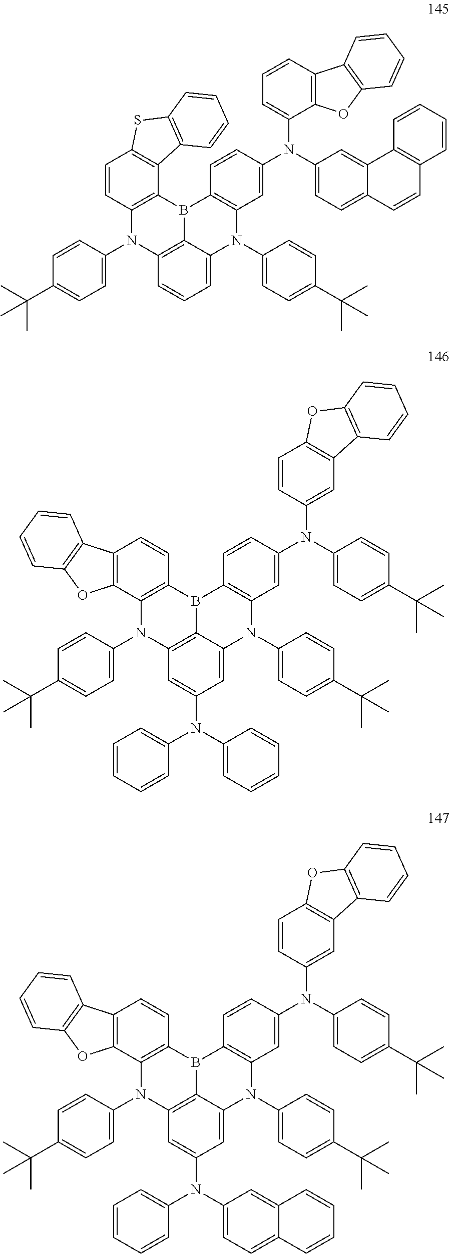

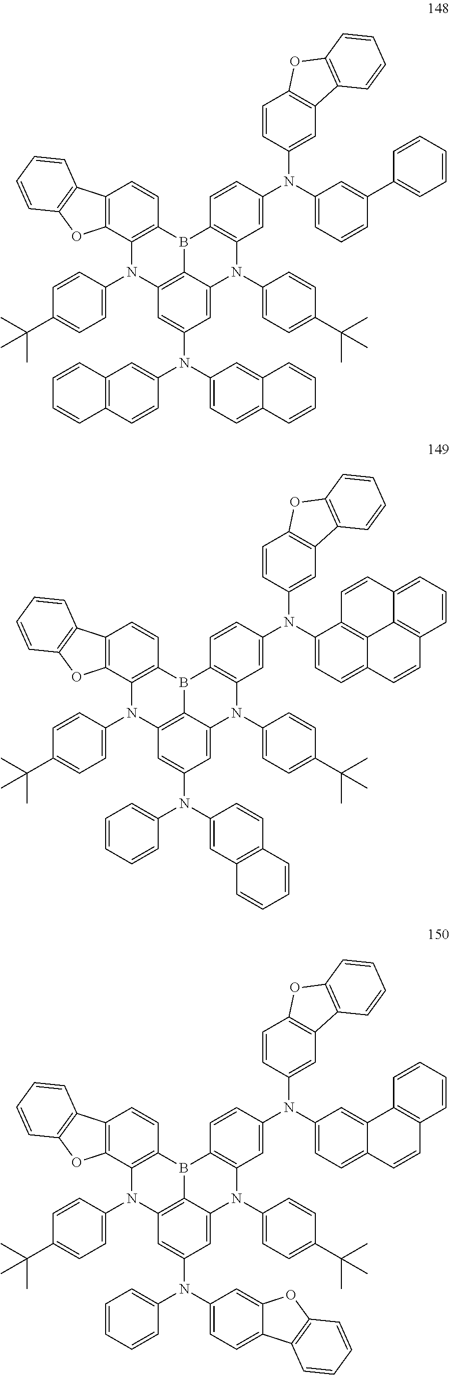 [SMILES: CC(C)(C)c1ccc(N2c3cc(N(c4cccc(-c5ccccc5)c4)c4ccc5oc6ccccc6c5c4)ccc3B3c4ccc5c(oc6ccccc65)c4N(c4ccc(C(C)(C)C)cc4)c4cc(N(c5ccc6ccccc6c5)c5ccc6ccccc6c5)cc2c43)cc1 ; CC(C)(C)c1ccc(N2c3cc(N(c4ccc5oc6ccccc6c5c4)c4ccc5ccc6cccc7ccc4c5c67)ccc3B3c4ccc5c(oc6ccccc65)c4N(c4ccc(C(C)(C)C)cc4)c4cc(N(c5ccccc5)c5ccc6ccccc6c5)cc2c43)cc1 ; CC(C)(C)c1ccc(N2c3cc(N(c4ccc5ccc6ccccc6c5c4)c4ccc5oc6ccccc6c5c4)ccc3B3c4ccc5c(oc6ccccc65)c4N(c4ccc(C(C)(C)C)cc4)c4cc(N(c5ccccc5)c5ccc6c(c5)oc5ccccc56)cc2c43)cc1]

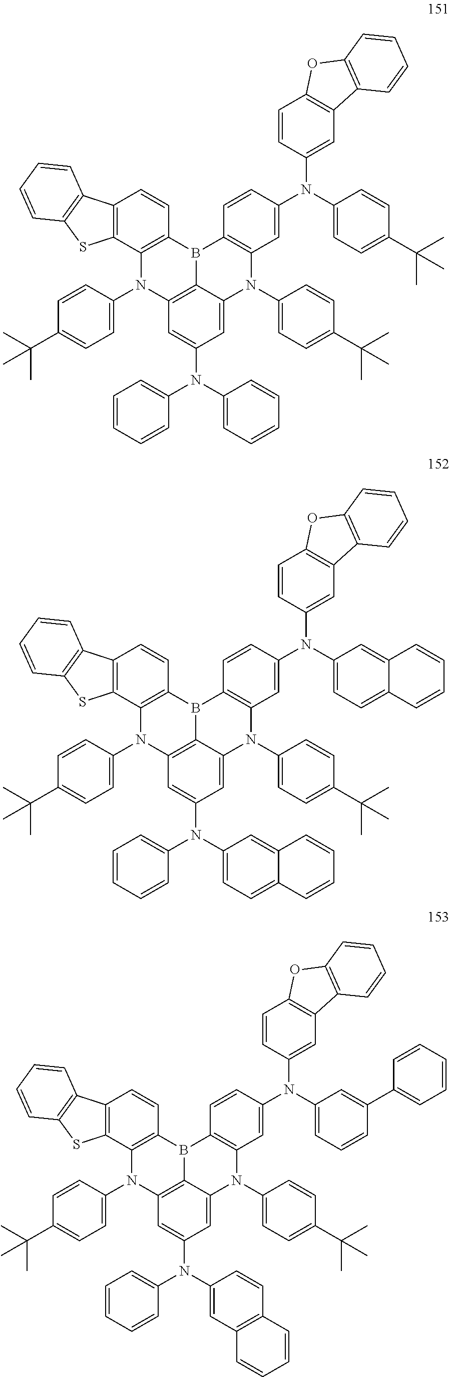

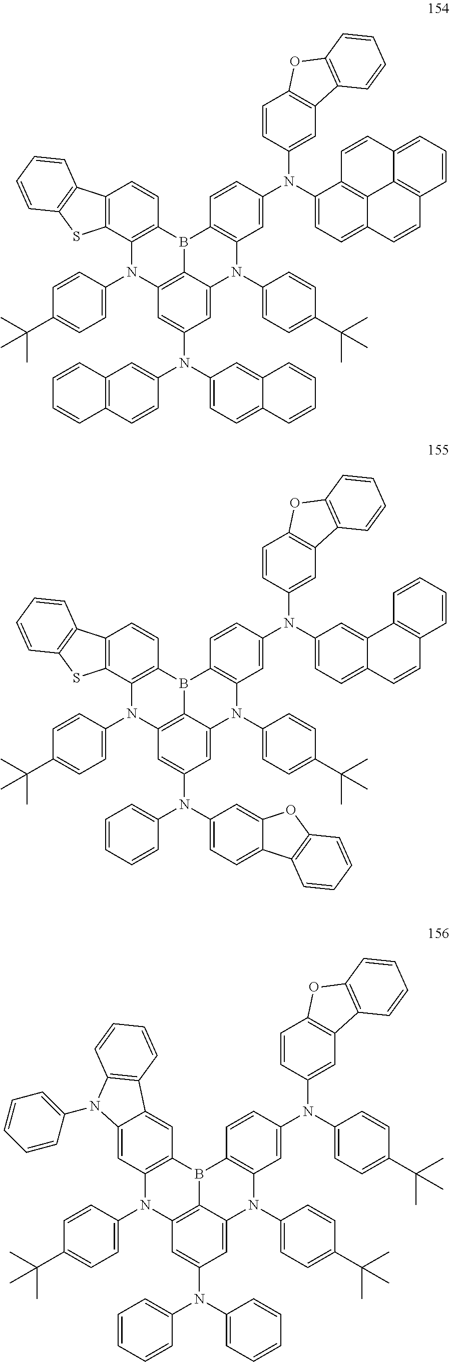 [SMILES: CC(C)(C)c1ccc(N2c3cc(N(c4ccc5oc6ccccc6c5c4)c4ccc5ccc6cccc7ccc4c5c67)ccc3B3c4ccc5c(sc6ccccc65)c4N(c4ccc(C(C)(C)C)cc4)c4cc(N(c5ccc6ccccc6c5)c5ccc6ccccc6c5)cc2c43)cc1 ; CC(C)(C)c1ccc(N2c3cc(N(c4ccc5ccc6ccccc6c5c4)c4ccc5oc6ccccc6c5c4)ccc3B3c4ccc5c(sc6ccccc65)c4N(c4ccc(C(C)(C)C)cc4)c4cc(N(c5ccccc5)c5ccc6c(c5)oc5ccccc56)cc2c43)cc1 ; CC(C)(C)c1ccc(N(c2ccc3c(c2)N(c2ccc(C(C)(C)C)cc2)c2cc(N(c4ccccc4)c4ccccc4)cc4c2B3c2cc3c5ccccc5n(-c5ccccc5)c3cc2N4c2ccc(C(C)(C)C)cc2)c2ccc3oc4ccccc4c3c2)cc1]

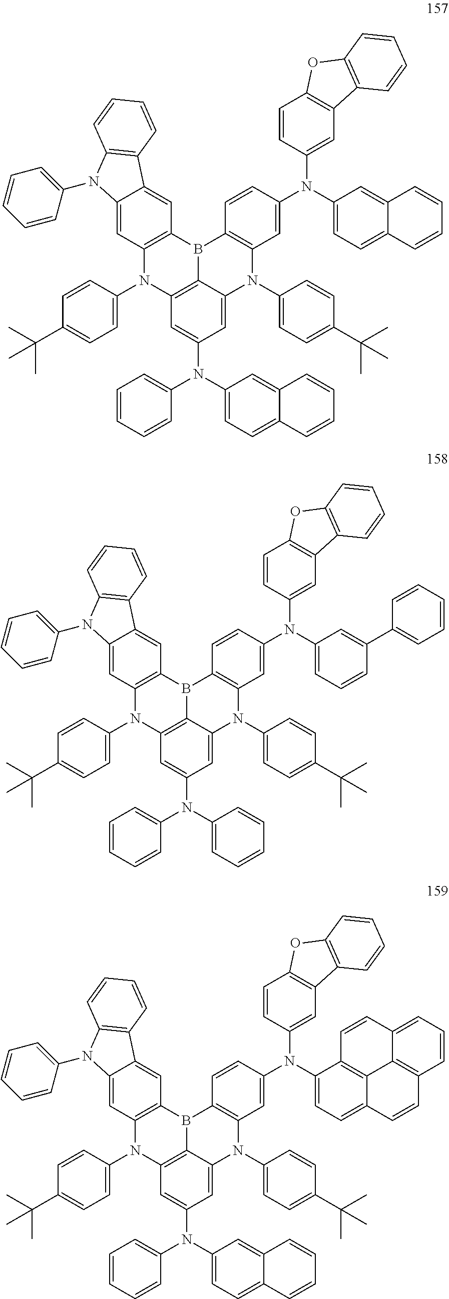 [SMILES: CC(C)(C)c1ccc(N2c3cc(N(c4ccc5ccccc5c4)c4ccc5oc6ccccc6c5c4)ccc3B3c4cc5c6ccccc6n(-c6ccccc6)c5cc4N(c4ccc(C(C)(C)C)cc4)c4cc(N(c5ccccc5)c5ccc6ccccc6c5)cc2c43)cc1 ; CC(C)(C)c1ccc(N2c3cc(N(c4cccc(-c5ccccc5)c4)c4ccc5oc6ccccc6c5c4)ccc3B3c4cc5c6ccccc6n(-c6ccccc6)c5cc4N(c4ccc(C(C)(C)C)cc4)c4cc(N(c5ccccc5)c5ccccc5)cc2c43)cc1 ; CC(C)(C)c1ccc(N2c3cc(N(c4ccc5oc6ccccc6c5c4)c4ccc5ccc6cccc7ccc4c5c67)ccc3B3c4cc5c6ccccc6n(-c6ccccc6)c5cc4N(c4ccc(C(C)(C)C)cc4)c4cc(N(c5ccccc5)c5ccc6ccccc6c5)cc2c43)cc1]

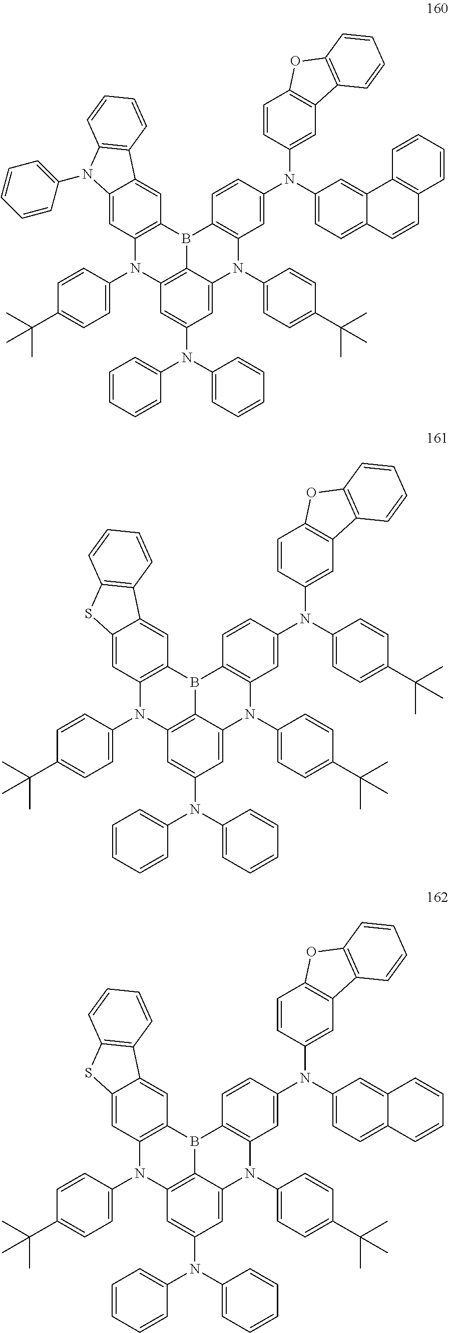

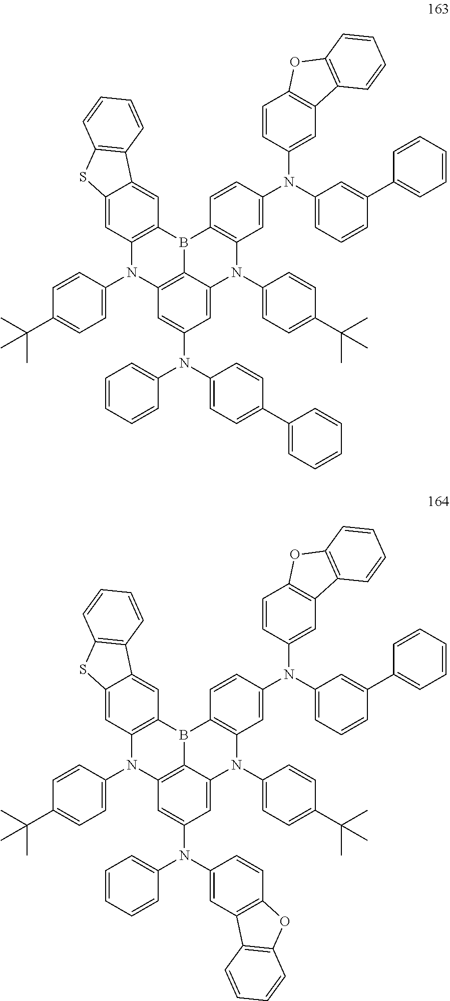 [SMILES: CC(C)(C)c1ccc(N2c3cc(N(c4cccc(-c5ccccc5)c4)c4ccc5oc6ccccc6c5c4)ccc3B3c4cc5c(cc4N(c4ccc(C(C)(C)C)cc4)c4cc(N(c6ccccc6)c6ccc(-c7ccccc7)cc6)cc2c43)sc2ccccc25)cc1 ; CC(C)(C)c1ccc(N2c3cc(N(c4cccc(-c5ccccc5)c4)c4ccc5oc6ccccc6c5c4)ccc3B3c4cc5c(cc4N(c4ccc(C(C)(C)C)cc4)c4cc(N(c6ccccc6)c6ccc7oc8ccccc8c7c6)cc2c43)sc2ccccc25)cc1]

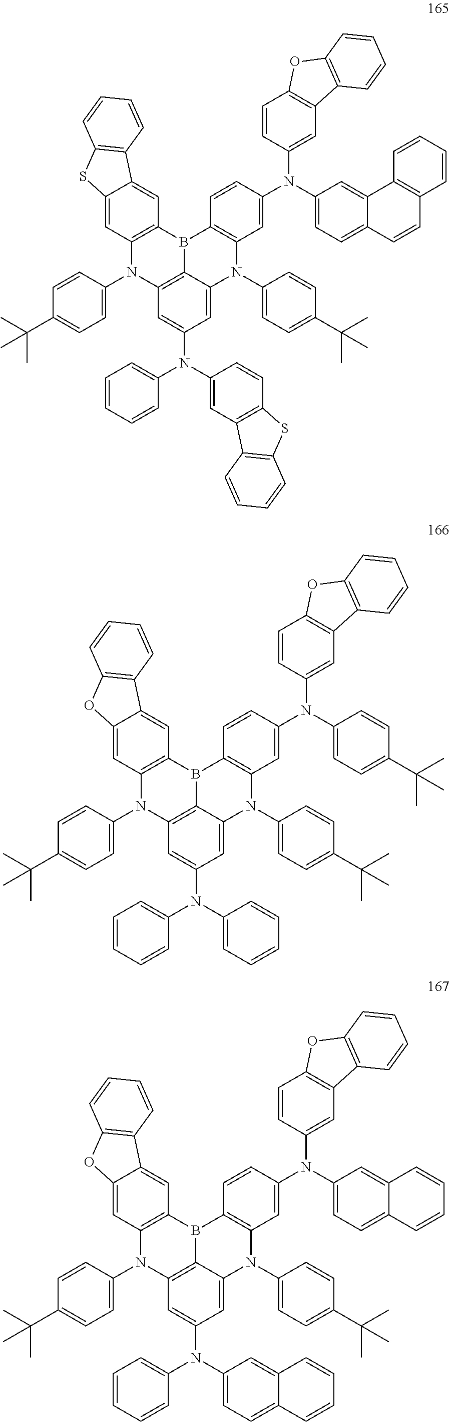

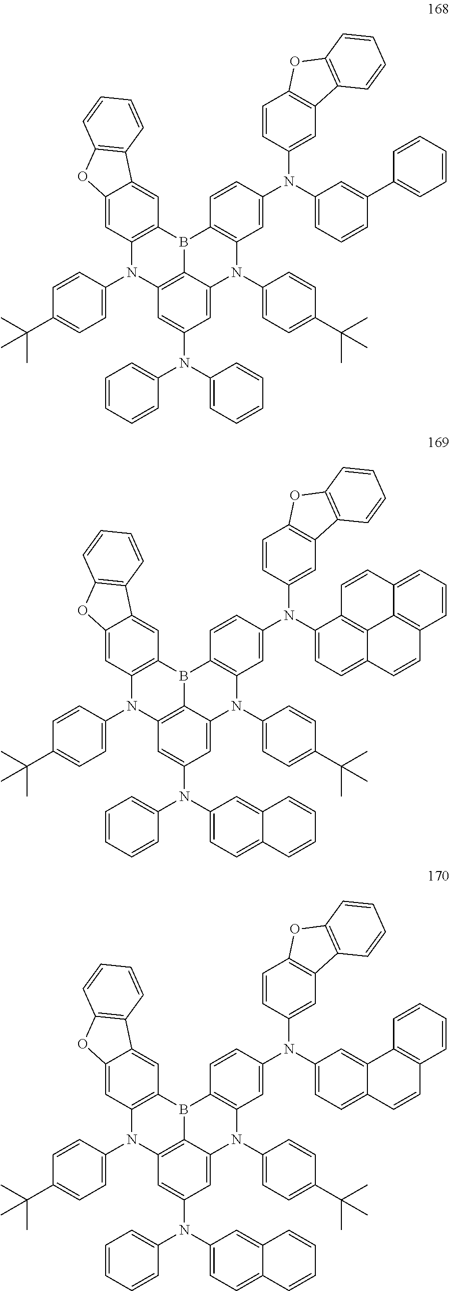 [SMILES: CC(C)(C)c1ccc(N2c3cc(N(c4cccc(-c5ccccc5)c4)c4ccc5oc6ccccc6c5c4)ccc3B3c4cc5c(cc4N(c4ccc(C(C)(C)C)cc4)c4cc(N(c6ccccc6)c6ccccc6)cc2c43)oc2ccccc25)cc1 ; CC(C)(C)c1ccc(N2c3cc(N(c4ccc5oc6ccccc6c5c4)c4ccc5ccc6cccc7ccc4c5c67)ccc3B3c4cc5c(cc4N(c4ccc(C(C)(C)C)cc4)c4cc(N(c6ccccc6)c6ccc7ccccc7c6)cc2c43)oc2ccccc25)cc1 ; CC(C)(C)c1ccc(N2c3cc(N(c4ccc5ccc6ccccc6c5c4)c4ccc5oc6ccccc6c5c4)ccc3B3c4cc5c(cc4N(c4ccc(C(C)(C)C)cc4)c4cc(N(c6ccccc6)c6ccc7ccccc7c6)cc2c43)oc2ccccc25)cc1]

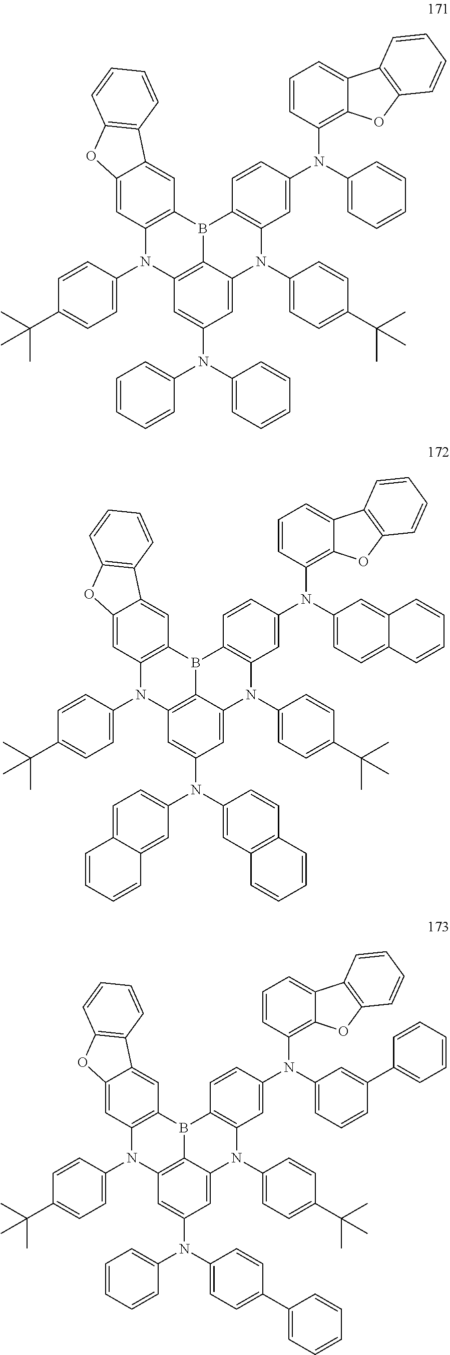 [SMILES: CC(C)(C)c1ccc(N2c3cc(N(c4ccccc4)c4cccc5c4oc4ccccc45)ccc3B3c4cc5c(cc4N(c4ccc(C(C)(C)C)cc4)c4cc(N(c6ccccc6)c6ccccc6)cc2c43)oc2ccccc25)cc1 ; CC(C)(C)c1ccc(N2c3cc(N(c4ccc5ccccc5c4)c4cccc5c4oc4ccccc45)ccc3B3c4cc5c(cc4N(c4ccc(C(C)(C)C)cc4)c4cc(N(c6ccc7ccccc7c6)c6ccc7ccccc7c6)cc2c43)oc2ccccc25)cc1 ; CC(C)(C)c1ccc(N2c3cc(N(c4cccc(-c5ccccc5)c4)c4cccc5c4oc4ccccc45)ccc3B3c4cc5c(cc4N(c4ccc(C(C)(C)C)cc4)c4cc(N(c6ccccc6)c6ccc(-c7ccccc7)cc6)cc2c43)oc2ccccc25)cc1]

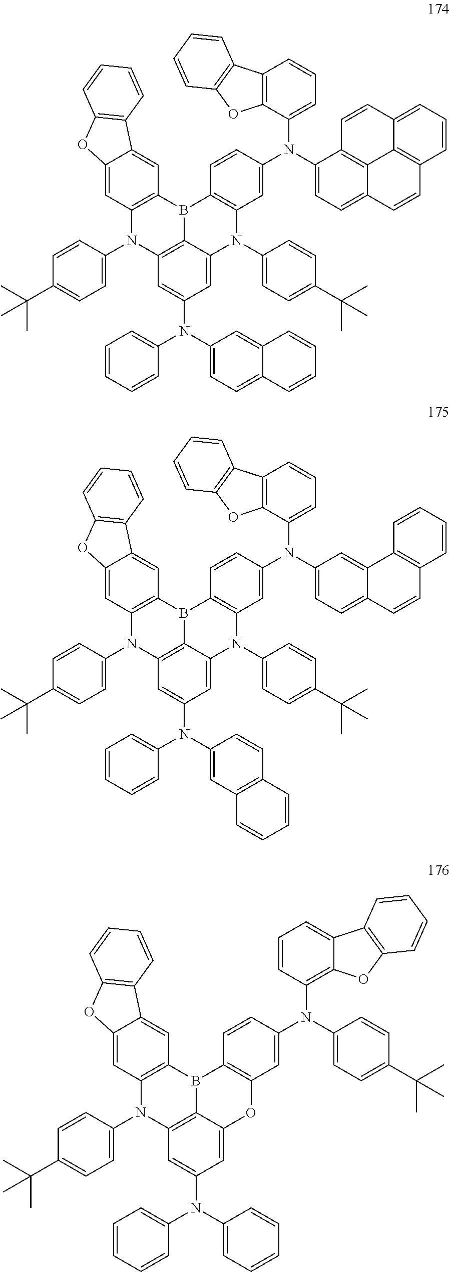 [SMILES: CC(C)(C)c1ccc(N2c3cc(N(c4ccc5ccc6cccc7ccc4c5c67)c4cccc5c4oc4ccccc45)ccc3B3c4cc5c(cc4N(c4ccc(C(C)(C)C)cc4)c4cc(N(c6ccccc6)c6ccc7ccccc7c6)cc2c43)oc2ccccc25)cc1 ; CC(C)(C)c1ccc(N2c3cc(N(c4ccc5ccc6ccccc6c5c4)c4cccc5c4oc4ccccc45)ccc3B3c4cc5c(cc4N(c4ccc(C(C)(C)C)cc4)c4cc(N(c6ccccc6)c6ccc7ccccc7c6)cc2c43)oc2ccccc25)cc1 ; CC(C)(C)c1ccc(N2c3cc4oc5ccccc5c4cc3B3c4ccc(N(c5ccc(C(C)(C)C)cc5)c5cccc6c5oc5ccccc56)cc4Oc4cc(N(c5ccccc5)c5ccccc5)cc2c43)cc1]

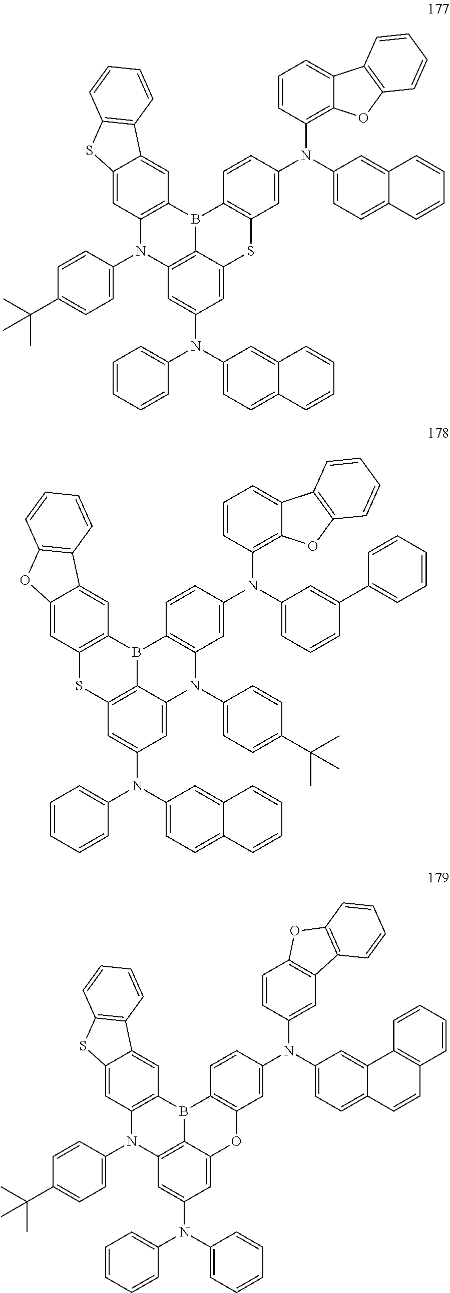 [SMILES: CC(C)(C)c1ccc(N2c3cc4sc5ccccc5c4cc3B3c4ccc(N(c5ccc6ccccc6c5)c5cccc6c5oc5ccccc56)cc4Sc4cc(N(c5ccccc5)c5ccc6ccccc6c5)cc2c43)cc1 ; CC(C)(C)c1ccc(N2c3cc(N(c4cccc(-c5ccccc5)c4)c4cccc5c4oc4ccccc45)ccc3B3c4cc5c(cc4Sc4cc(N(c6ccccc6)c6ccc7ccccc7c6)cc2c43)oc2ccccc25)cc1 ; CC(C)(C)c1ccc(N2c3cc4sc5ccccc5c4cc3B3c4ccc(N(c5ccc6ccc7ccccc7c6c5)c5ccc6oc7ccccc7c6c5)cc4Oc4cc(N(c5ccccc5)c5ccccc5)cc2c43)cc1]

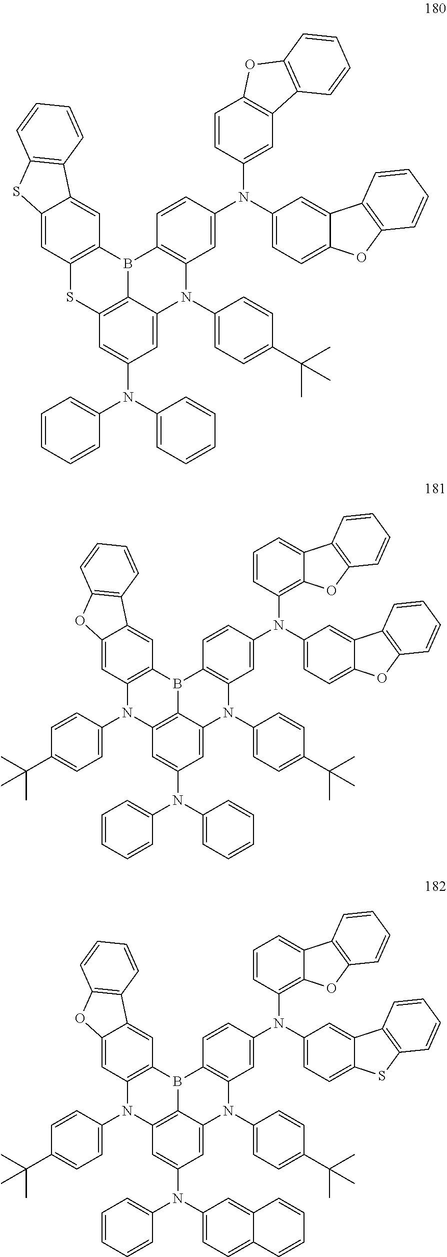 [SMILES: CC(C)(C)c1ccc(N2c3cc(N(c4ccc5oc6ccccc6c5c4)c4ccc5oc6ccccc6c5c4)ccc3B3c4cc5c(cc4Sc4cc(N(c6ccccc6)c6ccccc6)cc2c43)sc2ccccc25)cc1 ; CC(C)(C)c1ccc(N2c3cc(N(c4ccc5oc6ccccc6c5c4)c4cccc5c4oc4ccccc45)ccc3B3c4cc5c(cc4N(c4ccc(C(C)(C)C)cc4)c4cc(N(c6ccccc6)c6ccccc6)cc2c43)oc2ccccc25)cc1 ; CC(C)(C)c1ccc(N2c3cc(N(c4ccc5sc6ccccc6c5c4)c4cccc5c4oc4ccccc45)ccc3B3c4cc5c(cc4N(c4ccc(C(C)(C)C)cc4)c4cc(N(c6ccccc6)c6ccc7ccccc7c6)cc2c43)oc2ccccc25)cc1]

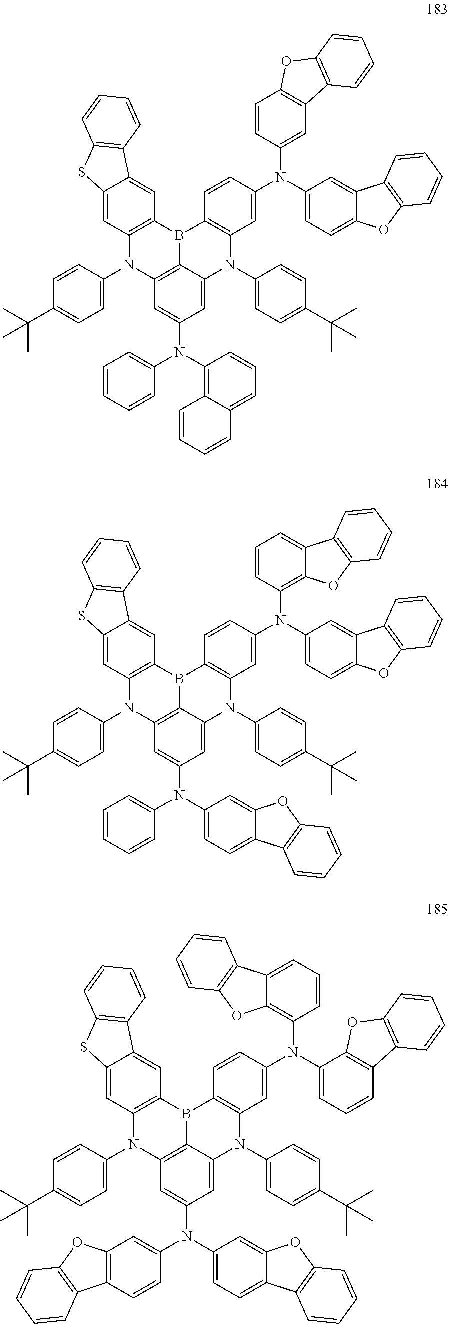 [SMILES: CC(C)(C)c1ccc(N2c3cc(N(c4ccc5oc6ccccc6c5c4)c4ccc5oc6ccccc6c5c4)ccc3B3c4cc5c(cc4N(c4ccc(C(C)(C)C)cc4)c4cc(N(c6ccccc6)c6cccc7ccccc67)cc2c43)sc2ccccc25)cc1 ; CC(C)(C)c1ccc(N2c3cc(N(c4ccc5oc6ccccc6c5c4)c4cccc5c4oc4ccccc45)ccc3B3c4cc5c(cc4N(c4ccc(C(C)(C)C)cc4)c4cc(N(c6ccccc6)c6ccc7c(c6)oc6ccccc67)cc2c43)sc2ccccc25)cc1 ; CC(C)(C)c1ccc(N2c3cc(N(c4cccc5c4oc4ccccc45)c4cccc5c4oc4ccccc45)ccc3B3c4cc5c(cc4N(c4ccc(C(C)(C)C)cc4)c4cc(N(c6ccc7c(c6)oc6ccccc67)c6ccc7c(c6)oc6ccccc67)cc2c43)sc2ccccc25)cc1]

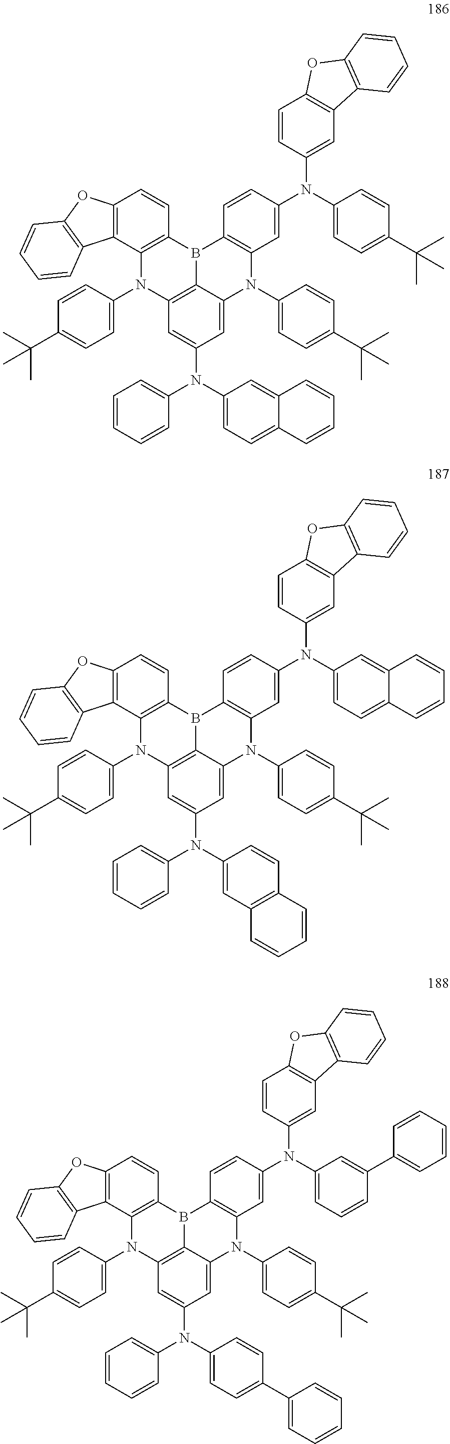

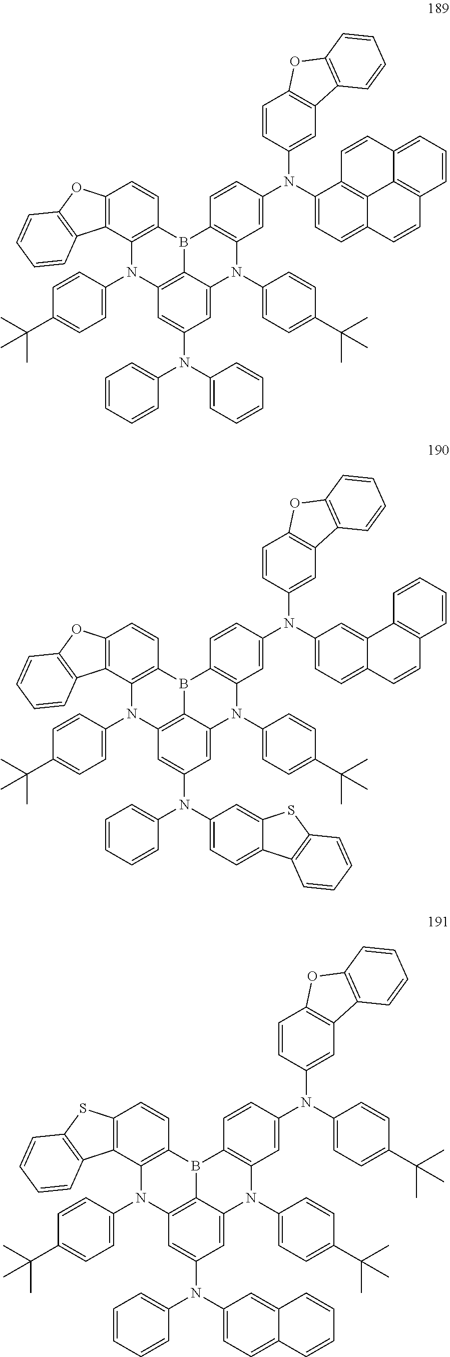 [SMILES: CC(C)(C)c1ccc(N2c3cc(N(c4ccc5oc6ccccc6c5c4)c4ccc5ccc6cccc7ccc4c5c67)ccc3B3c4ccc5oc6ccccc6c5c4N(c4ccc(C(C)(C)C)cc4)c4cc(N(c5ccccc5)c5ccccc5)cc2c43)cc1 ; CC(C)(C)c1ccc(N2c3cc(N(c4ccc5ccc6ccccc6c5c4)c4ccc5oc6ccccc6c5c4)ccc3B3c4ccc5oc6ccccc6c5c4N(c4ccc(C(C)(C)C)cc4)c4cc(N(c5ccccc5)c5ccc6c(c5)sc5ccccc56)cc2c43)cc1 ; CC(C)(C)c1ccc(N(c2ccc3c(c2)N(c2ccc(C(C)(C)C)cc2)c2cc(N(c4ccccc4)c4ccc5ccccc5c4)cc4c2B3c2ccc3sc5ccccc5c3c2N4c2ccc(C(C)(C)C)cc2)c2ccc3oc4ccccc4c3c2)cc1]

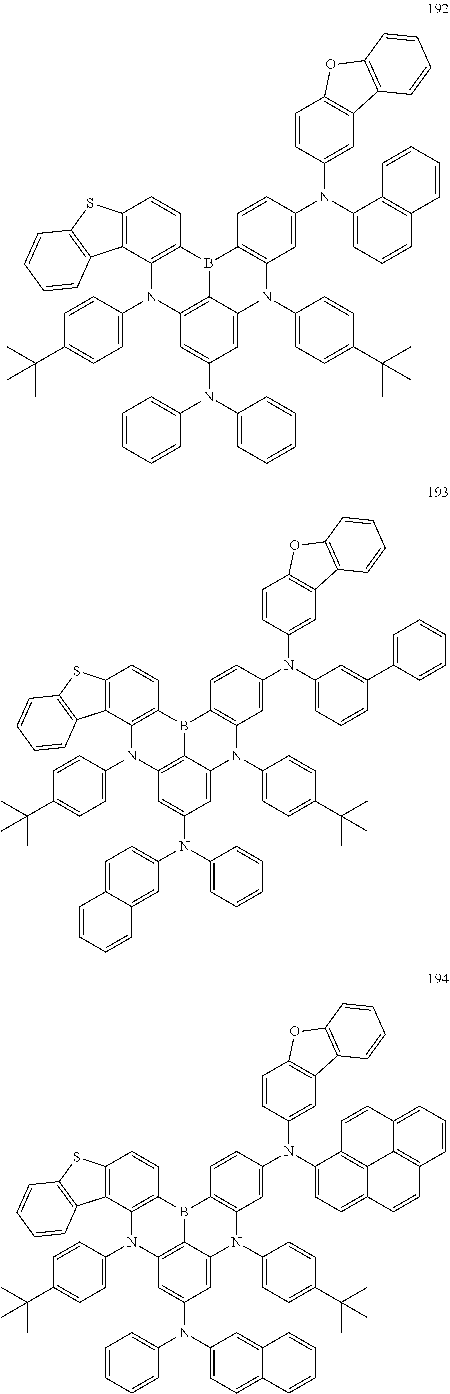 [SMILES: CC(C)(C)c1ccc(N2c3cc(N(c4ccc5oc6ccccc6c5c4)c4cccc5ccccc45)ccc3B3c4ccc5sc6ccccc6c5c4N(c4ccc(C(C)(C)C)cc4)c4cc(N(c5ccccc5)c5ccccc5)cc2c43)cc1 ; CC(C)(C)c1ccc(N2c3cc(N(c4cccc(-c5ccccc5)c4)c4ccc5oc6ccccc6c5c4)ccc3B3c4ccc5sc6ccccc6c5c4N(c4ccc(C(C)(C)C)cc4)c4cc(N(c5ccccc5)c5ccc6ccccc6c5)cc2c43)cc1 ; CC(C)(C)c1ccc(N2c3cc(N(c4ccc5oc6ccccc6c5c4)c4ccc5ccc6cccc7ccc4c5c67)ccc3B3c4ccc5sc6ccccc6c5c4N(c4ccc(C(C)(C)C)cc4)c4cc(N(c5ccccc5)c5ccc6ccccc6c5)cc2c43)cc1]

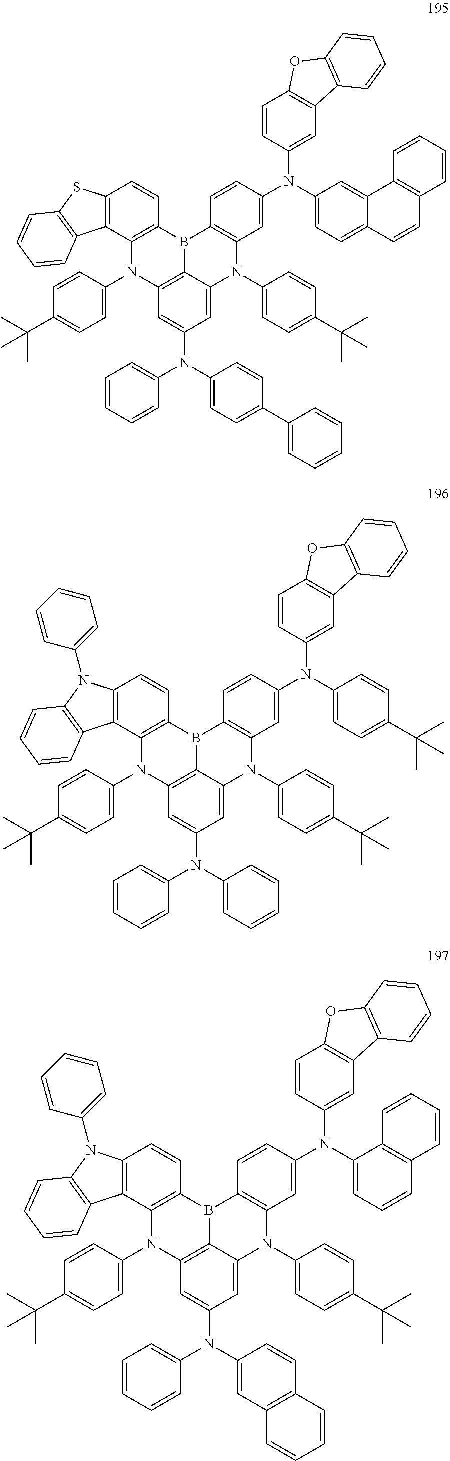

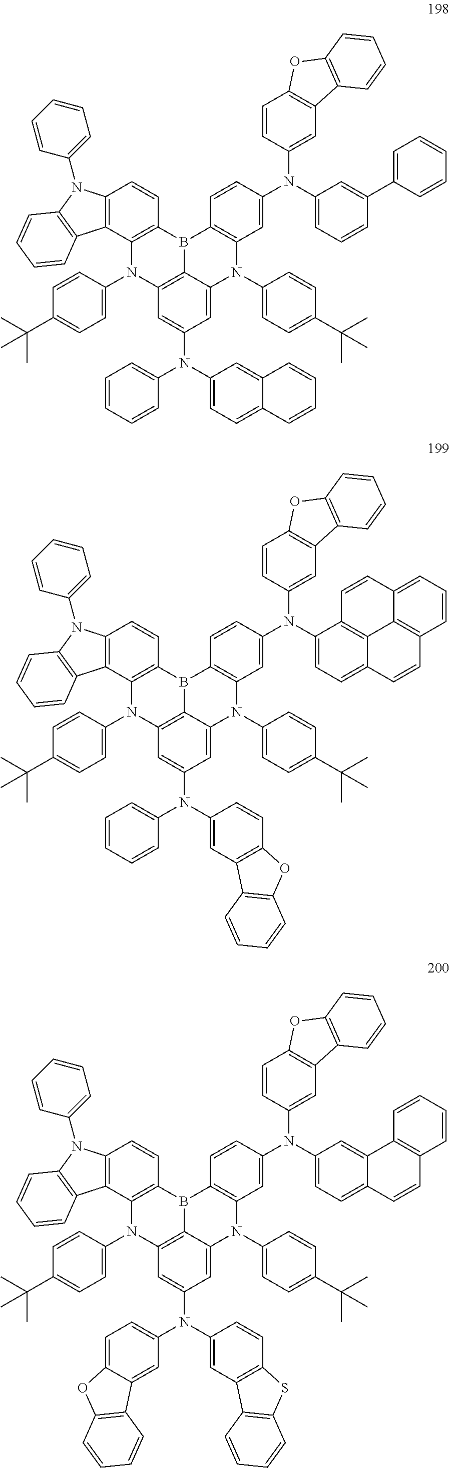

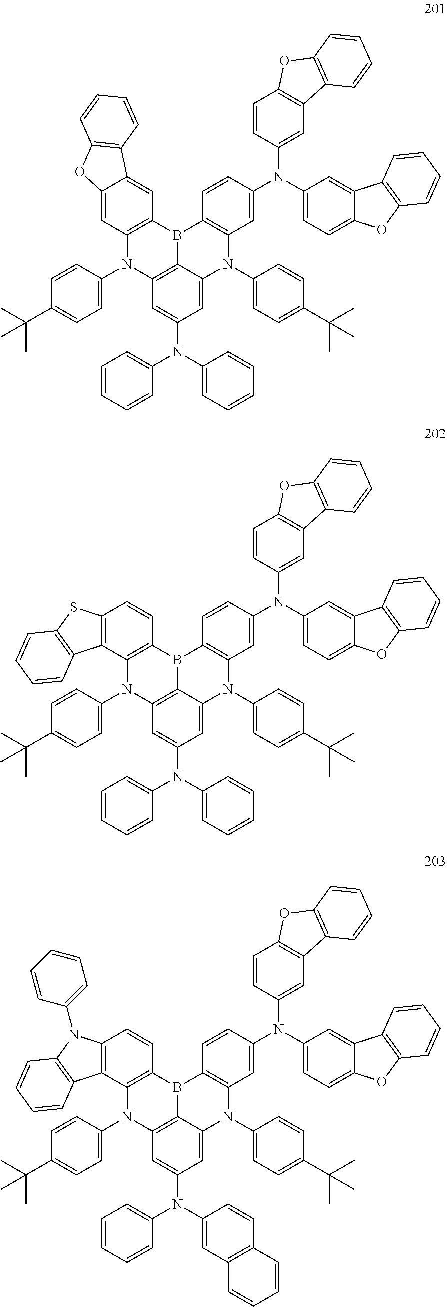 [SMILES: CC(C)(C)c1ccc(N2c3cc(N(c4ccc5oc6ccccc6c5c4)c4ccc5oc6ccccc6c5c4)ccc3B3c4cc5c(cc4N(c4ccc(C(C)(C)C)cc4)c4cc(N(c6ccccc6)c6ccccc6)cc2c43)oc2ccccc25)cc1 ; CC(C)(C)c1ccc(N2c3cc(N(c4ccc5oc6ccccc6c5c4)c4ccc5oc6ccccc6c5c4)ccc3B3c4ccc5sc6ccccc6c5c4N(c4ccc(C(C)(C)C)cc4)c4cc(N(c5ccccc5)c5ccccc5)cc2c43)cc1 ; CC(C)(C)c1ccc(N2c3cc(N(c4ccc5oc6ccccc6c5c4)c4ccc5oc6ccccc6c5c4)ccc3B3c4ccc5c(c4N(c4ccc(C(C)(C)C)cc4)c4cc(N(c6ccccc6)c6ccc7ccccc7c6)cc2c43)c2ccccc2n5-c2ccccc2)cc1]

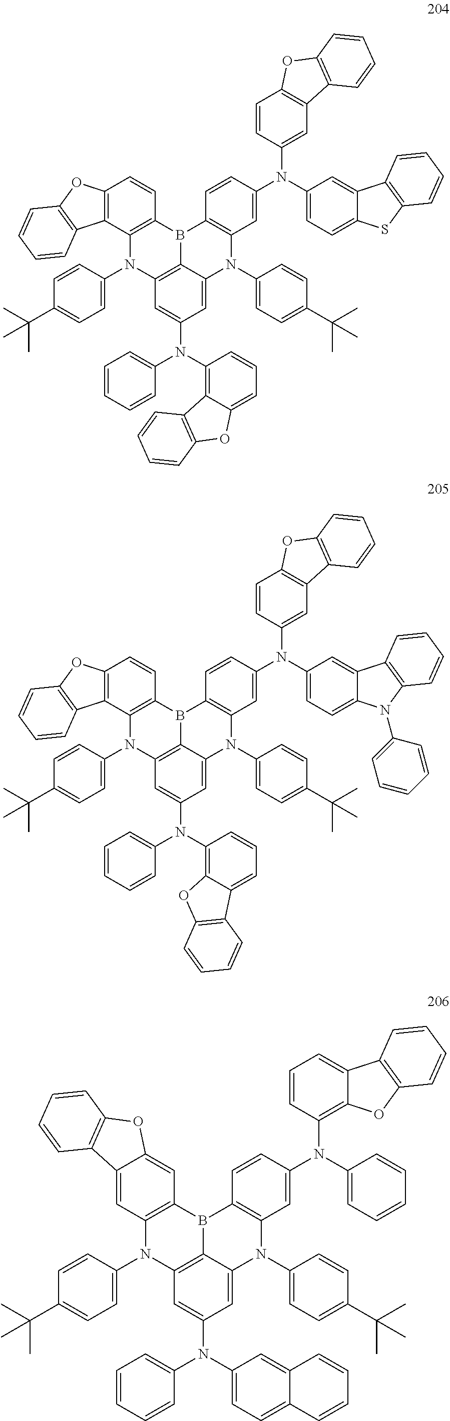 [SMILES: CC(C)(C)c1ccc(N2c3cc(N(c4ccc5oc6ccccc6c5c4)c4ccc5sc6ccccc6c5c4)ccc3B3c4ccc5oc6ccccc6c5c4N(c4ccc(C(C)(C)C)cc4)c4cc(N(c5ccccc5)c5cccc6oc7ccccc7c56)cc2c43)cc1 ; CC(C)(C)c1ccc(N2c3cc(N(c4ccc5oc6ccccc6c5c4)c4ccc5c(c4)c4ccccc4n5-c4ccccc4)ccc3B3c4ccc5oc6ccccc6c5c4N(c4ccc(C(C)(C)C)cc4)c4cc(N(c5ccccc5)c5cccc6c5oc5ccccc56)cc2c43)cc1 ; CC(C)(C)c1ccc(N2c3cc(N(c4ccccc4)c4cccc5c4oc4ccccc45)ccc3B3c4cc5oc6ccccc6c5cc4N(c4ccc(C(C)(C)C)cc4)c4cc(N(c5ccccc5)c5ccc6ccccc6c5)cc2c43)cc1]

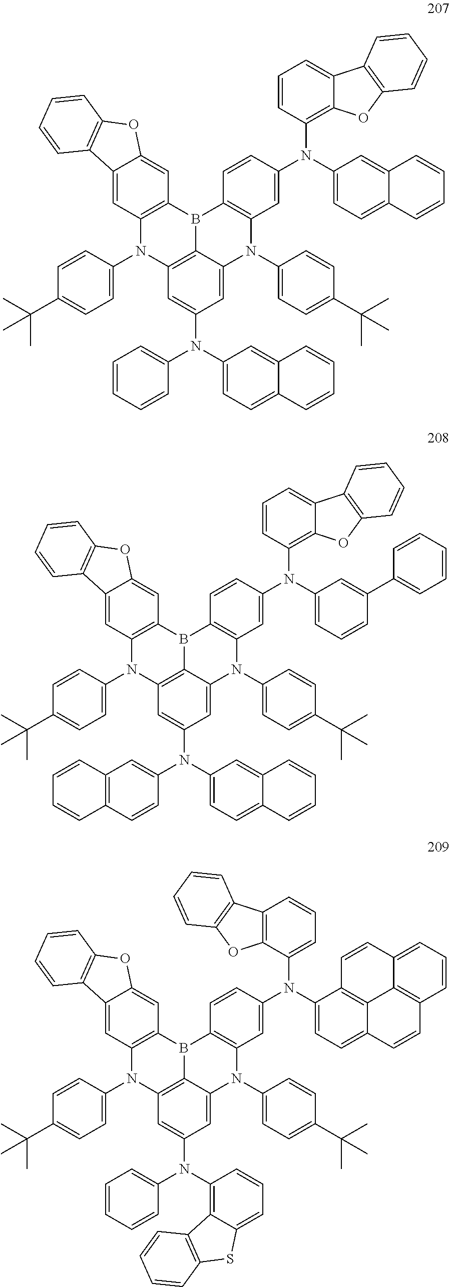 [SMILES: CC(C)(C)c1ccc(N2c3cc(N(c4ccc5ccccc5c4)c4cccc5c4oc4ccccc45)ccc3B3c4cc5oc6ccccc6c5cc4N(c4ccc(C(C)(C)C)cc4)c4cc(N(c5ccccc5)c5ccc6ccccc6c5)cc2c43)cc1 ; CC(C)(C)c1ccc(N2c3cc(N(c4cccc(-c5ccccc5)c4)c4cccc5c4oc4ccccc45)ccc3B3c4cc5oc6ccccc6c5cc4N(c4ccc(C(C)(C)C)cc4)c4cc(N(c5ccc6ccccc6c5)c5ccc6ccccc6c5)cc2c43)cc1 ; CC(C)(C)c1ccc(N2c3cc(N(c4ccc5ccc6cccc7ccc4c5c67)c4cccc5c4oc4ccccc45)ccc3B3c4cc5oc6ccccc6c5cc4N(c4ccc(C(C)(C)C)cc4)c4cc(N(c5ccccc5)c5cccc6sc7ccccc7c56)cc2c43)cc1]

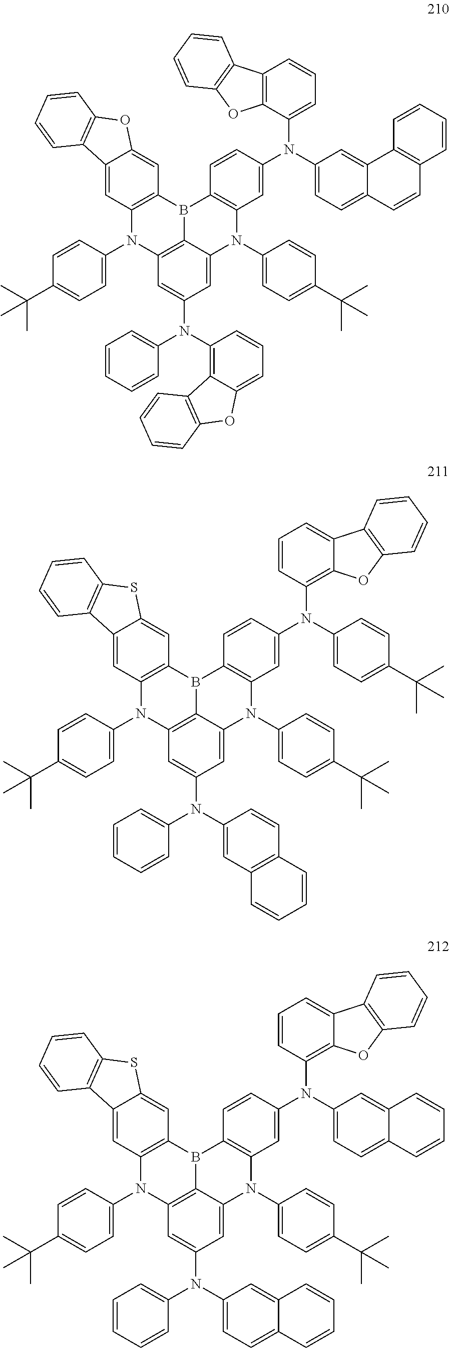

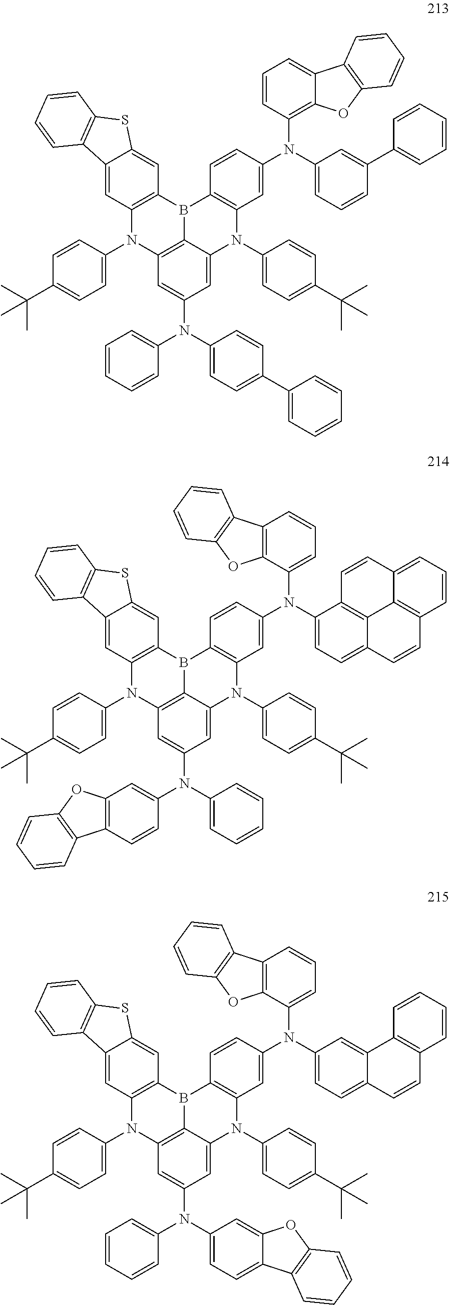 [SMILES: CC(C)(C)c1ccc(N2c3cc(N(c4cccc(-c5ccccc5)c4)c4cccc5c4oc4ccccc45)ccc3B3c4cc5sc6ccccc6c5cc4N(c4ccc(C(C)(C)C)cc4)c4cc(N(c5ccccc5)c5ccc(-c6ccccc6)cc5)cc2c43)cc1 ; CC(C)(C)c1ccc(N2c3cc(N(c4ccc5ccc6cccc7ccc4c5c67)c4cccc5c4oc4ccccc45)ccc3B3c4cc5sc6ccccc6c5cc4N(c4ccc(C(C)(C)C)cc4)c4cc(N(c5ccccc5)c5ccc6c(c5)oc5ccccc56)cc2c43)cc1 ; CC(C)(C)c1ccc(N2c3cc(N(c4ccc5ccc6ccccc6c5c4)c4cccc5c4oc4ccccc45)ccc3B3c4cc5sc6ccccc6c5cc4N(c4ccc(C(C)(C)C)cc4)c4cc(N(c5ccccc5)c5ccc6c(c5)oc5ccccc56)cc2c43)cc1]

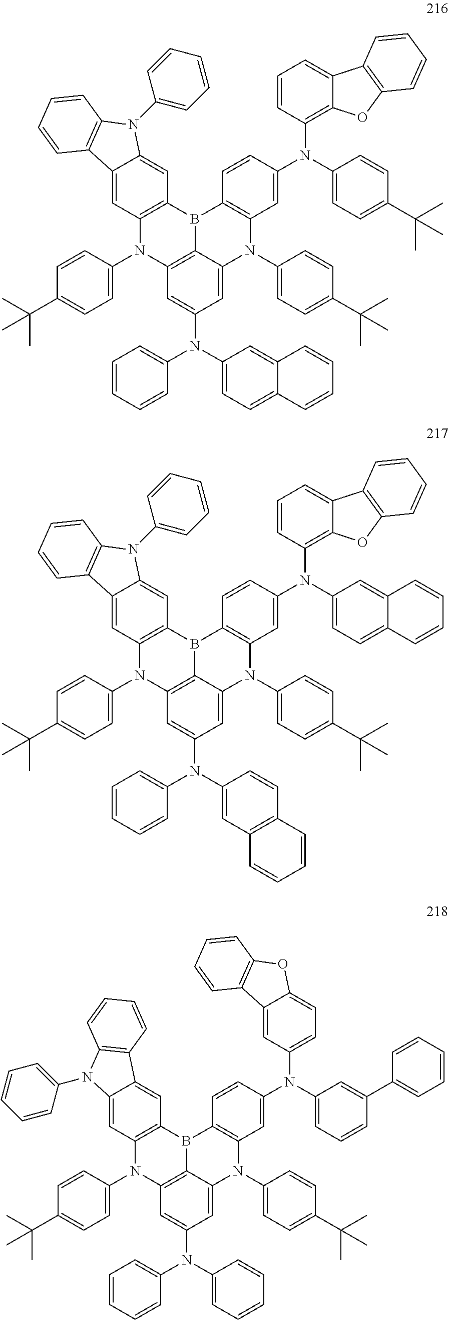

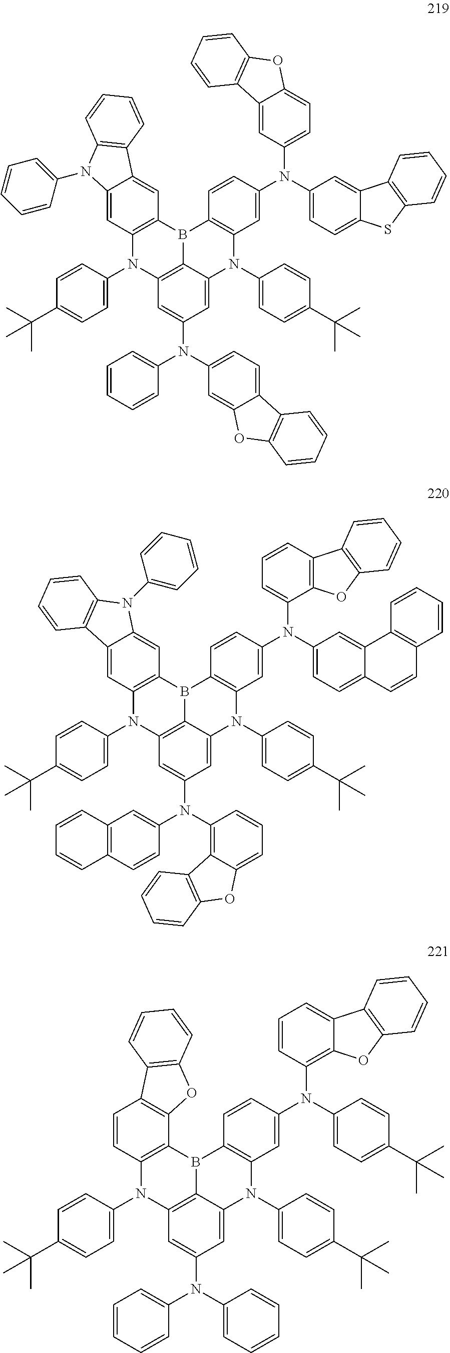 [SMILES: CC(C)(C)c1ccc(N2c3cc(N(c4ccc5oc6ccccc6c5c4)c4ccc5sc6ccccc6c5c4)ccc3B3c4cc5c6ccccc6n(-c6ccccc6)c5cc4N(c4ccc(C(C)(C)C)cc4)c4cc(N(c5ccccc5)c5ccc6c(c5)oc5ccccc56)cc2c43)cc1 ; CC(C)(C)c1ccc(N2c3cc(N(c4ccc5ccc6ccccc6c5c4)c4cccc5c4oc4ccccc45)ccc3B3c4cc5c(cc4N(c4ccc(C(C)(C)C)cc4)c4cc(N(c6ccc7ccccc7c6)c6cccc7oc8ccccc8c67)cc2c43)c2ccccc2n5-c2ccccc2)cc1 ; CC(C)(C)c1ccc(N2c3cc(N(c4ccc(C(C)(C)C)cc4)c4cccc5c4oc4ccccc45)ccc3B3c4c2cc(N(c2ccccc2)c2ccccc2)cc4N(c2ccc(C(C)(C)C)cc2)c2ccc4c(oc5ccccc54)c23)cc1]

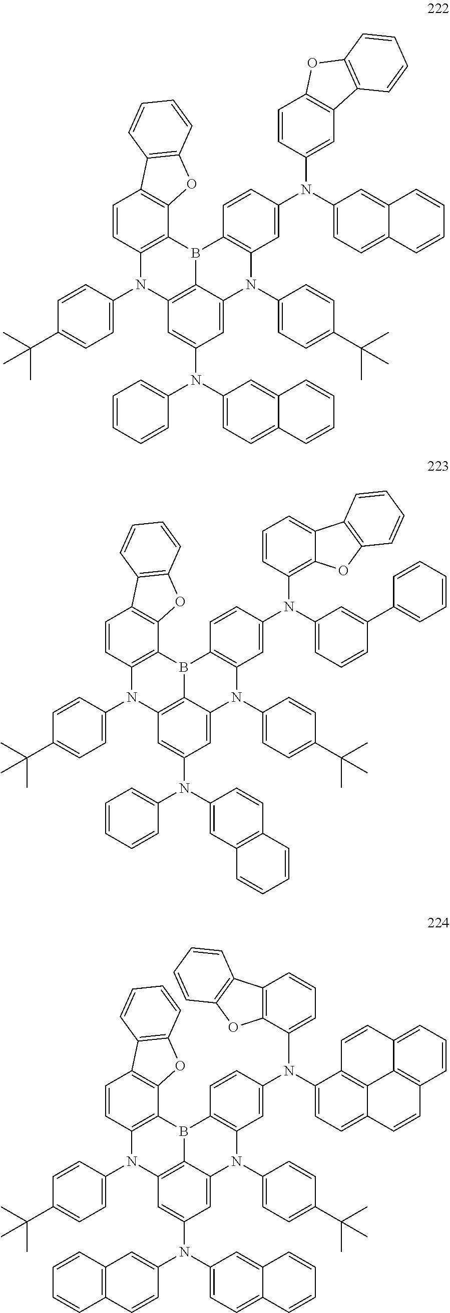 [SMILES: CC(C)(C)c1ccc(N2c3cc(N(c4ccc5ccccc5c4)c4ccc5oc6ccccc6c5c4)ccc3B3c4c2cc(N(c2ccccc2)c2ccc5ccccc5c2)cc4N(c2ccc(C(C)(C)C)cc2)c2ccc4c(oc5ccccc54)c23)cc1 ; CC(C)(C)c1ccc(N2c3cc(N(c4cccc(-c5ccccc5)c4)c4cccc5c4oc4ccccc45)ccc3B3c4c2cc(N(c2ccccc2)c2ccc5ccccc5c2)cc4N(c2ccc(C(C)(C)C)cc2)c2ccc4c(oc5ccccc54)c23)cc1 ; CC(C)(C)c1ccc(N2c3cc(N(c4ccc5ccc6cccc7ccc4c5c67)c4cccc5c4oc4ccccc45)ccc3B3c4c2cc(N(c2ccc5ccccc5c2)c2ccc5ccccc5c2)cc4N(c2ccc(C(C)(C)C)cc2)c2ccc4c(oc5ccccc54)c23)cc1]

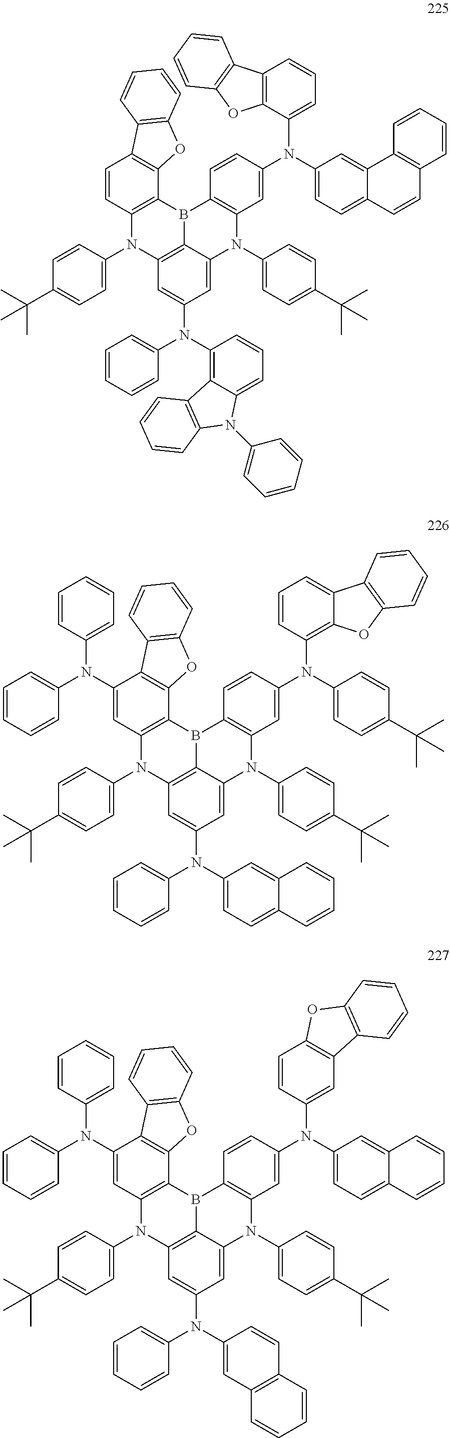

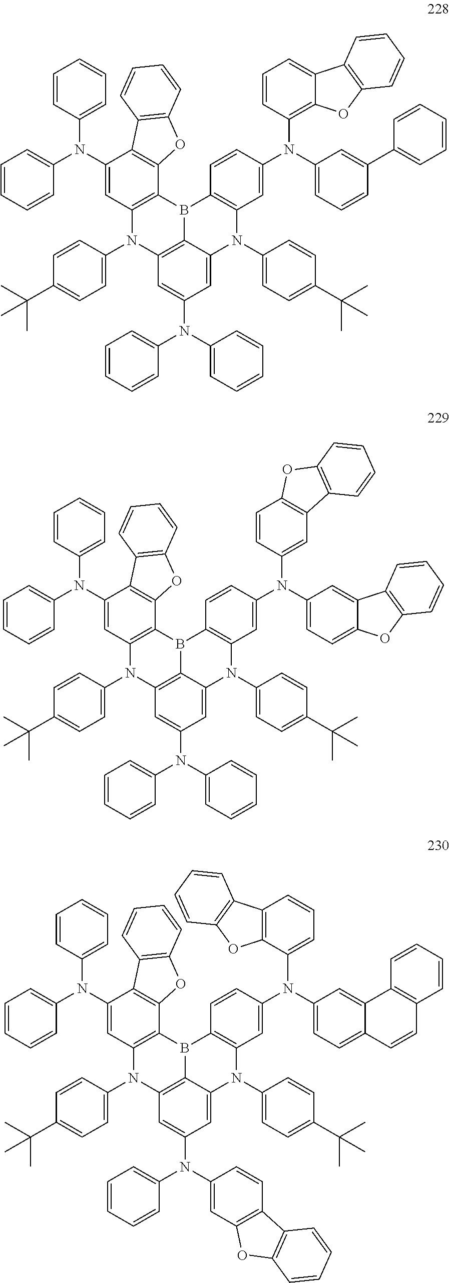

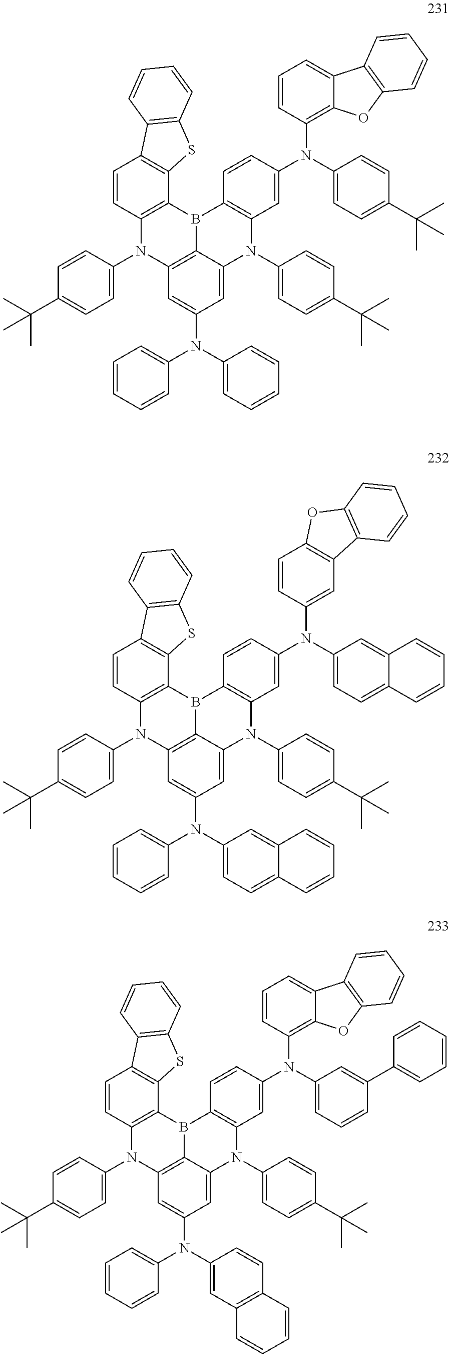

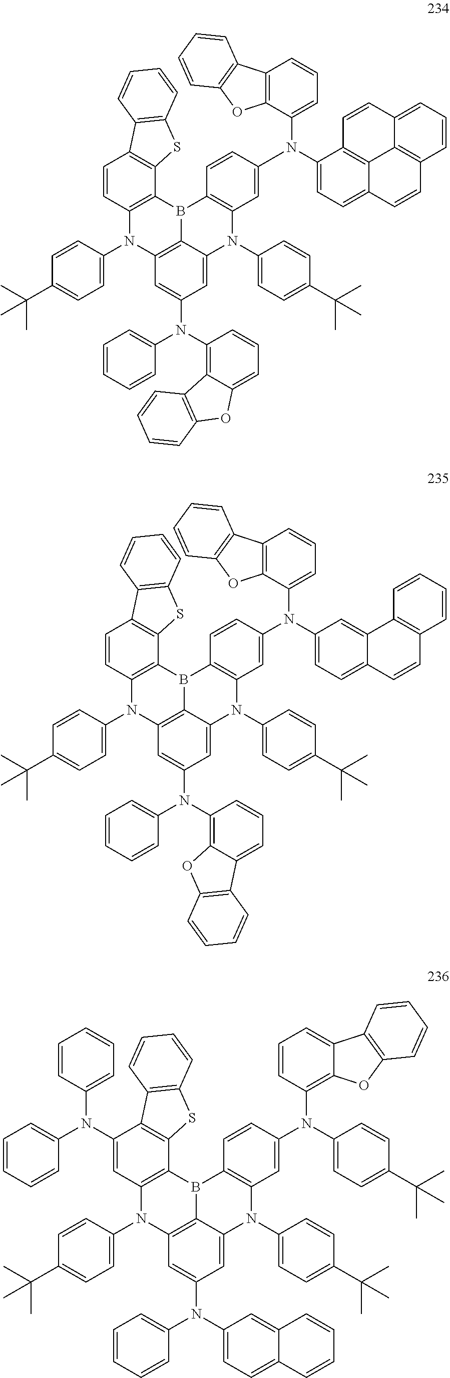 [SMILES: CC(C)(C)c1ccc(N2c3cc(N(c4ccc5ccc6cccc7ccc4c5c67)c4cccc5c4oc4ccccc45)ccc3B3c4c2cc(N(c2ccccc2)c2cccc5oc6ccccc6c25)cc4N(c2ccc(C(C)(C)C)cc2)c2ccc4c(sc5ccccc54)c23)cc1 ; CC(C)(C)c1ccc(N2c3cc(N(c4ccc5ccc6ccccc6c5c4)c4cccc5c4oc4ccccc45)ccc3B3c4c2cc(N(c2ccccc2)c2cccc5c2oc2ccccc25)cc4N(c2ccc(C(C)(C)C)cc2)c2ccc4c(sc5ccccc54)c23)cc1 ; CC(C)(C)c1ccc(N2c3cc(N(c4ccc(C(C)(C)C)cc4)c4cccc5c4oc4ccccc45)ccc3B3c4c2cc(N(c2ccccc2)c2ccc5ccccc5c2)cc4N(c2ccc(C(C)(C)C)cc2)c2cc(N(c4ccccc4)c4ccccc4)c4c(sc5ccccc54)c23)cc1]

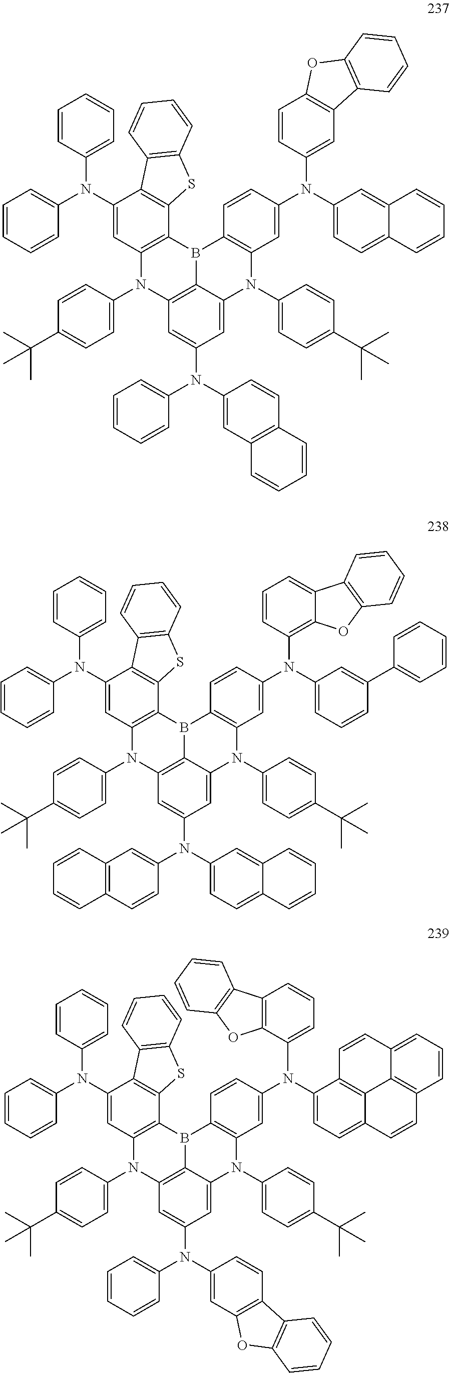

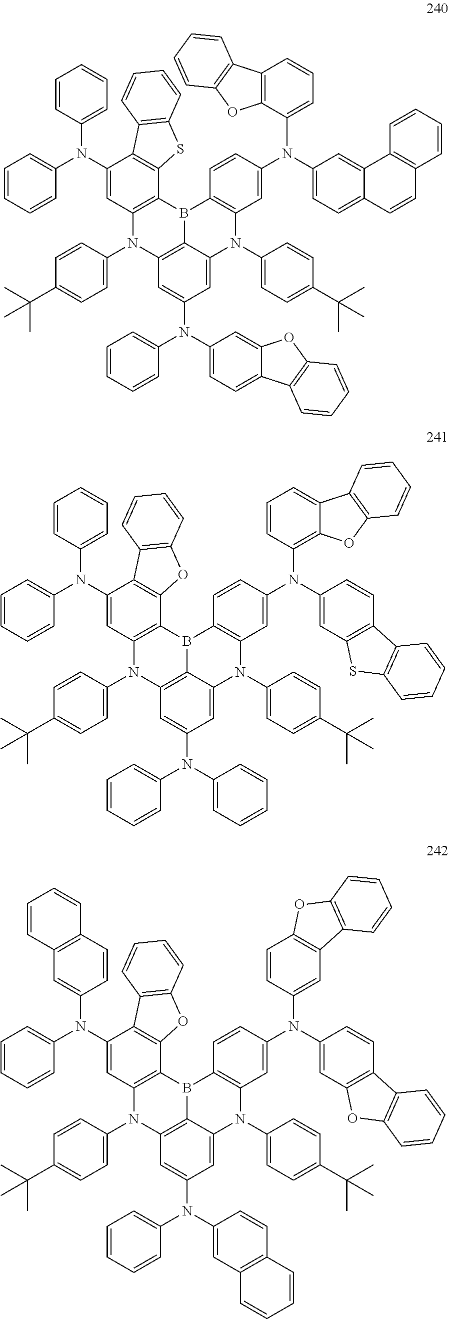

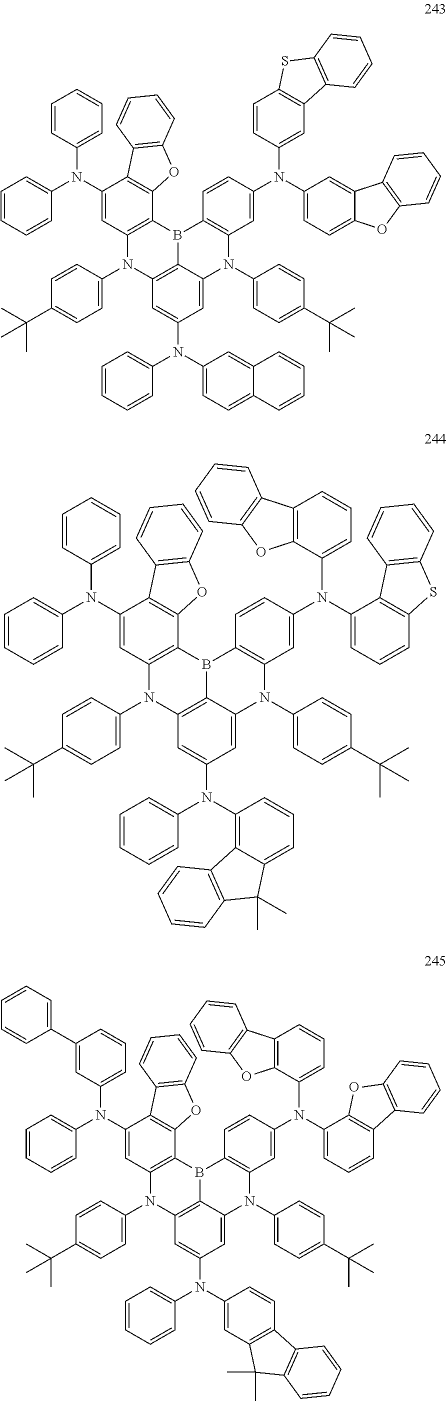

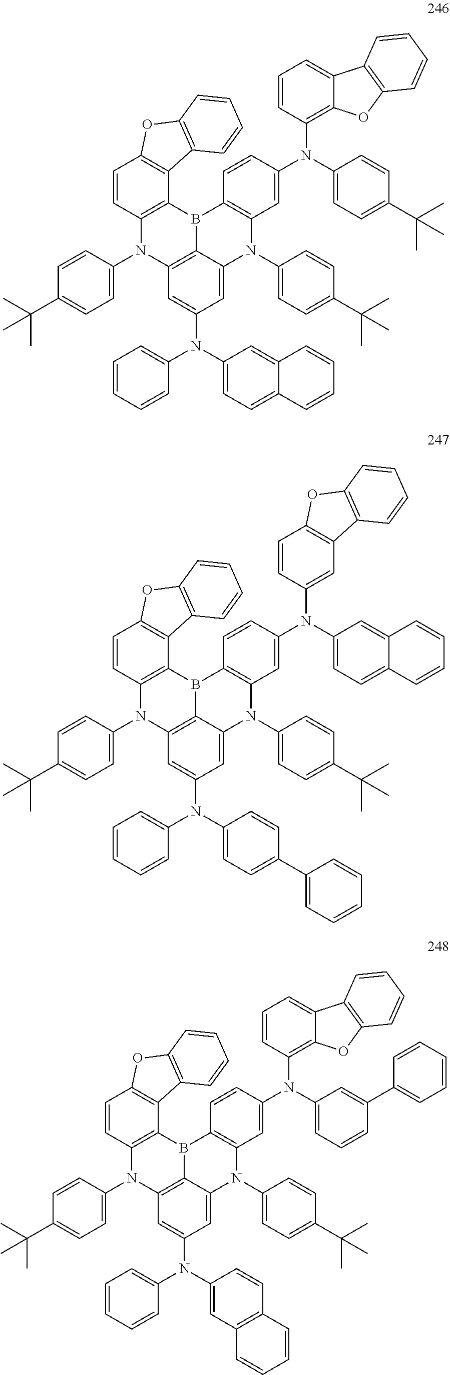

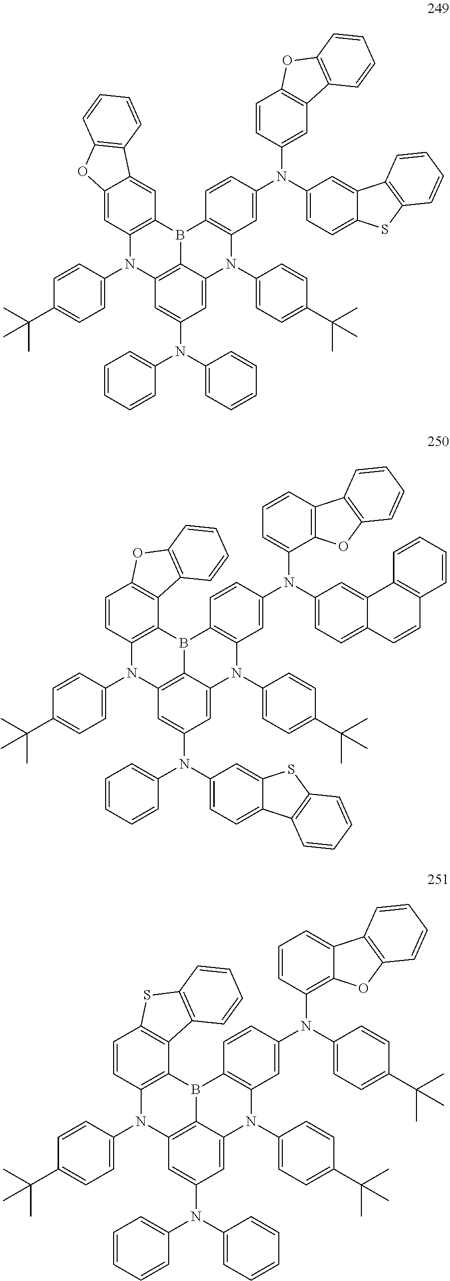 [SMILES: CC(C)(C)c1ccc(N2c3cc(N(c4ccc5oc6ccccc6c5c4)c4ccc5sc6ccccc6c5c4)ccc3B3c4cc5c(cc4N(c4ccc(C(C)(C)C)cc4)c4cc(N(c6ccccc6)c6ccccc6)cc2c43)oc2ccccc25)cc1 ; CC(C)(C)c1ccc(N2c3cc(N(c4ccc5ccc6ccccc6c5c4)c4cccc5c4oc4ccccc45)ccc3B3c4c2cc(N(c2ccccc2)c2ccc5c(c2)sc2ccccc25)cc4N(c2ccc(C(C)(C)C)cc2)c2ccc4oc5ccccc5c4c23)cc1 ; CC(C)(C)c1ccc(N2c3cc(N(c4ccc(C(C)(C)C)cc4)c4cccc5c4oc4ccccc45)ccc3B3c4c2cc(N(c2ccccc2)c2ccccc2)cc4N(c2ccc(C(C)(C)C)cc2)c2ccc4sc5ccccc5c4c23)cc1]

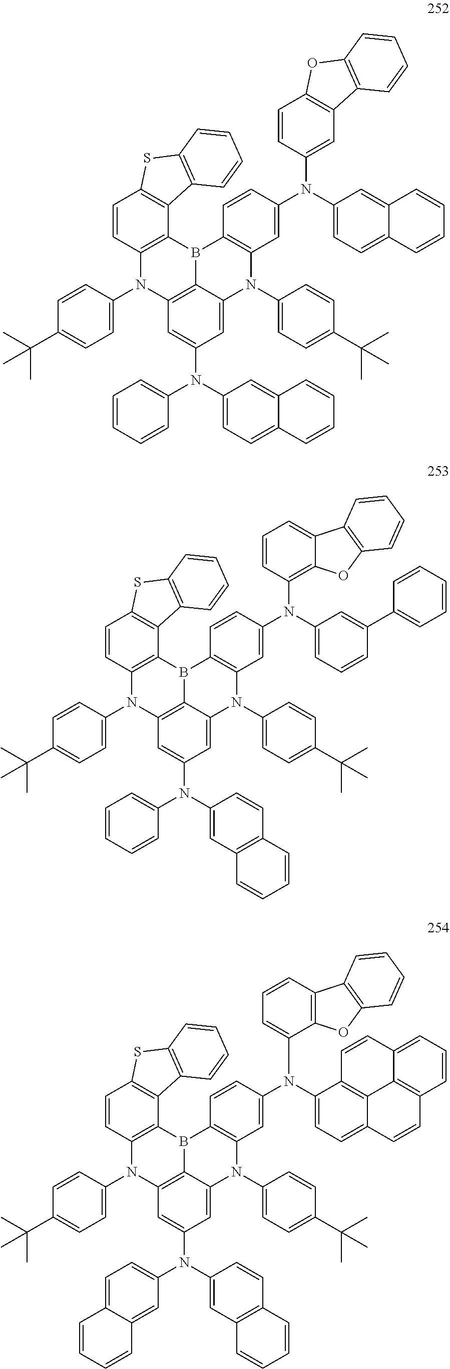 [SMILES: CC(C)(C)c1ccc(N2c3cc(N(c4ccc5ccccc5c4)c4ccc5oc6ccccc6c5c4)ccc3B3c4c2cc(N(c2ccccc2)c2ccc5ccccc5c2)cc4N(c2ccc(C(C)(C)C)cc2)c2ccc4sc5ccccc5c4c23)cc1 ; CC(C)(C)c1ccc(N2c3cc(N(c4cccc(-c5ccccc5)c4)c4cccc5c4oc4ccccc45)ccc3B3c4c2cc(N(c2ccccc2)c2ccc5ccccc5c2)cc4N(c2ccc(C(C)(C)C)cc2)c2ccc4sc5ccccc5c4c23)cc1 ; CC(C)(C)c1ccc(N2c3cc(N(c4ccc5ccc6cccc7ccc4c5c67)c4cccc5c4oc4ccccc45)ccc3B3c4c2cc(N(c2ccc5ccccc5c2)c2ccc5ccccc5c2)cc4N(c2ccc(C(C)(C)C)cc2)c2ccc4sc5ccccc5c4c23)cc1]

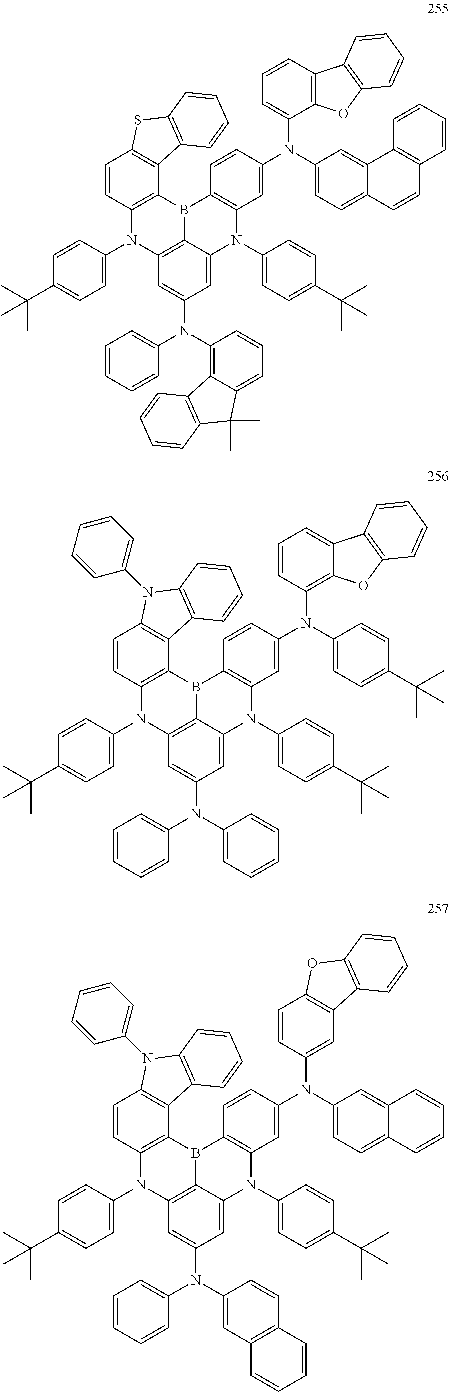

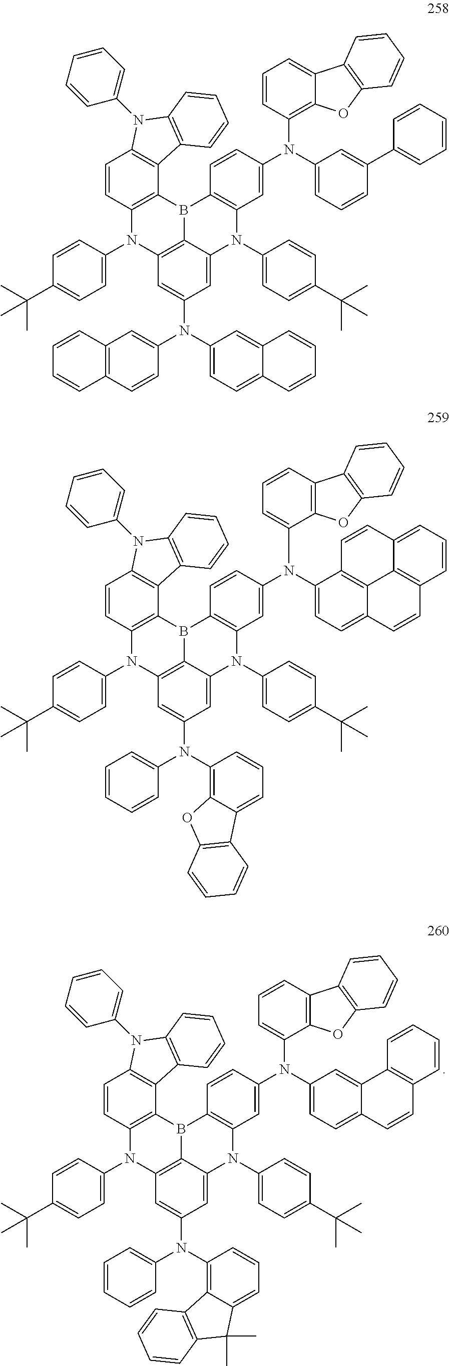

In some embodiments, the first excited singlet state (S1) of the organic compound has an energy level greater than or equal to 2.93 eV, and the first excited triplet state (T1) of the organic compound has an energy level greater than or equal to 2.48 eV. The organic compound has a relatively high S1 energy level and T1 energy level, facilitating the tendency of the organic compound to emit darker blue light, so as to obtain a blue light-emitting element that emittes darker blue light and has an excellent color coordinate.

The boron-containing organic compound according to an embodiment of the present disclosure comprises both a heterocycle and an amino group, thereby enhancing resonance effect of the material applied to the light-emitting element, improving the material performance, improving the luminous efficiency and prolonging the light-emitting life of the light-emitting element.

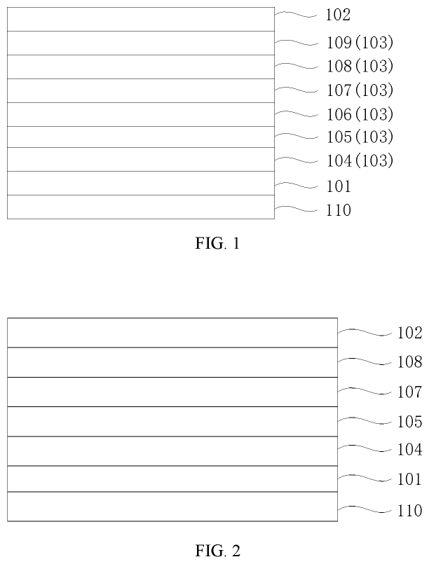

Referring to FIGS. 1 and 2, an embodiment of the present disclosure further provides a light-emitting element, including a first electrode 101 and a second electrode 102; and an organic functional layer 103 between the first electrode 101 and the second electrode 102. The material of the organic functional layer 103 includes one or more than one organic compound as described above. The first electrode 101 may be an anode and the second electrode 102 may be a cathode.

In some embodiments, the light-emitting element may be applied in an organic light-emitting diode, an organic photovoltaic cell, an organic light-emitting cell, an organic field-effect transistor, an organic light-emitting field-effect transistor, an organic laser, an organic electron spin device, an organic sensor, an organic plasmon-emitting diode, or the like, preferably an organic light-emitting diode, an organic light-emitting cell, an organic light-emitting field-effect transistor.

In some embodiments, the light-emitting element may be applied to a variety of electronic apparatuses, such as a display panel, a lighting device, and a light source.

In some embodiments, the organic functional layer 103 may be of a monolayer structure. In this case, the organic functional layer 103 is a mixture layer including a first compound selected from one or more than one organic compound described above and a second compound selected from one or more of a hole injection material, a hole transport material, an electron transport material, a hole blocking material, a light-emitting guest material, a light-emitting host material, or an organic dye. A detailed description of various organic functional materials contained in the organic functional layer 103 may be found in WO2010 135519A1, US 20090134784A1, and WO 2011110277A1, the entire contents of which are hereby incorporated by reference.

The light-emitting guest material is selected from the group consisting of a singlet emitter (fluorescent emitter), a triplet emitter (phosphorescent emitter), and a thermally activated delayed fluorescence (TADF) material.

When the second compound is selected from one or more of the hole injection material, the hole transport material, the electron transport material, the hole blocking material, the light-emitting host material, or the organic dye, a mass ratio of the first compound to the second compound is 1:99 to 30:70, preferably 1:99 to 10:90.

When the second compound is the light-emitting guest material, a mass ratio of the first compound to the second compound is 99:1 to 70:30, preferably 99:1 to 90:10.

In some embodiments, the organic functional layer 103 may include multiple layers. When the organic functional layer 103 is of a multilayer structure, the organic functional layer 103 includes at least a light-emitting layer 107. Preferably, the organic functional layer 103 includes a hole injection layer 104, a hole transport layer 105, a light-emitting layer 107, an electron blocking layer 106, an electron injection layer 109, an electron transport layer 108, or a hole blocking layer.

In some embodiments, the light-emitting element may be a blue light-emitting element, a green light-emitting element, or a red light-emitting element. The light-emitting layer 107 may include a host material and a guest material. The guest material is one or more than one organic compound described, and the host material includes a fused aromatic derivative or a heteroaromatic compound.

A wavelength of light emitted by the light-emitting element is from 300 to 1,000 nm, further from 350 to 900 nm, still further from 400 to 800 nm.

In some embodiments, the host material includes at least one of an anthracene derivative, a pyrene derivative, a naphthalene derivative, a pentacene derivative, a phenanthrene compound, a fluoranthene compound, a carbazole derivative, a dibenzofuran derivative, a ladder-type furan compound, or a pyrimidine derivative.

In some embodiments, a mass ratio of the host material to the guest material is 99:1 to 70:30, such as 90:10, 85:15, 80:20, and 75:25, preferably 99:1 to 90:10, such as 97:3, 96:4, 95:5, 93:7, and 92:8. The guest material is dispersed in the host material, and the mass ratio of the host material to the guest material is 99:1 to 70:30, so that crystallization of the light-emitting layer 107 and concentration quenching caused by a high concentration of the guest material can be suppressed, thereby improving the luminous efficiency of the light-emitting element.

In some embodiments, the anode is an electrode for injecting holes. The anode may inject holes into the organic functional layer 103, for example, into the hole injection layer, the hole transport layer, or the light-emitting layer. The anode may include at least one of a conductive metal, a conductive metal oxide, or a conductive polymer. In an embodiment, an absolute value of difference between the work function of the anode and the highest occupied molecular orbital (HOMO) level or valence band energy level of a p-type semiconductor material as the hole injection layer, or between the HOMO levels of the hole injection layer and the hole transport layer (or the electron blocking layer), is less than 0.5 eV, preferably less than 0.3 eV, more preferably less than 0.2 eV. A material of the anode includes, but is not limited to, at least one of Al, Cu, Au, Ag, Mg, Fe, Co, Ni, Mn, Pd, Pt, indium tin oxide (ITO), or aluminum-doped zinc oxide (AZO), or other suitable and known anode materials, which can be readily selected by one of ordinary skill in the art. The material of the anode may be deposited using any suitable technique, such as a suitable physical vapor deposition method, including radio frequency magnetron sputtering, vacuum thermal evaporation, e-beam, and the like. In some embodiments, the anode may be patterned. For example, the patterned ITO conductive substrates are commercially available and can be used to prepare the light-emitting element of the present disclosure.

In some embodiments, the cathode is an electrode for injecting electrons. The cathode may inject electrons into the organic functional layer, for example, into the electron injection layer, the electron transport layer, or the light-emitting layer. The cathode may include at least one of a conductive metal or a conductive metal oxide. In an embodiment, an absolute value of difference between the work function of the cathode and the lowest unoccupied molecular orbital (LUMO) energy level or conduction band energy level of a n-type semiconductor material as the electron injection layer, or between the LUMO levels of the electron injection layer and the electron transport layer (or the hole blocking layer), is less than 0.5 eV, preferably less than 0.3 eV, more preferably less than 0.2 eV All materials that can be used as a cathode of an organic electronic device, including but not limited to at least one of Al, Au, Ag, Ca, Ba, Mg, LiF/Al, MgAg alloy, BaF₂/Al, Cu, Fe, Co, Ni, Mn, Pd, Pt, or ITO, may be used as the material of the cathode of the device of the present disclosure. The material of the cathode may be deposited using any suitable technique, such as a suitable physical vapor deposition method, including radio frequency magnetron sputtering, vacuum thermal evaporation, and e-beam.

In some embodiments, the hole injection layer 104 is configured to facilitate hole injection from the anode to the light-emitting layer 107. The hole injection layer 104 includes a hole injection material, which is a material that can receive holes injected from a positive electrode at a low voltage. Preferably, the highest occupied molecular orbital (HOMO) of the hole injection material is between the work function of the material of the anode and the HOMO of a functional material (e.g. the hole transport material of the hole transport layer) of a film layer to which holes are injected on a side away from the anode. The hole injection material includes, but is not limited to, at least one of a metalloporphyrin, an oligomeric thiophene, an arylamine-based organic material, a hexanitrilehexaazatriphenylene-based organic material, a quinacridone-based organic material, a perylene-based organic material, an anthraquinone, a polyaniline-based and a polythiophene-based conductive polymer, or the like.

In some embodiments, the hole transport layer 105 may transport holes to the light-emitting layer 107. The hole transport layer 105 includes a hole transport material that receives holes transported from the anode or the hole injection layer and transfers holes to the light-emitting layer. The hole transport material is a material known in the art to have a high hole mobility, including but not limited to, at least one of an arylamine-based organic material, a conductive polymer, a block copolymer having both a conjugated moiety and a non-conjugated moiety, or the like.

In some embodiments, the electron transport layer 108 is configured to transport electrons. The electron transport layer 108 includes an electron transport material that receives electrons injected from the negative electrode and transfers electrons to the light-emitting layer 107. The electron transport material is a material known in the art to have a high electron mobility, including but not limited to, at least one of 8-hydroxylquinolinato aluminum complex, a complex comprising Alq3 (tris(8-hydroxyquinoline)aluminum), an organic radical compound, a hydroxylflavone-metal complex, 8-hydroxylquinolinato lithium (LiQ), or a benzimidazole-based compound.

In some embodiments, the electron injection layer 109 is configured to inject electrons. The electron injection layer 109 includes an electron injection material. The electron injection material preferably is a material that can transport electrons, can be injected electrons from the negative electrode, has an excellent effect of injecting electrons into the light-emitting layer 107 or the light-emitting material, prevents excitons generated by the light-emitting layer 107 from moving to the hole injection layer, and has an excellent ability to form a thin film. The electron injection material includes, but is not limited to, at least one of 8-hydroxylquinolinato lithium (LiQ), fluorenone, anthraquinone dimethane, diphenoquinone, thiopyran dioxide, pyrazole, diazole, triazole, imidazole, perylene tetracarboxylic acid, fluorenylidene methane, anthracenone and derivatives, metal complex compounds, nitrogen-containing five-membered ring derivatives thereof, and the like.

In some embodiments, the hole blocking layer is configured to block holes from reaching the negative electrode, and generally is formed in the same conditions as the hole injection layer 104. The hole blocking layer includes a hole blocking material including, but not limited to, at least one of a diazole derivative or a triazole derivative, a phenanthroline derivative, BCP, an aluminum complex, or the like.

Referring to FIG. 1, in some embodiments, the light-emitting element further includes a substrate 110 on which the first electrode 101, the hole injection layer 104, the hole transport layer 105, the electron blocking layer 106, the light-emitting layer 107, the electron transport layer 108, the electron injection layer 109, and the second electrode 102 are sequentially stacked. Referring to FIG. 2, the first electrode 101, the hole injection layer 104, the hole transport layer 105, the light-emitting layer 107, the electron transport layer 108, the electron injection layer 109, and the second electrode 102 are sequentially stacked on the substrate 110. The substrate 110 may be a transparent substrate or an opaque substrate. When the substrate 110 is a transparent substrate, a transparent light-emitting element may be fabricated. The substrate 110 may be a rigid substrate, or a flexible substrate having elasticity. The material of the substrate 110 may include, but is not limited to, plastic, polymer, metal, semiconductor wafer, glass, or the like. Preferably, the substrate 110 includes at least a smooth surface for forming the anode thereon. More preferably, the surface is free of surface defects. Preferably, the material of the substrate 110 is a polymer film or plastic, including, but not limited to, polyethylene terephthalate (PET) and polyethylene naphthalate (PEN). The substrate 110 has a glass transition temperature greater than or equal to 150° C., preferably greater than or equal to 200° C., more preferably greater than or equal to 250° C., and most preferably greater than or equal to 300° C.

In some embodiments, the light-emitting element may be a solution-processed light-emitting element. That is, at least one of the organic functional layers is prepared by printing (e.g., inkjet printing).

In some embodiments, the mixture layer or the light-emitting layer may be formed by a printing or coating of the composition. The printing or coating process includes inkjet printing, nozzle printing, typographic priming, screen printing, dip coating, spin coating, blade coating, roller printing, torsion roller printing, lithographic printing, flexographic printing, rotary printing, spray coating, brush coating or pad printing, slot-die coating, and the like, preferably gravure printing, nozzle printing or inkjet printing.

The composition may be in a solution or suspension form. The composition may comprise a dispersoid and a dispersing agent. The dispersoid is one or more than one organic compound as described above, and the dispersing agent is used to disperse the dispersoid.

In the composition, a mass fraction of the organic compound as described above may be from 0.3% to 30%, preferably from 0.5% to 20%, more preferably from 0.5% to 15%, further preferably from 0.5% to 10%, most preferably from 1% to 5%.

When the composition is used in the printing process, the composition may be an ink. The viscosity and surface tension of the ink are important parameters. Suitable surface tension of the ink is useful for a particular substrate and printing process. In some embodiments, the surface tension of the ink at an operating temperature or at 25° C. is in a range of 19 dyne/cm to 50 dyne/cm, preferably 22 dyne/cm to 35 dyne/cm, more preferably 25 dyne/cm to 33 dyne/cm, so as to use in the inkjet printing process. In some embodiments, the viscosity of the ink at an operating temperature or 25° C. is in a range of 1 cps to 100 cps, preferably 1 cps to 50 cps, more preferably 1.5 cps to 20 cps, most preferably 4.0 cps to 20 cps, so as to apply to the inkjet printing process.

In some embodiments, Hansen solubility parameters of the dispersing agent are as follows: δd (dispersion force) of 17.0-23.2 MPa^{1/2}, preferably 18.5-21.0 MPa^{1/2}; Sp (polar force) of 0.2-12.5 MPa^{1/2}, preferably 2.0-6.0 MPa^{1/2}; δh (hydrogen bonding force) of 0.9-14.2 MPa^{1/2}, preferably 2.0-6.0 MPa^{1/2}.

In some embodiments, the dispersing agent has a boiling point greater than or equal to 150° C., preferably greater than or equal to 180° C., more preferably greater than or equal to 200° C., more preferably greater than or equal to 250° C., further preferably greater than or equal to 275° C., most preferably greater than or equal to 300° C. The boiling point of the dispersing agent is at least greater than or equal to 150° C., preventing nozzles of the inkjet printing head from clogging during inkjet printing. The higher the boiling point, the better for preventing clogging.

The dispersing agent may include at least one organic solvent, and the organic solvent may be evaporated from a solvent system to form a film comprising the functional materials. The organic solvent may include at least one first organic solvent, which may be selected from aromatic compounds or heteroaromatic compounds. Specifically, the first organic solvent may be selected from at least one of p-diisopropylbenzene, pentylbenzene, tetrahydronaphthalene, cyclohexylbenzene, chloronaphthalene, 1,4-dimethylnaphthalene, 3-isopropylbiphenyl, p-methyl isopropylbenzene, dipentylbenzene, tripentylbenzene, pentyltoluene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, cyclohexylbenzene, benzylbutylbenzene, dimethylnaphthalene, 3-isopropylbiphenyl, p-methyl isopropylbenzene, 1-methylnaphthalene, 1,2,4-trichlorobenzene, 4,4-difluorodiphenylmethane, 1,2-dimethoxy-4-(1-propenyl)benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl)pyridine, benzyl benzoate, 1,1-bis(3,4-dimethylphenyl)ethane, 2-isopropylnaphthalene, quinoline, isoquinoline, methyl 2-furancarboxylate, ethyl 2-furancarboxylate, or the combination thereof.

The first organic solvent may be selected from aromatic ketone-based solvents. Specifically, the first organic solvent may be selected from at least one of 1-tetralone, 2-tetralone, 2-(phenylepoxy)tetralone, 6-(methoxy)tetralone, acetophenone, propiophenone, benzophenone, and derivatives thereof, such as 4-methylacetophenone, 3-methylacetophenone, 2-methylacetophenone, 4-methylpropiophenone, 3-methylpropiophenone, 2-methylpropiophenone, or the combination thereof.

The first organic solvent may be selected from aromatic ether-based solvents. Specifically, the first organic solvent may be selected from at least one of 3-phenoxytoluene, butoxybenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylphenetole, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenyl anisole, 1,2-dimethoxybenzene, 1-methoxynaphthalene, diphenyl ether, 2-phenoxymethyl ether, 2-phenoxytetrahydrofuran, ethyl-2-naphthyl ether, or the combination thereof.

The first organic solvent may be selected from aliphatic ketones. Specifically, the first organic solvent may be selected from at least one of the following: aliphatic ketones, such as, 2-nonanone, 3-nonanone, 5-nonanone, 2-decanone, 2,5-hexanedione, 2,6,8-trimethyl-4-nonanone, fenchone, phorone, isophorone, di-n-pentyl ketone, or the like; or aliphatic ethers, such as, pentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, or the combination thereof.

The first organic solvent may be selected from organic ester solvents. Specifically, the first solvent may be selected from at least one of alkyl octanoate, alkyl sebacate, alkyl stearate, alkyl benzoate, alkyl phenylacetate, alkyl cinnamate, alkyl oxalate, alkyl maleate, alkyl lactone, alkyl oleate, or the like, preferably octyl octanoate, diethyl sebacate, diallyl phthalate, isononyl isononanoate, or the combination thereof.

The organic solvent further may include a second organic solvent, which may be selected from one or more of methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethylsulfoxide, tetrahydronaphthalene, decalin, indene, or the like.

In addition to the dispersoid and the dispersing agent, the composition may further include one or more components such as a surfactant agent, a lubricant, a wetting agent, a hydrophobic agent, a binder, or the like, to adjust the viscosity and film-forming property and to improve the adhesion property.

An embodiment of the present disclosure provides an exemplary method for preparing the organic compound described herein, as shown in exemplary Examples 1 to 37 below.

### Example 1

### Synthesis of Organic Compound M1

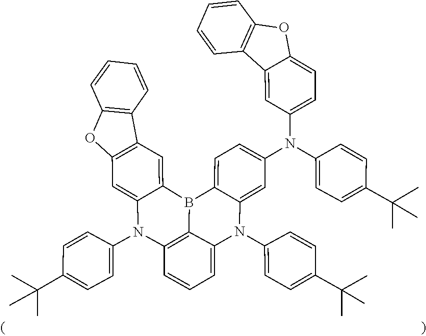 [SMILES: CC(C)(C)c1ccc(N(c2ccc3c(c2)N(c2ccc(C(C)(C)C)cc2)c2cccc4c2B3c2cc3c(cc2N4c2ccc(C(C)(C)C)cc2)oc2ccccc23)c2ccc3oc4ccccc4c3c2)cc1]

The synthetic route of the organic compound M1 is shown as follows:

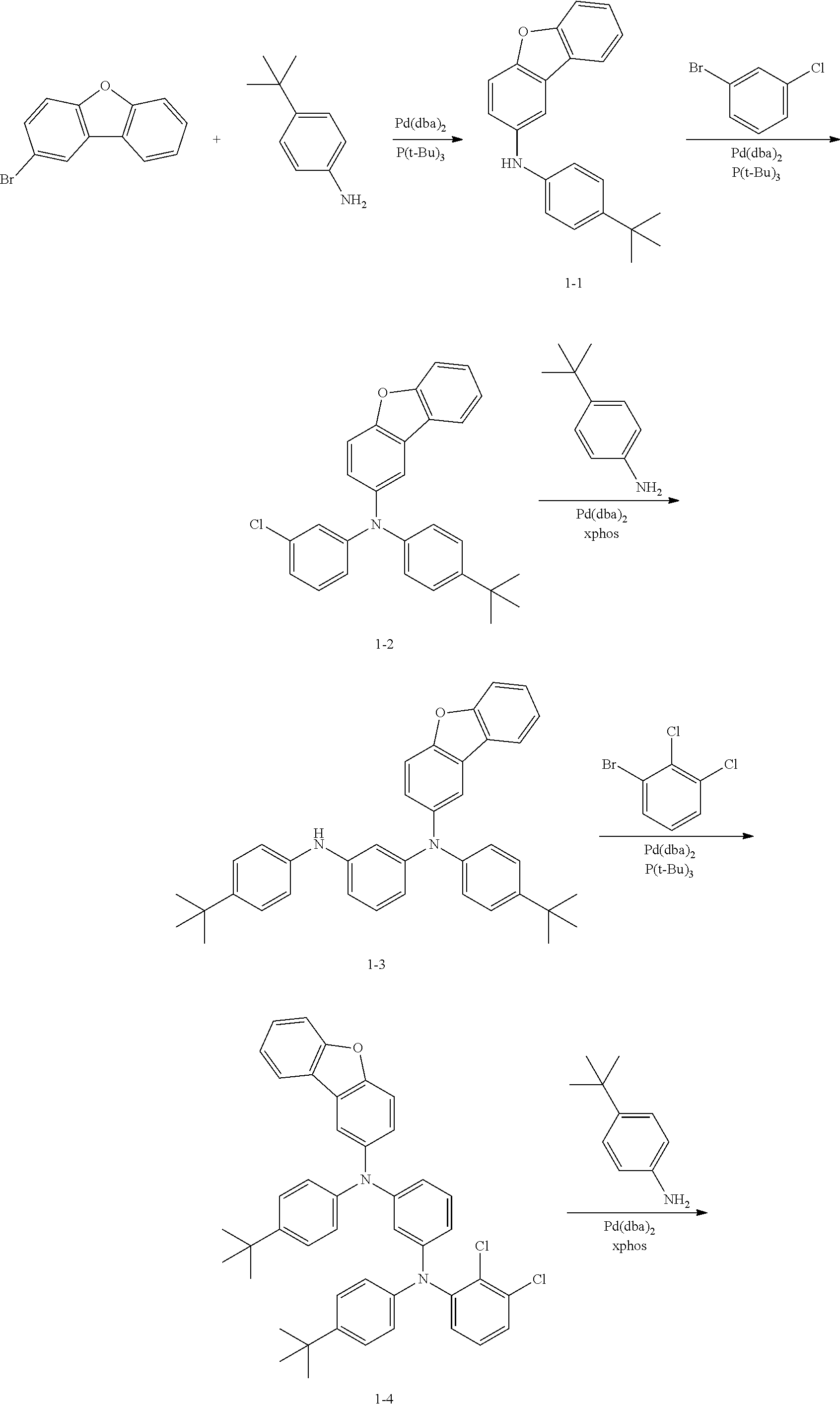

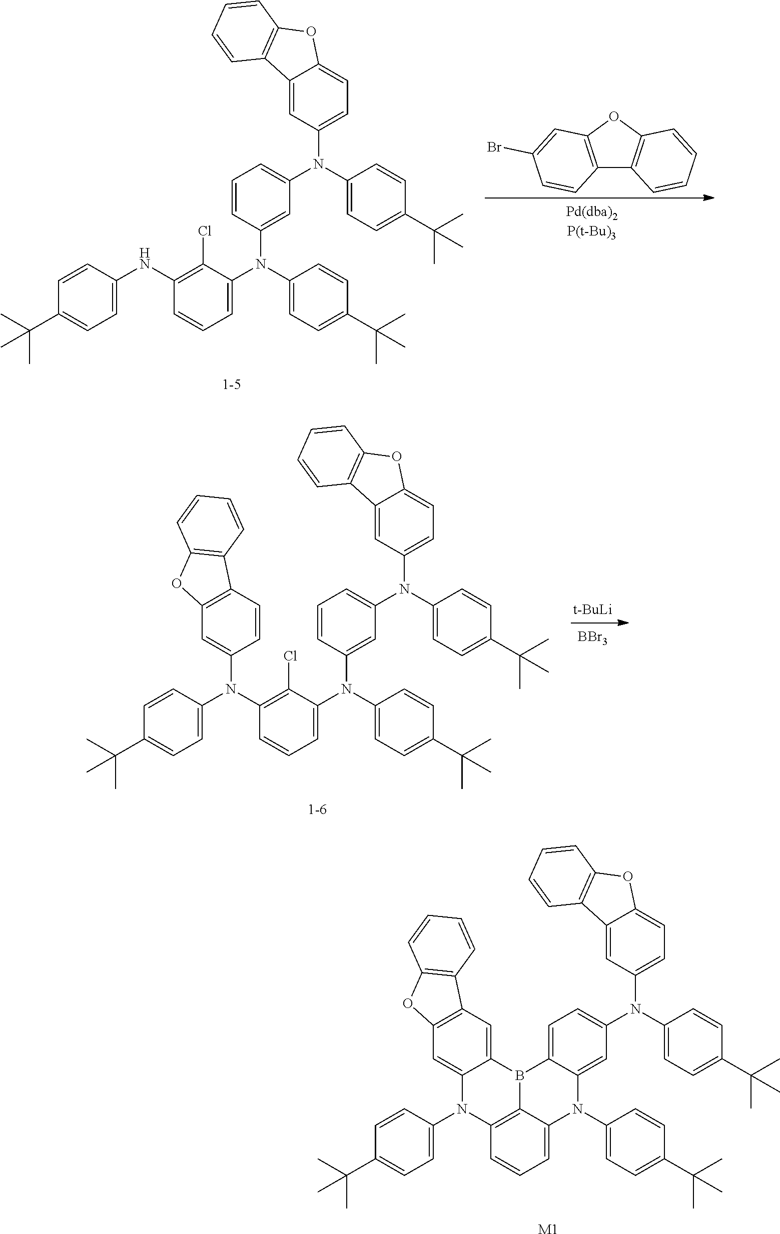

The specific synthetic procedure of the organic compound M1 is as follows:

### Synthesis of Intermediate 1-1

2-bromodibenzofuran (24.6 g, 100 mmol), 4-tert-butylaniline (14.9 g, 100 mmol), bis(dibenzylideneacetone) palladium (Pd(dba)₂, 0.57 g, 1.0 mmol), tri(tert-butyl)phosphine (P(t-Bu)₃, 0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 1-1 in 85% yield. The result of atmospheric pressure solids analysis probe mass spectrum (ASAP-MS) of Intermediate 1-1 is: MS (ASAP)=315.2.

### Synthesis of Intermediate 1-2

1-bromo-3-chlorobenzene (19 g, 100 mmol), Intermediate 1-1 (31.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 1-2 in 72% yield, MS (ASAP)=425.2.

### Synthesis of Intermediate 1-3

Intermediate 1-2 (42.5 g, 100 mmol), 4-tert-butylaniline (14.9 g, 100 mmol), Pd(dba)₂ (0.57 g, 1.0 mmol), 2-dicyclohexylphosphino-2′,4′,6′-triisopropylbiphenyl (X-Phos, 0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 1-3 in 64% yield, MS (ASAP)=538.3.

### Synthesis of Intermediate 1-4

Intermediate 1-3 (53.8 g, 100 mmol), 1-bromo-2,3-dichlorobenzene (22.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 1-4 in 67% yield, MS (ASAP)=682.3.

### Synthesis of Intermediate 1-5

Intermediate 1-4 (68.2 g, 100 mmol), 4-tert-butylaniline (14.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 1-5 in 71% yield, MS (ASAP)=795.4.

### Synthesis of Intermediate 1-6

Intermediate 1-5 (80 g, 100 mmol), 3-bromodibenzofuran (25 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 1-6 in 66% yield, MS (ASAP)=961.4.

### Synthesis of Organic Compound M1

Intermediate 1-6 (48 g, 50 mmol) and 200 ml of dry tert-butylbenzene were added into a 500 ml three-necked flask, under N₂ atmosphere, and cooled to −30° C., and t-BuLi (2.5M tert-butyllithium, 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N,N-diisopropylethylamine (64.5 g, 500 mmol) was added. After the completion of the addition, the reaction solution was warmed to room temperature and stirred. Then, the reaction solution was heated to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M1 as a pale yellow solid powder in 28% yield, MS (ASAP)=935.5.

### Example 2

### Synthesis of Organic Compound M2

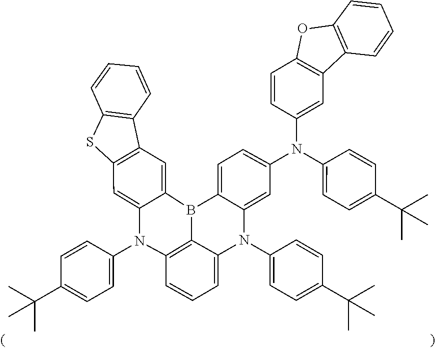

The synthetic route of the organic compound M2 is as follows:

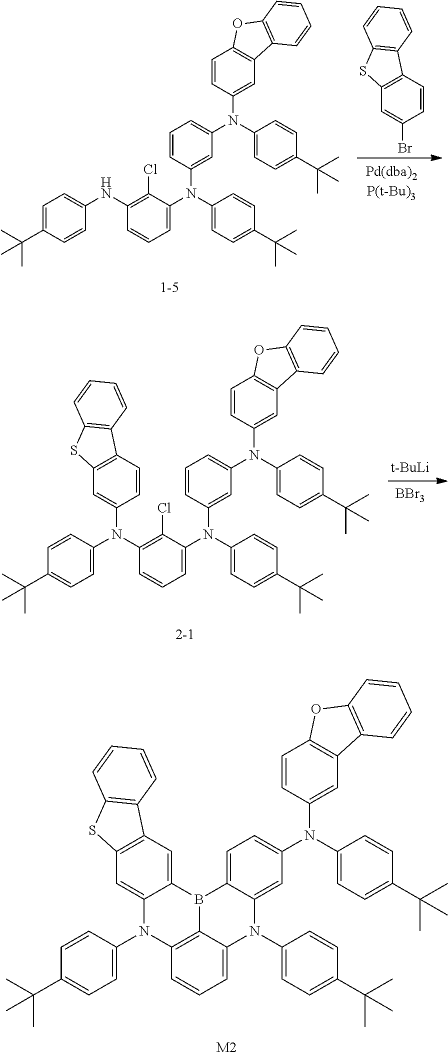

The specific synthetic procedure of the organic compound M2 is carried out as follows:

### Synthesis of Intermediate 2-1

Intermediate 1-5 (80 g, 100 mmol), 3-bromodibenzothiophene (26 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 2-1 in 61% yield, MS (ASAP)=977.4.

### Synthesis of Organic Compound M2

Intermediate 2-1 (49 g, 50 mmol) and 200 ml of dry tert-butylbenzene were added into a 500 ml three-necked flask, under N₂ atmosphere, and cooled to −30° C., and t-BuLi (2.5M tert-butyllithium 80 ml, 200 mmol) was added dropwise; The temperature was raised to 60° C. for 2 hours, and the solvent was removed by rotary evaporation under reduced pressure. The reaction solution was cooled again to −30° C., and then boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was heated to room temperature and stirred. Then, the reaction solution was warmed to 120° C. and stirred for 12 hours. The reaction solution was cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M2 as a pale yellow solid powder in 23% yield, MS (ASAP)=951.4.

### Example 3

### Synthesis of Organic Compound M3

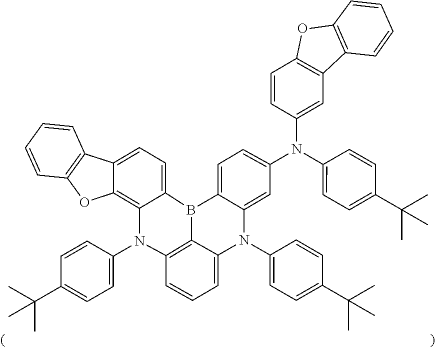

The synthetic route of the organic compound M3 is as follows:

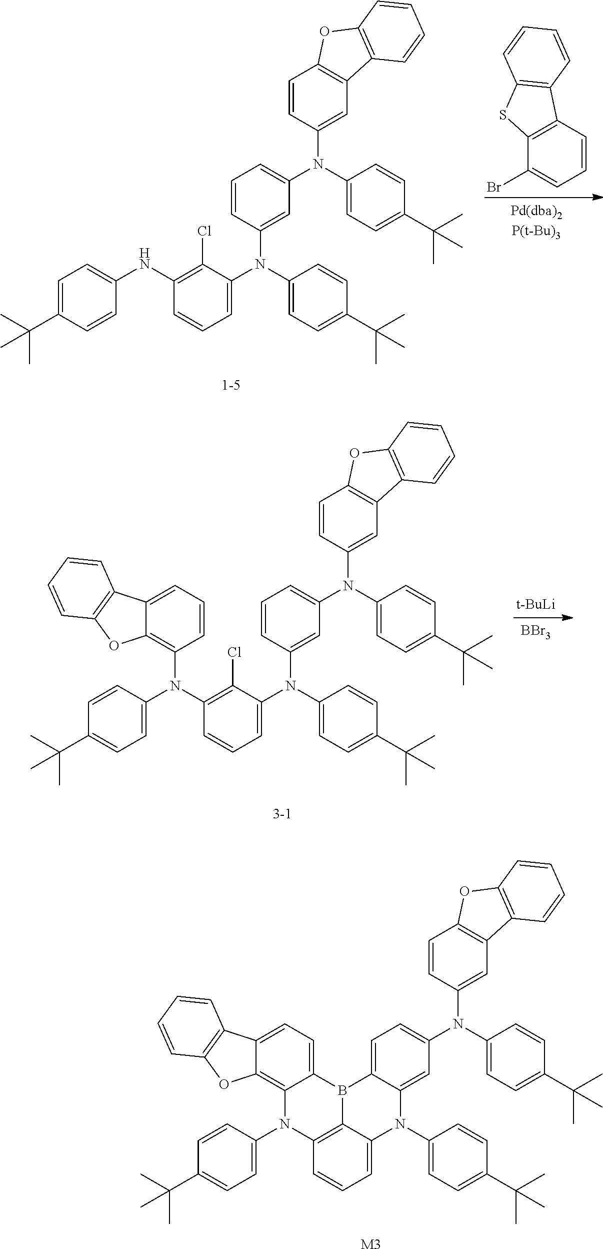

The specific synthetic procedure of the organic compound M3 is carried out as follows:

### Synthesis of Intermediate 3-1

Intermediate 1-5 (80 g, 100 mmol), 4-bromodibenzofuran (24.6 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 3-1 in 61% yield, MS (ASAP)=961.4.

### Synthesis of Organic Compound M3

Intermediate 3-1 (48 g, 50 mmol) and 200 ml of dry tert-butylbenzene were added into a 500 ml three-necked flask, under N₂ atmosphere, and cooled to −30° C., and t-BuLi (2.5M tert-butyllithium 80 ml, 200 mmol) was added dropwise. The temperature was raised to 60° C. for 2 hours, and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M3 as a pale yellow solid powder in 34% yield, MS (ASAP)=935.5.

### Example 4

### Synthesis of Organic Compound M4

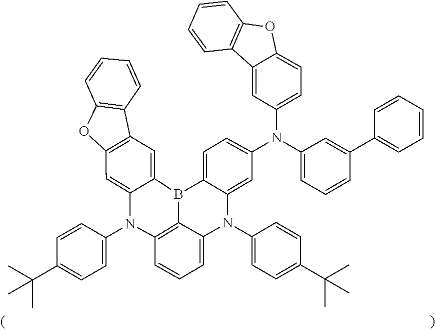

The synthetic route of the organic compound M4 is as follows:

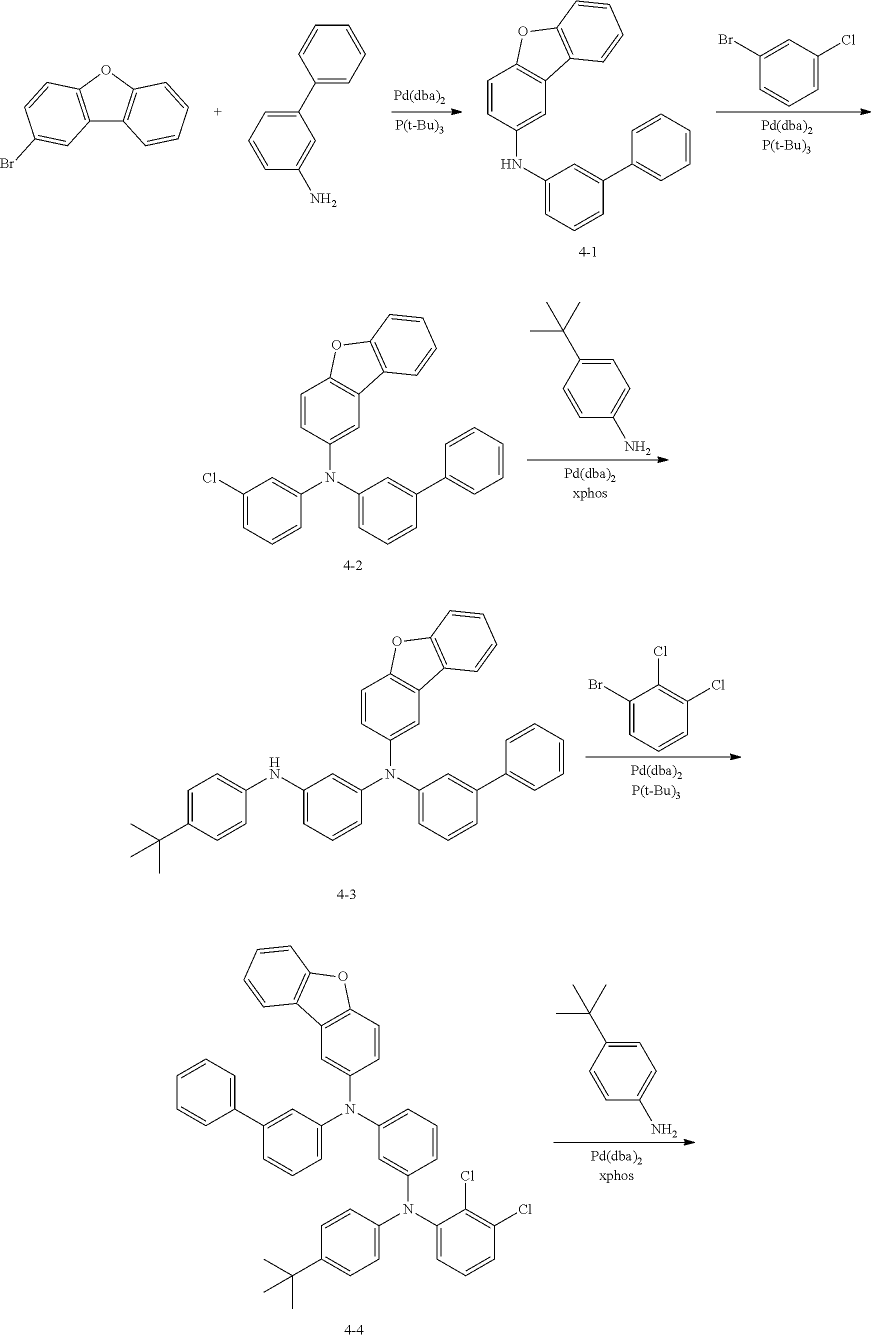

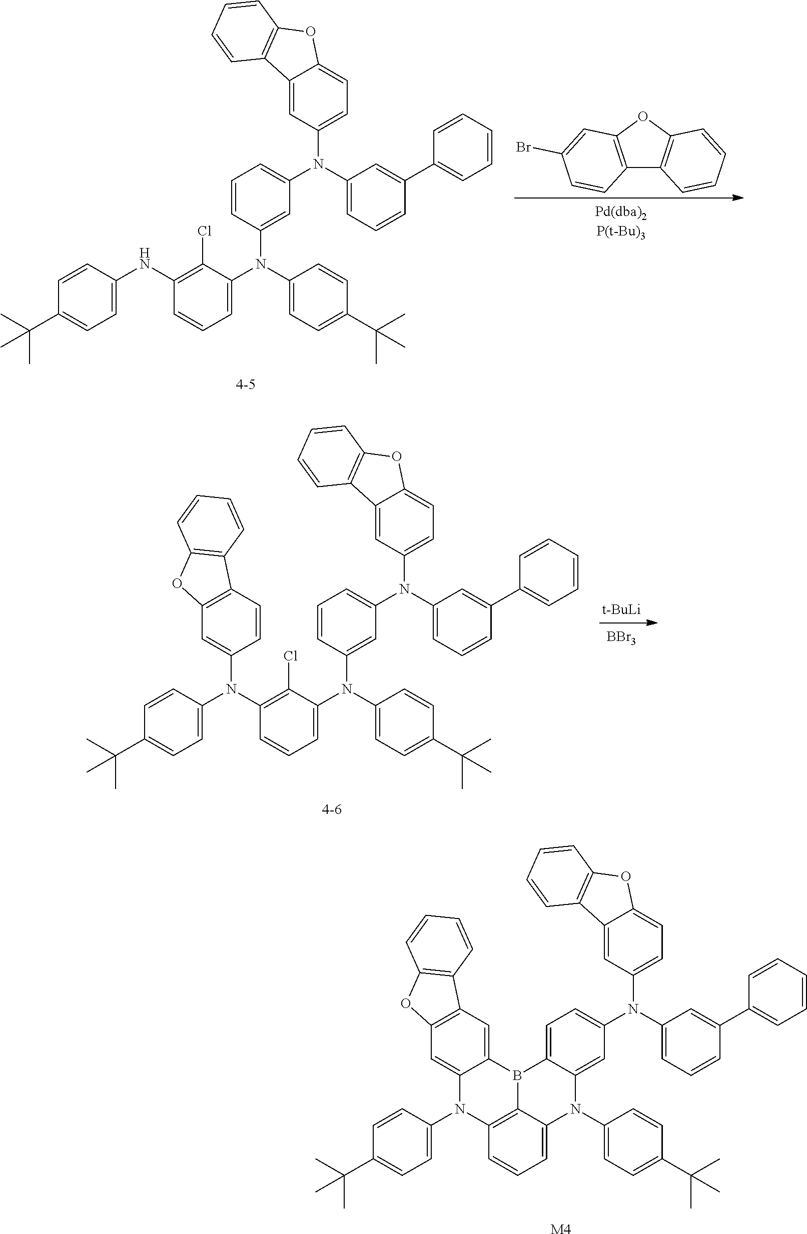

The specific synthetic procedure of the organic compound M4 is carried out as follows:

### Synthesis of Intermediate 4-1

2-Bromodibenzofuran (24.6 g, 100 mmol), 3-aminobiphenyl (16.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 4-1 in 82% yield, MS (ASAP)=335.2.

### Synthesis of Intermediate 4-2

1-bromo-3-chlorobenzene (19 g, 100 mmol), Intermediate 4-1 (33.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 4-2 in 68% yield, MS (ASAP)=445.1.

### Synthesis of Intermediate 4-3

Intermediate 4-2 (44.5 g, 100 mmol), 4-tert-butylaniline (14.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 4-3 in 71% yield, MS (ASAP)=558.3.

### Synthesis of Intermediate 4-4

Intermediate 4-3 (55.8 g, 100 mmol), 1-bromo-2,3-dichlorobenzene (22.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 4-4 in 53% yield, MS (ASAP)=702.2.

### Synthesis of Intermediate 4-5

Intermediate 4-4 (70 g, 100 mmol), 4-tert-butylaniline (14.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 4-5 in 66% yield, MS (ASAP)=815.4.

### Synthesis of Intermediate 4-6

Intermediate 4-5 (81.5 g, 100 mmol), 3-bromodibenzofuran (25 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 4-6 in 82% yield, MS (ASAP)=981.4.

### Synthesis of Organic Compound M4

Intermediate 4-6 (49 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M4 as a pale yellow solid powder in 22% yield, MS (ASAP)=955.4.

### Example 5

### Synthesis of Organic Compound M5

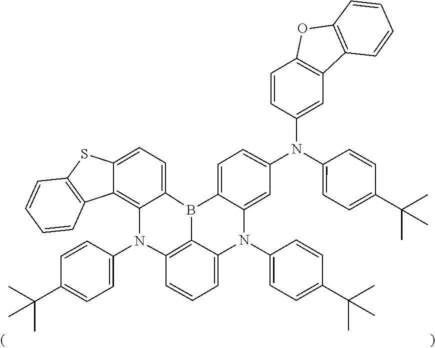

The synthetic route of the organic compound M5 is as follows:

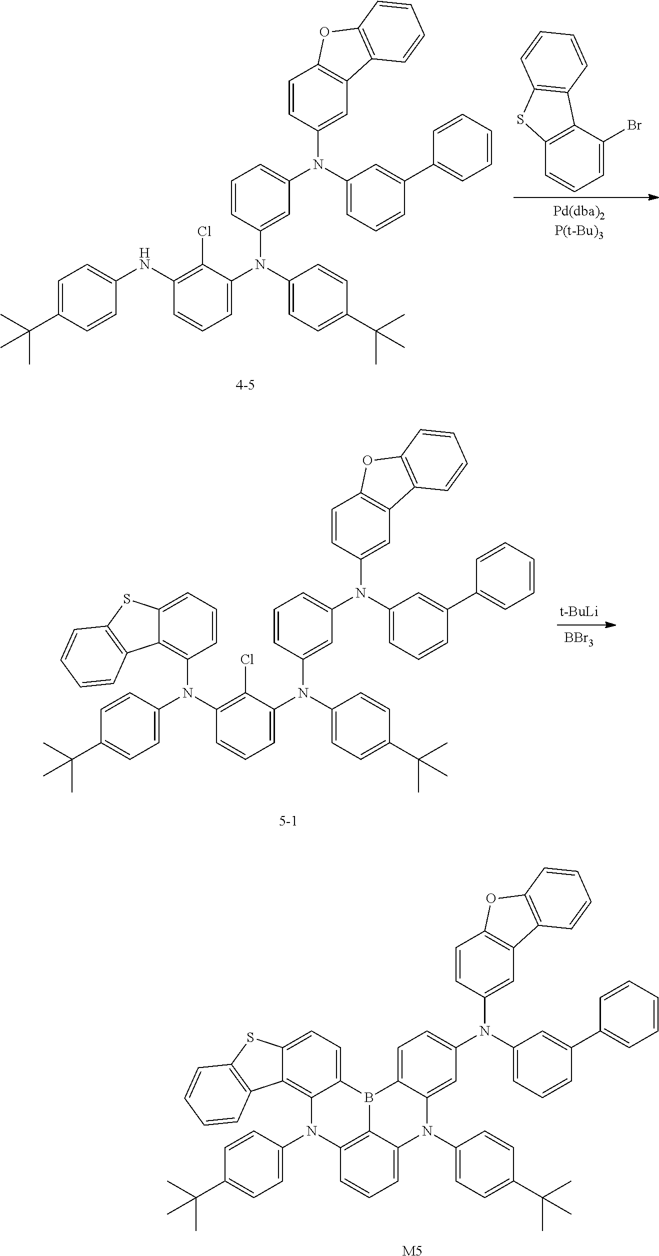

The specific synthetic procedure of the organic compound M5 is carried out as follows:

### Synthesis of Intermediate 5-1

Intermediate 4-5 (81.5 g, 100 mmol), 1-bromodibenzothiophene (26.2 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 5-1 in 78% yield, MS (ASAP)=997.4.

### Synthesis of Organic Compound M5

Intermediate 5-1 (50 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M5 as a pale yellow solid powder in 31% yield, MS (ASAP)=971.4.

### Example 6

### Synthesis of Organic Compound M6

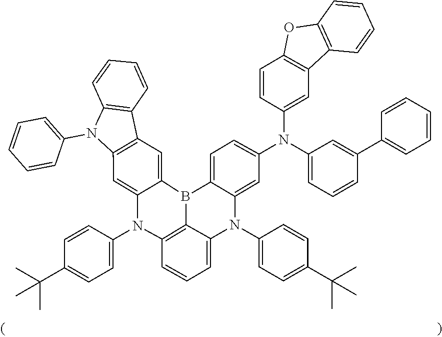

The synthetic route of the organic compound M6 is as follows:

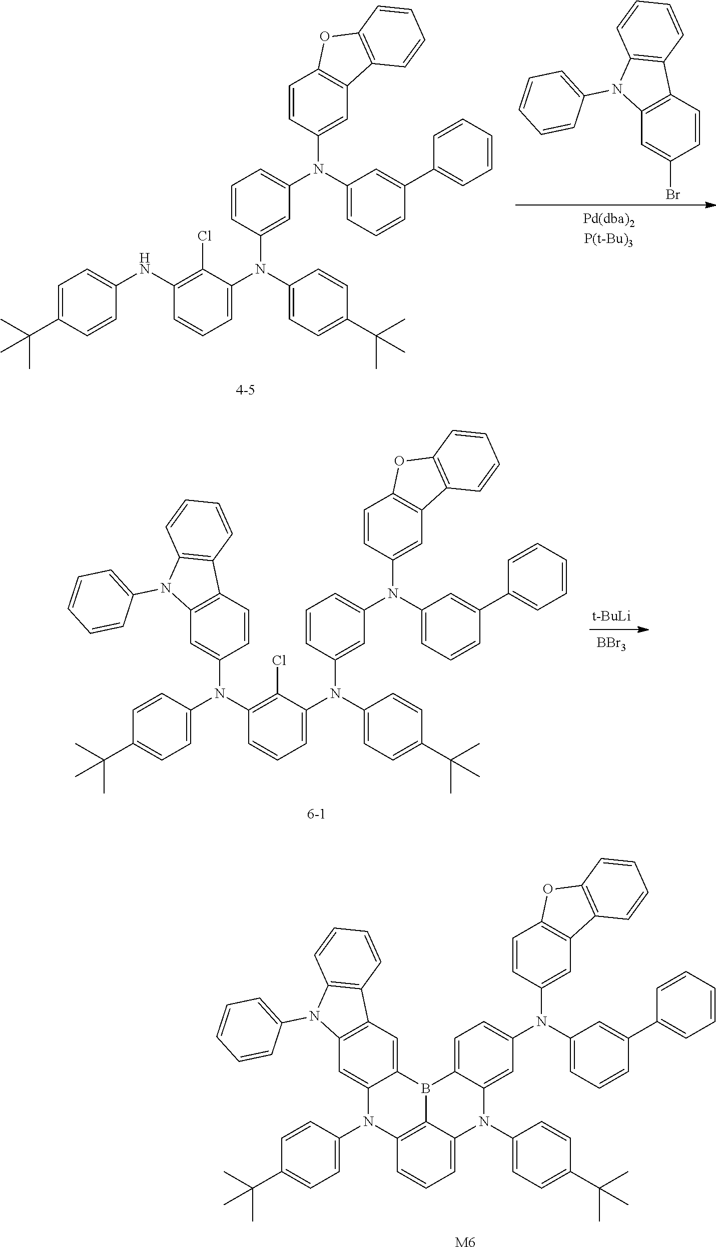

The specific synthetic procedure of the organic compound M6 is carried out as follows:

### Synthesis of Intermediate 6-1

Intermediate 4-5 (81.5 g, 100 mmol), 2-bromo-9-phenylcarbazole (32.1 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 6-1 in 75% yield, MS (ASAP)=1056.5.

### Synthesis of Organic Compound M6

Intermediate 6-1 (52.8 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M6 as a pale yellow solid powder in 27% yield, MS (ASAP)=1030.5.

### Example 7

### Synthesis of Organic Compound M7

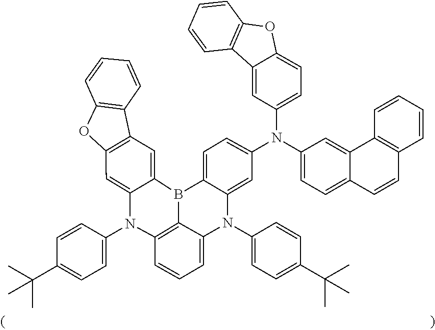

The synthetic route of the organic compound M7 is as follows:

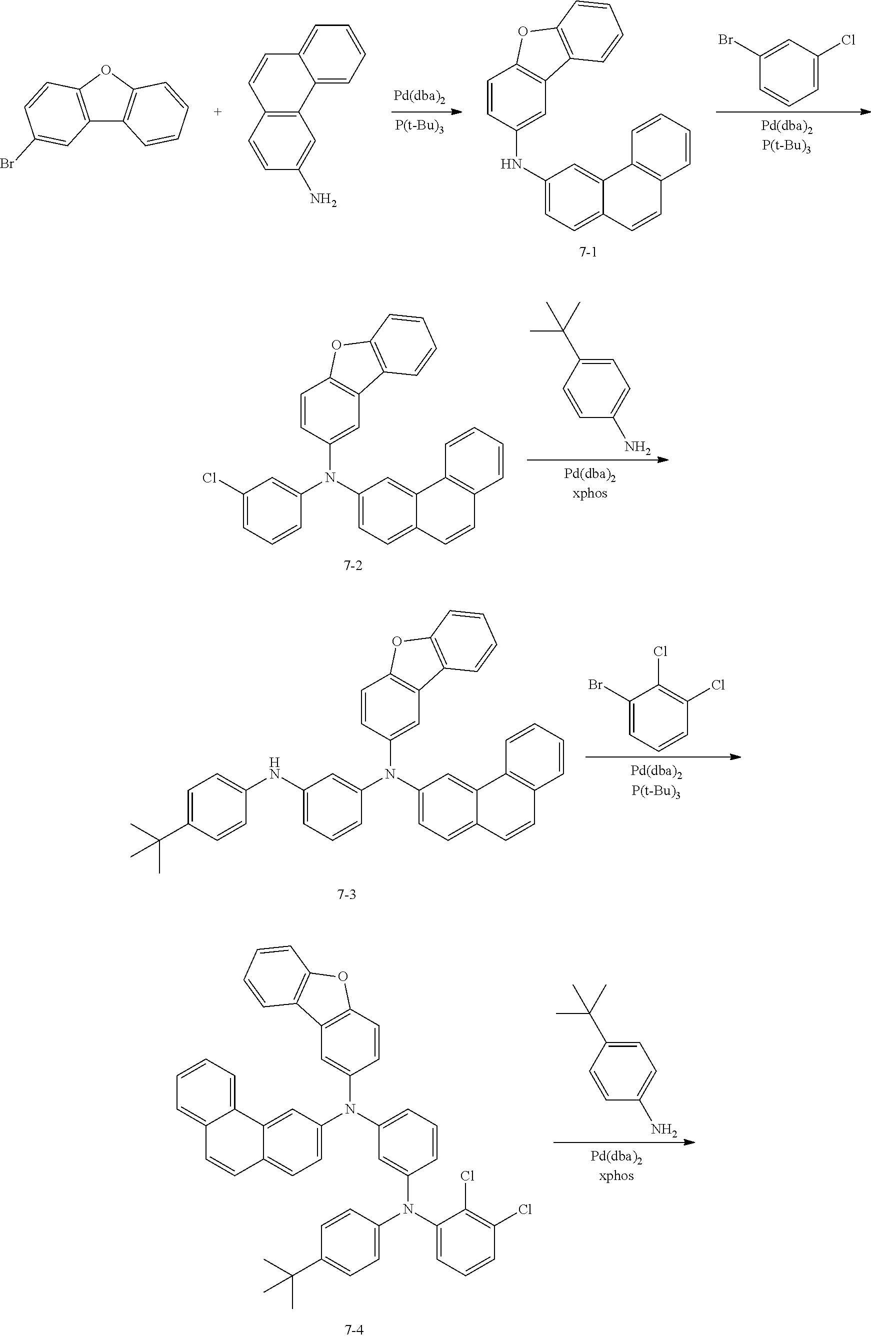

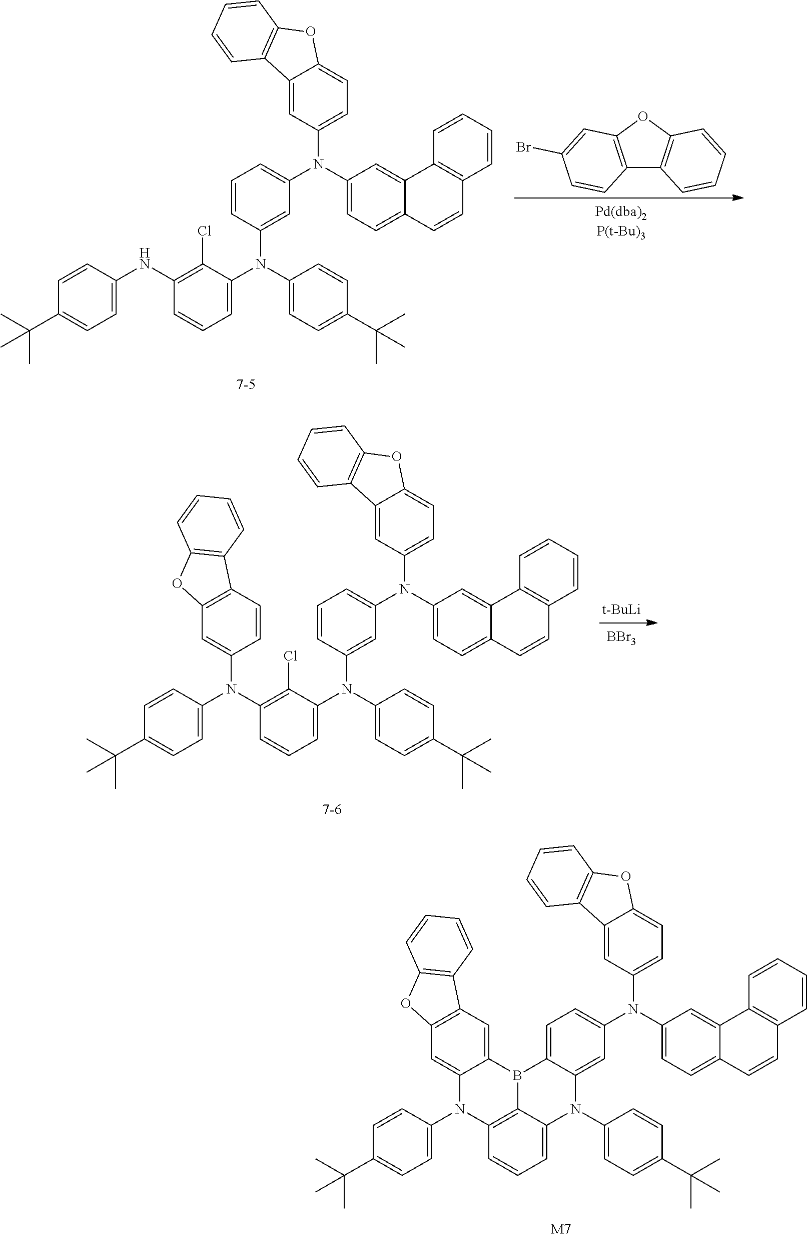

The specific synthetic procedure of the organic compound M7 is carried out as follows:

### Synthesis of Intermediate 7-1

2-bromodibenzofuran (24.6 g, 100 mmol), 3-phenanthrylamine (19.3 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and inorganic phase, and the organic phase was subjected to column chromatography to give Intermediate 7-1 in 90% yield, MS (ASAP)=359.1.

### Synthesis of Intermediate 7-2

1-bromo-3-chlorobenzene (19 g, 100 mmol), Intermediate 7-1 (35.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 7-2 in 62% yield, MS (ASAP)=469.1.

### Synthesis of Intermediate 7-3

Intermediate 7-2 (46.9 g, 100 mmol), 4-tert-butylaniline (14.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 7-3 in 82% yield, MS (ASAP)=582.3.

### Synthesis of Intermediate 7-4

Intermediate 7-3 (58.2 g, 100 mmol), 1-bromo-2,3-dichlorobenzene (22.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 7-4 in 58% yield, MS (ASAP)=726.2.

### Synthesis of Intermediate 7-5

Intermediate 7-4 (72.6 g, 100 mmol), 4-tert-butylaniline (14.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 7-5 in 61% yield, MS (ASAP)=839.4.

### Synthesis of Intermediate 7-6

Intermediate 7-5 (83.9 g, 100 mmol), 3-bromodibenzofuran (25 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 7-6 in 77% yield, MS (ASAP)=1005.4.

### Synthesis of Organic Compound M7

Intermediate 7-6 (50.3 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M1 as a pale yellow solid powder in 24% yield, MS (ASAP)=979.4.

### Example 8

### Synthesis of Organic Compound M8

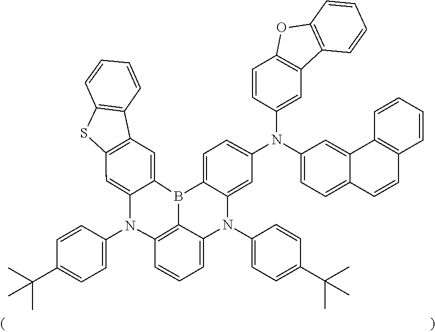

The synthetic route of the organic compound M8 is as follows:

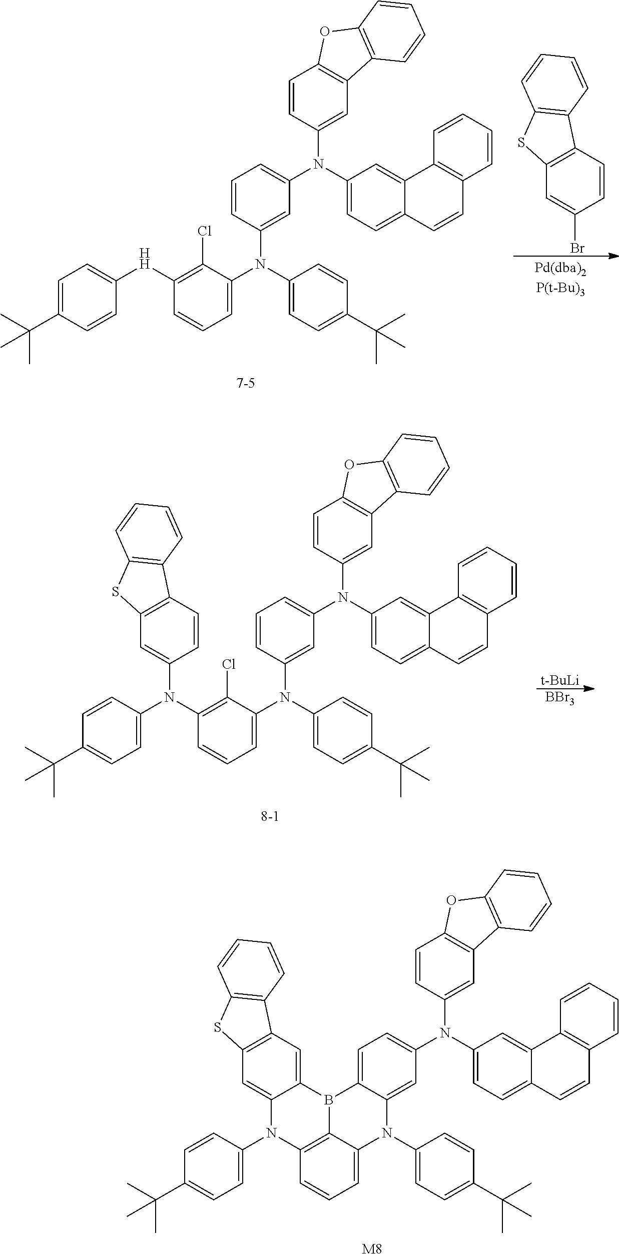

The specific synthetic procedure of organic compound M8 is carried out as follows:

### Synthesis of Intermediate 8-1

Intermediate 7-5 (83.9 g, 100 mmol), 3-bromodibenzothiophene (26.2 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 8-1 in 73% yield, MS (ASAP)=1021.4.

### Synthesis of Organic Compound M8

Intermediate 8-1 (51 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M8 as a pale yellow solid powder in 33% yield, MS (ASAP)=995.4.

### Example 9

### Synthesis of Organic Compound M9

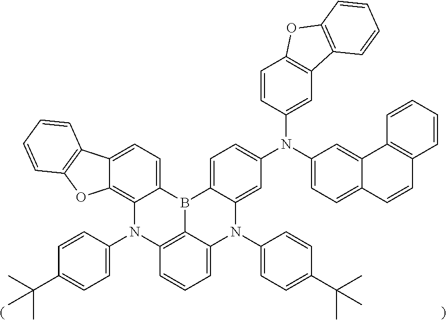 [SMILES: CC(C)(C)c1ccc(N2c3cc(N(c4ccc5ccc6ccccc6c5c4)c4ccc5oc6ccccc6c5c4)ccc3B3c4ccc5c(oc6ccccc65)c4N(c4ccc(C(C)(C)C)cc4)c4cccc2c43)cc1]

The synthetic route of the organic compound M9 is as follows:

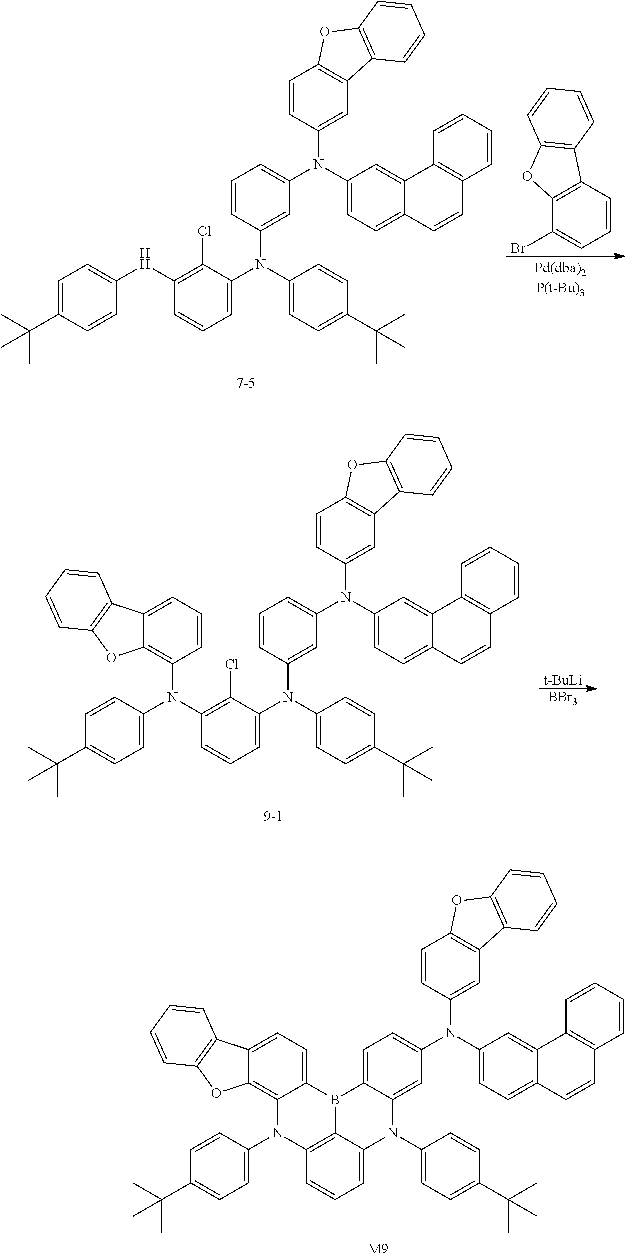

The specific synthetic procedure of the organic compound M9 is carried out as follows:

### Synthesis of Intermediate 9-1

Intermediate 7-5 (83.9 g, 100 mmol), 4-bromodibenzofuran (26.2 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 9-1 in 68% yield, MS (ASAP)=1005.4.

### Synthesis of Organic Compound M9

Intermediate 9-1 (50 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M9 as a pale yellow solid powder in 27% yield, MS (ASAP)=979.4.

### Example 10

### Synthesis of Organic Compound M10

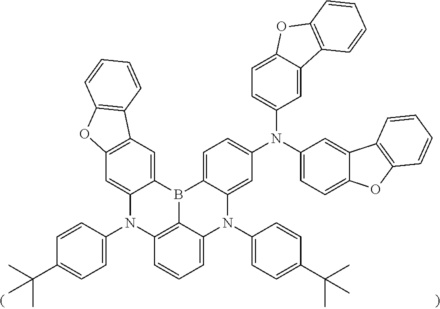 [SMILES: CC(C)(C)c1ccc(N2c3cc(N(c4ccc5oc6ccccc6c5c4)c4ccc5oc6ccccc6c5c4)ccc3B3c4cc5c(cc4N(c4ccc(C(C)(C)C)cc4)c4cccc2c43)oc2ccccc25)cc1]

The synthetic route of the organic compound M10 is as follows:

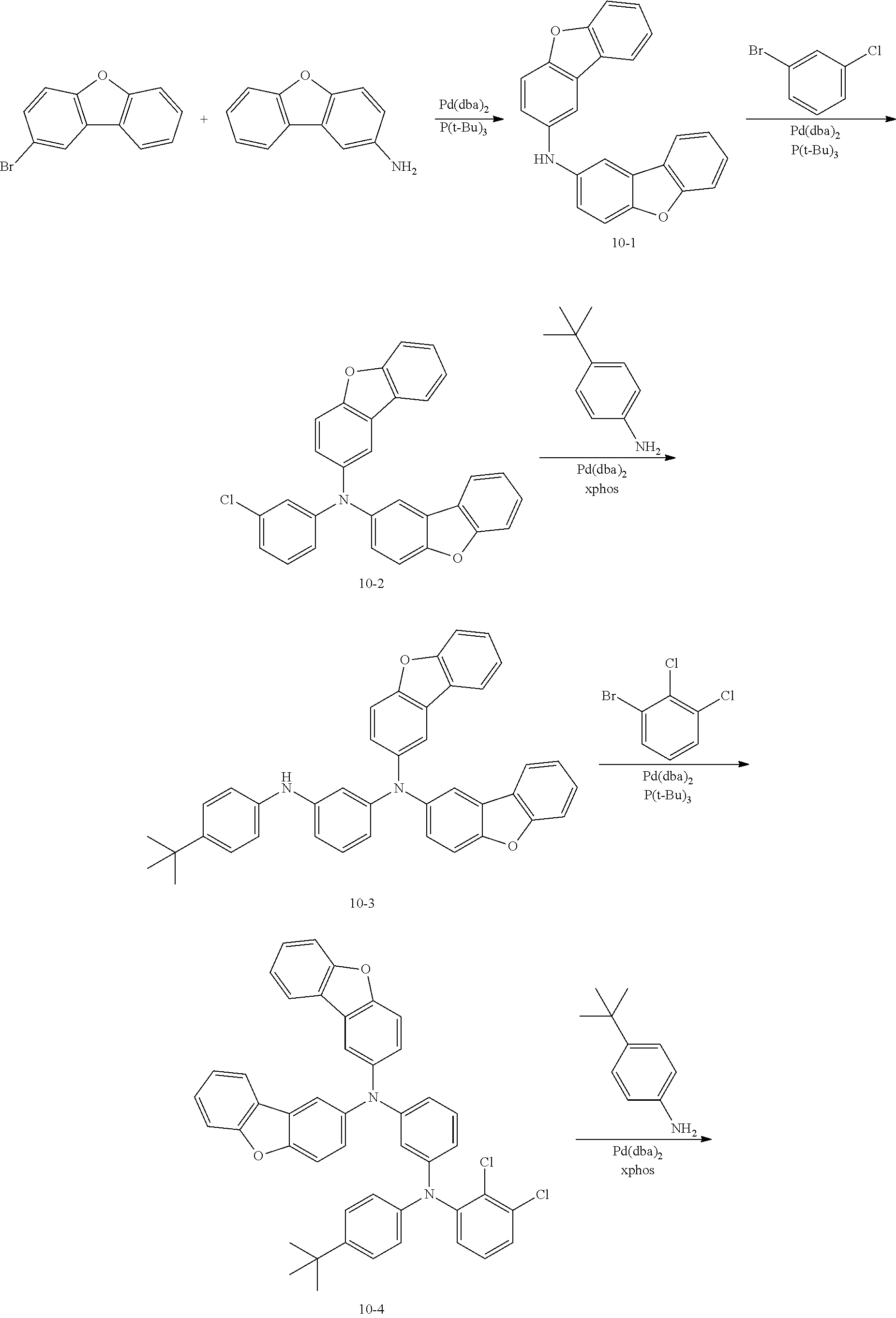

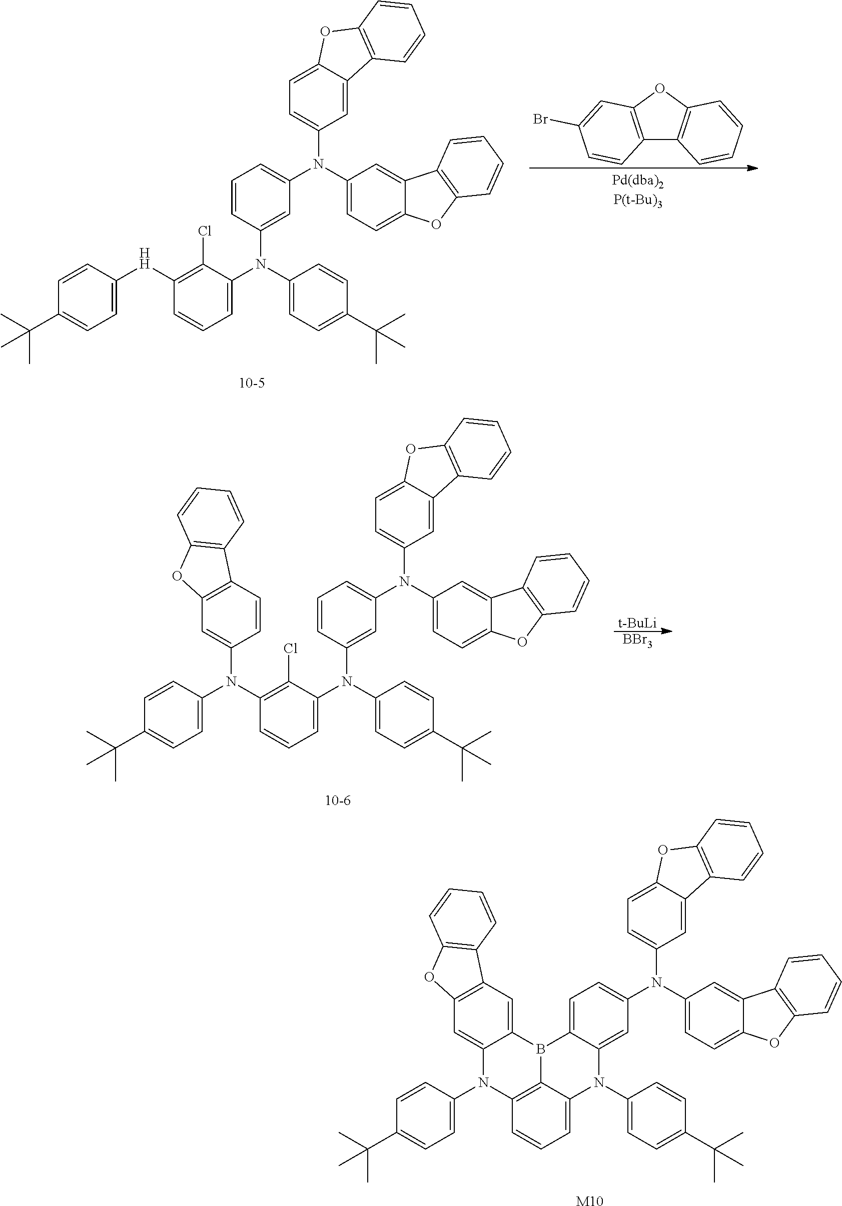

The specific synthetic procedure of the organic compound M10 is carried out as follows:

### Synthesis of Intermediate 10-1

2-bromodibenzofuran (24.6 g, 100 mmol), 2-aminodibenzofuran (18.3 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 10-1 in 88% yield, MS (ASAP)=349.1.

### Synthesis of Intermediate 10-2

1-bromo-3-chlorobenzene (19 g, 100 mmol), Intermediate 10-1 (34.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 10-2 in 55% yield, MS (ASAP)=459.1.

### Synthesis of Intermediate 10-3

Intermediate 10-2 (45.9 g, 100 mmol), 4-tert-butylaniline (14.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 10-3 in 85% yield, MS (ASAP)=572.3.

### Synthesis of Intermediate 10-4

Intermediate 10-3 (57.2 g, 100 mmol), 1-bromo-2,3-dichlorobenzene (22.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 10-4 in 73% yield, MS (ASAP)=716.2.

### Synthesis of Intermediate 10-5

Intermediate 10-4 (71.6 g, 100 mmol), 4-tert-butylaniline (14.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation, The mixture was extracted and washed with water and separated to an organic phase and an inorganic phase, and the organic phase was subjected to column chromatography to give Intermediate 10-5 in 58% yield, MS (ASAP)=829.4.

### Synthesis of Intermediate 10-6

Intermediate 10-5 (82.9 g, 100 mmol), 3-bromodibenzofuran (25 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 10-6 in 74% yield, MS (ASAP)=995.4.

### Synthesis of Organic Compound M10

Intermediate 10-6 (49.8 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M10 as a pale yellow solid powder in 19% yield, MS (ASAP)=969.4.

### Example 11

### Synthesis of Organic Compound M11

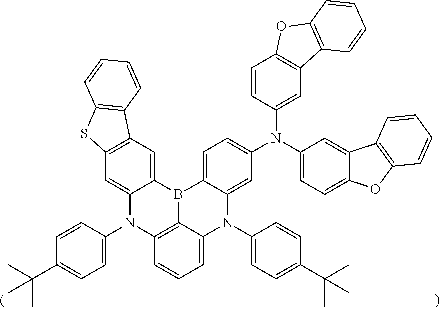 [SMILES: CC(C)(C)c1ccc(N2c3cc(N(c4ccc5oc6ccccc6c5c4)c4ccc5oc6ccccc6c5c4)ccc3B3c4cc5c(cc4N(c4ccc(C(C)(C)C)cc4)c4cccc2c43)sc2ccccc25)cc1]

The synthetic route of the organic compound M11 is as follows:

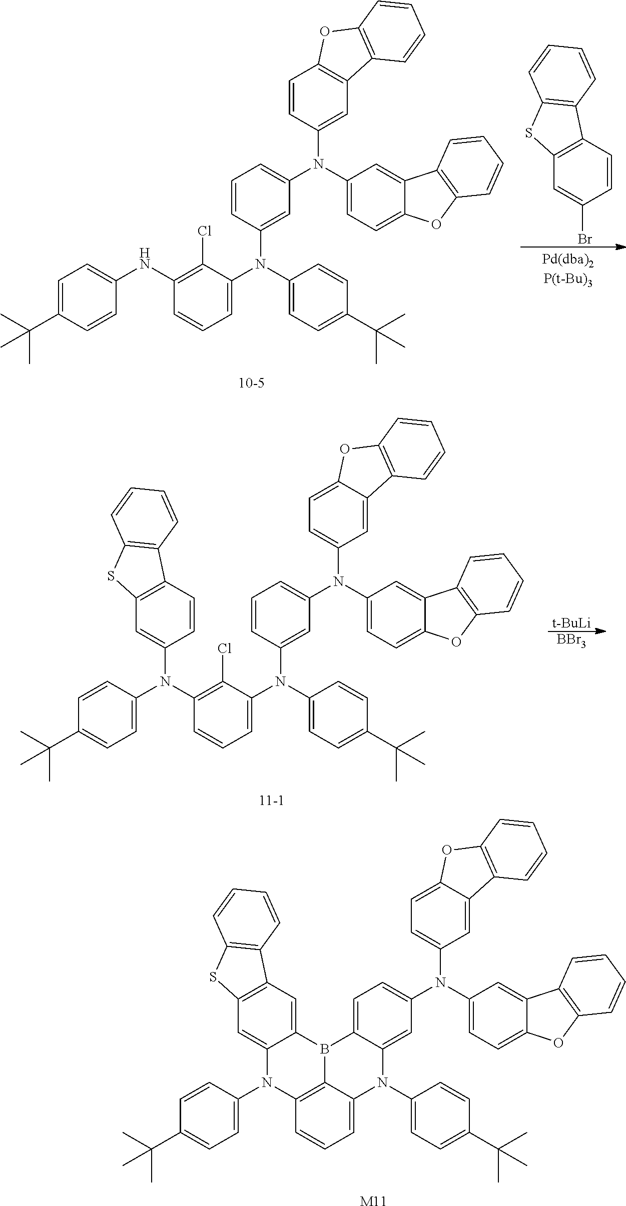

The specific synthetic procedure of the organic compound M11 is carried out as follows:

### Synthesis of Intermediate 11-1

Intermediate 10-5 (82.9 g, 100 mmol), 3-bromodibenzothiophene (26.2 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 10-1 in 62% yield, MS (ASAP)=1011.4.

### Synthesis of Organic Compound M11

Intermediate 11-1 (50.6 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M11 as a pale yellow solid powder in 29% yield, MS (ASAP)=985.4.

### Example 12

### Synthesis of Organic Compound M12

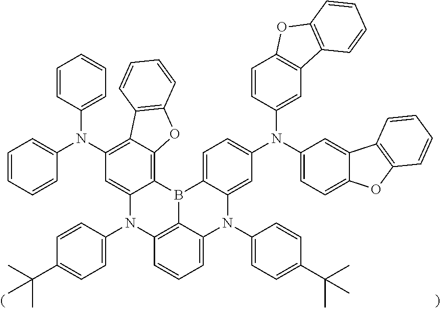 [SMILES: CC(C)(C)c1ccc(N2c3cc(N(c4ccc5oc6ccccc6c5c4)c4ccc5oc6ccccc6c5c4)ccc3B3c4c2cccc4N(c2ccc(C(C)(C)C)cc2)c2cc(N(c4ccccc4)c4ccccc4)c4c(oc5ccccc54)c23)cc1]

The synthetic route of the organic compound M12 is as follows:

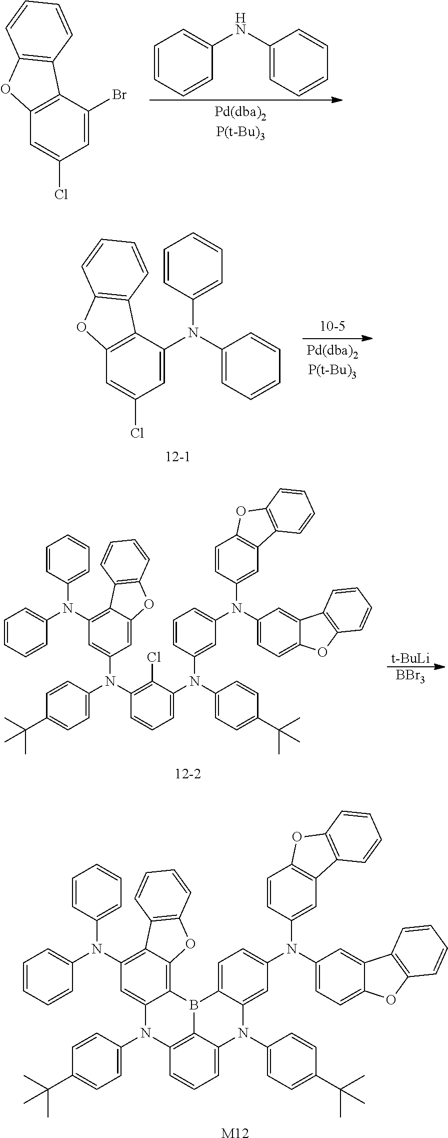

The specific synthetic procedure of the organic compound M12 is carried out as follows:

### Synthesis of Intermediate 12-1

1-bromo-3-chlorodibenzofuran (28 g, 100 mmol), diphenylamine (16.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase and separated to an organic phase and an inorganic phase, and the organic phase was subjected to column chromatography to give Intermediate 12-1 in 85% yield, MS (ASAP)=369.1.

### Synthesis of Intermediate 12-2

Intermediate 10-5 (82.9 g, 100 mmol), Intermediate 12-1 (36.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 12-2 in 67% yield, MS (ASAP)=1162.5.

### Synthesis of Organic Compound M12

Intermediate 12-2 (58.1 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M12 as a pale yellow solid powder in 28% yield, MS (ASAP)=1136.5.

### Example 13

### Synthesis of Organic Compound M13

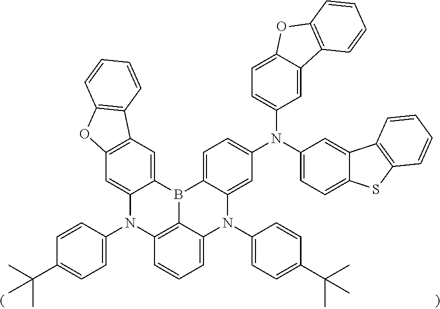 [SMILES: CC(C)(C)c1ccc(N2c3cc(N(c4ccc5oc6ccccc6c5c4)c4ccc5sc6ccccc6c5c4)ccc3B3c4cc5c(cc4N(c4ccc(C(C)(C)C)cc4)c4cccc2c43)oc2ccccc25)cc1]

The synthetic route of the organic compound M13 is as follows:

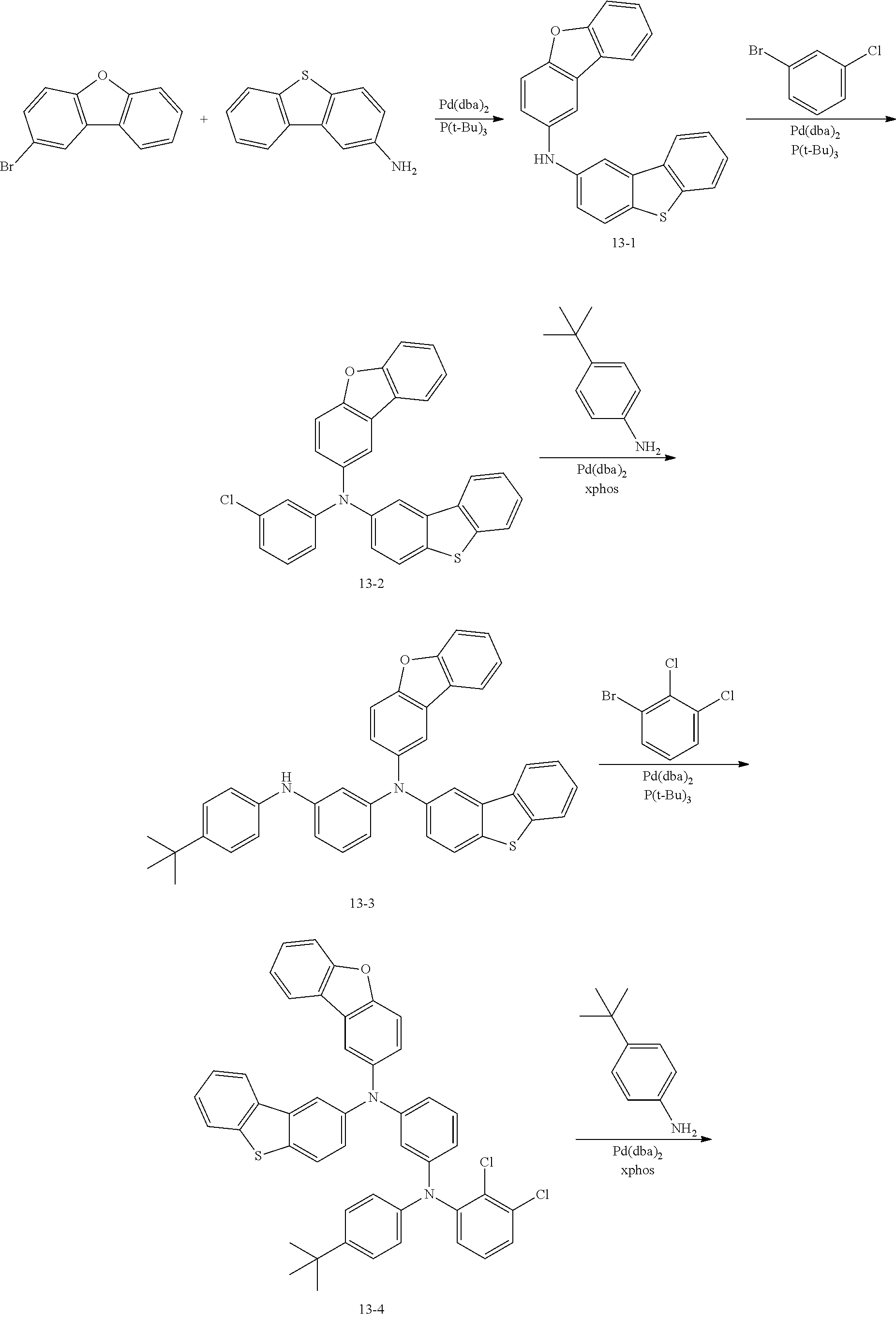

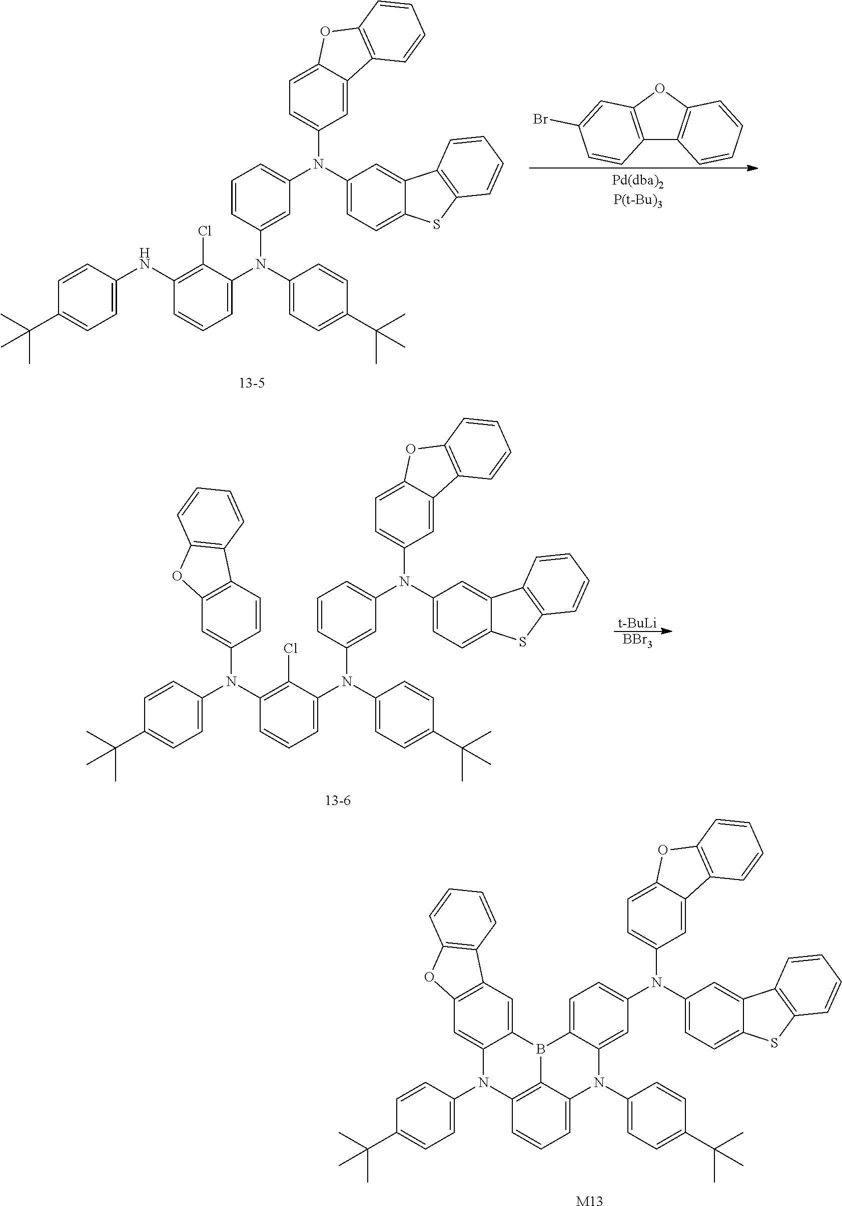

The specific synthetic procedure of the organic compound M13 is carried out as follows:

### Synthesis of Intermediate 13-1

2-Bromodibenzofuran (24.6 g, 100 mmol), 2-aminodibenzothiophene (19.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 13-1 in 65% yield, MS (ASAP)=365.1.

### Synthesis of Intermediate 13-2

1-bromo-3-chlorobenzene (19 g, 100 mmol), Intermediate 13-1 (36.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 13-2 in 57% yield, MS (ASAP)=475.1.

### Synthesis of Intermediate 13-3

Intermediate 13-2 (47.5 g, 100 mmol), 4-tert-butylaniline (14.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 13-3 in 77% yield, MS (ASAP)=588.2.

### Synthesis of Intermediate 13-4

Intermediate 13-3 (58.8 g, 100 mmol), 1-bromo-2,3-dichlorobenzene (22.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 13-4 in 71% yield, MS (ASAP)=732.2.

### Synthesis of Intermediate 13-5

Intermediate 13-4 (73.2 g, 100 mmol), 4-tert-butylaniline (14.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 13-5 in 53% yield, MS (ASAP)=845.3.

### Synthesis of Intermediate 13-6

Intermediate 13-5 (84.5 g, 100 mmol), 3-bromodibenzofuran (25 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 13-6 in 79% yield, MS (ASAP)=1011.4.

### Synthesis of Organic Compound M13

Intermediate 13-6 (50.6 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M13 as a pale yellow solid powder in 25% yield, MS (ASAP)=985.4.

### Example 14

### Synthesis of Organic Compound M14

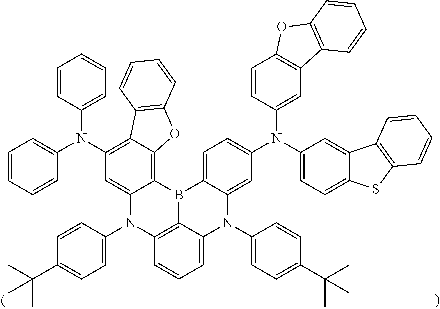 [SMILES: CC(C)(C)c1ccc(N2c3cc(N(c4ccc5oc6ccccc6c5c4)c4ccc5sc6ccccc6c5c4)ccc3B3c4c2cccc4N(c2ccc(C(C)(C)C)cc2)c2cc(N(c4ccccc4)c4ccccc4)c4c(oc5ccccc54)c23)cc1]

The synthetic route of the organic compound M14 is as follows:

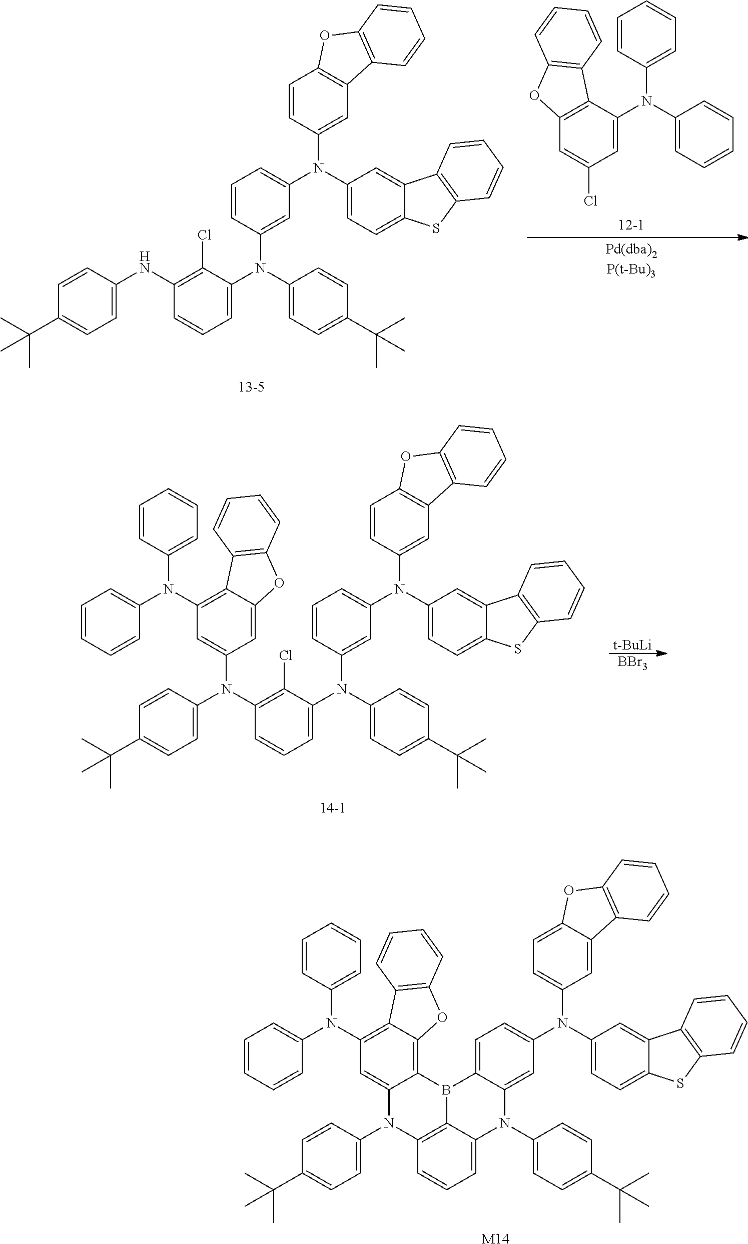

The specific synthetic procedure of the organic compound M14 is carried out as follows:

### Synthesis of Intermediate 14-1

Intermediate 13-5 (84.5 g, 100 mmol), Intermediate 12-1 (36.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 14-1 in 62% yield, MS (ASAP)=1178.4.

### Synthesis of Organic Compound M14

Intermediate 14-1 (58.9 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M14 as a pale yellow solid powder in 31% yield, MS (ASAP)=1152.5.

### Example 15

### Synthesis of Organic Compound M15

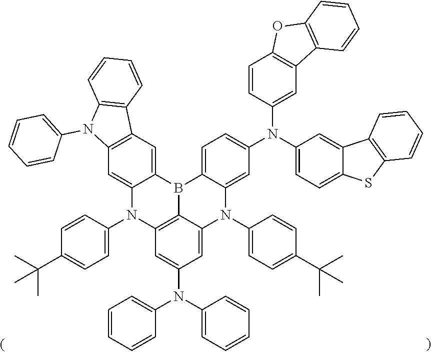 [SMILES: CC(C)(C)c1ccc(N2c3cc(N(c4ccc5oc6ccccc6c5c4)c4ccc5sc6ccccc6c5c4)ccc3B3c4cc5c6ccccc6n(-c6ccccc6)c5cc4N(c4ccc(C(C)(C)C)cc4)c4cc(N(c5ccccc5)c5ccccc5)cc2c43)cc1]

The synthetic route of the organic compound M15 is as follows:

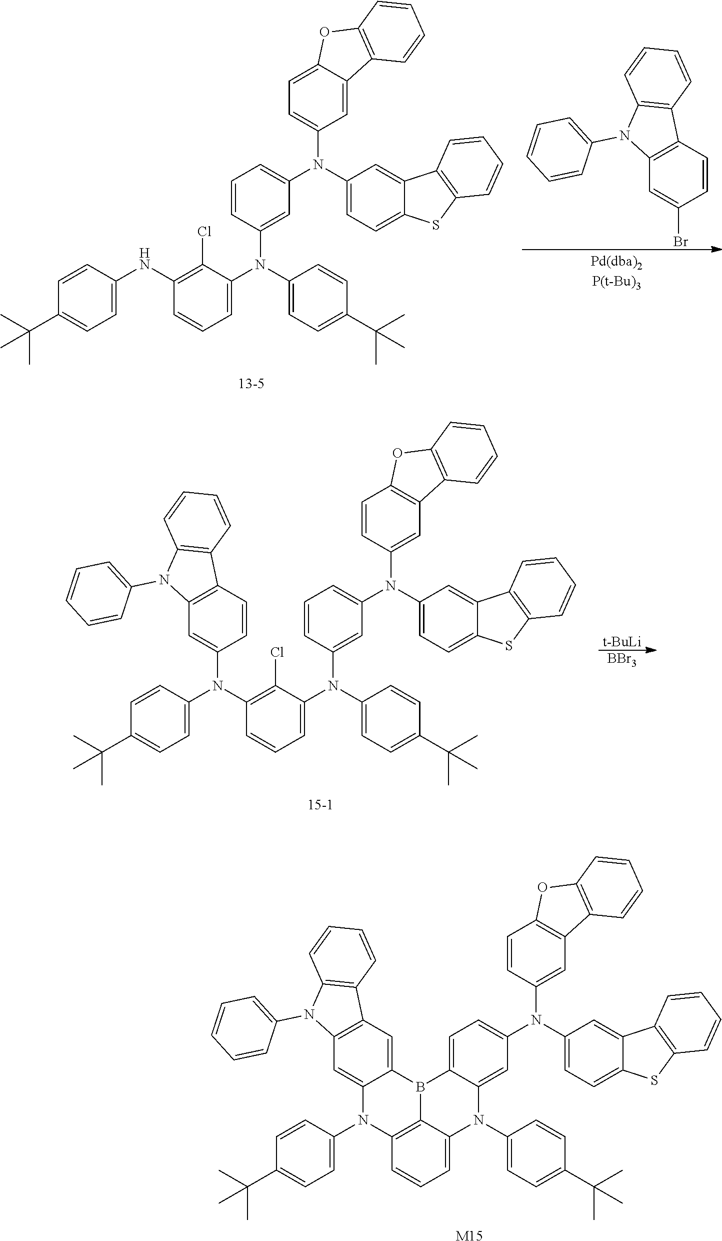

The specific synthetic procedure of the organic compound M15 is carried out as follows:

Intermediate 13-5 (84.5 g, 100 mmol), 2-bromo-9-phenylcarbazole (32.1 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 15-1 in 54% yield, MS (ASAP)=1086.4.

### Synthesis of Organic Compound M15

Intermediate 15-1 (54.3 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M15 as a pale yellow solid powder in 36% yield, MS (ASAP)=1060.4.

### Example 16

### Synthesis of Organic Compound M16

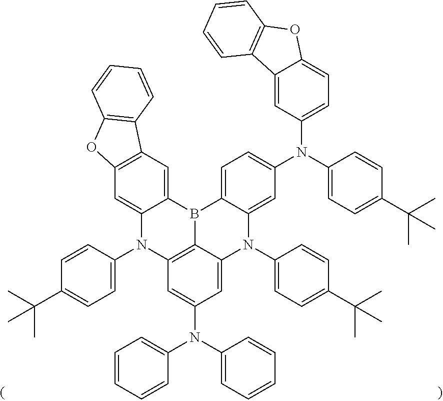 [SMILES: CC(C)(C)c1ccc(N(c2ccc3c(c2)N(c2ccc(C(C)(C)C)cc2)c2cc(N(c4ccccc4)c4ccccc4)cc4c2B3c2cc3c(cc2N4c2ccc(C(C)(C)C)cc2)oc2ccccc23)c2ccc3oc4ccccc4c3c2)cc1]

The synthetic route of the organic compound M16 is as follows:

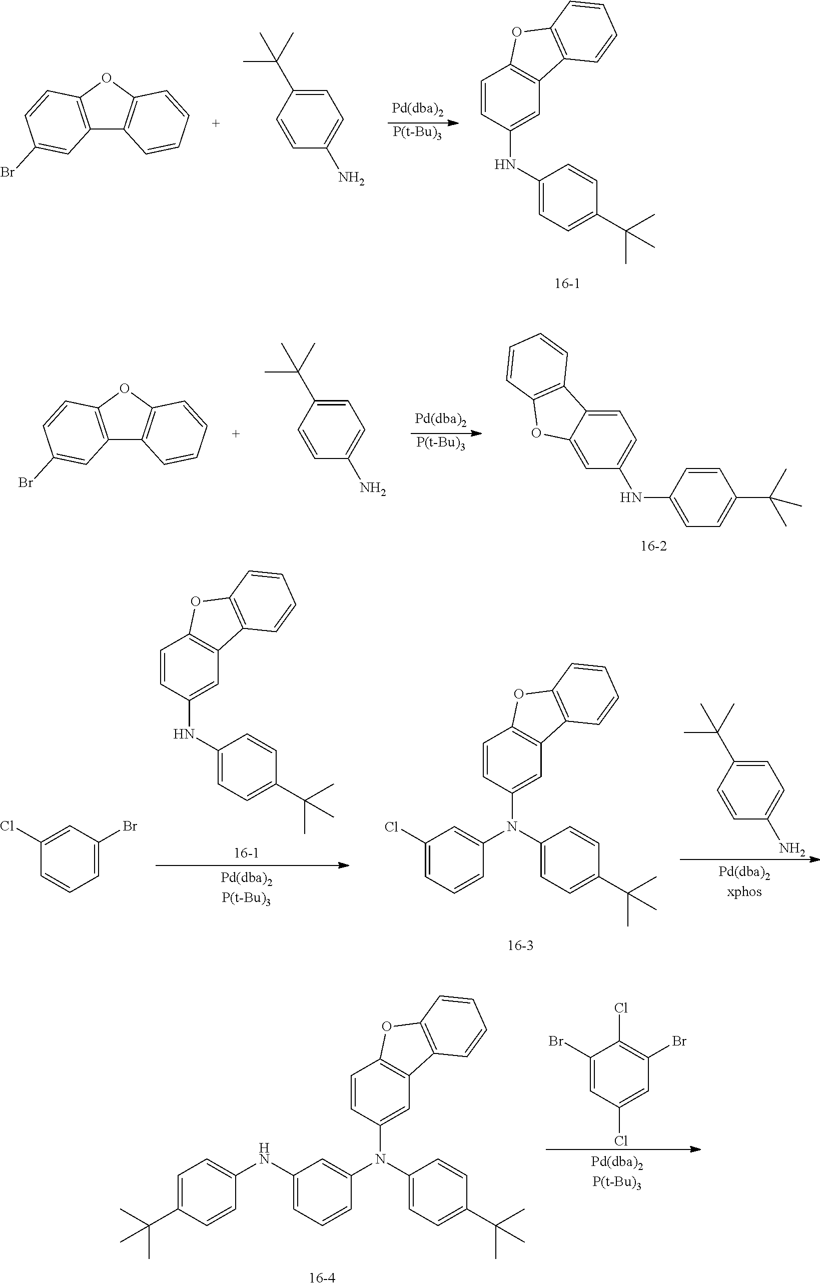

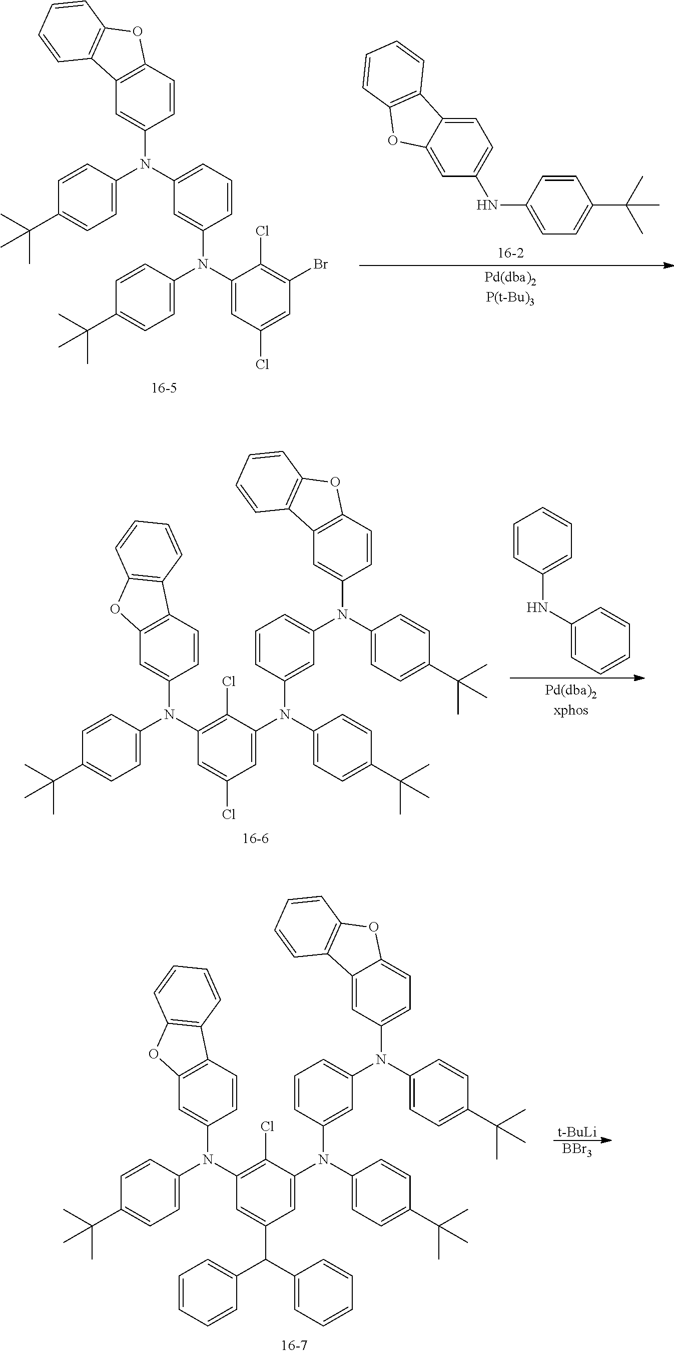

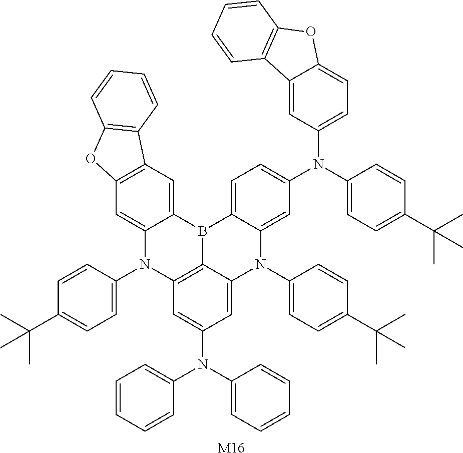

The specific synthetic procedure of the organic compound M16 is carried out as follows:

### Synthesis of Intermediate 16-1

2-bromodibenzofuran (24.6 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 16-1 in 85% yield, MS (ASAP)=315.2.

### Synthesis of Intermediate 16-2

3-bromodibenzofuran (24.6 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 100° C. for 12 h. After cooling, the solvent was removed by rotary evaporation. The mixture was extracted and washed with water and separated to an organic phase and an inorganic phase, and the organic phase was subjected to column chromatography to give Intermediate 16-2 in 88% yield, MS (ASAP)=315.2.

### Synthesis of Intermediate 16-3

1-bromo-3-chlorobenzene (19 g, 100 mmol), Intermediate 16-1 (31.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 16-3 in 74% yield, MS (ASAP)=425.2.

### Synthesis of Intermediate 16-4

Intermediate 16-3 (42.5 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 16-4 in 64% yield, MS (ASAP)=538.3.

### Synthesis of Intermediate 16-5

Intermediate 16-4 (53.8 g, 100 mmol), 1,3-dibromo-2,5-dichlorobenzene (30.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 16-5 in 62% yield, MS (ASAP)=762.2.

### Synthesis of Intermediate 16-6

Intermediate 16-5 (76.2 g, 100 mmol), Intermediate 16-2 (31.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 16-6 in 63% yield, MS (ASAP)=995.4.

### Synthesis of Intermediate 16-7

Intermediate 16-6 (99.5 g, 100 mmol), diphenylamine (16.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 16-7 in 64% yield, MS (ASAP)=1128.5.

### Synthesis of Organic Compound 16

Intermediate 16-7 (56.4 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M16 as a pale yellow solid powder in 32% yield, MS (ASAP)=1102.5.

### Example 17

### Synthesis of Organic Compound M17

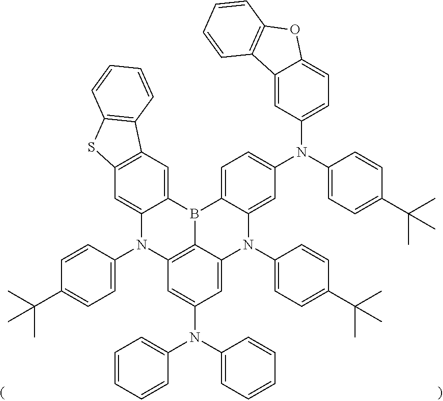 [SMILES: CC(C)(C)c1ccc(N(c2ccc3c(c2)N(c2ccc(C(C)(C)C)cc2)c2cc(N(c4ccccc4)c4ccccc4)cc4c2B3c2cc3c(cc2N4c2ccc(C(C)(C)C)cc2)sc2ccccc23)c2ccc3oc4ccccc4c3c2)cc1]

The synthetic route of the organic compound M17 is as follows:

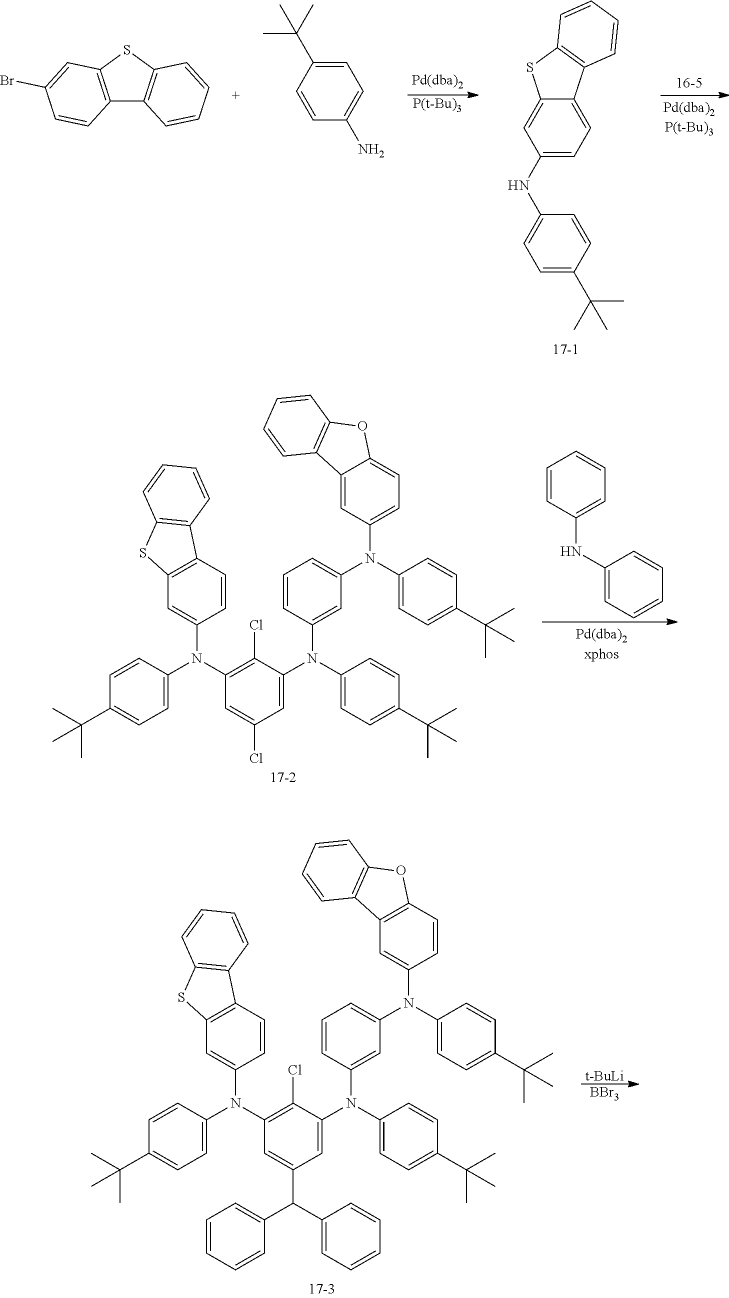

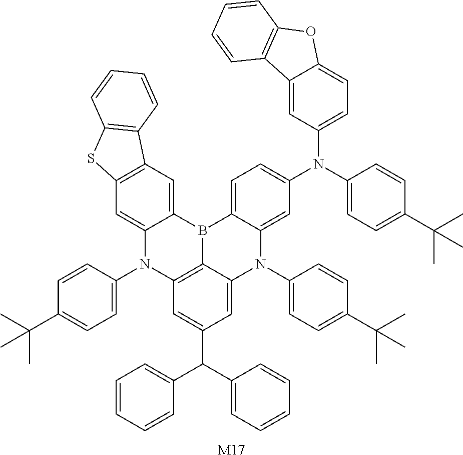

The specific synthetic procedure of the organic compound M17 is carried out as follows:

### Synthesis of Intermediate 17-1

3-bromodibenzothiophene (26 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 17-1 in 87% yield, MS (ASAP)=331.1.

### Synthesis of Intermediate 17-2

Intermediate 16-5 (76.2 g, 100 mmol), Intermediate 17-1 (33.1 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 17-2 in 61% yield, MS (ASAP)=1013.2.

### Synthesis of Intermediate 17-3

Intermediate 17-2 (101.3 g, 100 mmol), diphenylamine (16.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 17-3 in 68% yield, MS (ASAP)=1144.5.

### Synthesis of Organic Compound M17

Intermediate 17-3 (57.2 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M17 as a pale yellow solid powder in 33% yield, MS (ASAP)=1118.5.

### Example 18

### Synthesis of Organic Compound M18

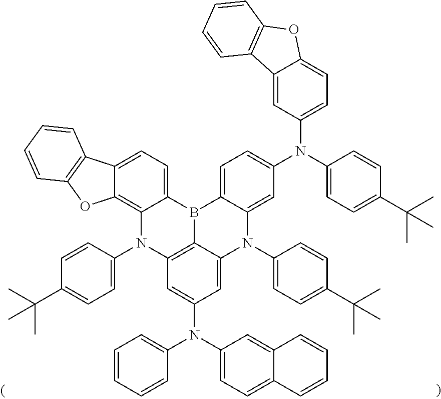 [SMILES: CC(C)(C)c1ccc(N(c2ccc3c(c2)N(c2ccc(C(C)(C)C)cc2)c2cc(N(c4ccccc4)c4ccc5ccccc5c4)cc4c2B3c2ccc3c(oc5ccccc53)c2N4c2ccc(C(C)(C)C)cc2)c2ccc3oc4ccccc4c3c2)cc1]

The synthetic route of the organic compound M18 is as follows:

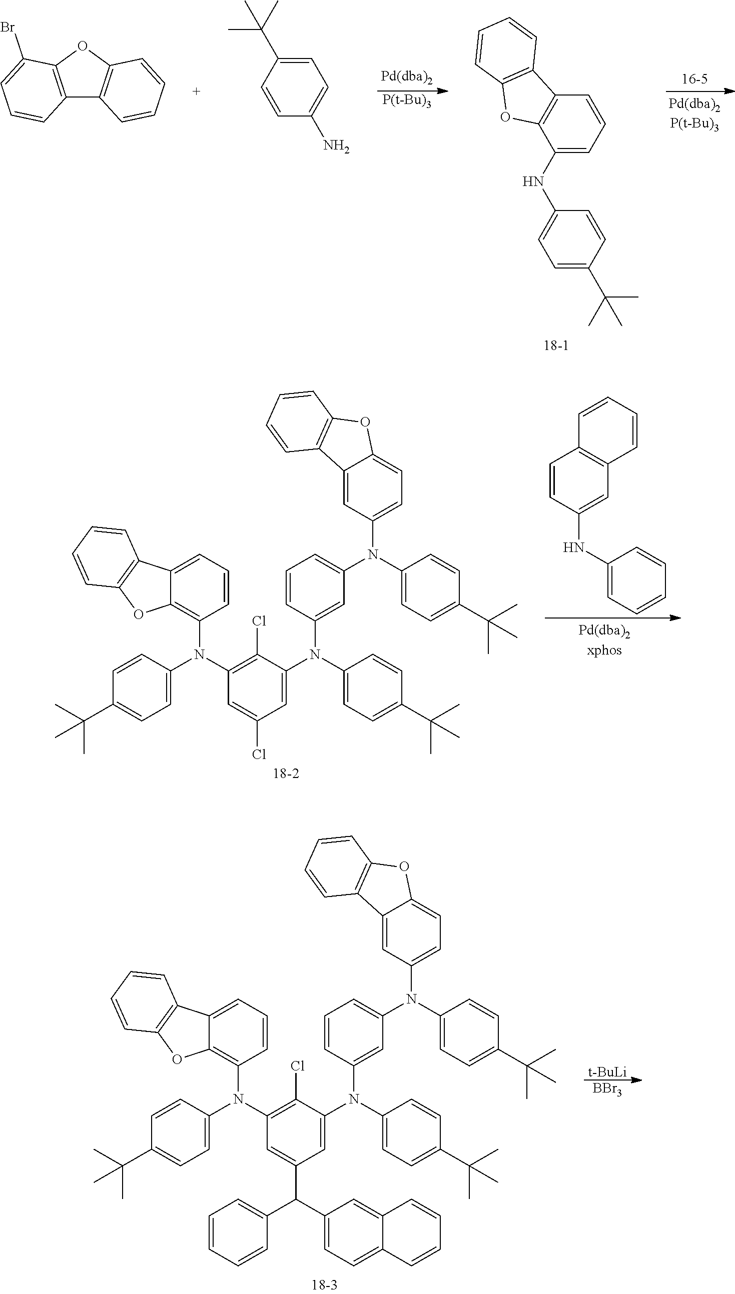

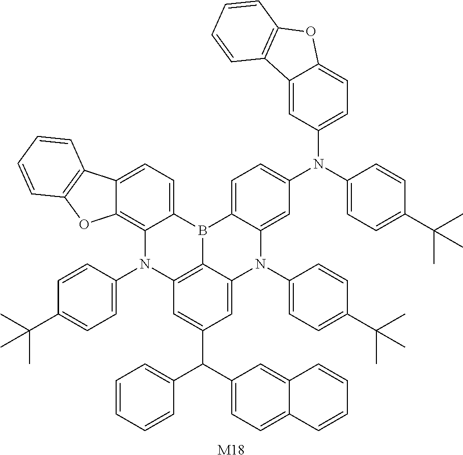

The specific synthetic procedure of the organic compound M18 is carried out as follows:

### Synthesis of Intermediate 18-1

4-Bromodibenzofuran (24.6 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 18-1 in 87% yield, MS (ASAP)=331.1.

### Synthesis of Intermediate 18-2

Intermediate 16-5 (76.2 g, 100 mmol), Intermediate 18-1 (33.1 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 18-2 in 62% yield, MS (ASAP)=995.4.

### Synthesis of Intermediate 18-3

Intermediate 18-2 (99.5 g, 100 mmol), N-phenyl-2-naphthylamine (21.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 18-3 in 71% yield, MS (ASAP)=1178.5.

### Synthesis of Organic Compound M18

Intermediate 18-3 (58.9 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M18 as a pale yellow solid powder in 34% yield, MS (ASAP)=1152.6.

### Example 19

### Synthesis of Organic Compound M19

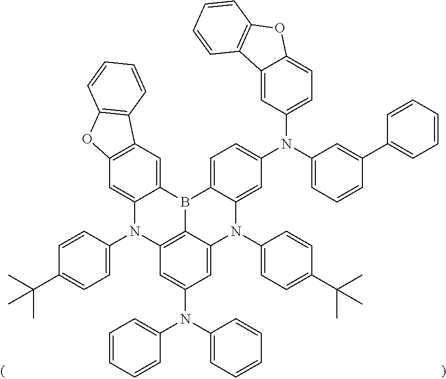 [SMILES: CC(C)(C)c1ccc(N2c3cc(N(c4cccc(-c5ccccc5)c4)c4ccc5oc6ccccc6c5c4)ccc3B3c4cc5c(cc4N(c4ccc(C(C)(C)C)cc4)c4cc(N(c6ccccc6)c6ccccc6)cc2c43)oc2ccccc25)cc1]

The synthetic route of the organic compound M19 is as follows:

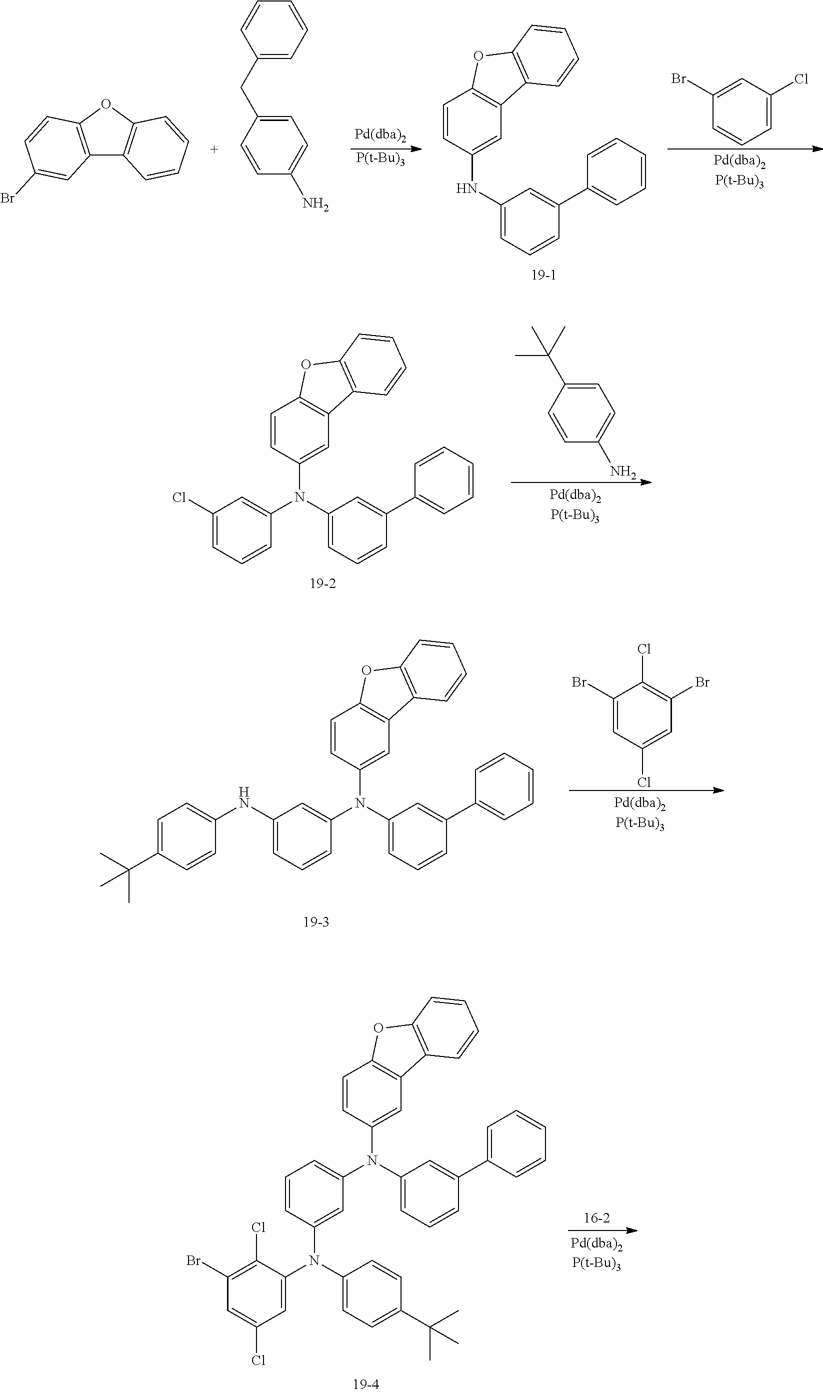

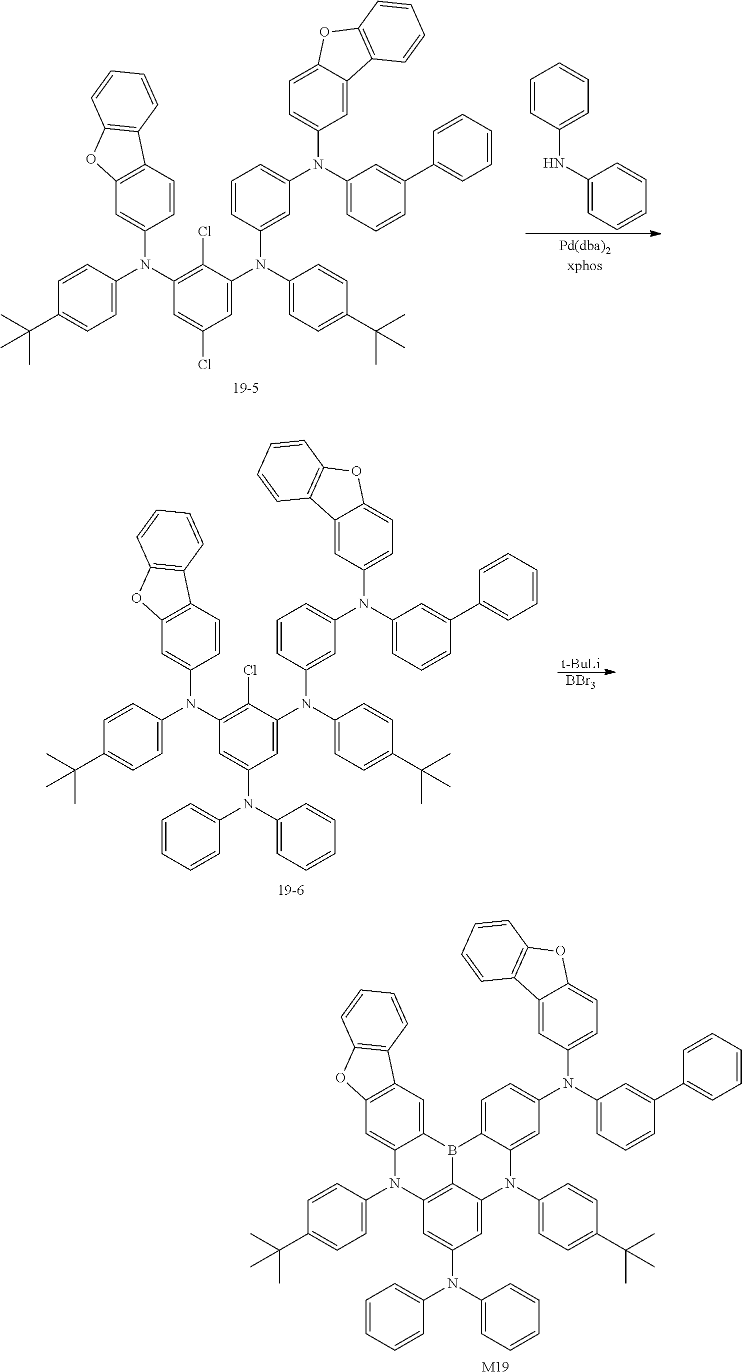

The specific synthetic procedure of the organic compound M19 is carried out as follows:

### Synthesis of Intermediate 19-1

2-bromodibenzofuran (24.6 g, 100 mmol), 3-aminobiphenyl (16.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 19-1 in 82% yield, MS (ASAP)=335.2.

### Synthesis of Intermediate 19-2

1-bromo-3-chlorobenzene (19 g, 100 mmol), Intermediate 19-1 (33.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 19-2 in 68% yield, MS (ASAP)=445.1.

### Synthesis of Intermediate 19-3

Intermediate 19-2 (44.5 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 100° C. for 6 h. After cooling, the solvent was removed by rotary evaporation. The mixture was extracted and washed with water and separated to an organic phase and an inorganic phase, and the organic phase was subjected to column chromatography to give Intermediate 19-3 in 71% yield, MS (ASAP)=558.3.

### Synthesis of Intermediate 19-4

Intermediate 19-3 (55.8 g, 100 mmol), 1,3-dibromo-2,5-dichlorobenzene (30.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation, The mixture was extracted and washed with water and separated to an organic phase and an inorganic phase, and the organic phase was subjected to column chromatography to give Intermediate 19-4 in 61% yield, MS (ASAP)=782.1.

### Synthesis of Intermediate 19-5

Intermediate 19-4 (78.2 g, 100 mmol), Intermediate 16-2 (31.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 19-5 in 62% yield, MS (ASAP)=1015.4.

### Synthesis of Intermediate 19-6

Intermediate 19-5 (101.5 g, 100 mmol), diphenylamine (16.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 19-6 in 57% yield, MS (ASAP)=1148.5.

### Synthesis of Organic Compound M19

Intermediate 19-6 (57.3 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M19 as a pale yellow solid powder in 35% yield, MS (ASAP)=1122.5.

### Example 20

### Synthesis of Organic Compound M20

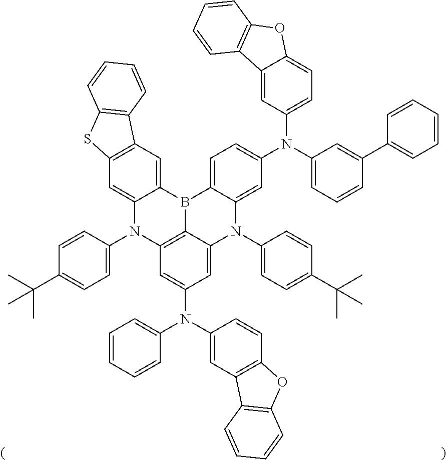 [SMILES: CC(C)(C)c1ccc(N2c3cc(N(c4cccc(-c5ccccc5)c4)c4ccc5oc6ccccc6c5c4)ccc3B3c4cc5c(cc4N(c4ccc(C(C)(C)C)cc4)c4cc(N(c6ccccc6)c6ccc7oc8ccccc8c7c6)cc2c43)sc2ccccc25)cc1]

The synthetic route of the organic compound M20 is as follows:

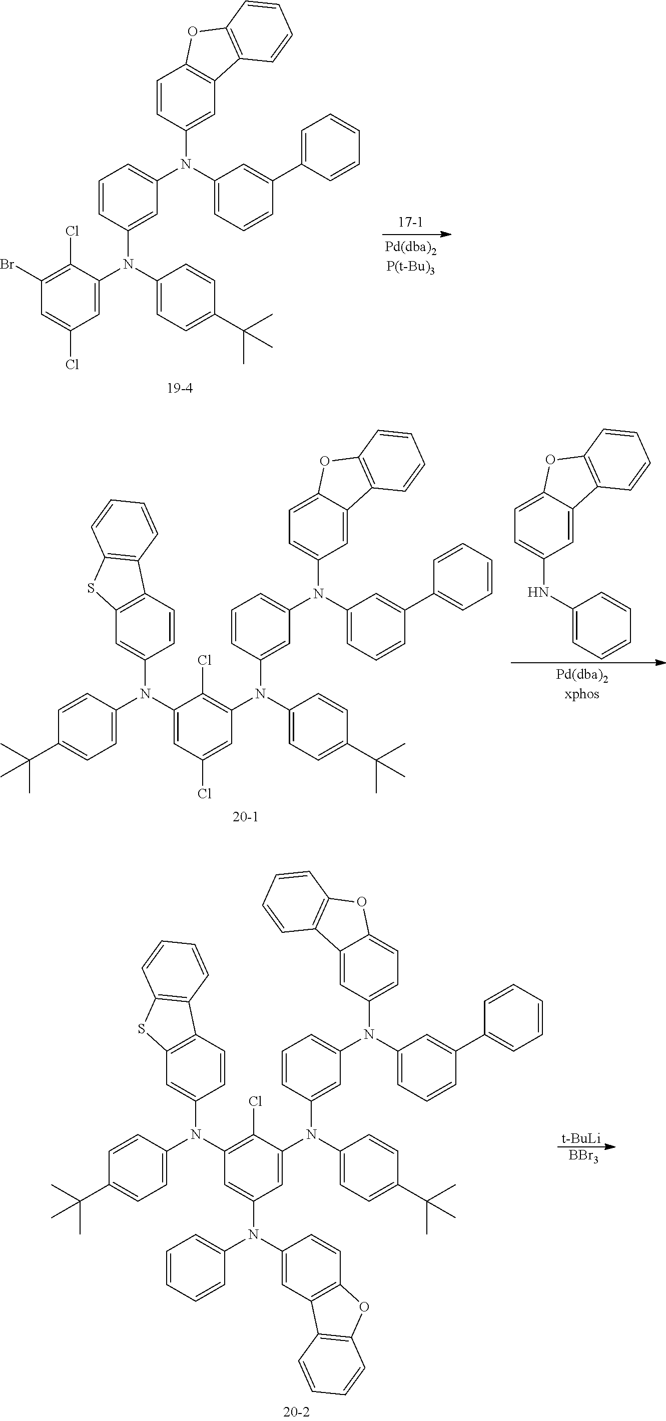

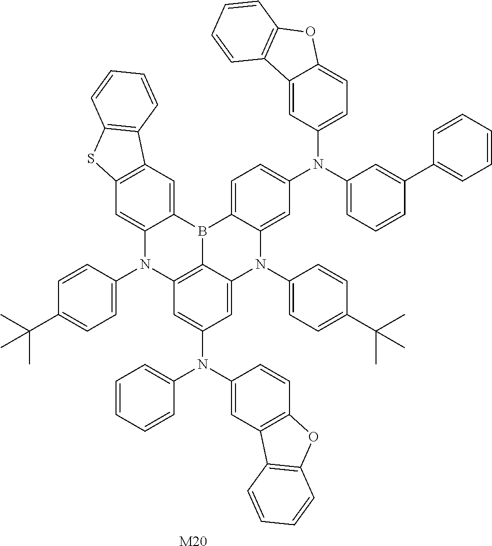 [SMILES: CC(C)(C)c1ccc(N2c3cc(N(c4cccc(-c5ccccc5)c4)c4ccc5oc6ccccc6c5c4)ccc3B3c4cc5c(cc4N(c4ccc(C(C)(C)C)cc4)c4cc(N(c6ccccc6)c6ccc7oc8ccccc8c7c6)cc2c43)sc2ccccc25)cc1 ; "M20"]

The specific synthetic procedure of the organic compound M20 is carried out as follows:

### Synthesis of Intermediate 20-1

Intermediate 19-4 (78.2 g, 100 mmol), Intermediate 17-1 (33.1 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 20-1 in 62% yield, MS (ASAP)=1031.3.

### Synthesis of Intermediate 20-2

Intermediate 20-1 (101.5 g, 100 mmol), N-phenyl-2-dibenzofuranamine (25.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 20-2 in 52% yield, MS (ASAP)=1254.5.

### Synthesis of Organic Compound M20

Intermediate 20-2 (62.7 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M20 as a pale yellow solid powder in 31% yield, MS (ASAP)=1229.5.

### Example 21

### Synthesis of Organic Compound M21

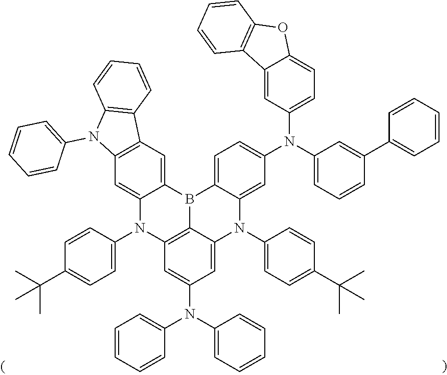 [SMILES: CC(C)(C)c1ccc(N2c3cc(N(c4cccc(-c5ccccc5)c4)c4ccc5oc6ccccc6c5c4)ccc3B3c4cc5c6ccccc6n(-c6ccccc6)c5cc4N(c4ccc(C(C)(C)C)cc4)c4cc(N(c5ccccc5)c5ccccc5)cc2c43)cc1]

The synthetic route of the organic compound M21 is as follows:

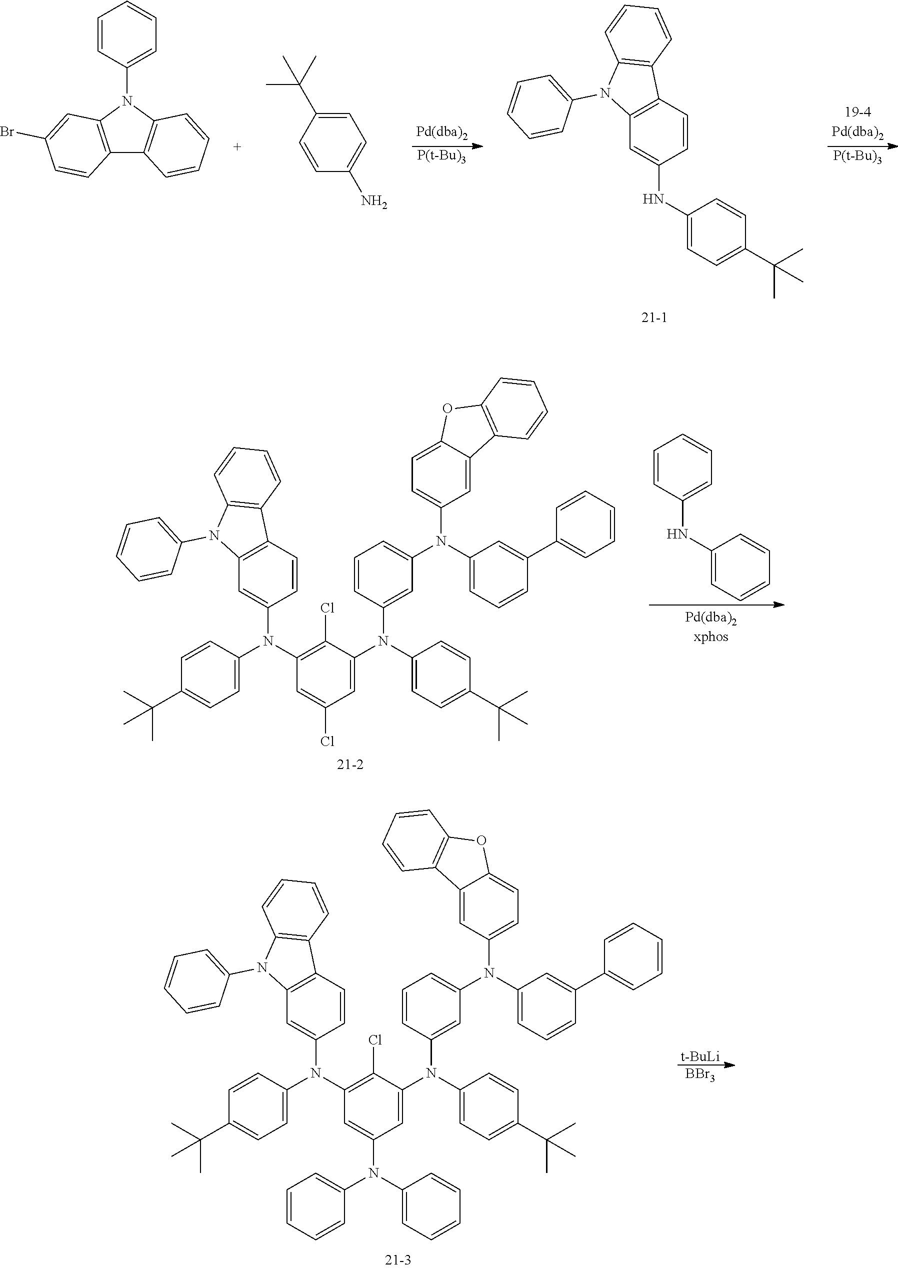

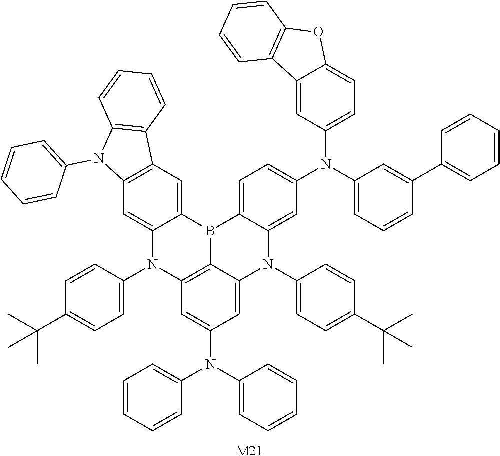

The specific synthetic procedure of the organic compound M21 is carried out as follows:

### Synthesis of Intermediate 21-1

N-phenyl-2-bromocarbazole (32.1 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 21-1 in 82% yield, MS (ASAP)=390.2.

### Synthesis of Intermediate 21-2

Intermediate 19-4 (78.2 g, 100 mmol), Intermediate 21-1 (39.0 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 21-2 in 67% yield, MS (ASAP)=1090.4.

### Synthesis of Intermediate 21-3

Intermediate 21-2 (109 g, 100 mmol), diphenylamine (16.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 21-3 in 77% yield, MS (ASAP)=1223.5.

### Synthesis of Organic Compound M21

Intermediate 21-3 (61.1 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M21 as a pale yellow solid powder in 31% yield, MS (ASAP)=1198.6.

### Example 22

### Synthesis of Organic Compound M22

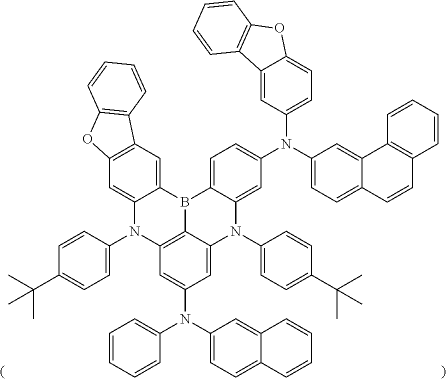 [SMILES: CC(C)(C)c1ccc(N2c3cc(N(c4ccc5ccc6ccccc6c5c4)c4ccc5oc6ccccc6c5c4)ccc3B3c4cc5c(cc4N(c4ccc(C(C)(C)C)cc4)c4cc(N(c6ccccc6)c6ccc7ccccc7c6)cc2c43)oc2ccccc25)cc1]

The synthetic route of the organic compound M22 is as follows:

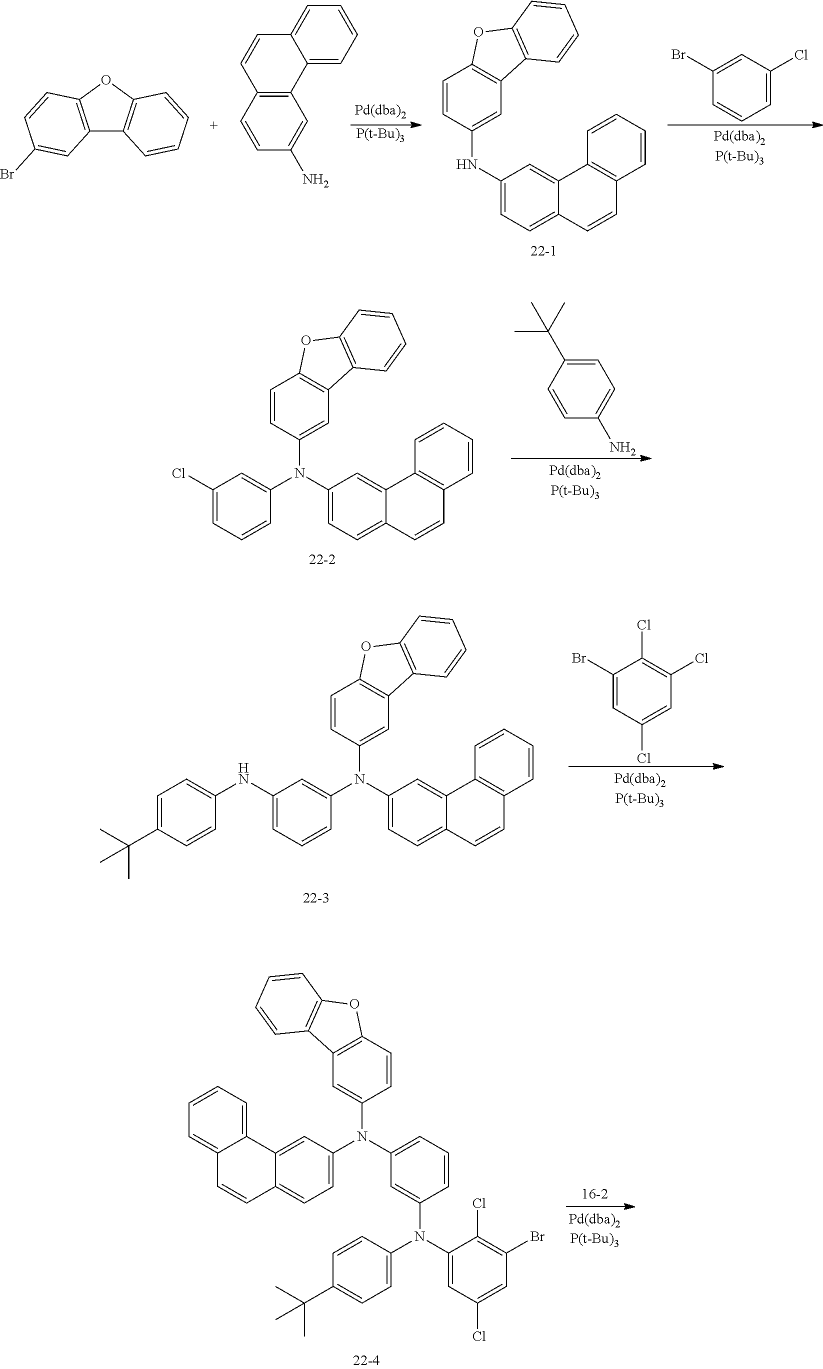

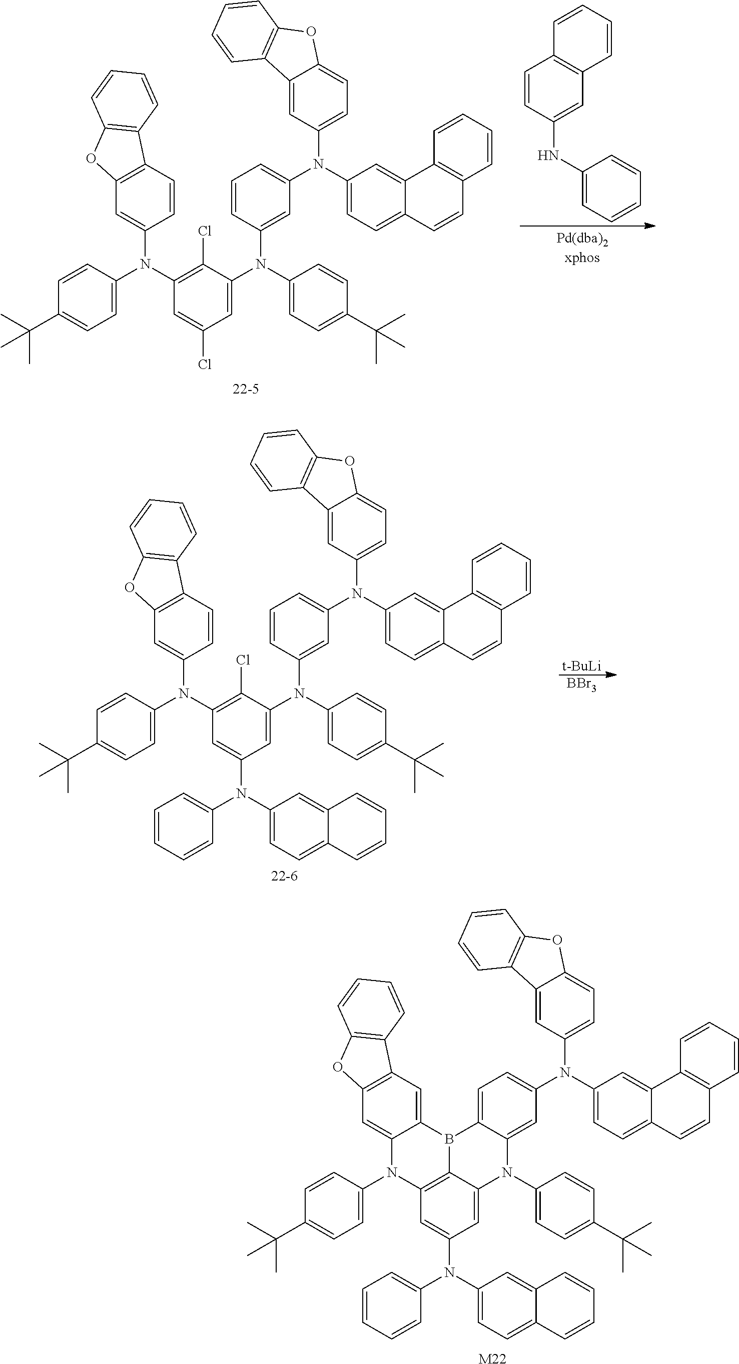

The specific synthetic procedure of the organic compound M22 is carried out as follows:

### Synthesis of Intermediate 22-1

2-bromodibenzofuran (24.6 g, 100 mmol), 3-phenanthrylamine (19.3 g, 100 mmol), Pd(dba)₂ 0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 22-1 in 90% yield, MS (ASAP)=359.1.

### Synthesis of Intermediate 22-2

1-bromo-3-chlorobenzene (19 g, 100 mmol), Intermediate 22-1 (35.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 22-2 in 62% yield, MS (ASAP)=469.1.

### Synthesis of Intermediate 22-3

Intermediate 22-2 (46.9 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 22-3 in 82% yield, MS (ASAP)=582.3.

### Synthesis of Intermediate 22-4

Intermediate 22-3 (58.2 g, 100 mmol), 1,3-dibromo-2,5-dichlorobenzene (30.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 22-4 in 53% yield, MS (ASAP)=806.1.

### Synthesis of Intermediate 22-5

Intermediate 22-4 (80.6 g, 100 mmol), Intermediate 16-2 (31.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 22-5 in 66% yield, MS (ASAP)=1039.4.

### Synthesis of Intermediate 22-6

Intermediate 22-5 (104 g, 100 mmol), N-phenyl-2-naphthylamine (21.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 22-6 in 74% yield, MS (ASAP)=1222.5.

### Synthesis of Organic Compound M22

Intermediate 22-6 (61.1 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M22 as a pale yellow solid powder in 28% yield, MS (ASAP)=1196.5.

### Example 23

### Synthesis of Organic Compound M23

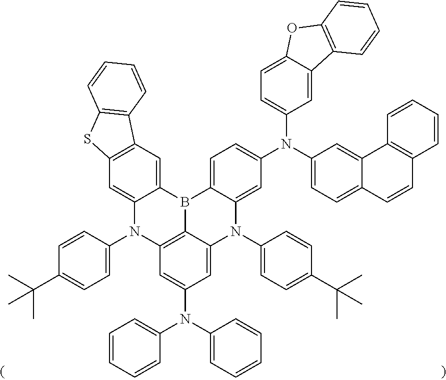 [SMILES: CC(C)(C)c1ccc(N2c3cc(N(c4ccc5ccc6ccccc6c5c4)c4ccc5oc6ccccc6c5c4)ccc3B3c4cc5c(cc4N(c4ccc(C(C)(C)C)cc4)c4cc(N(c6ccccc6)c6ccccc6)cc2c43)sc2ccccc25)cc1]

The synthetic route of the organic compound M23 is as follows:

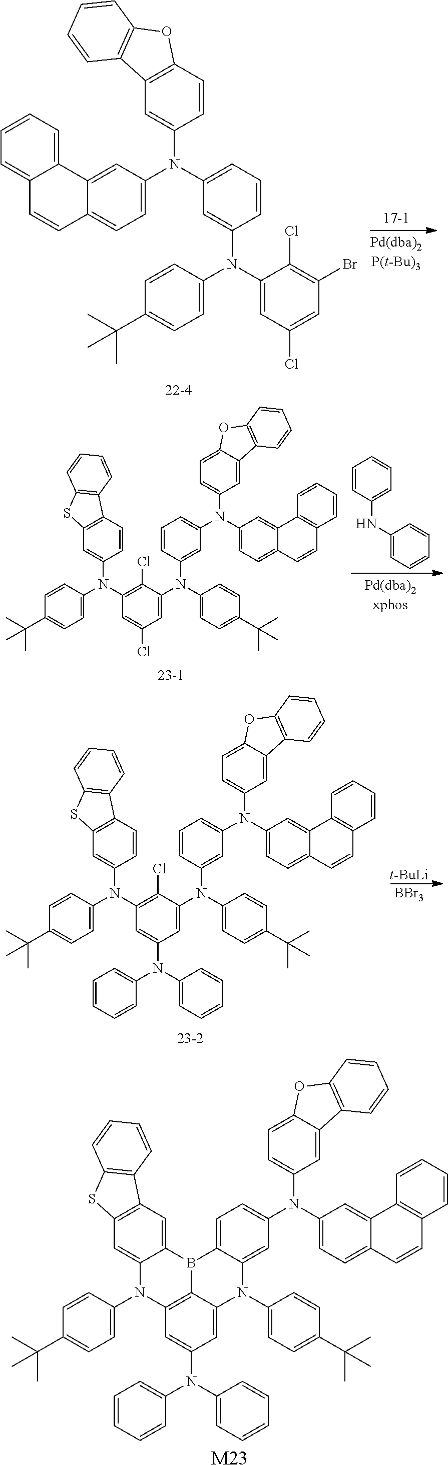

The specific synthetic procedure of the organic compound M23 is carried out as follows:

### Synthesis of Intermediate 23-1

Intermediate 22-4 (80.6 g, 100 mmol), Intermediate 17-1 (33.1 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 23-1 in 67% yield, MS (ASAP)=1055.3.

### Synthesis of Intermediate 23-2

Intermediate 23-1 (105.5 g, 100 mmol), diphenylamine (16.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 23-2 in 72% yield, MS (ASAP)=1188.5.

### Synthesis of Organic Compound M23

Intermediate 23-2 (59.4 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M23 as a pale yellow solid powder in 33% yield, MS (ASAP)=1162.5.

### Example 24

### Synthesis of Organic Compound M24

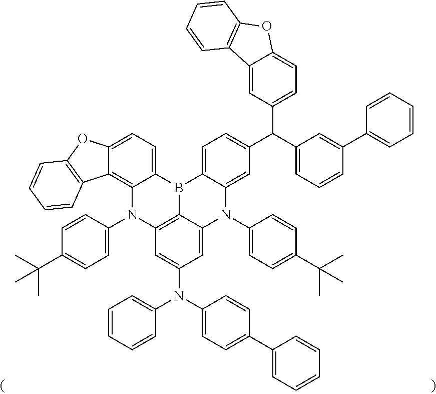 [SMILES: CC(C)(C)c1ccc(N2c3cc(C(c4cccc(-c5ccccc5)c4)c4ccc5oc6ccccc6c5c4)ccc3B3c4ccc5oc6ccccc6c5c4N(c4ccc(C(C)(C)C)cc4)c4cc(N(c5ccccc5)c5ccc(-c6ccccc6)cc5)cc2c43)cc1]

The synthetic route of the organic compound M24 is as follows:

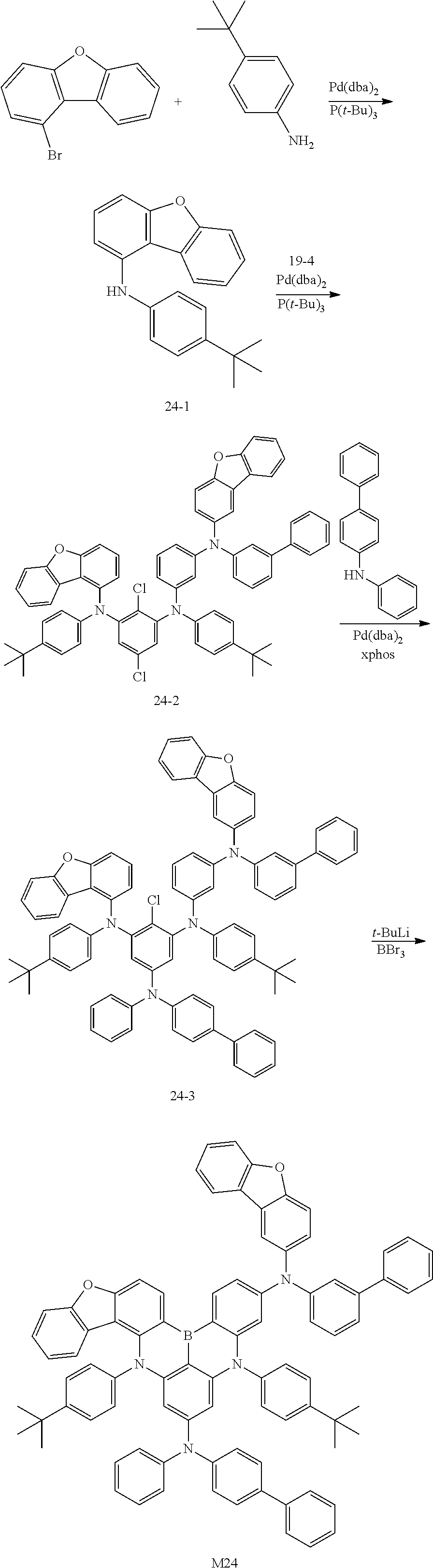

The specific synthetic procedure of the organic compound M24 is carried out as follows:

### Synthesis of Intermediate 24-1

1-bromodibenzofuran (24.6 g, 100 mmol), 4-tert-butyl aniline (14.9 g, 100 mmol), Pd(dba) (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 100° C. for 12 h. After cooling, the solvent was removed by rotary evaporation. The mixture was extracted and washed with water and separated to an organic phase and an inorganic phase, and the organic phase was subjected to column chromatography to give Intermediate 24-1 in 88% yield, MS (ASAP)=315.2.

### Synthesis of Intermediate 24-2

Intermediate 19-4 (78.2 g, 100 mmol), Intermediate 24-1 (31.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 24-2 in 69% yield, MS (ASAP)=1015.4.

### Synthesis of Intermediate 24-3

Intermediate 24-2 (102 g, 100 mmol), N-phenyl-4-benzidine (24.5 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 24-3 in 75% yield, MS (ASAP)=1224.5.

### Synthesis of Organic Compound M24

Intermediate 24-3 (61.2 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M24 as a pale yellow solid powder in 33% yield, MS (ASAP)=1198.5.

### Example 25

### Synthesis of Organic Compound M25

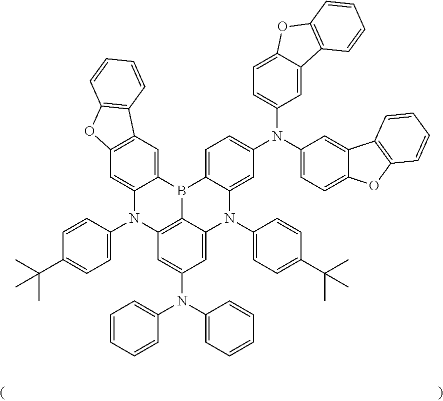 [SMILES: CC(C)(C)c1ccc(N2c3cc(N(c4ccc5oc6ccccc6c5c4)c4ccc5oc6ccccc6c5c4)ccc3B3c4cc5c(cc4N(c4ccc(C(C)(C)C)cc4)c4cc(N(c6ccccc6)c6ccccc6)cc2c43)oc2ccccc25)cc1]

The synthetic route of the organic compound M25 is as follows:

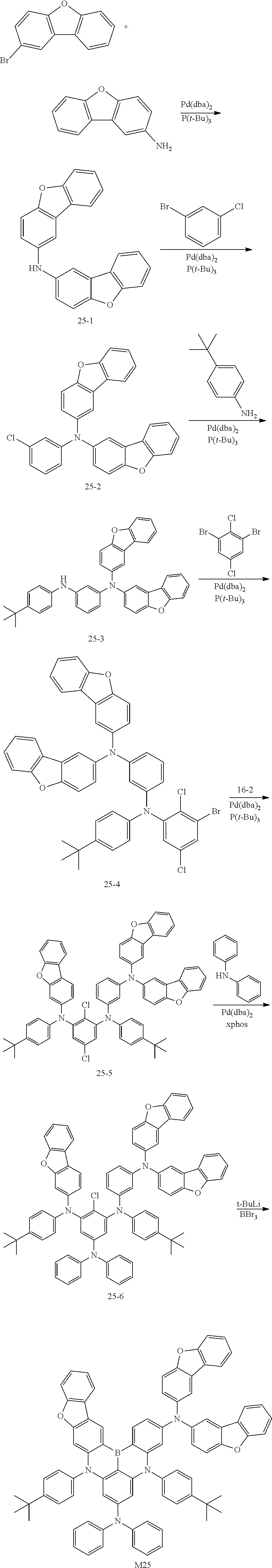

The specific synthetic procedure of the organic compound M25 is carried out as follows:

### Synthesis of Intermediate 25-1

2-bromodibenzofuran (24.6 g, 100 mmol), 2-aminodibenzofuran (18.3 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 25-1 in 88% yield, MS (ASAP)=349.1.

### Synthesis of Intermediate 25-2

1-bromo-3-chlorobenzene (19 g, 100 mmol), Intermediate 25-1 (34.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 25-2 in 55% yield, MS (ASAP)=459.1.

### Synthesis of Intermediate 25-3

Intermediate 25-2 (45.9 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 25-3 in 85% yield, MS (ASAP)=572.3.

### Synthesis of Intermediate 25-4

Intermediate 25-3 (57.2 g, 100 mmol), 1,3-dibromo-2,5-dichlorobenzene (30.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 25-4 in 51% yield, MS (ASAP)=796.1.

### Synthesis of Intermediate 25-5

Intermediate 25-4 (79.6 g, 100 mmol), Intermediate 16-2 (31.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 25-5 in 61% yield, MS (ASAP)=1029.4.

### Synthesis of Intermediate 25-6

Intermediate 25-5 (103 g, 100 mmol), diphenylamine (16.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 25-6 in 71% yield, MS (ASAP)=1162.5.

### Synthesis of Organic Compound M25

Intermediate 25-6 (58.1 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M25 as a pale yellow solid powder in 29% yield, MS (ASAP)=1136.5.

### Example 26

### Synthesis of Organic Compound M26

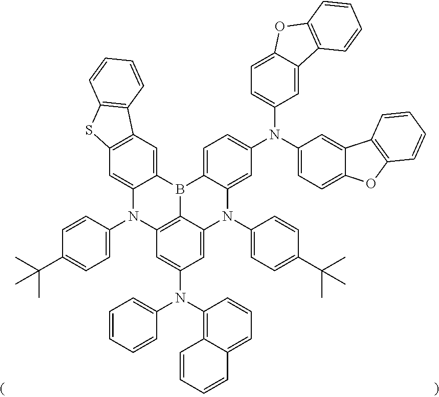 [SMILES: CC(C)(C)c1ccc(N2c3cc(N(c4ccc5oc6ccccc6c5c4)c4ccc5oc6ccccc6c5c4)ccc3B3c4cc5c(cc4N(c4ccc(C(C)(C)C)cc4)c4cc(N(c6ccccc6)c6cccc7ccccc67)cc2c43)sc2ccccc25)cc1]

The synthetic route of the organic compound M26 is as follows:

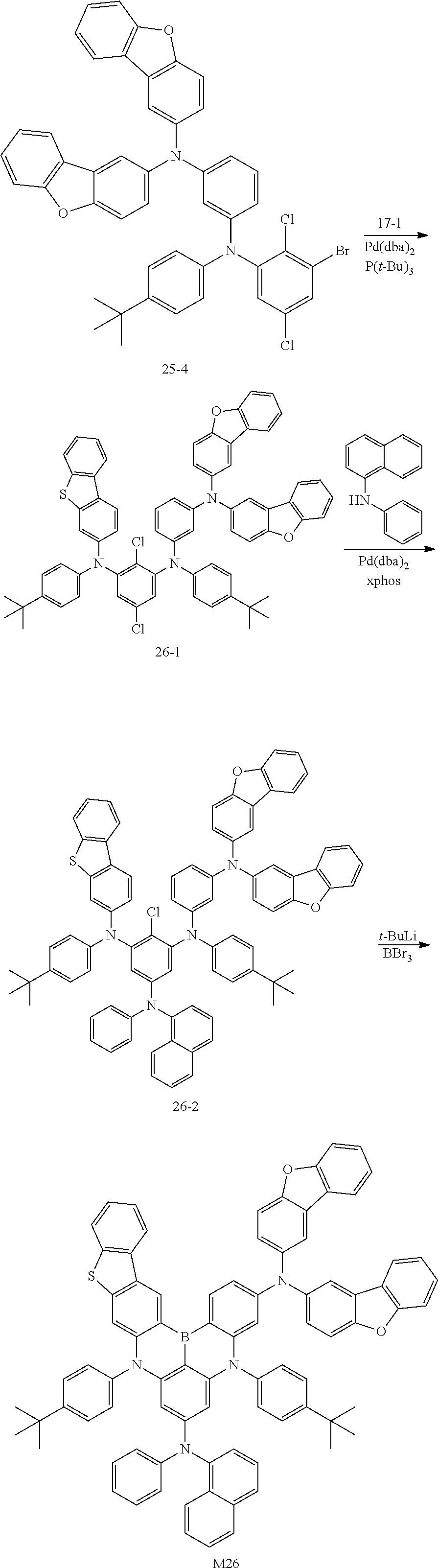

The specific synthetic procedure of the organic compound M26 is carried out as follows:

### Synthesis of Intermediate 26-1

Intermediate 25-4 (79.6 g, 100 mmol), Intermediate 17-1 (33.1 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 26-1 in 61% yield, MS (ASAP)=1045.3.

### Synthesis of Intermediate 26-2

Intermediate 26-1 (104.5 g, 100 mmol), N-phenyl-1-naphthylamine (21.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 26-2 in 74% yield, MS (ASAP)=1228.5.

### Synthesis of Organic Compound M26

Intermediate 26-2 (61.4 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M26 as a pale yellow solid powder in 35% yield, MS (ASAP)=1202.5.

### Example 27

### Synthesis of Organic Compound M27

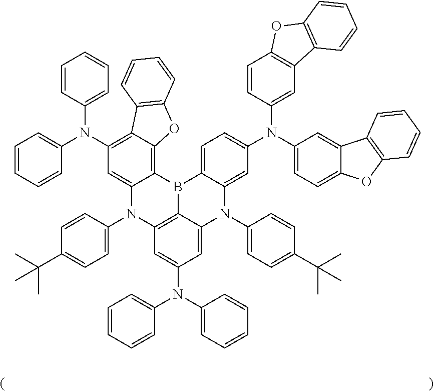 [SMILES: CC(C)(C)c1ccc(N2c3cc(N(c4ccc5oc6ccccc6c5c4)c4ccc5oc6ccccc6c5c4)ccc3B3c4c2cc(N(c2ccccc2)c2ccccc2)cc4N(c2ccc(C(C)(C)C)cc2)c2cc(N(c4ccccc4)c4ccccc4)c4c(oc5ccccc54)c23)cc1]

The synthetic route of the organic compound M27 is as follows:

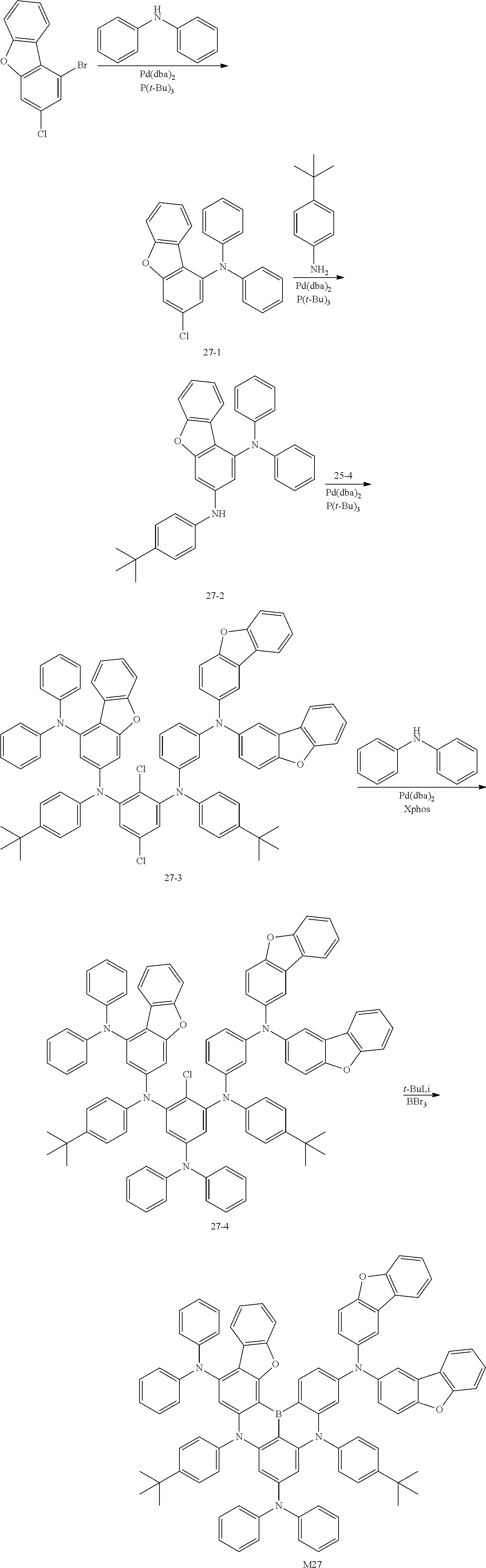

The specific synthetic procedure of the organic compound M27 is carried out as follows:

### Synthesis of Intermediate 27-1

1-Bromo-3-chlorodibenzofuran (28 g, 100 mmol), diphenylamine (16.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 27-1 in 85% yield, MS (ASAP)=369.1.

### Synthesis of Intermediate 27-2

Intermediate 27-1 (36.9 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 27-2 in 89% yield, MS (ASAP)=482.2.

### Synthesis of Intermediate 27-3

Intermediate 25-4 (79.6 g, 100 mmol), Intermediate 27-2 (48.2 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 27-3 in 69% yield, MS (ASAP)=1196.4.

### Synthesis of Intermediate 27-4

Intermediate 27-3 (119.6 g, 100 mmol), diphenylamine (16.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 27-4 in 73% yield, MS (ASAP)=1330.5.

### Synthesis of Organic Compound M27

Intermediate 27-4 (66.5 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M27 as a pale yellow solid powder in 24% yield, MS (ASAP)=1303.6.

### Example 28

### Synthesis of Organic Compound M28

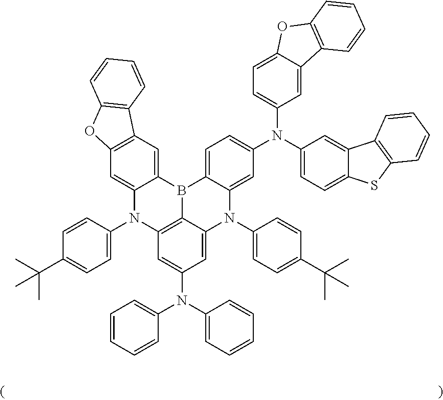 [SMILES: CC(C)(C)c1ccc(N2c3cc(N(c4ccc5oc6ccccc6c5c4)c4ccc5sc6ccccc6c5c4)ccc3B3c4cc5c(cc4N(c4ccc(C(C)(C)C)cc4)c4cc(N(c6ccccc6)c6ccccc6)cc2c43)oc2ccccc25)cc1]

The synthetic route of the organic compound M28 is as follows:

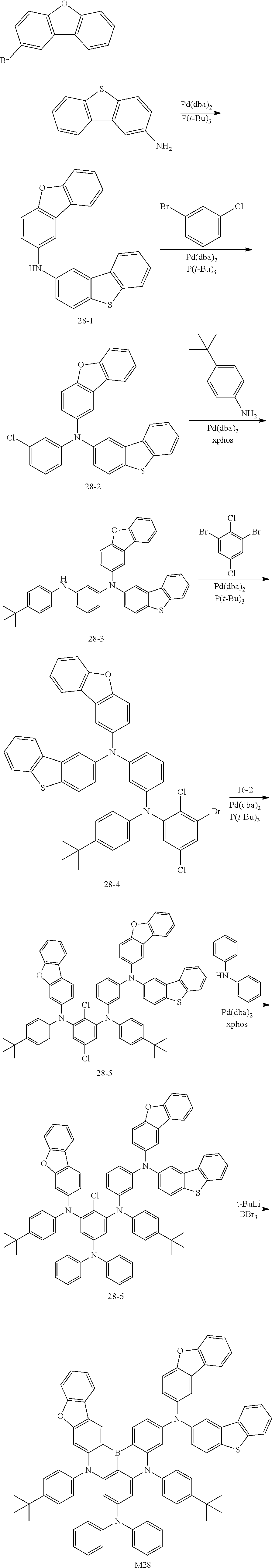

The specific synthetic procedure of the organic compound M28 is carried out as follows:

### Synthesis of Intermediate 28-1

2-bromodibenzofuran (24.6 g, 100 mmol), 2-aminodibenzothiophene (19.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 28-1 in 65% yield, MS (ASAP)=365.1.

### Synthesis of Intermediate 28-2

1-bromo-3-chlorobenzene (19 g, 100 mmol), Intermediate 28-1 (36.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 28-2 in 57% yield, MS (ASAP)=475.1.

### Synthesis of Intermediate 28-3

Intermediate 28-2 (47.5 g, 100 mmol), 4-tert-butylaniline (14.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 28-3 in 77% yield, MS (ASAP)=588.2.

### Synthesis of Intermediate 28-4

Intermediate 28-3 (58.8 g, 100 mmol), 1,3-dibromo-2,5-dichlorobenzene (30.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 28-4 in 55% yield, MS (ASAP)=768.1.

### Synthesis of Intermediate 28-5

Intermediate 28-4 (76.8 g, 100 mmol), Intermediate 16-2 (31.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 28-5 in 66% yield, MS (ASAP)=1045.3.

### Synthesis of Intermediate 28-6

Intermediate 28-5 (105 g, 100 mmol), diphenylamine (16.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 28-6 in 75% yield, MS (ASAP)=1178.4.

### Synthesis of Organic Compound M28

Intermediate 28-6 (58.9 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M28 as a pale yellow solid powder in 22% yield, MS (ASAP)=1152.5.

### Example 29

### Synthesis of Organic Compound M29

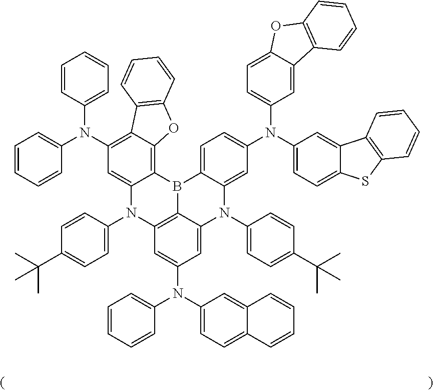 [SMILES: CC(C)(C)c1ccc(N2c3cc(N(c4ccc5oc6ccccc6c5c4)c4ccc5sc6ccccc6c5c4)ccc3B3c4c2cc(N(c2ccccc2)c2ccc5ccccc5c2)cc4N(c2ccc(C(C)(C)C)cc2)c2cc(N(c4ccccc4)c4ccccc4)c4c(oc5ccccc54)c23)cc1]

The synthetic route of the organic compound M29 is as follows:

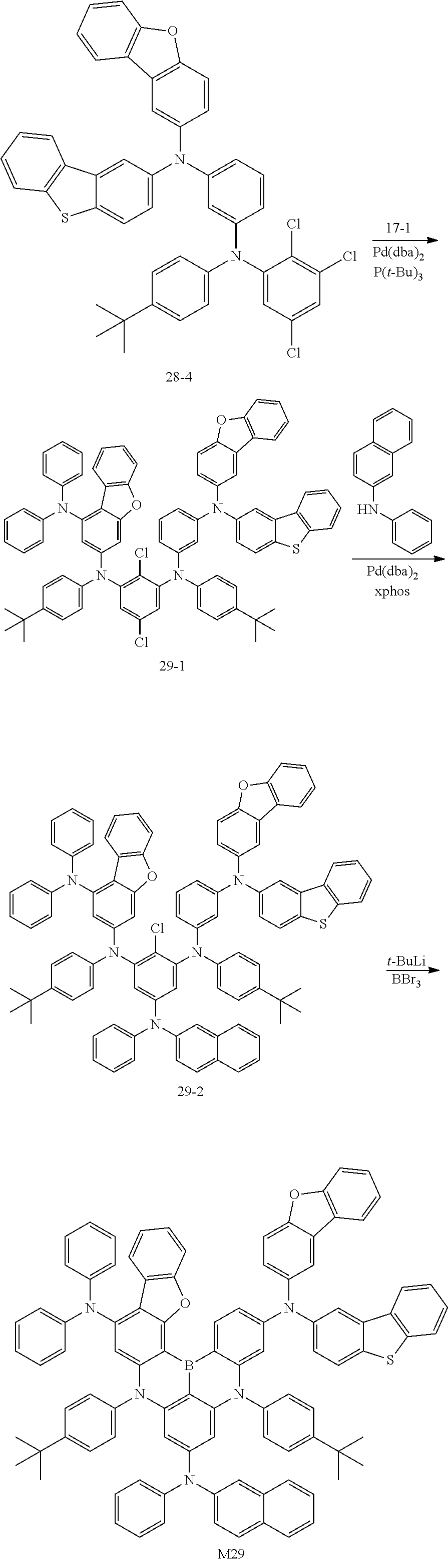

The specific synthetic procedure of the organic compound M29 is carried out as follows:

### Synthesis of Intermediate 29-1

Intermediate 28-4 (76.8 g, 100 mmol), Intermediate 27-2 (48.2 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 29-1 in 61% yield, MS (ASAP)=1212.4.

### Synthesis of Intermediate 29-2

Intermediate 29-1 (121 g, 100 mmol), N-phenyl-2-naphthylamine (21.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 29-2 in 71% yield, MS (ASAP)=1396.5.

### Synthesis of Organic Compound M29

Intermediate 29-2 (69.8 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M29 as a pale yellow solid powder in 33% yield, MS (ASAP)=1370.6.

### Example 30

### Synthesis of Organic Compound M30

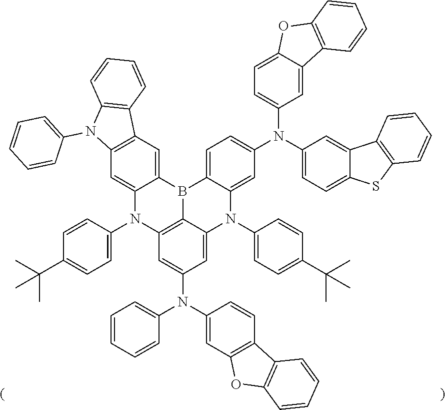 [SMILES: CC(C)(C)c1ccc(N2c3cc(N(c4ccc5oc6ccccc6c5c4)c4ccc5sc6ccccc6c5c4)ccc3B3c4cc5c6ccccc6n(-c6ccccc6)c5cc4N(c4ccc(C(C)(C)C)cc4)c4cc(N(c5ccccc5)c5ccc6c(c5)oc5ccccc56)cc2c43)cc1]

The synthetic route of the organic compound M30 is as follows:

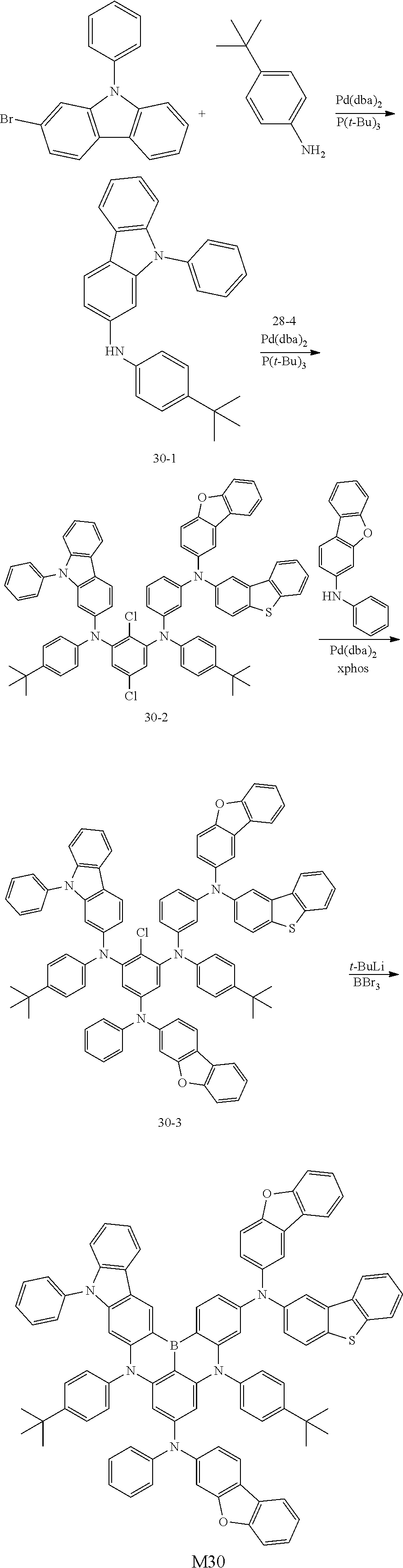

The specific synthetic procedure of the organic compound M30 is carried out as follows:

### Synthesis of Intermediate 30-1

4-tert-butylaniline (14.9 g, 100 mmol), 2-bromo-9-phenylcarbazole (32.1 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 30-1 in 89% yield, MS (ASAP)=390.2.

### Synthesis of Intermediate 30-2

Intermediate 28-4 (76.8 g, 100 mmol), Intermediate 30-1 (39 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 30-2 in 64% yield, MS (ASAP)=1120.4.

### Synthesis of Intermediate 30-3

Intermediate 30-2 (112 g, 100 mmol), N-phenyl-3-dibenzofuranamine (25.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 30-3 in 75% yield, MS (ASAP)=1344.5.

### Synthesis of Organic Compound M30

Intermediate 30-3 (67.2 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M30 as a pale yellow solid powder in 35% yield, MS (ASAP)=1318.5.

### Example 31

### Synthesis of Organic Compound M31

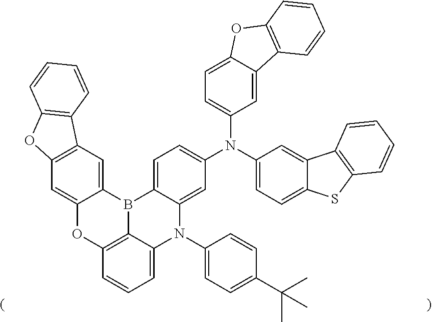 [SMILES: CC(C)(C)c1ccc(N2c3cc(N(c4ccc5oc6ccccc6c5c4)c4ccc5sc6ccccc6c5c4)ccc3B3c4cc5c(cc4Oc4cccc2c43)oc2ccccc25)cc1]

The synthetic route of the organic compound M31 is as follows:

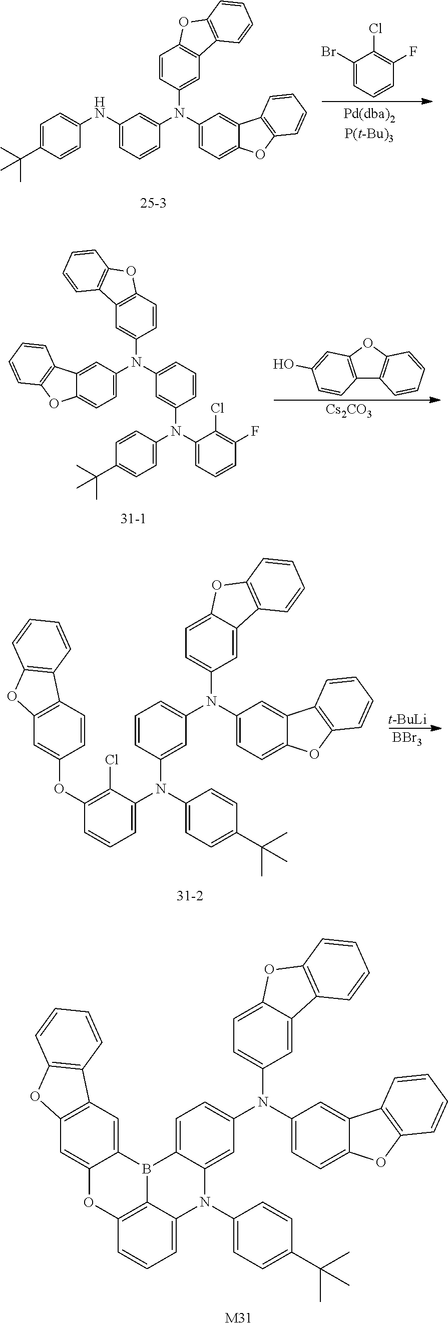

The specific synthetic procedure of the organic compound M31 is carried out as follows:

### Synthesis of Intermediate 31-1

Intermediate 25-3 (57.2 g, 100 mmol), 1-bromo-2-chloro-3-fluorobenzene (20.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 31-1 in 72% yield, MS (ASAP)=700.2.

### Synthesis of Intermediate 31-2

Intermediate 31-1 (70.0 g, 100 mmol), 3-hydroxyldibenzofuran (18.4 g, 100 mmol), cesium carbonate (163 g, 500 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 31-2 in 76% yield, MS (ASAP)=864.3.

### Synthesis of Organic Compound M31

Intermediate 31-2 (43.2 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M31 as a pale yellow solid powder in 16% yield, MS (ASAP)=838.3.

### Example 32

### Synthesis of Organic Compound M32

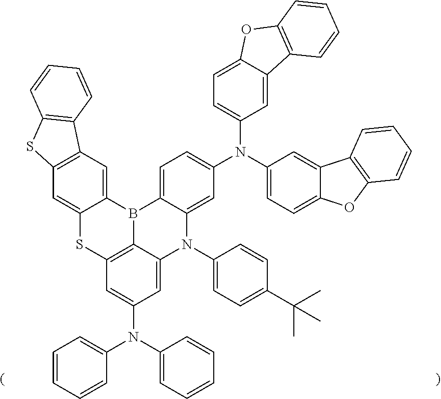 [SMILES: CC(C)(C)c1ccc(N2c3cc(N(c4ccc5oc6ccccc6c5c4)c4ccc5oc6ccccc6c5c4)ccc3B3c4cc5c(cc4Sc4cc(N(c6ccccc6)c6ccccc6)cc2c43)sc2ccccc25)cc1]

The synthetic route of the organic compound M32 is as follows:

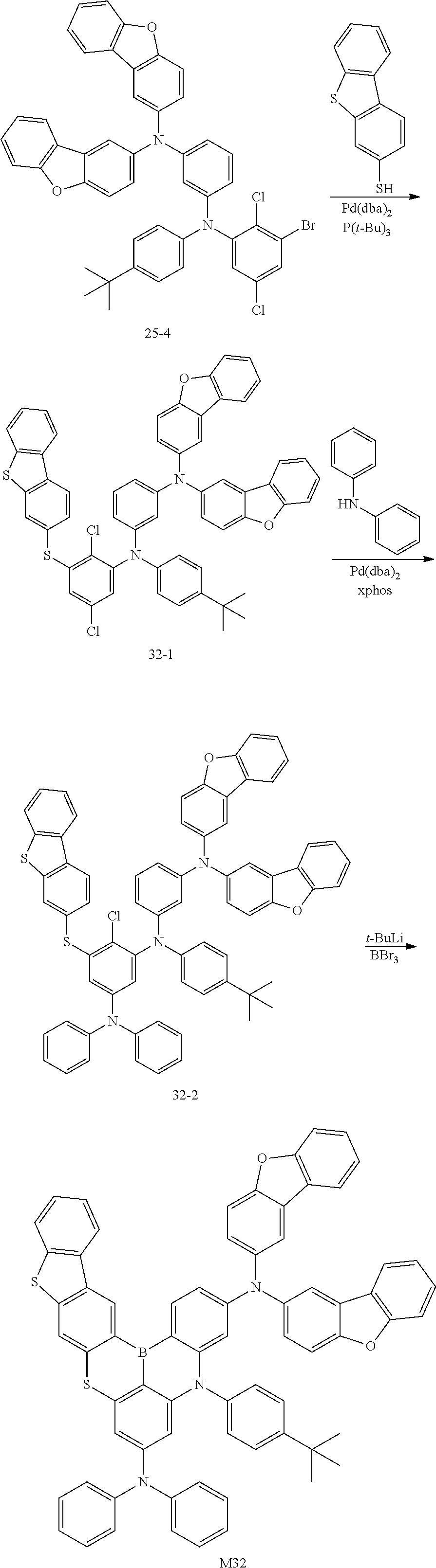

The specific synthetic procedure of the organic compound M32 is carried out as follows:

### Synthesis of Intermediate 32-1

Intermediate 25-4 (79.6 g, 100 mmol), 3-thiophenyl dibenzothiophene (21.6 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 110° C. for 12 h. After cooling, the solvent was removed by rotary evaporation. The mixture was extracted and washed with water and separated to an organic phase and an inorganic phase, and the organic phase was subjected to column chromatography to give Intermediate 32-1 in 66% yield, MS (ASAP)=930.2.

### Synthesis of Intermediate 32-2

Intermediate 32-1 (93.0 g, 100 mmol), diphenylamine (16.9 g, 100 mmol), Pd(dba)₂ (0.57 g, 1.0 mmol), X-Phos (0.95 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 32-2 in 72% yield, MS (ASAP)=1063.3.

### Synthesis of Organic Compound M32

Intermediate 32-2 (53.2 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M32 as a pale yellow solid powder in 17% yield, MS (ASAP)=1037.3.

### Example 33

### Synthesis of Organic Compound M33

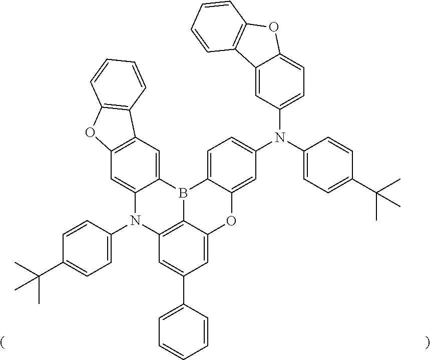 [SMILES: CC(C)(C)c1ccc(N(c2ccc3c(c2)Oc2cc(-c4ccccc4)cc4c2B3c2cc3c(cc2N4c2ccc(C(C)(C)C)cc2)oc2ccccc23)c2ccc3oc4ccccc4c3c2)cc1]

The synthetic route of the organic compound M33 is as follows:

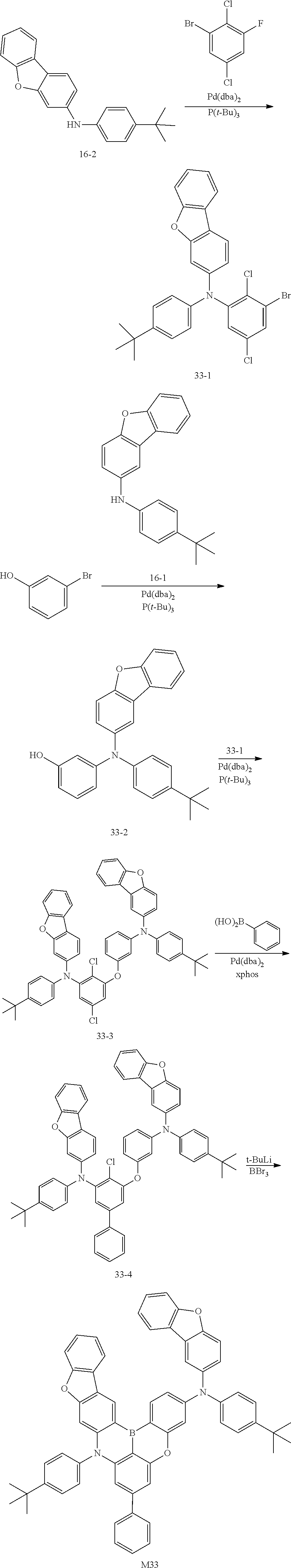

The specific synthetic procedure of the organic compound M33 is carried out as follows:

### Synthesis of Intermediate 33-1

1,3-dibromo-2,5-dichlorobenzene (30.4 g, 100 mmol), Intermediate 16-2 (31.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred under a nitrogen atmosphere at 100° C. for 6 h. After cooling, the solvent was removed by rotary evaporation. The mixture was extracted and washed with water and separated to an organic phase and an inorganic phase, and the organic phase was subjected to column chromatography to give Intermediate 33-1 in 74% yield, MS (ASAP)=539.2.

### Synthesis of Intermediate 33-2

Intermediate 16-1 (31.5 g, 100 mmol), 3-bromophenol (17.2 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 33-2 in 64% yield, MS (ASAP)=407.2.

### Synthesis of Intermediate 33-3

Intermediate 33-1 (53.9 g, 100 mmol), Intermediate 33-2 (40.7 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 33-3 in 65% yield, MS (ASAP)=864.3.

### Synthesis of Intermediate 33-4

Intermediate 33-3 (86.4 g, 100 mmol), phenylboronic acid (12.2 g, 100 mmol), Pd(dba)₂ (0.57 g, 1.0 mmol), X-Phos (0.95 g, 2.0 mmol) and potassium carbonate (11.4 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 33-4 in 87% yield, MS (ASAP)=906.4.

### Synthesis of Organic Compound M33

Intermediate 33-4 (45.3 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M33 as a pale yellow solid powder in 21% yield, MS (ASAP)=880.4.

### Example 34

### Synthesis of Organic Compound M34

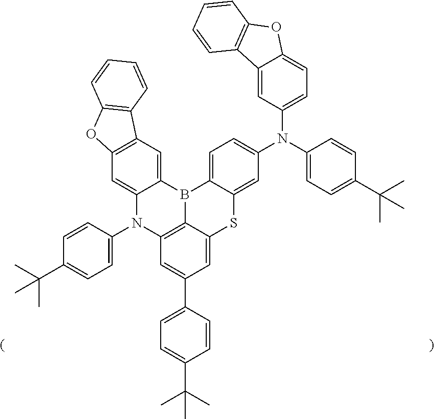 [SMILES: CC(C)(C)c1ccc(-c2cc3c4c(c2)N(c2ccc(C(C)(C)C)cc2)c2cc5oc6ccccc6c5cc2B4c2ccc(N(c4ccc(C(C)(C)C)cc4)c4ccc5oc6ccccc6c5c4)cc2S3)cc1]

The synthetic route of the organic compound M34 is as follows:

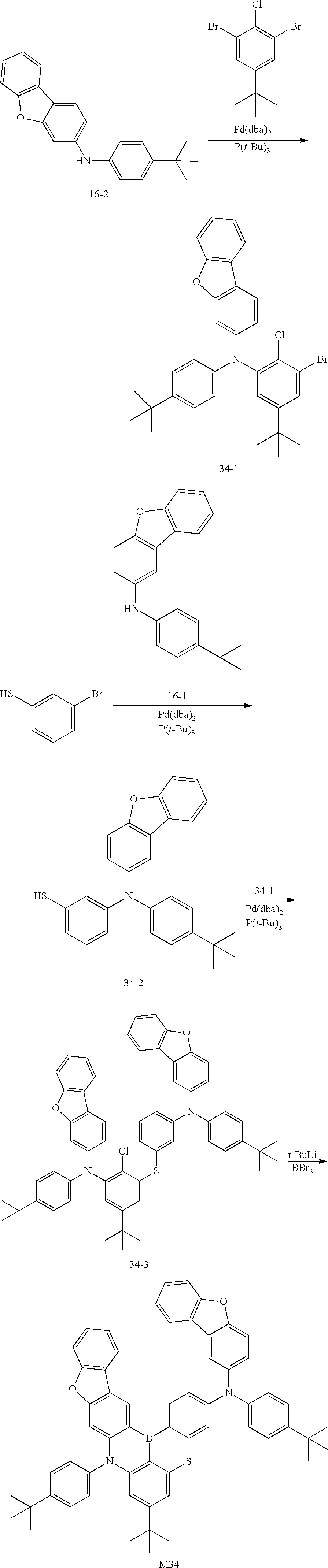

The specific synthetic procedure of the organic compound M34 is carried out as follows:

### Synthesis of Intermediate 34-1

1,3-dibromo-2-chloro-5-tert-butylbenzene (32.5 g, 100 mmol), Intermediate 16-2 (32.6 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 34-1 in 67% yield, MS (ASAP)=561.1.

### Synthesis of Intermediate 34-2

Intermediate 16-1 (31.5 g, 100 mmol), 3-bromothiophenol (19.0 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 34-2 in 55% yield, MS (ASAP)=423.2.

### Synthesis of Intermediate 34-3

Intermediate 34-1 (56.1 g, 100 mmol), Intermediate 34-2 (42.3 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 110° C. for 12 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 34-3 in 58% yield, MS (ASAP)=902.4.

### Synthesis of Organic Compound M34

Intermediate 34-3 (45.1 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M34 as a pale yellow solid powder in 19% yield, MS (ASAP)=876.4.

### Example 35

### Synthesis of Organic Compound M35

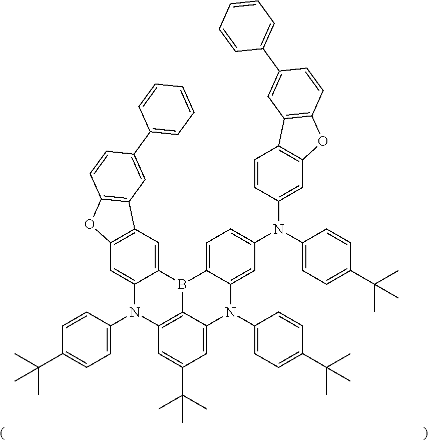 [SMILES: CC(C)(C)c1ccc(N(c2ccc3c(c2)N(c2ccc(C(C)(C)C)cc2)c2cc(C(C)(C)C)cc4c2B3c2cc3c(cc2N4c2ccc(C(C)(C)C)cc2)oc2ccc(-c4ccccc4)cc23)c2ccc3c(c2)oc2ccc(-c4ccccc4)cc23)cc1]

The synthetic route of the organic compound M35 is as follows:

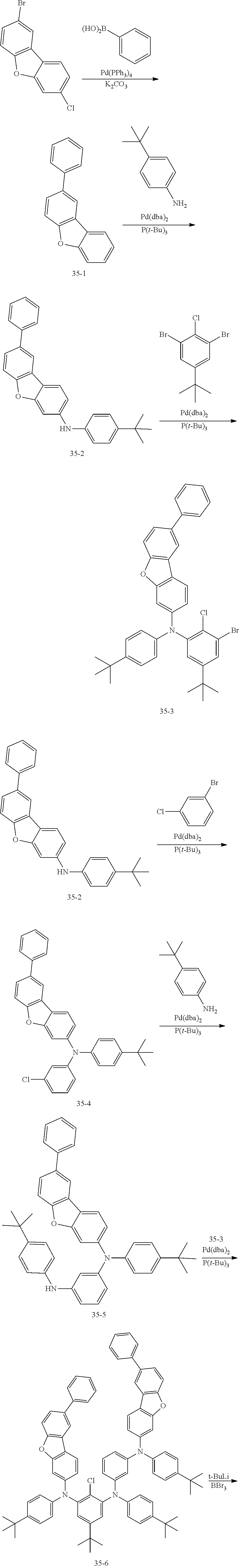

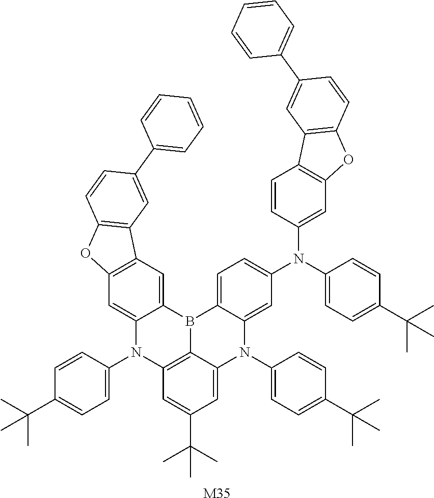

The specific synthetic procedure of the organic compound M35 is carried out as follows:

### Synthesis of Intermediate 35-1

2-bromo-7-chlorodibenzofuran (30.4 g, 100 mmol), phenylboronic acid (31.5 g, 100 mmol), tetrakis(triphenylphosphine)palladium (Pd(PPh₃)₄, 1.16 g, 1.0 mmol), and potassium carbonate (41.4 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 35-1 in 92% yield, MS (ASAP)=244.1.

### Synthesis of Intermediate 35-2

Intermediate 35-1 (24.4 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 35-2 in 78% yield, MS (ASAP)=391.2.

### Synthesis of Intermediate 35-3

Intermediate 35-2 (39.1 g, 100 mmol), 1,3-dibromo-2-chloro-5-tert-butylbenzene (32.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 35-3 in 61% yield, MS (ASAP)=637.2.

### Synthesis of Intermediate 35-4

Intermediate 35-2 (39.1 g, 100 mmol), 1-bromo-3-chlorobenzene (19.2 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 35-4 in 69% yield, MS (ASAP)=501.2.

### Synthesis of Intermediate 35-5

Intermediate 35-4 (39.1 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 35-5 in 67% yield, MS (ASAP)=614.3.

### Synthesis of Intermediate 35-6

Intermediate 35-3 (63.7 g, 100 mmol), Intermediate 35-5 (61.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 35-6 in 72% yield, MS (ASAP)=1169.6.

### Synthesis of Organic Compound M35

Intermediate 35-6 (58.5 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M35 as a pale yellow solid powder in 22% yield, MS (ASAP)=1143.6.

### Example 36

### Synthesis of Organic Compound M36

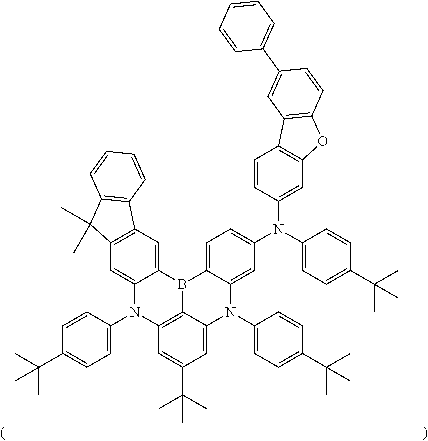 [SMILES: CC(C)(C)c1ccc(N(c2ccc3c(c2)N(c2ccc(C(C)(C)C)cc2)c2cc(C(C)(C)C)cc4c2B3c2cc3c(cc2N4c2ccc(C(C)(C)C)cc2)C(C)(C)c2ccccc2-3)c2ccc3c(c2)oc2ccc(-c4ccccc4)cc23)cc1]

The synthetic route of the organic compound M36 is as follows:

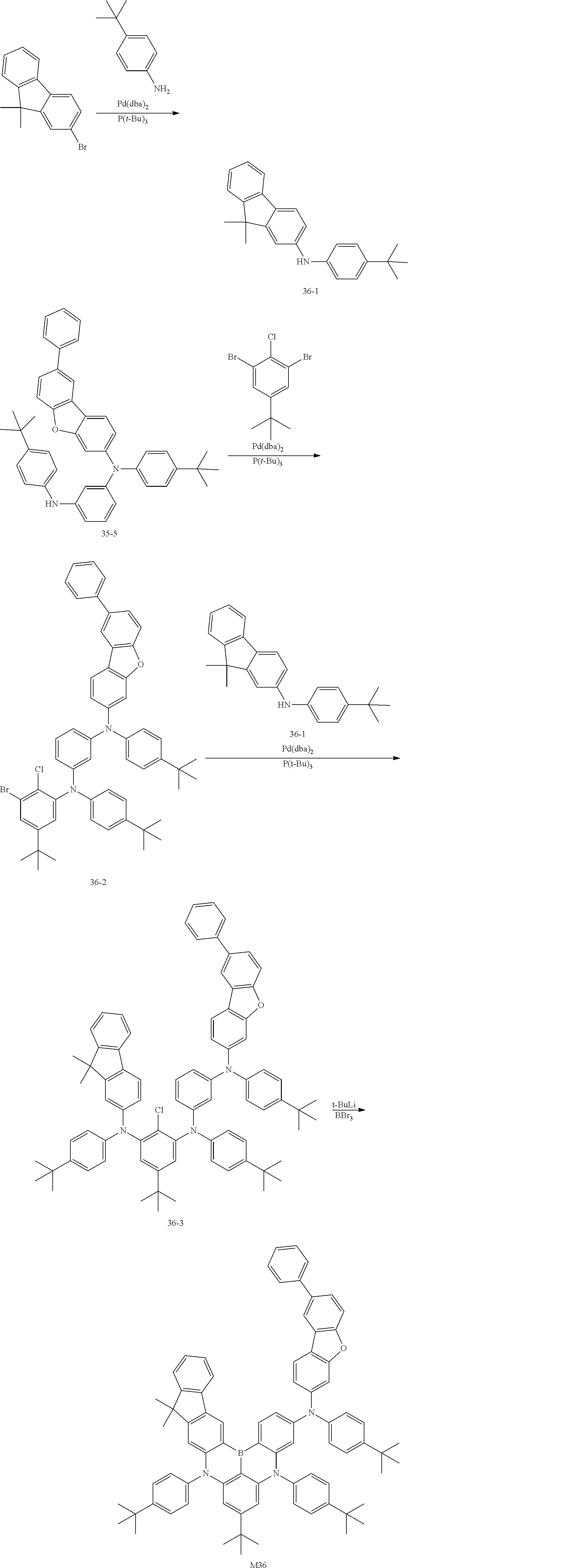

The specific synthetic procedure of the organic compound M36 is carried out as follows:

### Synthesis of Intermediate 36-1

2-bromo-9,9-dimethylfluorene (27.2 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 36-1 in 73% yield, MS (ASAP)=341.2.

### Synthesis of Intermediate 36-2

Intermediate 35-5 (61.4 g, 100 mmol), 1,3-dibromo-2-chloro-5-tert-butylbenzene (32.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 36-2 in 66% yield, MS (ASAP)=860.3.

### Synthesis of Intermediate 36-3

Intermediate 36-2 (86.0 g, 100 mmol), Intermediate 36-1 (34.1 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 36-3 in 54% yield, MS (ASAP)=1119.6.

### Synthesis of Organic Compound M36

Intermediate 36-3 (56.0 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M36 as a pale yellow solid powder in 23% yield, MS (ASAP)=1093.6.

### Example 37

### Synthesis of Organic Compound M37

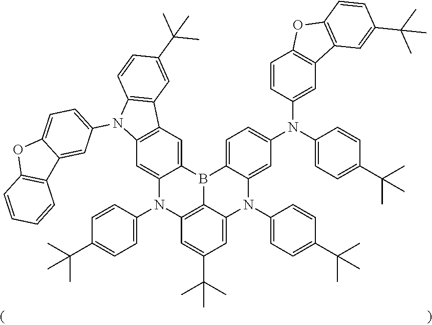 [SMILES: CC(C)(C)c1ccc(N(c2ccc3c(c2)N(c2ccc(C(C)(C)C)cc2)c2cc(C(C)(C)C)cc4c2B3c2cc3c5cc(C(C)(C)C)ccc5n(-c5ccc6oc7ccccc7c6c5)c3cc2N4c2ccc(C(C)(C)C)cc2)c2ccc3oc4ccc(C(C)(C)C)cc4c3c2)cc1]

The synthetic route of the organic compound M37 is as follows:

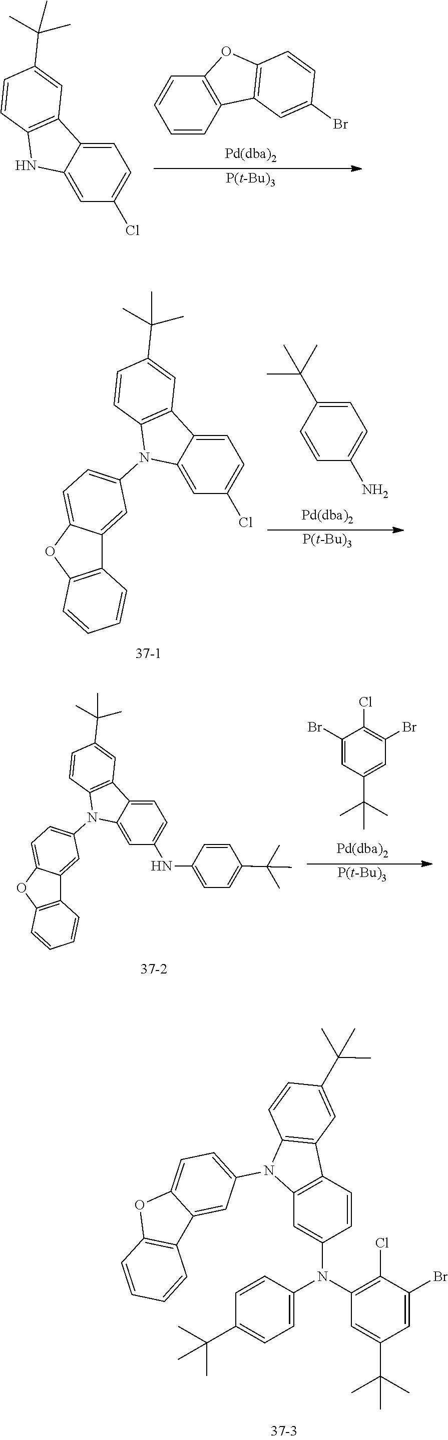

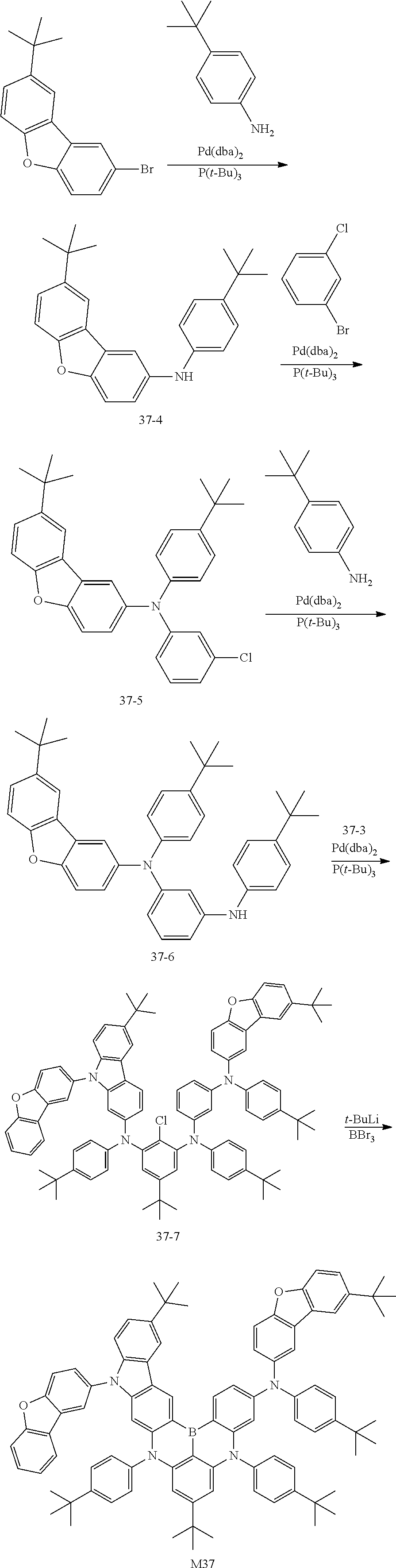

The specific synthetic procedure of the organic compound M37 is carried out as follows:

### Synthesis of Intermediate 37-1

2-Chloro-6-tert-butyl-9-H-carbazole (25.7 g, 100 mmol), 2-bromodibenzofuran (24.6 g, 100 mmol), Pd(dba)_{z}(0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 37-1 in 75% yield, MS (ASAP)=423.1.

### Synthesis of Intermediate 37-2

Intermediate 37-1 (42.3 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 37-2 in 86% yield, MS (ASAP)=536.3.

### Synthesis of Intermediate 37-3

Intermediate 37-2 (53.6 g, 100 mmol), 1,3-dibromo-2-chloro-5-tert-butylbenzene (32.5 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 37-3 in 68% yield, MS (ASAP)=782.3.

### Synthesis of Intermediate 37-4

2-bromo-8-tert-butyldibenzofuran (30.2 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 37-4 in 90% yield, MS (ASAP)=371.2.

### Synthesis of Intermediate 37-5

Intermediate 37-4 (37.1 g, 100 mmol), 1-bromo-3-chlorobenzene (19.2 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 37-5 in 87% yield, MS (ASAP)=481.2.

### Synthesis of Intermediate 37-6

Intermediate 37-5 (48.1 g, 100 mmol), 4-tert-butylaniline (14.9 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 37-6 in 73% yield, MS (ASAP)=594.4.

### Synthesis of Intermediate 37-7

Intermediate 37-3 (78.2 g, 100 mmol), Intermediate 37-6 (59.4 g, 100 mmol), Pd(dba)₂ (0.57 g, 1.0 mmol), P(t-Bu)₃ (0.4 g, 2.0 mmol) and sodium tert-butoxide (28.8 g, 300 mmol) were dissolved in toluene and stirred at 100° C. for 6 h under a nitrogen atmosphere. After cooling, the solvent was removed by rotary evaporation. The mixture was extracted and washed with water and separated to an organic phase and an inorganic phase, and the organic phase was subjected to column chromatography to give Intermediate 37-7 in 78% yield, MS (ASAP)=1294.7.

### Synthesis of Organic Compound M37

Intermediate 37-7 (64.7 g, 50 mmol) and 200 ml of dry tert-butylbenzene were added into a 500 ml three-necked flask, and cooled to −30° C., under N₂ atmosphere, and t-BuLi (2.5M tert-butyllithium 80 ml, 200 mmol) was added dropwise. The temperature was raised to 60° C. for 2 hours and the solvent was removed by rotary evaporation under reduced pressure. The reaction solution was cooled again to −30° C., and boron tribromide (75 g, 300 mmol) was added, warmed to room temperature and stirred for 2 hours. Then, the reaction solution was cooled to 0° C., and N, N-diisopropylethylamine (64.5 g, 500 mmol) was added. After completion of the addition, the reaction solution was warmed to room temperature and stirred. Then, the reaction solution was warmed to 120° C. and stirred for 12 hours. The reaction solution was then cooled to room temperature. The reaction was quenched with aqueous sodium carbonate solution and ethyl acetate, was extracted with ethyl acetate, and organic phases were combined. The solvent therein was removed by rotary evaporation to obtain a crude product. The organic phase was subjected to column chromatography, followed by recrystallization with toluene and ethyl acetate to give the organic compound M37 as a pale yellow solid powder in 24% yield, MS (ASAP)=1268.7.

### Comparative Example 1

As Comparative Example 1 for Examples 1 to 37 described above, a comparative compound 1 has the following structure:

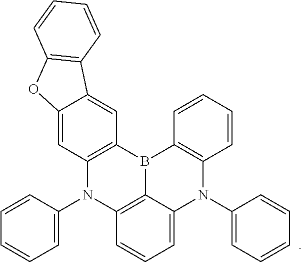 [SMILES: c1ccc(N2c3ccccc3B3c4cc5c(cc4N(c4ccccc4)c4cccc2c43)oc2ccccc25)cc1]

### Comparative Example 2

As Comparative Example 2 for Examples 1 to 37 described above, a comparative compound 2 has the following structure:

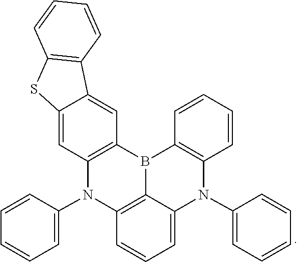 [SMILES: c1ccc(N2c3ccccc3B3c4cc5c(cc4N(c4ccccc4)c4cccc2c43)sc2ccccc25)cc1]

As shown in Table 1, the highest occupied molecular orbital (HOMO) energy levels, the lowest unoccupied molecular orbital (LUMO) energy levels, the first excited triplet state (T1) energy levels, and the first excited singlet state (S1) energy levels of the compounds M1 to M37 obtained in Examples 1 to 37 and the comparative compounds 1 and 2 obtained in Comparative Examples 1 and 2 can be obtained by quantum calculation, specifically, by Gaussian 09W (Gaussian Inc.) using TD-DFT (time dependent density function theory), with a simulation method referring to WO2011141110, in which the semi-empirical method “Ground State/Semi-empirical/Default Spin/AM1” (Charge 0/Spin Singlet) is used to optimise the molecular geometry, and then the energy levels of the organic molecule are calculated by the TD-DFT (time dependent density function theory) method as “TD-SCF/DFT/Default Spin/B3PW91” with the base set “6-31G(d)” (Charge 0/Spin Singlet). The HOMO and LUMO energy levels are calculated according to the calibration equations below, and the S1 and T1 energy levels are used directly.

$$HOMO ( eV ) = ( ( HOMO ( G ) \times 27.212 ) - 0.9899 ) / 1.1206 \\ LUMO ( eV ) = ( ( LUMO ( G ) \times 27.212 ) - 2.0041 ) / 1.385$$

HOMO, LUMO, T1 and S1 are direct calculation results of Gaussian 09W, with a unit of Hartree.

TABLE 1
Results of HOMO energy levels, LUMO, S1 energy levels and T1 energy levels
of organic compounds M1 to M37 and comparative compounds 1 and 2

| | | HOMO energy | LUMO energy | T1 energy | S1 energy |
|---|---|---|---|---|---|
| | Compound | level [eV] | level [eV] | level [eV] | level [eV] |
| Example 1 | Organic compound M1 | −5.24 | −2.43 | 2.51 | 2.96 |
| Example 2 | Organic compound M2 | −5.29 | −2.38 | 2.56 | 2.95 |
| Example 3 | Organic compound M3 | −5.31 | −2.41 | 2.55 | 2.97 |
| Example 4 | Organic compound M4 | −5.24 | −2.42 | 2.57 | 3.08 |
| Example 5 | Organic compound M5 | −5.26 | −2.45 | 2.55 | 3.01 |
| Example 6 | Organic compound M6 | −5.21 | −2.48 | 2.54 | 2.98 |
| Example 7 | Organic compound M7 | −5.32 | −2.42 | 2.55 | 2.98 |
| Example 8 | Organic compound M8 | −5.19 | −2.49 | 2.59 | 3.06 |
| Example 9 | Organic compound M9 | −5.28 | −2.44 | 2.51 | 3.05 |
| Example 10 | Organic compound M10 | −5.27 | −2.48 | 2.55 | 3.04 |
| Example 11 | Organic compound M11 | −5.22 | −2.38 | 2.56 | 3.09 |
| Example 12 | Organic compound M12 | −5.27 | −2.48 | 2.59 | 3.06 |
| Example 13 | Organic compound M13 | −5.22 | −2.42 | 2.54 | 2.96 |
| Example 14 | Organic compound M14 | −5.27 | −2.44 | 2.48 | 2.97 |
| Example 15 | Organic compound M15 | −5.28 | −2.46 | 2.49 | 3.09 |
| Example 16 | Organic compound M16 | −5.21 | −2.41 | 2.52 | 2.95 |
| Example 17 | Organic compound M17 | −5.25 | −2.40 | 2.53 | 2.96 |
| Example 18 | Organic compound M18 | −5.28 | −2.43 | 2.51 | 2.94 |
| Example 19 | Organic compound M19 | −5.25 | −2.42 | 2.53 | 3.06 |
| Example 20 | Organic compound M20 | −5.21 | −2.46 | 2.57 | 3.02 |
| Example 21 | Organic compound M21 | −5.27 | −2.41 | 2.52 | 2.95 |
| Example 22 | Organic compound M22 | −5.33 | −2.43 | 2.51 | 2.97 |
| Example 23 | Organic compound M23 | −5.22 | −2.46 | 2.52 | 3.01 |
| Example 24 | Organic compound M24 | −5.28 | −2.47 | 2.58 | 3.04 |
| Example 25 | Organic compound M25 | −5.24 | −2.45 | 2.59 | 3.02 |
| Example 26 | Organic compound M26 | −5.23 | −2.42 | 2.54 | 3.05 |
| Example 27 | Organic compound M27 | −5.25 | −2.41 | 2.52 | 3.07 |
| Example 28 | Organic compound M28 | −5.21 | −2.46 | 2.51 | 2.93 |
| Example 29 | Organic compound M29 | −5.25 | −2.48 | 2.45 | 2.92 |
| Example 30 | Organic compound M30 | −5.26 | −2.43 | 2.42 | 3.04 |
| Example 31 | Organic compound M31 | −5.24 | −2.46 | 2.43 | 3.06 |
| Example 32 | Organic compound M32 | −5.26 | −2.48 | 2.46 | 3.03 |
| Example 33 | Organic compound M33 | −5.25 | −2.45 | 2.48 | 3.07 |
| Example 34 | Organic compound M34 | −5.26 | −2.43 | 2.43 | 3.02 |
| Example 35 | Organic compound M35 | −5.24 | −2.42 | 2.42 | 3.05 |
| Example 36 | Organic compound M36 | −5.23 | −2.44 | 2.48 | 3.03 |
| Example 37 | Organic compound M37 | −5.26 | −2.47 | 2.43 | 3.07 |
| Comparative | Comparative Compound 1 | −5.32 | −2.42 | 2.30 | 2.90 |
| Example 1 | | | | | |
| Comparative | Comparative Compound 2 | −5.36 | −2.50 | 2.35 | 2.91 |
| Example 2 | | | | | |

From the results in Table 1, it can be seen that the T1 energy levels and S1 energy levels of the organic compounds M1 to M37 provided in Examples 1 to 37 of the present disclosure are significantly higher than those of the comparative compounds 1 and 2, indicating that the organic compounds M1 to M37 tend to emit darker blue light than the comparative compounds 1 and 2, thereby allowing the blue light-emitting element having the organic compounds M1 to M37 as the guest material of the light-emitting layer to obtain better color coordinates.

An exemplary fabricating procedure of the light-emitting element according to the present disclosure is shown in the following exemplary example 38.

### Example 38

In the light-emitting element according to the present embodiment, ITO (indium tin oxide) is used as an anode, PEDOT (poly(ethylenedioxythiophene), Clevios™ AI4083) is used as a material of a hole injection layer, PVK (Sigma Aldrich, average Mn of 25,000-50,000) is used as a material of a hole transport layer. BH is used as a host material in a light-emitting layer of the light-emitting element, and organic compounds M1 to M37 in Examples 1 to 37 and comparative compounds 1 and 2 in Comparative Examples 1 and 2 are used as guest materials in the light-emitting layer of the light-emitting element, respectively. ET and Liq (8-hydroxylquinoline lithium) are used as materials of an electron transport layer, and Al is used as a cathode. The specific preparation procedure is carried out as follows:
a. cleaning an ITO anode: cleaning the ITO conductive glass with chloroform, acetone and/or isopropanol, followed by UV ozone treatment;
b. forming a hole injection layer: spin-coating the material PEDOT (poly(ethylenedioxythiophene), Clevios™ AI4083) of the hole injection layer on the ITO anode, and treating on a hot plate at 180° C. for 10 minutes to form the hole injection layer having a thickness of 40 nm;
c. forming a hole transport layer: spin-coating 5 mg/ml of PVK (Sigma Aldrich, Mn of 25,000-50,000) in toluene onto the hole injection layer, and treating on a hot plate at 180° C. for 60 minutes to form the hole transport layer having a thickness of 20 nm;
d. forming a light-emitting layer: spin-coating a solution of a light-emitting layer material in methyl benzoate, with a concentration of 15 mg/ml, onto the hole transport layer in a nitrogen glove box, and treating on a hot plate at 140° C. for 10 minutes to form the light-emitting layer having a thickness of 40 nm, wherein for each of different light-emitting elements, the corresponding light-emitting layer material includes BH as the host material, and one of the organic compounds M1 to M37 and the comparative compounds 1 and 2 as the guest material, and the mass ratio of the host material to the guest material is 95:5;
e. forming an electron transport layer: placing ET and Liq in different evaporation units in a vacuum chamber, and co-depositing ET and Liq at a weight ratio of 50:50 under a high vacuum (1×10⁻⁶ mbar) on the light-emitting layer to form the electron transport layer having a thickness of 20 nm;
f. forming a cathode layer: depositing Al on the electron transport layer to obtain the Al cathode having a thickness of 100 nm;
g. encapsulation: curing a resin by UV in a nitrogen glove box to encapsulate the element.

Specifically, in the embodiment, the light-emitting elements 1 to 37 and the comparative elements 1 to 2 are obtained by the above procedure. The guest materials used for the light-emitting elements 1 to 37 are the organic compounds M1 to M37, respectively. The guest materials used for the comparative elements 1 to 2 are the comparative compounds 1 and 2, respectively.

Specifically, the chemical structures of BH, ET, and Liq are as follows:

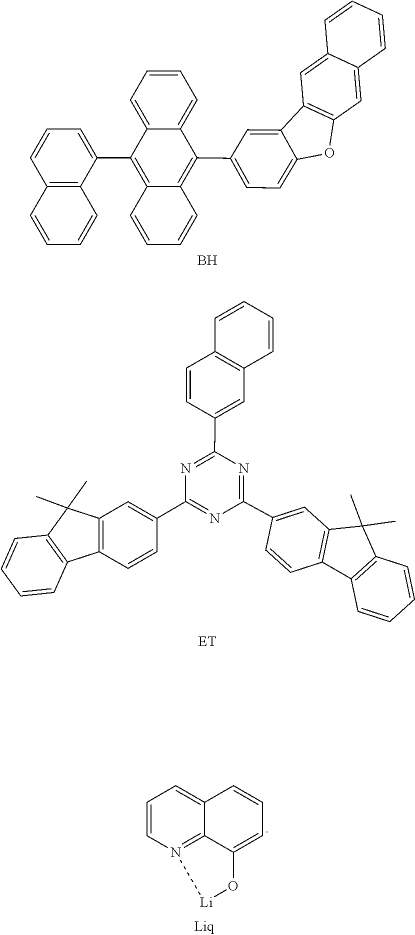

In the embodiment, the light-emitting elements 1 to 37 and the comparative elements 1 to 2 were tested for the current-voltage (J-V) performance, the CIE color coordinates (x, y), the driving voltage at the luminance of 1 knits (voltage @ 1 knits[V]), the luminous efficiency (CE @1 knits [cd/A]) under the current density of 10 mA/cm², and the time (LT90@1 knits [h]) taken for the luminance to decrease from the initial luminance of 1 knits to 90% of the initial luminance, and the results were shown in Table 2.

TABLE 2
Performance data of light-emitting elements
1 to 37 and comparative elements 1 to 2

| | | CIE color | Voltage @ | CE @ 1 | LT90 @1 |
|---|---|---|---|---|---|
| | | coordinates | 1 knits | knits | knits |
| | Guest material | (x, y) | [V] | [cd/A] | [h] |
| Light-emitting | Organic compound | 0.143, 0.085 | 5.6 | 6.1 | 144 |
| element 1 | M1 | | | | |
| Light-emitting | Organic compound | 0.142, 0.081 | 5.6 | 6.2 | 156 |
| element 2 | M2 | | | | |
| Light-emitting | Organic compound | 0.143, 0.082 | 5.6 | 6.0 | 167 |
| element 3 | M3 | | | | |
| Light-emitting | Organic compound | 0.142, 0.083 | 5.6 | 5.5 | 145 |
| element 4 | M4 | | | | |
| Light-emitting | Organic compound | 0.142, 0.086 | 5.6 | 6.1 | 157 |
| element 5 | M5 | | | | |
| Light-emitting | Organic compound | 0.141, 0.082 | 5.4 | 5.8 | 158 |
| element 6 | M6 | | | | |
| Light-emitting | Organic compound | 0.141, 0.084 | 5.6 | 5.4 | 149 |
| element 7 | M7 | | | | |
| Light-emitting | Organic compound | 0.142, 0.083 | 5.6 | 5.1 | 161 |
| element 8 | M8 | | | | |
| Light-emitting | Organic compound | 0.144, 0.085 | 5.6 | 5.3 | 143 |
| element 9 | M9 | | | | |
| Light-emitting | Organic compound | 0.141, 0.084 | 5.6 | 5.4 | 141 |
| element 10 | M10 | | | | |
| Light-emitting | Organic compound | 0.142, 0.084 | 5.6 | 5.9 | 168 |
| element 11 | M11 | | | | |
| Light-emitting | Organic compound | 0.141, 0.085 | 5.5 | 6.1 | 143 |
| element 12 | M12 | | | | |
| Light-emitting | Organic compound | 0.142, 0.081 | 5.6 | 5.9 | 152 |
| element 13 | M13 | | | | |
| Light-emitting | Organic compound | 0.141, 0.084 | 5.6 | 6.2 | 158 |
| element 14 | M14 | | | | |
| Light-emitting | Organic compound | 0.142, 0.085 | 5.6 | 5.8 | 146 |
| element 15 | M15 | | | | |
| Light-emitting | Organic compound | 0.142, 0.083 | 5.5 | 6.1 | 155 |
| element 16 | M16 | | | | |
| Light-emitting | Organic compound | 0.143, 0.082 | 5.4 | 5.5 | 151 |
| element 17 | M17 | | | | |
| Light-emitting | Organic compound | 0.142, 0.082 | 5.4 | 5.9 | 153 |
| element 18 | M18 | | | | |
| Light-emitting | Organic compound | 0.143, 0.084 | 5.4 | 5.7 | 148 |
| element 19 | M19 | | | | |
| Light-emitting | Organic compound | 0.144, 0.082 | 5.4 | 6.2 | 147 |
| element 20 | M20 | | | | |
| Light-emitting | Organic compound | 0.143, 0.081 | 5.4 | 5.9 | 152 |
| element 21 | M21 | | | | |
| Light-emitting | Organic compound | 0.142, 0.083 | 5.4 | 5.5 | 144 |
| element 22 | M22 | | | | |
| Light-emitting | Organic compound | 0.141, 0.082 | 5.4 | 5.6 | 154 |
| element 23 | M23 | | | | |
| Light-emitting | Organic compound | 0.143, 0.083 | 5.4 | 5.7 | 167 |
| element 24 | M24 | | | | |
| Light-emitting | Organic compound | 0.142, 0.081 | 5.4 | 5.9 | 144 |
| element 25 | M25 | | | | |
| Light-emitting | rganic compound M26 | 0.142, 0.082 | 5.4 | 5.7 | 151 |
| element 26 | | | | | |
| Light-emitting | Organic compound | 0.141, 0.082 | 5.5 | 6.3 | 142 |
| element 27 | M27 | | | | |
| Light-emitting | Organic compound | 0.144, 0.082 | 5.5 | 5.6 | 156 |
| element 28 | M28 | | | | |
| Light-emitting | Organic compound | 0.143, 0.081 | 5.4 | 6.1 | 151 |
| element 29 | M29 | | | | |
| Light-emitting | Organic compound | 0.143, 0.084 | 5.6 | 5.9 | 148 |
| element 30 | M30 | | | | |
| ight-emitting | Organic compound | 0.142, 0.083 | 5.4 | 5.5 | 150 |
| element 31 | M31 | | | | |
| Light-emitting | Organic compound | 0.144, 0.084 | 5.5 | 5.6 | 144 |
| element 32 | M32 | | | | |
| Light-emitting | Organic compound | 0.142, 0.081 | 5.6 | 5.6 | 148 |
| element 33 | M33 | | | | |
| Light-emitting | Organic compound | 0.143, 0.082 | 5.4 | 5.7 | 155 |
| element 34 | M34 | | | | |
| Light-emitting | Organic compound | 0.142, 0.085 | 5.6 | 5.9 | 161 |
| element 35 | M35 | | | | |
| Light-emitting | Organic compound | 0.142, 0.086 | 5.5 | 5.5 | 143 |
| element 36 | M36 | | | | |
| Light-emitting | Organic compound | 0.141, 0.084 | 5.6 | 5.7 | 149 |
| element 37 | M37 | | | | |
| Comparative | Comparative | 0.144, 0.145 | 5.9 | 2.7 | 92 |
| element 1 | Compound 1 | | | | |
| Comparative | Comparative | 0.141, 0.142 | 6.2 | 3.5 | 82 |
| element 2 | Compound 2 | | | | |

As can be seen from Table 2, the light-emitting elements 1 to 37 obtained by using the organic compounds 1 to 37 as guest materials of the light-emitting layer of the present disclosure have superior color coordinates compared to the comparative elements 1 to 2. The luminous efficiency of the light-emitting elements 1 to 37 is in a range of 5.1 cd/A-6.2 cd/A, which is much higher than a luminous efficiency of the comparative elements 1 to 2. The time taken for decreasing the luminance of the light-emitting elements 1 to 37 from the initial luminance of 1 knits to 9000 of the initial luminance is in a range of 141 h-168 h, which is a significant increase compared to the time taken for decreasing the luminance of the comparative elements 1 to 2 from the initial luminance of 1 knits to 900% of the initial luminance, indicating that the light-emitting elements 1 to 37 have a significantly increased lifetime.

According to the light-emitting element in the embodiments of the present disclosure, by using a boron-containing organic compound, the material performance is improved, the luminous efficiency, of the light-emitting element is improved, and the service life of the light-emitting element is prolonged.

An embodiment of the present disclosure further provides a display panel including the light-emitting element as described above.

The display panel further includes an array substrate on a side of the light-emitting element, and an encapsulation layer located on a side of the light-emitting element away from the array substrate and covering the light-emitting element. The display panel further includes a polarizer layer on a side of the encapsulation layer away from the light-emitting element, and a cover layer on a side of the polarizer layer away from the light-emitting element. The polarizer layer may be replaced with a color film layer. The color film layer may include a plurality of color resistors and a black matrix located on two sides of the color resistors.

According to the display panel of an embodiment of the present disclosure, by using a light-emitting element containing a boron-containing organic compound, the material performance is improved, the luminous efficiency, of the light-emitting element is improved, and the light-emitting life of the light-emitting element is prolonged.

An embodiment of the present disclosure discloses the organic compound, the light-emitting element, and the display panel. The organic compound has a structure as shown in formula (1):

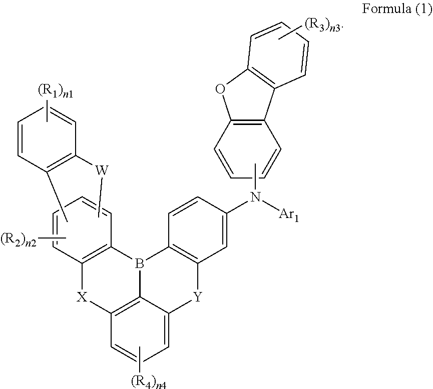

According to the present disclosure, by using a boron-containing organic compound to which an aromatic group or a heteroaromatic group is introduced to enhance the overall conjugation of the molecule, and to which an aliphatic hydrocarbon group is introduced to enhance the solubility of the molecule, the material performance is improved in terms of luminous efficiency, service life, and purity of the boron-containing organic compound in the light-emitting element, thereby improving the luminous efficiency, and prolonging the service life of the light-emitting element.

The organic compound, light-emitting element, and display panel according to embodiments of the present disclosure are described in detail above. The principles and implementation of the present disclosure are set forth herein using specific examples. The description of the above embodiments is merely provided to help understand the method of the present disclosure and the core idea thereof. For those skilled in the art, there will be changes in the specific implementation and the scope of application in accordance with the teachings of the present disclosure. In light of the foregoing, the present specification is not to be construed as limiting the invention.

What is claimed is:

1. An organic compound having a structure represented by formula (1): 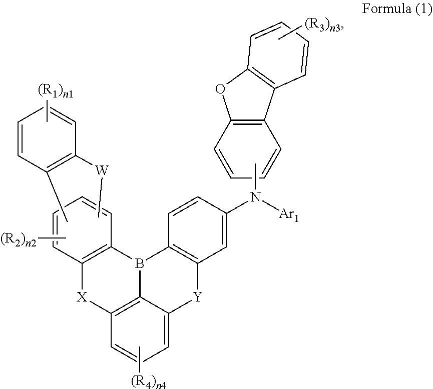
wherein Ar₁ is selected from the group consisting of a substituted or unsubstituted aromatic group having 6 to 60 ring atoms, and a substituted or unsubstituted heteroaromatic group having 5 to 60 ring atoms;
X and Y are each independently selected from the group consisting of O, S, CR₅R₆, and NR₇;
W is selected from the group consisting of O, S, CR₈R₉, and NR₁₀;
R₁, R₂, R₃, R₄, R₅, R₆, R₇, R₈, R₉, and R₁₀, at each occurrence, are each independently selected from the group consisting of —H, a linear alkyl group having 1 to 20 carbon atoms, a branched alkyl group having 3 to 20 carbon atoms, and a substituted or unsubstituted aromatic group having 6 to 30 ring atoms; and
n1 is selected from 0, 1, 2, 3, or 4; n2 is selected from 0, 1, or 2; n3 is selected from 0, 1, 2, 3, or 4; n4 is selected from 0, 1, 2, or 3.

2. The organic compound according to claim 1, wherein the organic compound has a structure represented by any one of formulae (2-1) to (2-6):

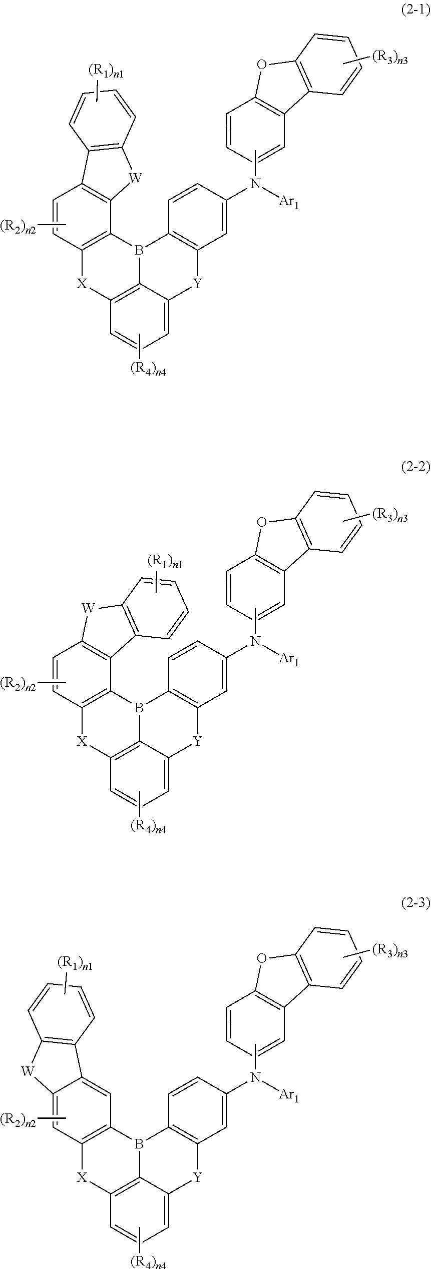

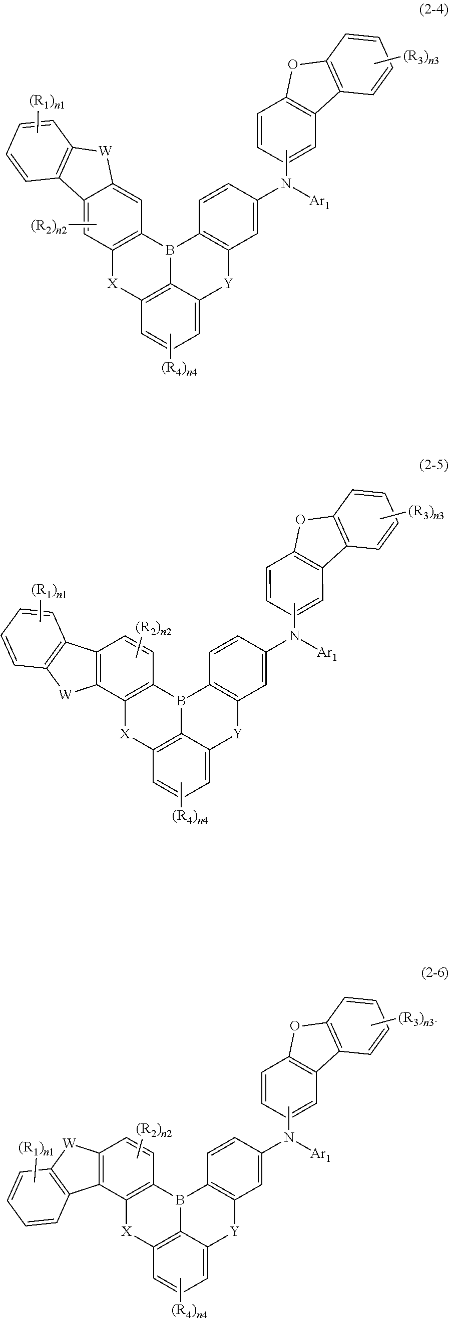

3. The organic compound according to claim 2, wherein the organic compound has a structure represented by any one of formulae (3-1) to (3-6): 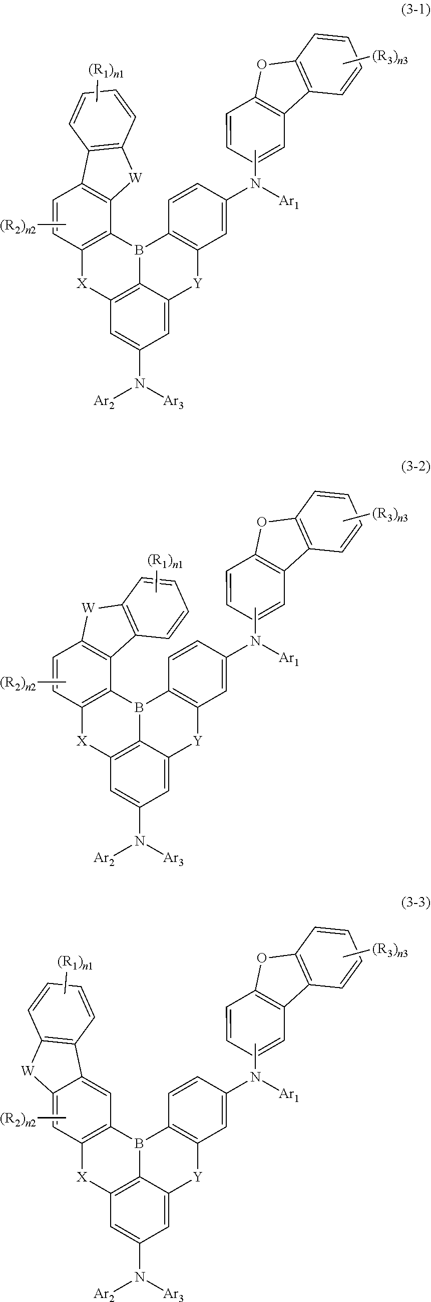 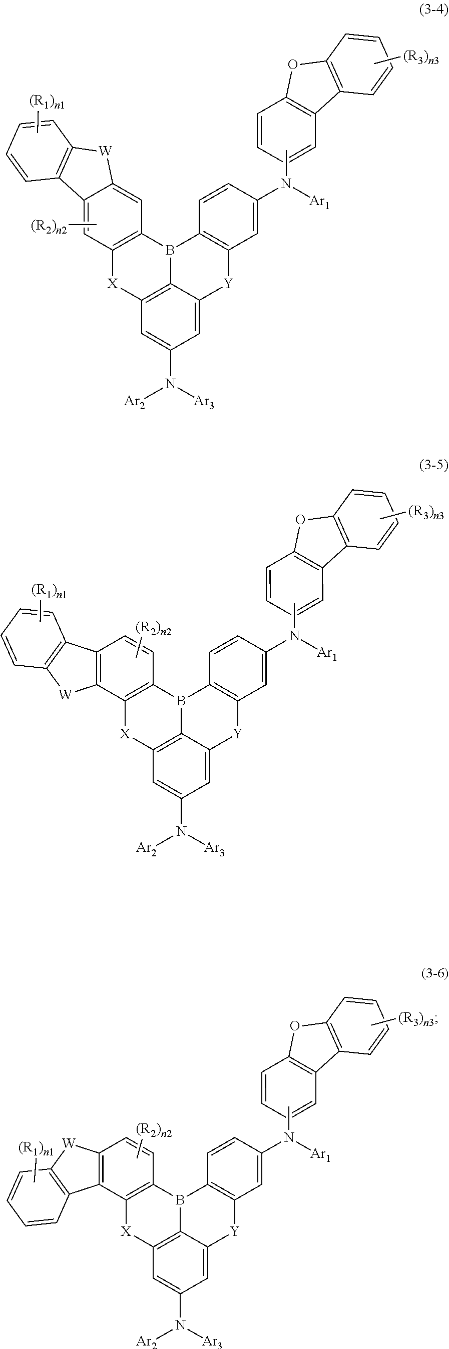
Ar₂ and Ar₃ are each independently selected from the group consisting of a substituted or unsubstituted aromatic group having 6 to 60 ring atoms, and a substituted or unsubstituted heteroaromatic group having 5 to 60 ring atoms.

4. The organic compound according to claim 3, wherein Ar₁, Ar₂, and Arₙ are each independently selected from any one of structures represented by the following: 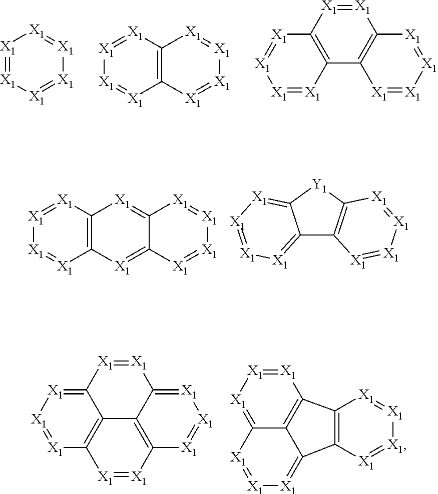
X₁, at each occurrence, is independently selected from CRₙ or N;
Y₁ is selected from the group consisting of NR₁₂, CR₁₃R₁₄, SiR₁₃R₁₄, O, S, S═O, and SO₂; and
R₁₁, R₁₂, R₁₃, and R₁₄, at each occurrence, are each independently selected from the group consisting of —H, a linear alkyl group having 1 to 20 carbon atoms, a branched alkyl group having 3 to 20 carbon atoms, and a substituted or unsubstituted aromatic group having 6 to 30 ring atoms.

5. The organic compound according to claim 4, wherein R₁₁, R₁₂, R₁₃ and R₁₄, at each occurrence, are each independently selected from the group consisting of —H, methyl, tert-butyl, and phenyl.

6. The organic compound according to claim 1, wherein R₁, R₂, R₃, and R₄, at each occurrence, are each independently selected from the group consisting of —H, methyl, 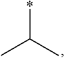 [SMILES: *C(C)C]
tert-butyl, 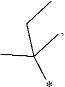 [SMILES: *C(C)(C)CC]
phenyl 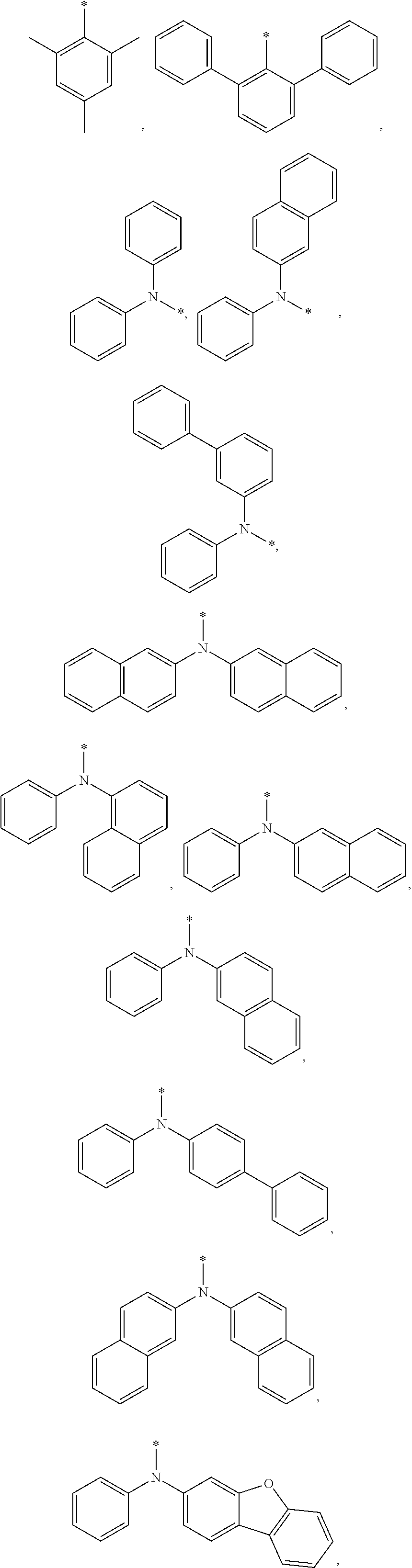 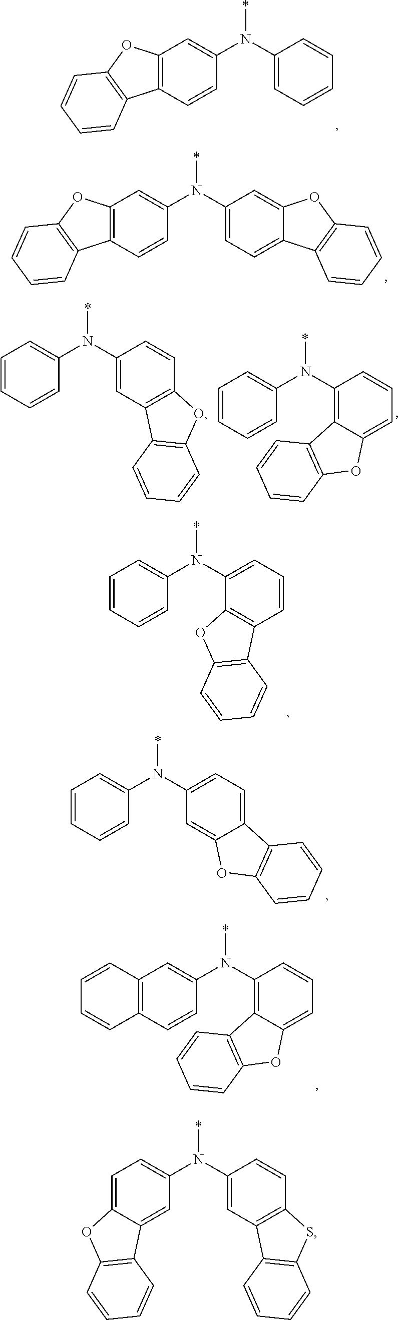 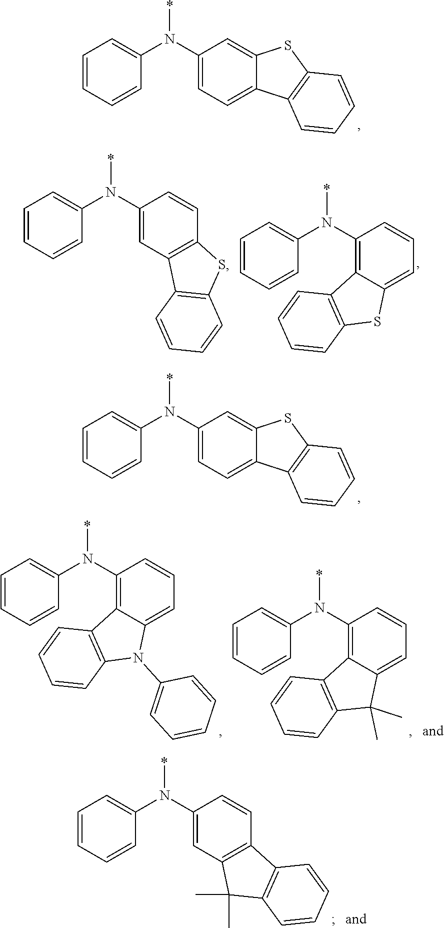
R₅, R₆, R₇, R₈, R₉ and R₁₀, at each occurrence, are each independently selected from the group consisting of —H, methyl, tert-butyl, phenyl,

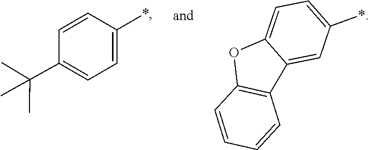

7. The organic compound according to claim 1, wherein the organic compound is selected from any one of the following structures:

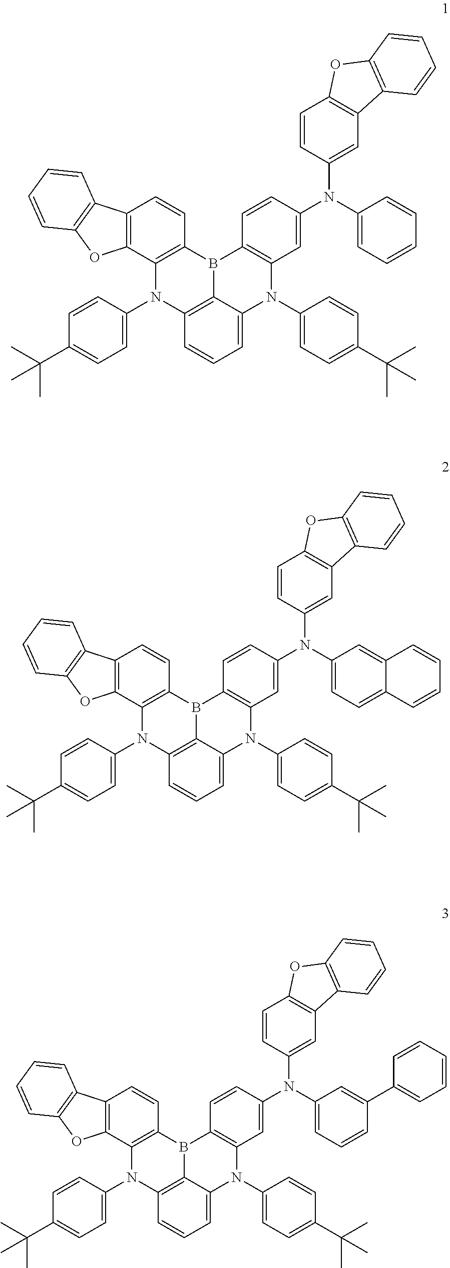 [SMILES: CC(C)(C)c1ccc(N2c3cc(N(c4ccccc4)c4ccc5oc6ccccc6c5c4)ccc3B3c4ccc5c(oc6ccccc65)c4N(c4ccc(C(C)(C)C)cc4)c4cccc2c43)cc1 ; CC(C)(C)c1ccc(N2c3cc(N(c4ccc5ccccc5c4)c4ccc5oc6ccccc6c5c4)ccc3B3c4ccc5c(oc6ccccc65)c4N(c4ccc(C(C)(C)C)cc4)c4cccc2c43)cc1 ; CC(C)(C)c1ccc(N2c3cc(N(c4cccc(-c5ccccc5)c4)c4ccc5oc6ccccc6c5c4)ccc3B3c4ccc5c(oc6ccccc65)c4N(c4ccc(C(C)(C)C)cc4)c4cccc2c43)cc1]

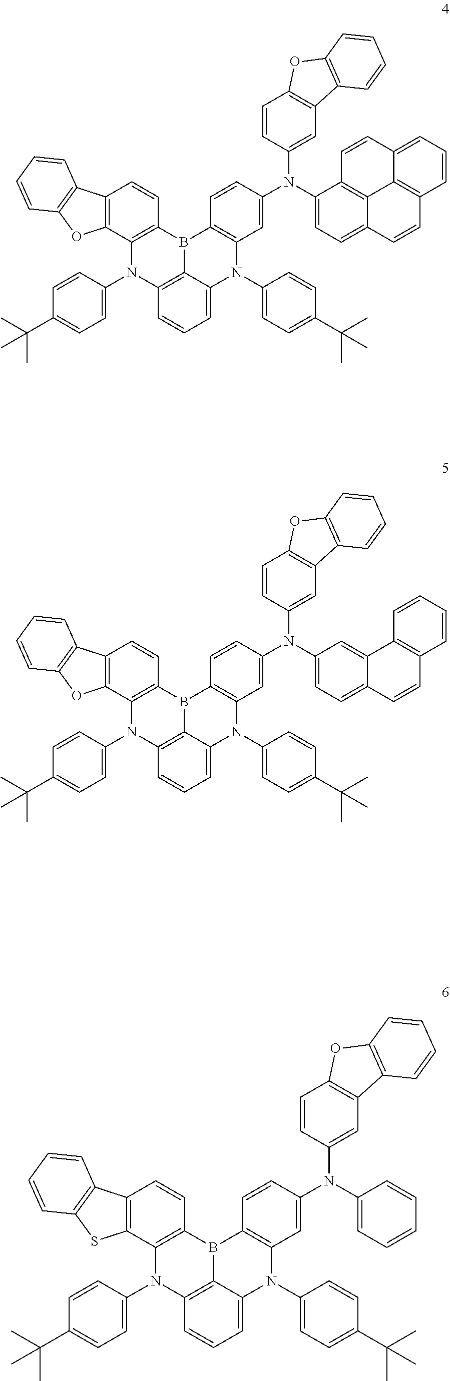 [SMILES: CC(C)(C)c1ccc(N2c3cc(N(c4ccc5oc6ccccc6c5c4)c4ccc5ccc6cccc7ccc4c5c67)ccc3B3c4ccc5c(oc6ccccc65)c4N(c4ccc(C(C)(C)C)cc4)c4cccc2c43)cc1 ; CC(C)(C)c1ccc(N2c3cc(N(c4ccc5ccc6ccccc6c5c4)c4ccc5oc6ccccc6c5c4)ccc3B3c4ccc5c(oc6ccccc65)c4N(c4ccc(C(C)(C)C)cc4)c4cccc2c43)cc1 ; CC(C)(C)c1ccc(N2c3cc(N(c4ccccc4)c4ccc5oc6ccccc6c5c4)ccc3B3c4ccc5c(sc6ccccc65)c4N(c4ccc(C(C)(C)C)cc4)c4cccc2c43)cc1]

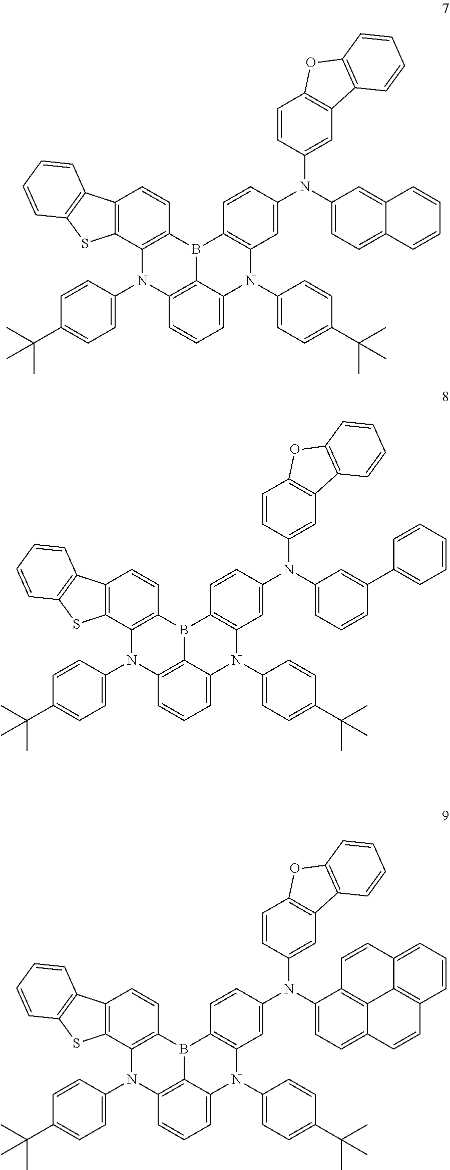 [SMILES: CC(C)(C)c1ccc(N2c3cc(N(c4ccc5ccccc5c4)c4ccc5oc6ccccc6c5c4)ccc3B3c4ccc5c(sc6ccccc65)c4N(c4ccc(C(C)(C)C)cc4)c4cccc2c43)cc1 ; CC(C)(C)c1ccc(N2c3cc(N(c4cccc(-c5ccccc5)c4)c4ccc5oc6ccccc6c5c4)ccc3B3c4ccc5c(sc6ccccc65)c4N(c4ccc(C(C)(C)C)cc4)c4cccc2c43)cc1 ; CC(C)(C)c1ccc(N2c3cc(N(c4ccc5oc6ccccc6c5c4)c4ccc5ccc6cccc7ccc4c5c67)ccc3B3c4ccc5c(sc6ccccc65)c4N(c4ccc(C(C)(C)C)cc4)c4cccc2c43)cc1]

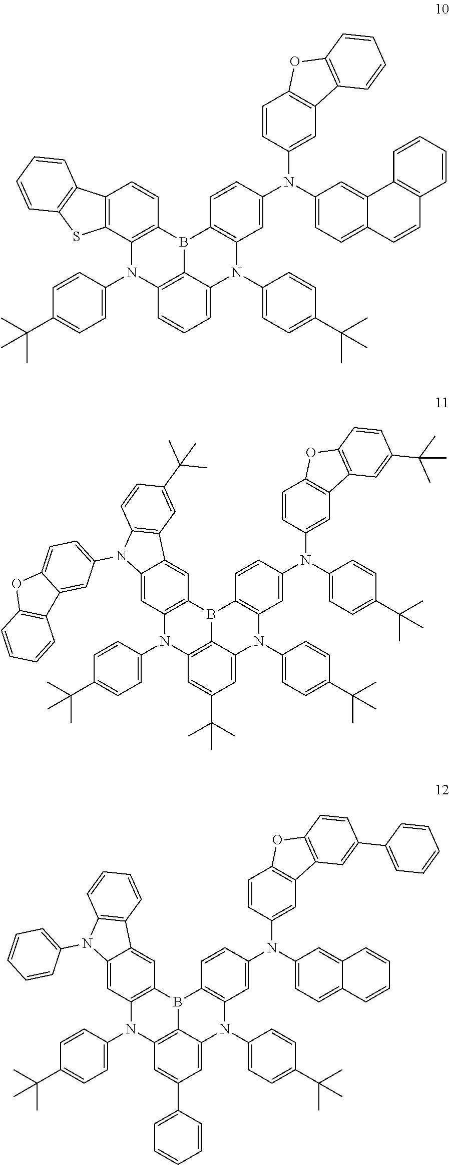 [SMILES: CC(C)(C)c1ccc(N2c3cc(N(c4ccc5ccc6ccccc6c5c4)c4ccc5oc6ccccc6c5c4)ccc3B3c4ccc5c(sc6ccccc65)c4N(c4ccc(C(C)(C)C)cc4)c4cccc2c43)cc1 ; CC(C)(C)c1ccc(N(c2ccc3c(c2)N(c2ccc(C(C)(C)C)cc2)c2cc(C(C)(C)C)cc4c2B3c2cc3c5cc(C(C)(C)C)ccc5n(-c5ccc6oc7ccccc7c6c5)c3cc2N4c2ccc(C(C)(C)C)cc2)c2ccc3oc4ccc(C(C)(C)C)cc4c3c2)cc1 ; CC(C)(C)c1ccc(N2c3cc(N(c4ccc5ccccc5c4)c4ccc5oc6ccc(-c7ccccc7)cc6c5c4)ccc3B3c4cc5c6ccccc6n(-c6ccccc6)c5cc4N(c4ccc(C(C)(C)C)cc4)c4cc(-c5ccccc5)cc2c43)cc1]

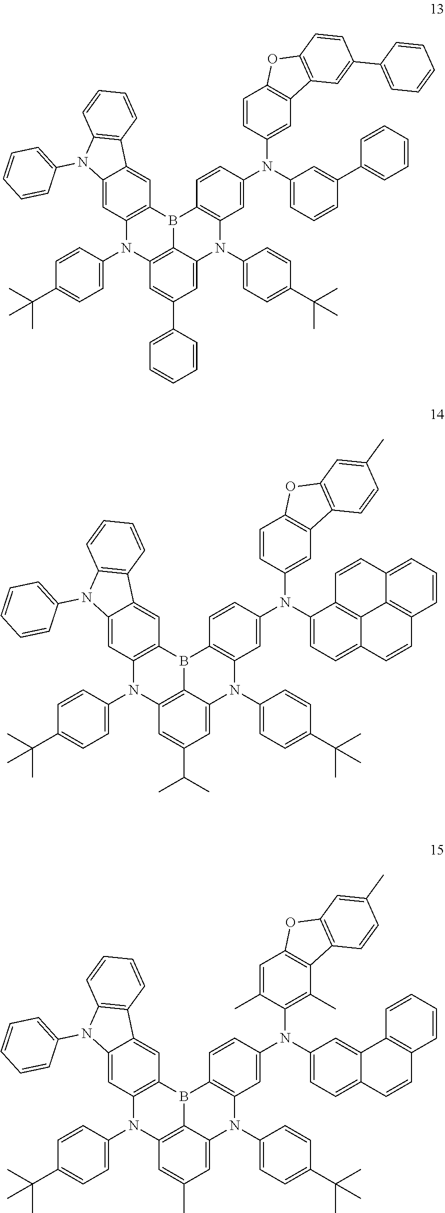 [SMILES: CC(C)(C)c1ccc(N2c3cc(N(c4cccc(-c5ccccc5)c4)c4ccc5oc6ccc(-c7ccccc7)cc6c5c4)ccc3B3c4cc5c6ccccc6n(-c6ccccc6)c5cc4N(c4ccc(C(C)(C)C)cc4)c4cc(-c5ccccc5)cc2c43)cc1 ; Cc1ccc2c(c1)oc1ccc(N(c3ccc4c(c3)N(c3ccc(C(C)(C)C)cc3)c3cc(C(C)C)cc5c3B4c3cc4c6ccccc6n(-c6ccccc6)c4cc3N5c3ccc(C(C)(C)C)cc3)c3ccc4ccc5cccc6ccc3c4c56)cc12 ; Cc1cc2c3c(c1)N(c1ccc(C(C)(C)C)cc1)c1cc4c(cc1B3c1ccc(N(c3ccc5ccc6ccccc6c5c3)c3c(C)cc5oc6cc(C)ccc6c5c3C)cc1N2c1ccc(C(C)(C)C)cc1)c1ccccc1n4-c1ccccc1]

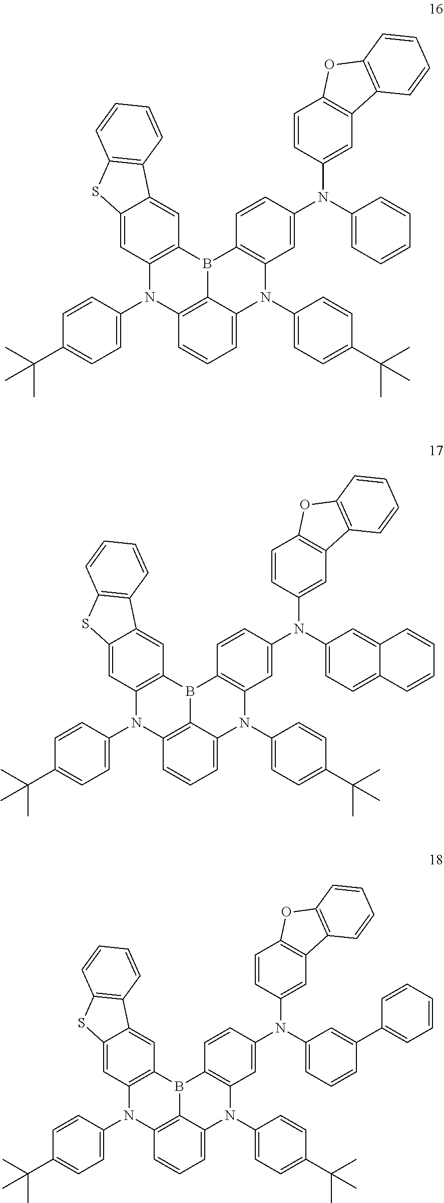 [SMILES: CC(C)(C)c1ccc(N2c3cc(N(c4ccccc4)c4ccc5oc6ccccc6c5c4)ccc3B3c4cc5c(cc4N(c4ccc(C(C)(C)C)cc4)c4cccc2c43)sc2ccccc25)cc1 ; CC(C)(C)c1ccc(N2c3cc(N(c4ccc5ccccc5c4)c4ccc5oc6ccccc6c5c4)ccc3B3c4cc5c(cc4N(c4ccc(C(C)(C)C)cc4)c4cccc2c43)sc2ccccc25)cc1 ; CC(C)(C)c1ccc(N2c3cc(N(c4cccc(-c5ccccc5)c4)c4ccc5oc6ccccc6c5c4)ccc3B3c4cc5c(cc4N(c4ccc(C(C)(C)C)cc4)c4cccc2c43)sc2ccccc25)cc1]

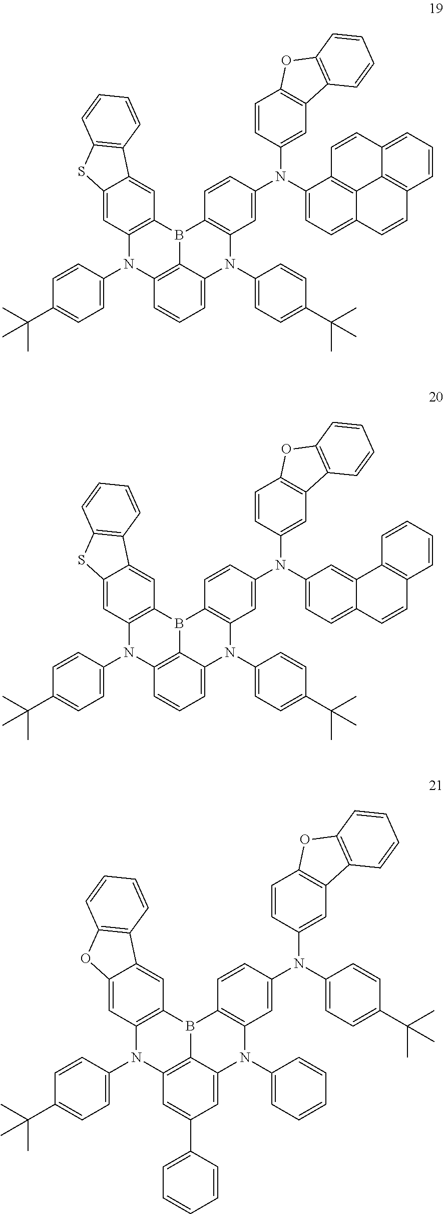 [SMILES: CC(C)(C)c1ccc(N2c3cc(N(c4ccc5oc6ccccc6c5c4)c4ccc5ccc6cccc7ccc4c5c67)ccc3B3c4cc5c(cc4N(c4ccc(C(C)(C)C)cc4)c4cccc2c43)sc2ccccc25)cc1 ; CC(C)(C)c1ccc(N2c3cc(N(c4ccc5ccc6ccccc6c5c4)c4ccc5oc6ccccc6c5c4)ccc3B3c4cc5c(cc4N(c4ccc(C(C)(C)C)cc4)c4cccc2c43)sc2ccccc25)cc1 ; CC(C)(C)c1ccc(N(c2ccc3c(c2)N(c2ccccc2)c2cc(-c4ccccc4)cc4c2B3c2cc3c(cc2N4c2ccc(C(C)(C)C)cc2)oc2ccccc23)c2ccc3oc4ccccc4c3c2)cc1]

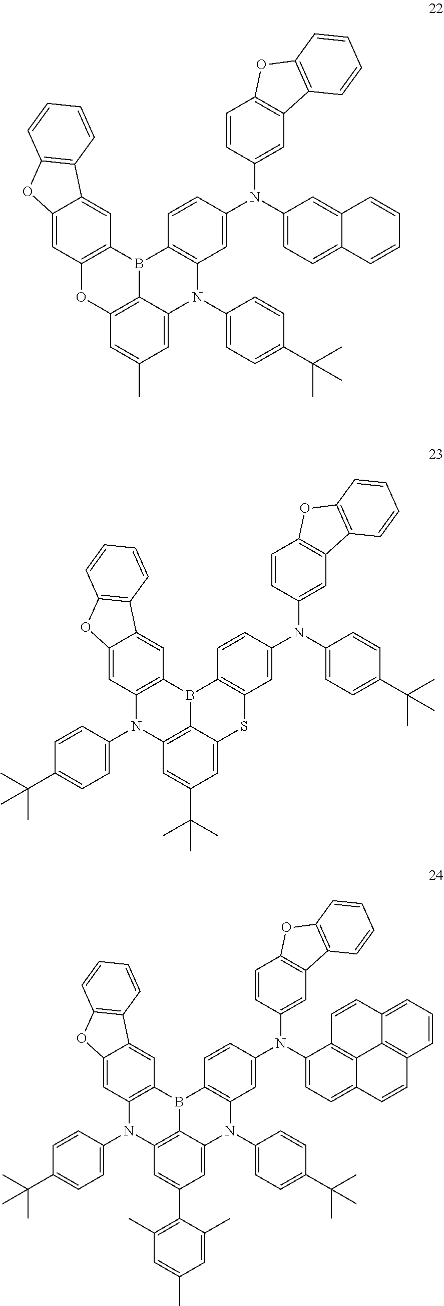

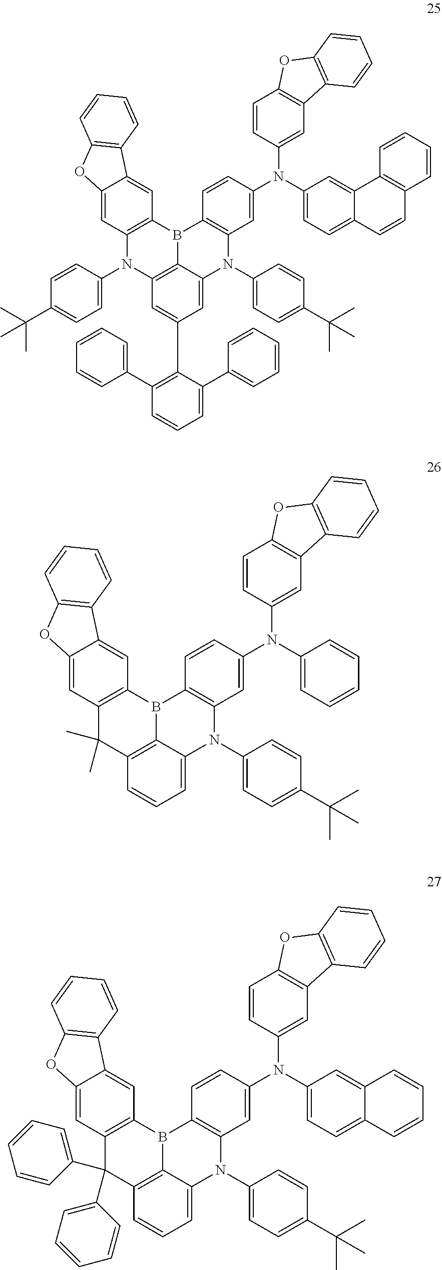 [SMILES: CC(C)(C)c1ccc(N2c3cc(N(c4ccc5ccc6ccccc6c5c4)c4ccc5oc6ccccc6c5c4)ccc3B3c4cc5c(cc4N(c4ccc(C(C)(C)C)cc4)c4cc(-c6c(-c7ccccc7)cccc6-c6ccccc6)cc2c43)oc2ccccc25)cc1 ; CC(C)(C)c1ccc(N2c3cc(N(c4ccccc4)c4ccc5oc6ccccc6c5c4)ccc3B3c4cc5c(cc4C(C)(C)c4cccc2c43)oc2ccccc25)cc1 ; CC(C)(C)c1ccc(N2c3cc(N(c4ccc5ccccc5c4)c4ccc5oc6ccccc6c5c4)ccc3B3c4cc5c(cc4C(c4ccccc4)(c4ccccc4)c4cccc2c43)oc2ccccc25)cc1]

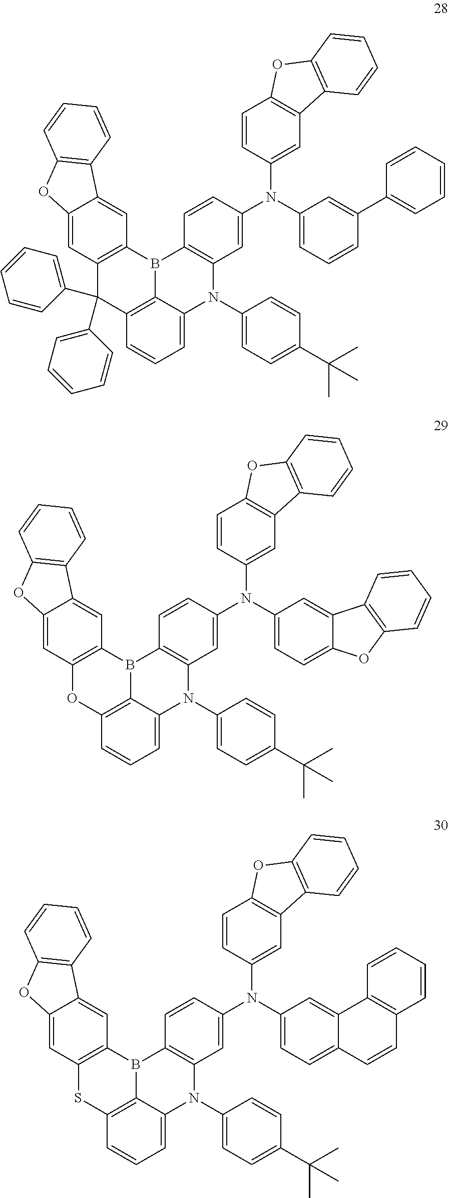

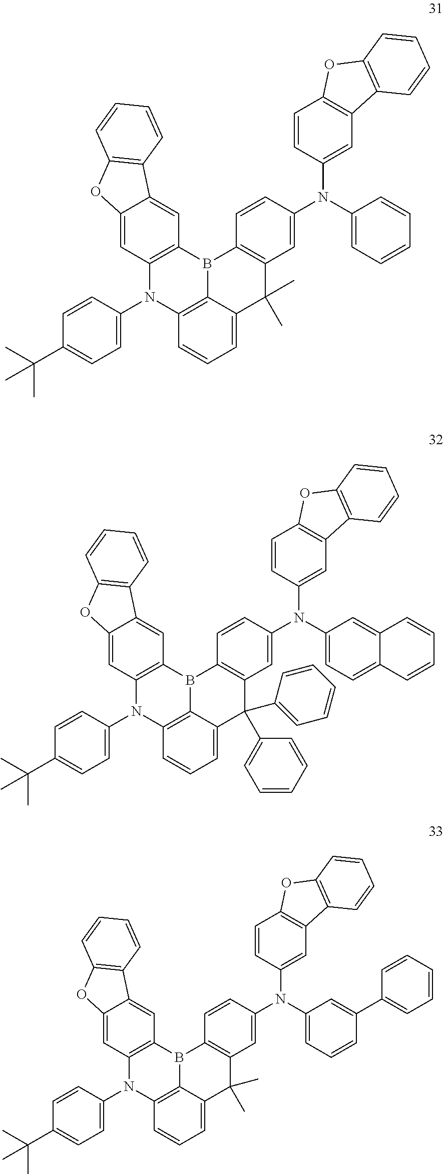 [SMILES: CC(C)(C)c1ccc(N2c3cc4oc5ccccc5c4cc3B3c4ccc(N(c5ccccc5)c5ccc6oc7ccccc7c6c5)cc4C(C)(C)c4cccc2c43)cc1 ; CC(C)(C)c1ccc(N2c3cc4oc5ccccc5c4cc3B3c4ccc(N(c5ccc6ccccc6c5)c5ccc6oc7ccccc7c6c5)cc4C(c4ccccc4)(c4ccccc4)c4cccc2c43)cc1 ; CC(C)(C)c1ccc(N2c3cc4oc5ccccc5c4cc3B3c4ccc(N(c5cccc(-c6ccccc6)c5)c5ccc6oc7ccccc7c6c5)cc4C(C)(C)c4cccc2c43)cc1]

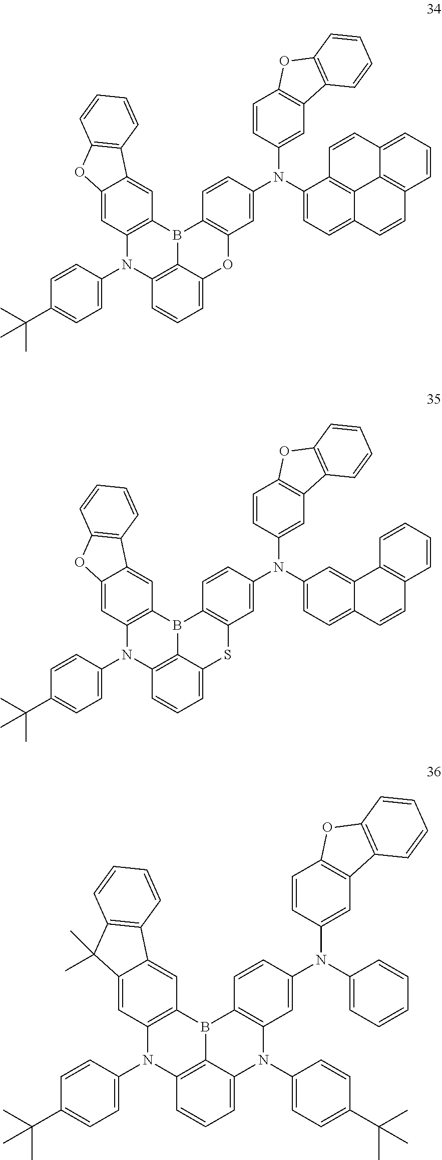 [SMILES: CC(C)(C)c1ccc(N2c3cc4oc5ccccc5c4cc3B3c4ccc(N(c5ccc6oc7ccccc7c6c5)c5ccc6ccc7cccc8ccc5c6c78)cc4Oc4cccc2c43)cc1 ; CC(C)(C)c1ccc(N2c3cc4oc5ccccc5c4cc3B3c4ccc(N(c5ccc6ccc7ccccc7c6c5)c5ccc6oc7ccccc7c6c5)cc4Sc4cccc2c43)cc1 ; CC(C)(C)c1ccc(N2c3cc(N(c4ccccc4)c4ccc5oc6ccccc6c5c4)ccc3B3c4cc5c(cc4N(c4ccc(C(C)(C)C)cc4)c4cccc2c43)C(C)(C)c2ccccc2-5)cc1]

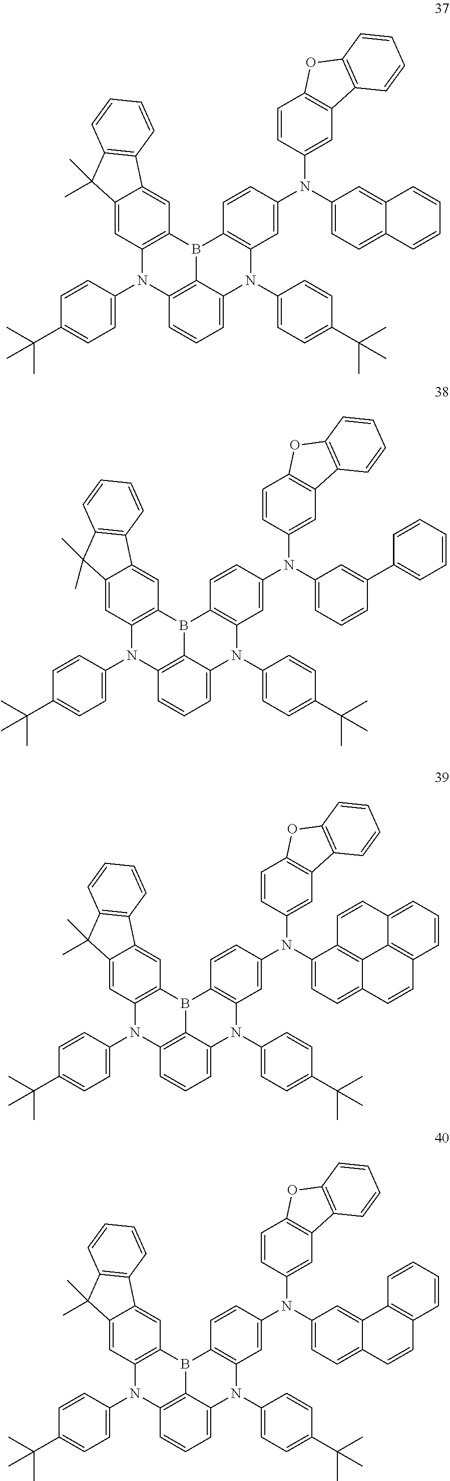

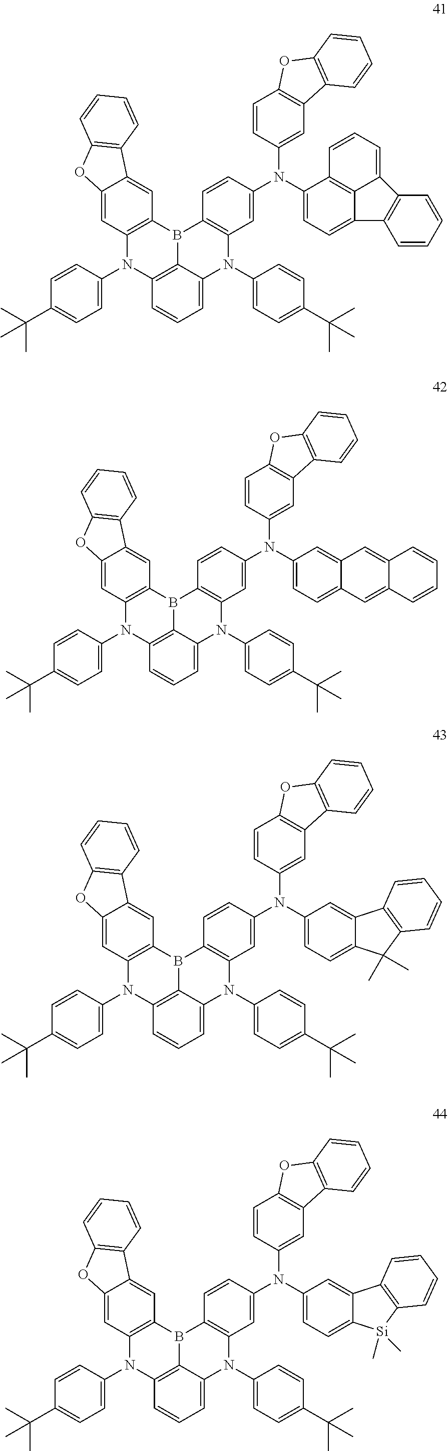

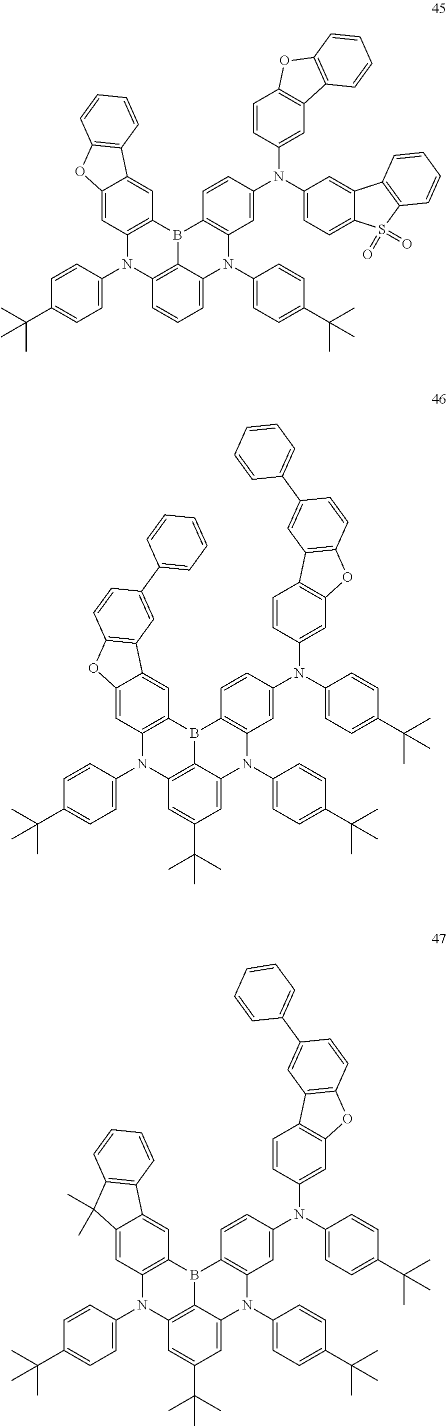

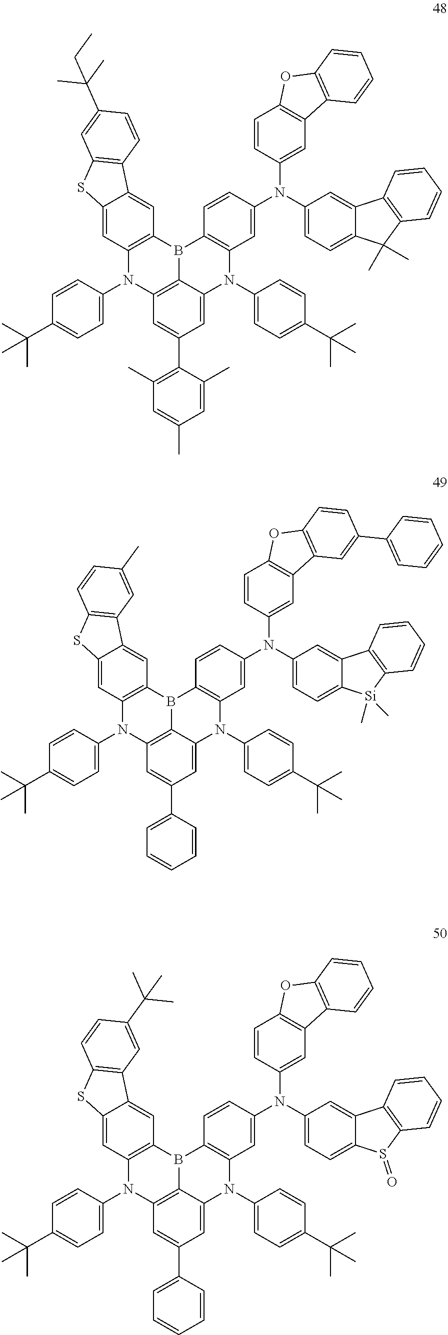 [SMILES: CCC(C)(C)c1ccc2c(c1)sc1cc3c(cc12)B1c2ccc(N(c4ccc5c(c4)-c4ccccc4C5(C)C)c4ccc5oc6ccccc6c5c4)cc2N(c2ccc(C(C)(C)C)cc2)c2cc(-c4c(C)cc(C)cc4C)cc(c21)N3c1ccc(C(C)(C)C)cc1 ; Cc1ccc2sc3cc4c(cc3c2c1)B1c2ccc(N(c3ccc5c(c3)-c3ccccc3[Si]5(C)C)c3ccc5oc6ccc(-c7ccccc7)cc6c5c3)cc2N(c2ccc(C(C)(C)C)cc2)c2cc(-c3ccccc3)cc(c21)N4c1ccc(C(C)(C)C)cc1 ; CC(C)(C)c1ccc(N2c3cc(N(c4ccc5c(c4)-c4ccccc4S5=O)c4ccc5oc6ccccc6c5c4)ccc3B3c4cc5c(cc4N(c4ccc(C(C)(C)C)cc4)c4cc(-c6ccccc6)cc2c43)sc2ccc(C(C)(C)C)cc25)cc1]

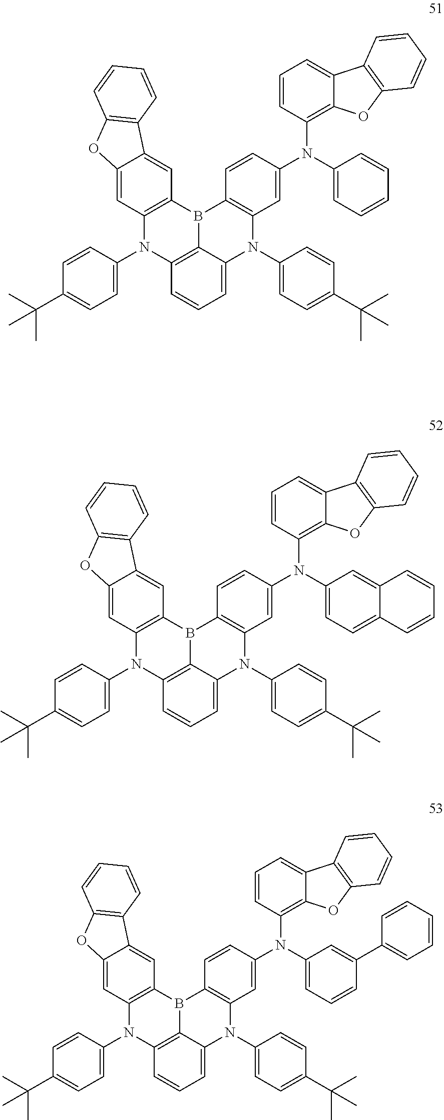 [SMILES: CC(C)(C)c1ccc(N2c3cc(N(c4ccccc4)c4cccc5c4oc4ccccc45)ccc3B3c4cc5c(cc4N(c4ccc(C(C)(C)C)cc4)c4cccc2c43)oc2ccccc25)cc1 ; CC(C)(C)c1ccc(N2c3cc(N(c4ccc5ccccc5c4)c4cccc5c4oc4ccccc45)ccc3B3c4cc5c(cc4N(c4ccc(C(C)(C)C)cc4)c4cccc2c43)oc2ccccc25)cc1 ; CC(C)(C)c1ccc(N2c3cc(N(c4cccc(-c5ccccc5)c4)c4cccc5c4oc4ccccc45)ccc3B3c4cc5c(cc4N(c4ccc(C(C)(C)C)cc4)c4cccc2c43)oc2ccccc25)cc1]

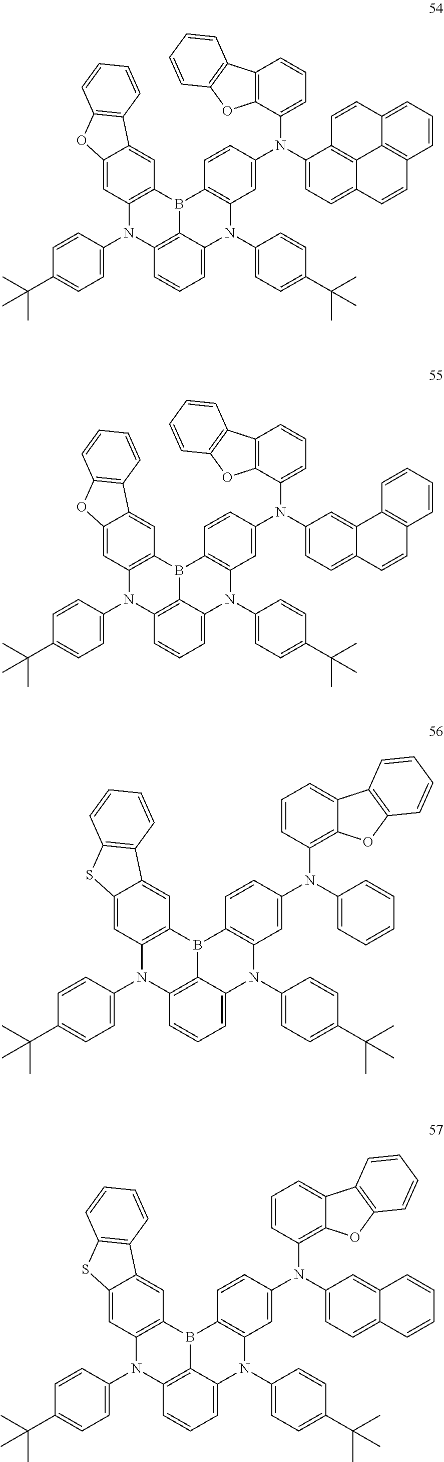 [SMILES: CC(C)(C)c1ccc(N2c3cc(N(c4ccc5ccc6cccc7ccc4c5c67)c4cccc5c4oc4ccccc45)ccc3B3c4cc5c(cc4N(c4ccc(C(C)(C)C)cc4)c4cccc2c43)oc2ccccc25)cc1 ; CC(C)(C)c1ccc(N2c3cc(N(c4ccc5ccc6ccccc6c5c4)c4cccc5c4oc4ccccc45)ccc3B3c4cc5c(cc4N(c4ccc(C(C)(C)C)cc4)c4cccc2c43)oc2ccccc25)cc1 ; CC(C)(C)c1ccc(N2c3cc(N(c4ccccc4)c4cccc5c4oc4ccccc45)ccc3B3c4cc5c(cc4N(c4ccc(C(C)(C)C)cc4)c4cccc2c43)sc2ccccc25)cc1 ; CC(C)(C)c1ccc(N2c3cc(N(c4ccc5ccccc5c4)c4cccc5c4oc4ccccc45)ccc3B3c4cc5c(cc4N(c4ccc(C(C)(C)C)cc4)c4cccc2c43)sc2ccccc25)cc1]

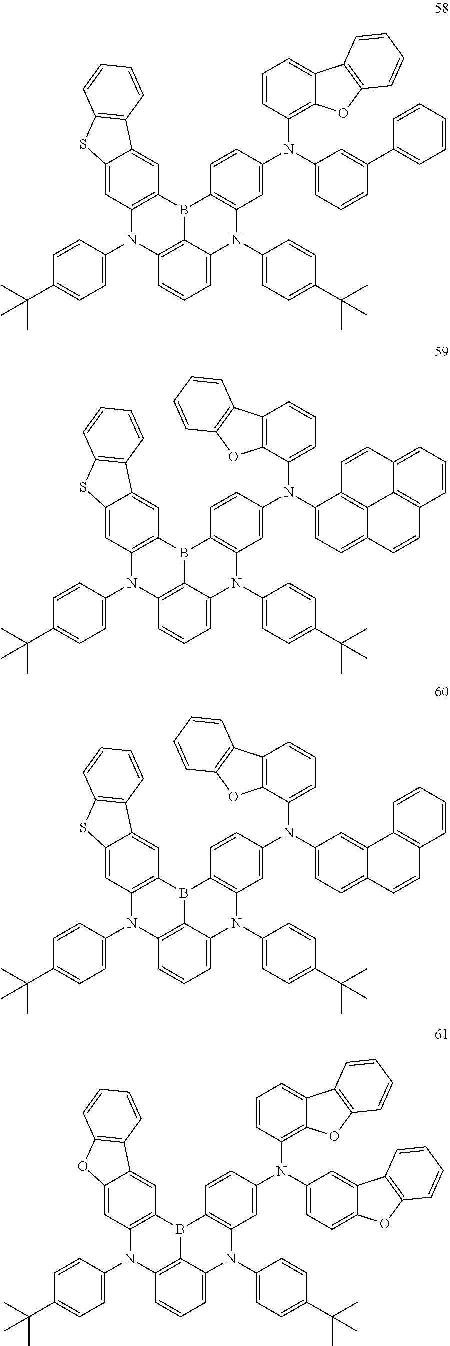

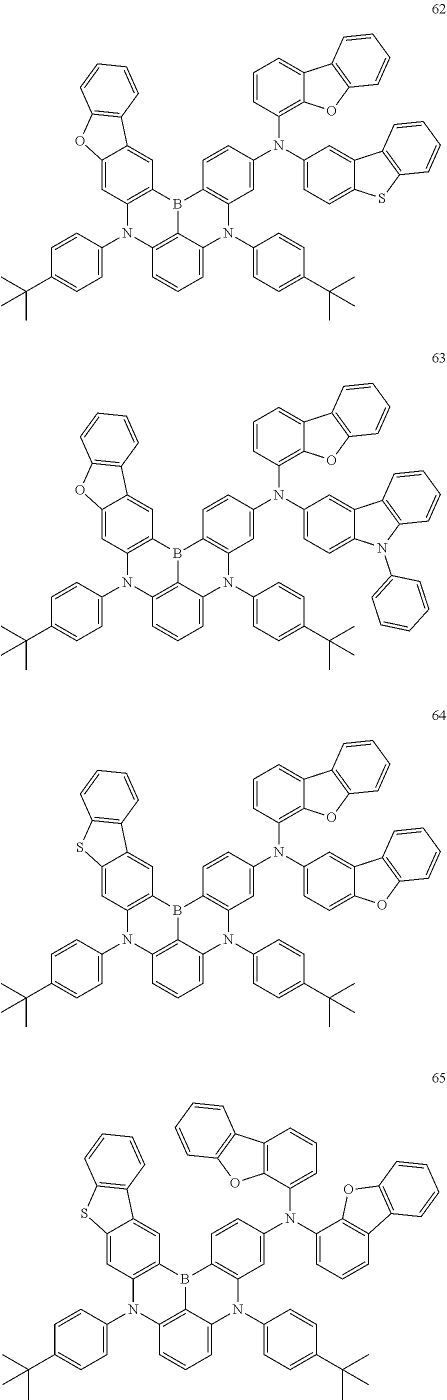

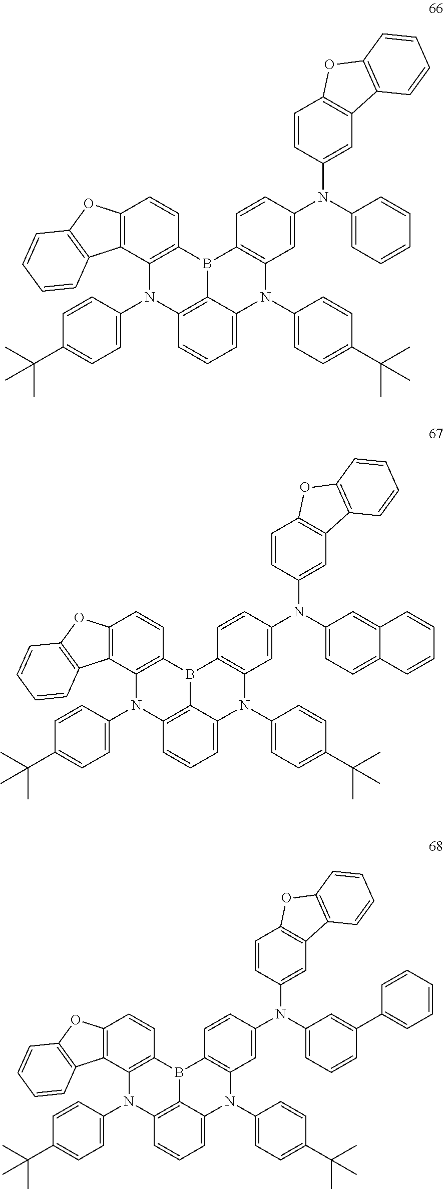 [SMILES: CC(C)(C)c1ccc(N2c3cc(N(c4ccccc4)c4ccc5oc6ccccc6c5c4)ccc3B3c4ccc5oc6ccccc6c5c4N(c4ccc(C(C)(C)C)cc4)c4cccc2c43)cc1 ; CC(C)(C)c1ccc(N2c3cc(N(c4ccc5ccccc5c4)c4ccc5oc6ccccc6c5c4)ccc3B3c4ccc5oc6ccccc6c5c4N(c4ccc(C(C)(C)C)cc4)c4cccc2c43)cc1 ; CC(C)(C)c1ccc(N2c3cc(N(c4cccc(-c5ccccc5)c4)c4ccc5oc6ccccc6c5c4)ccc3B3c4ccc5oc6ccccc6c5c4N(c4ccc(C(C)(C)C)cc4)c4cccc2c43)cc1]

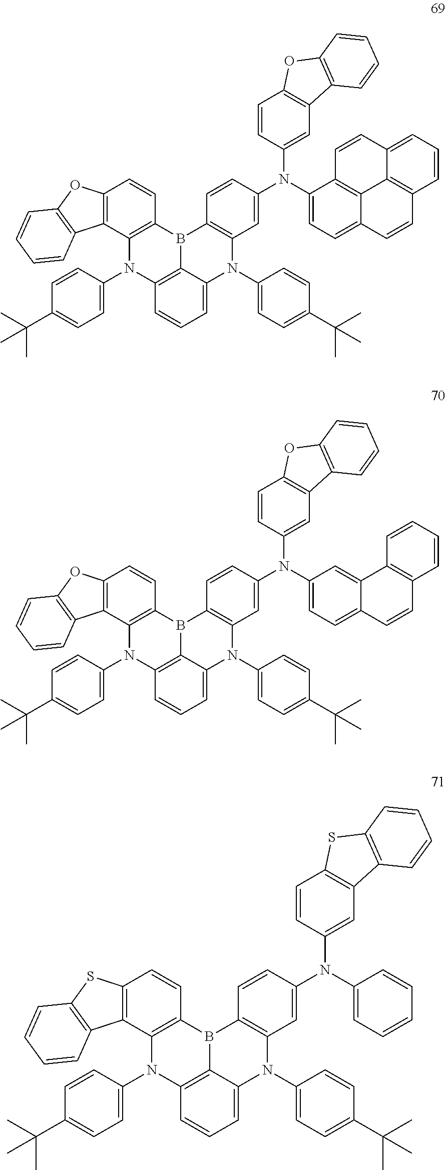 [SMILES: CC(C)(C)c1ccc(N2c3cc(N(c4ccc5oc6ccccc6c5c4)c4ccc5ccc6cccc7ccc4c5c67)ccc3B3c4ccc5oc6ccccc6c5c4N(c4ccc(C(C)(C)C)cc4)c4cccc2c43)cc1 ; CC(C)(C)c1ccc(N2c3cc(N(c4ccc5ccc6ccccc6c5c4)c4ccc5oc6ccccc6c5c4)ccc3B3c4ccc5oc6ccccc6c5c4N(c4ccc(C(C)(C)C)cc4)c4cccc2c43)cc1 ; CC(C)(C)c1ccc(N2c3cc(N(c4ccccc4)c4ccc5sc6ccccc6c5c4)ccc3B3c4ccc5sc6ccccc6c5c4N(c4ccc(C(C)(C)C)cc4)c4cccc2c43)cc1]

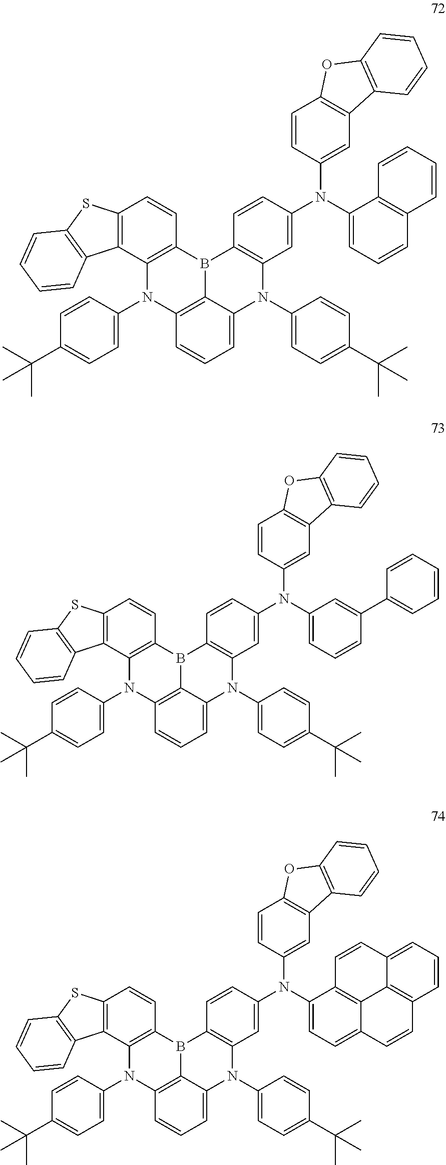 [SMILES: CC(C)(C)c1ccc(N2c3cc(N(c4ccc5oc6ccccc6c5c4)c4cccc5ccccc45)ccc3B3c4ccc5sc6ccccc6c5c4N(c4ccc(C(C)(C)C)cc4)c4cccc2c43)cc1 ; CC(C)(C)c1ccc(N2c3cc(N(c4cccc(-c5ccccc5)c4)c4ccc5oc6ccccc6c5c4)ccc3B3c4ccc5sc6ccccc6c5c4N(c4ccc(C(C)(C)C)cc4)c4cccc2c43)cc1 ; CC(C)(C)c1ccc(N2c3cc(N(c4ccc5oc6ccccc6c5c4)c4ccc5ccc6cccc7ccc4c5c67)ccc3B3c4ccc5sc6ccccc6c5c4N(c4ccc(C(C)(C)C)cc4)c4cccc2c43)cc1]

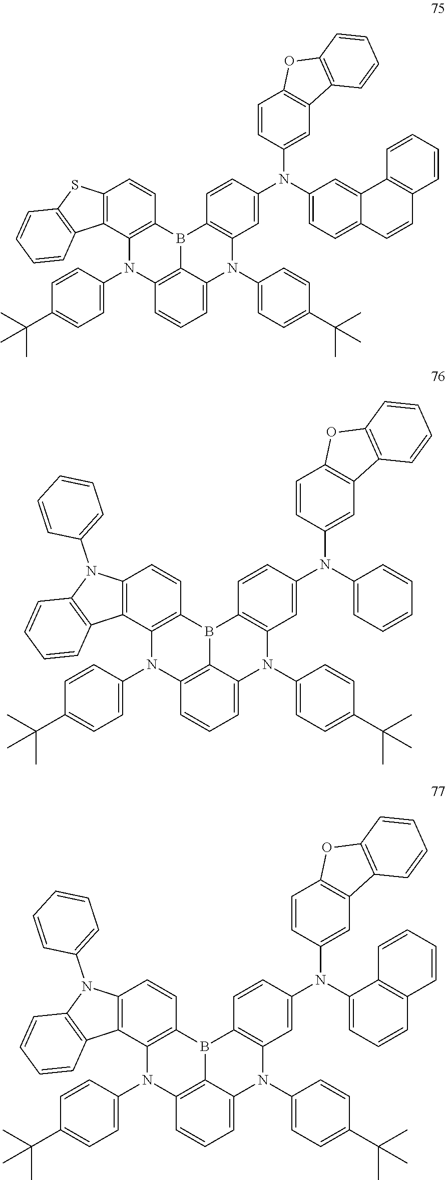 [SMILES: CC(C)(C)c1ccc(N2c3cc(N(c4ccc5ccc6ccccc6c5c4)c4ccc5oc6ccccc6c5c4)ccc3B3c4ccc5sc6ccccc6c5c4N(c4ccc(C(C)(C)C)cc4)c4cccc2c43)cc1 ; CC(C)(C)c1ccc(N2c3cc(N(c4ccccc4)c4ccc5oc6ccccc6c5c4)ccc3B3c4ccc5c(c4N(c4ccc(C(C)(C)C)cc4)c4cccc2c43)c2ccccc2n5-c2ccccc2)cc1 ; CC(C)(C)c1ccc(N2c3cc(N(c4ccc5oc6ccccc6c5c4)c4cccc5ccccc45)ccc3B3c4ccc5c(c4N(c4ccc(C(C)(C)C)cc4)c4cccc2c43)c2ccccc2n5-c2ccccc2)cc1]

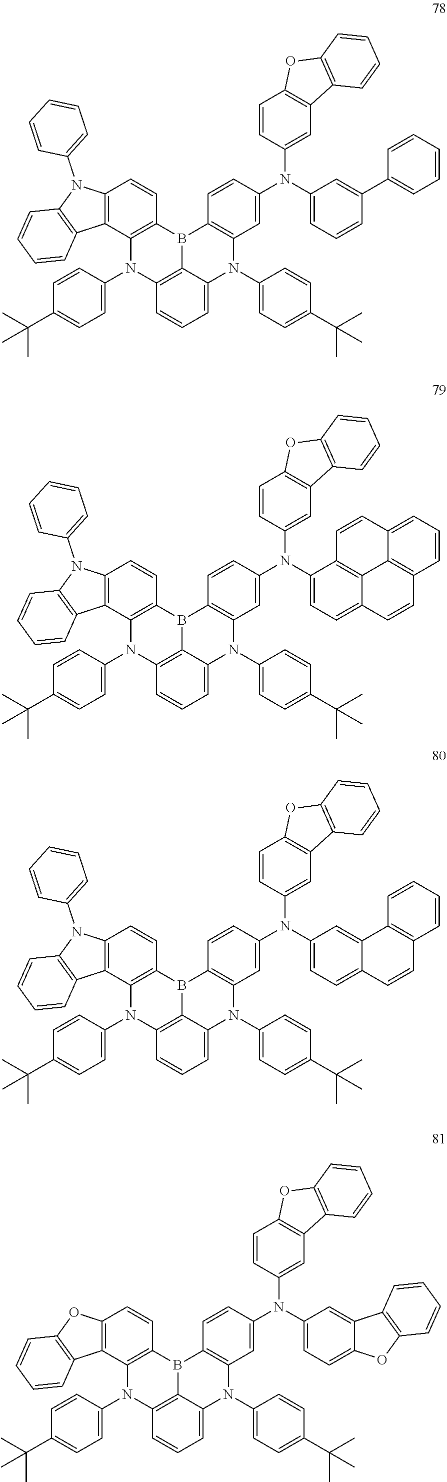

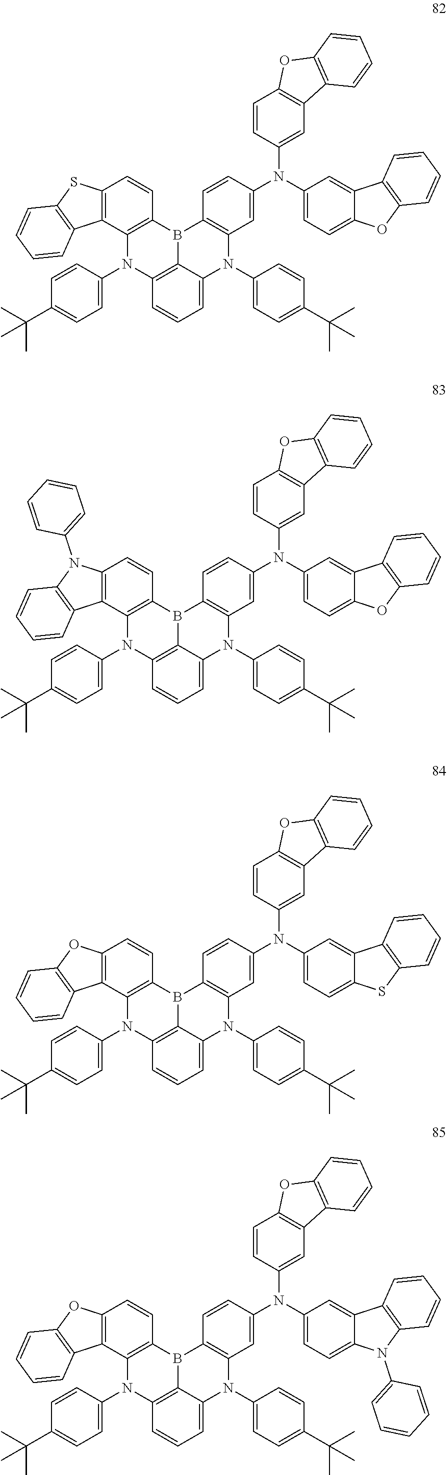

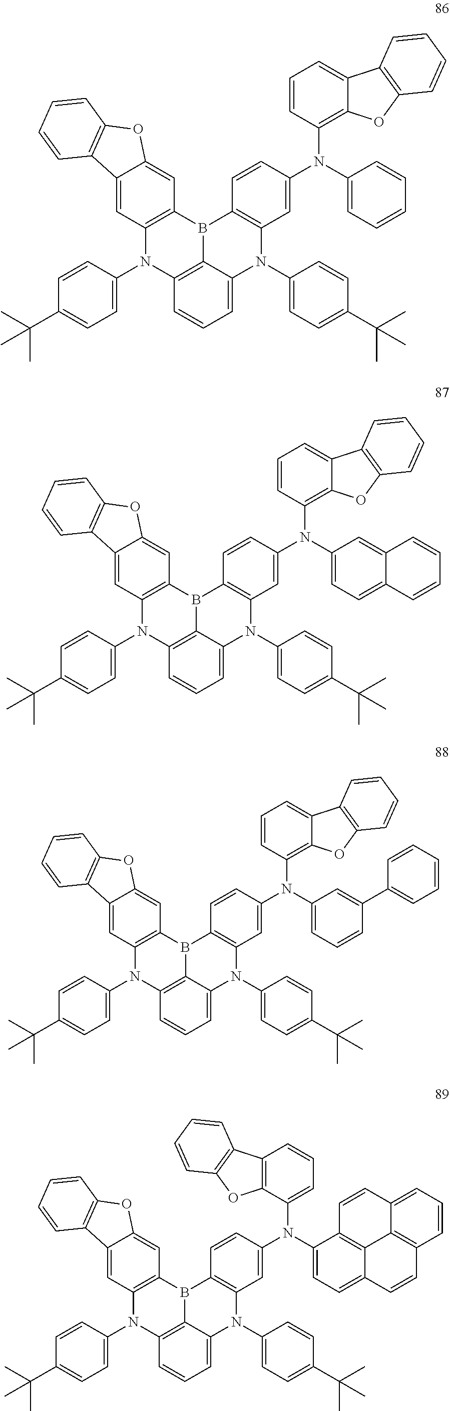 [SMILES: CC(C)(C)c1ccc(N2c3cc(N(c4ccccc4)c4cccc5c4oc4ccccc45)ccc3B3c4cc5oc6ccccc6c5cc4N(c4ccc(C(C)(C)C)cc4)c4cccc2c43)cc1 ; CC(C)(C)c1ccc(N2c3cc(N(c4ccc5ccccc5c4)c4cccc5c4oc4ccccc45)ccc3B3c4cc5oc6ccccc6c5cc4N(c4ccc(C(C)(C)C)cc4)c4cccc2c43)cc1 ; CC(C)(C)c1ccc(N2c3cc(N(c4cccc(-c5ccccc5)c4)c4cccc5c4oc4ccccc45)ccc3B3c4cc5oc6ccccc6c5cc4N(c4ccc(C(C)(C)C)cc4)c4cccc2c43)cc1 ; CC(C)(C)c1ccc(N2c3cc(N(c4ccc5ccc6cccc7ccc4c5c67)c4cccc5c4oc4ccccc45)ccc3B3c4cc5oc6ccccc6c5cc4N(c4ccc(C(C)(C)C)cc4)c4cccc2c43)cc1]

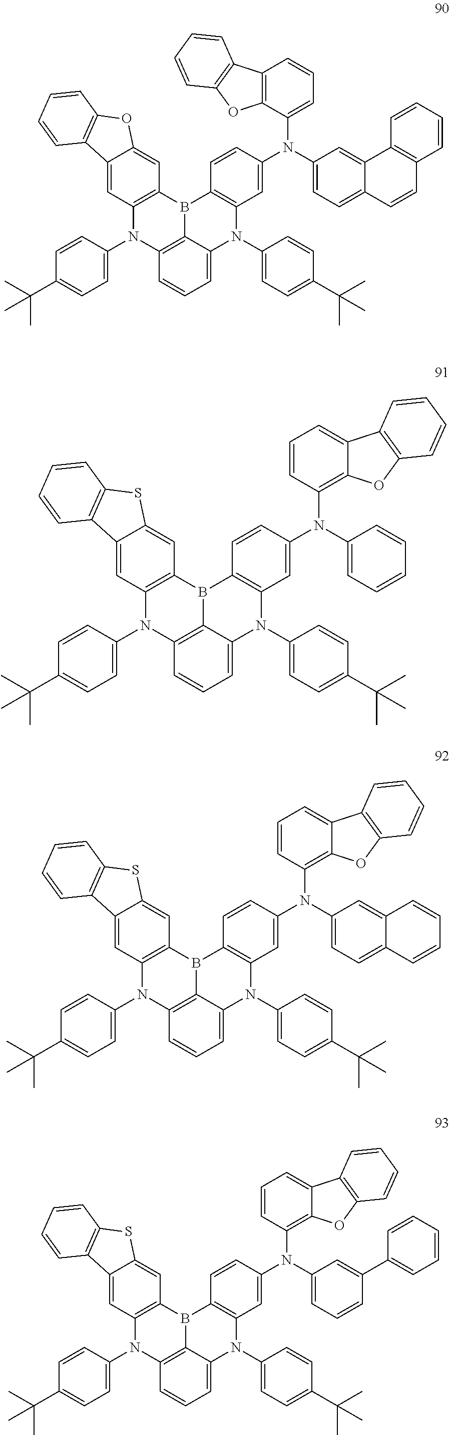 [SMILES: CC(C)(C)c1ccc(N2c3cc(N(c4ccc5ccc6ccccc6c5c4)c4cccc5c4oc4ccccc45)ccc3B3c4cc5oc6ccccc6c5cc4N(c4ccc(C(C)(C)C)cc4)c4cccc2c43)cc1 ; CC(C)(C)c1ccc(N2c3cc(N(c4ccccc4)c4cccc5c4oc4ccccc45)ccc3B3c4cc5sc6ccccc6c5cc4N(c4ccc(C(C)(C)C)cc4)c4cccc2c43)cc1 ; CC(C)(C)c1ccc(N2c3cc(N(c4ccc5ccccc5c4)c4cccc5c4oc4ccccc45)ccc3B3c4cc5sc6ccccc6c5cc4N(c4ccc(C(C)(C)C)cc4)c4cccc2c43)cc1 ; CC(C)(C)c1ccc(N2c3cc(N(c4cccc(-c5ccccc5)c4)c4cccc5c4oc4ccccc45)ccc3B3c4cc5sc6ccccc6c5cc4N(c4ccc(C(C)(C)C)cc4)c4cccc2c43)cc1]

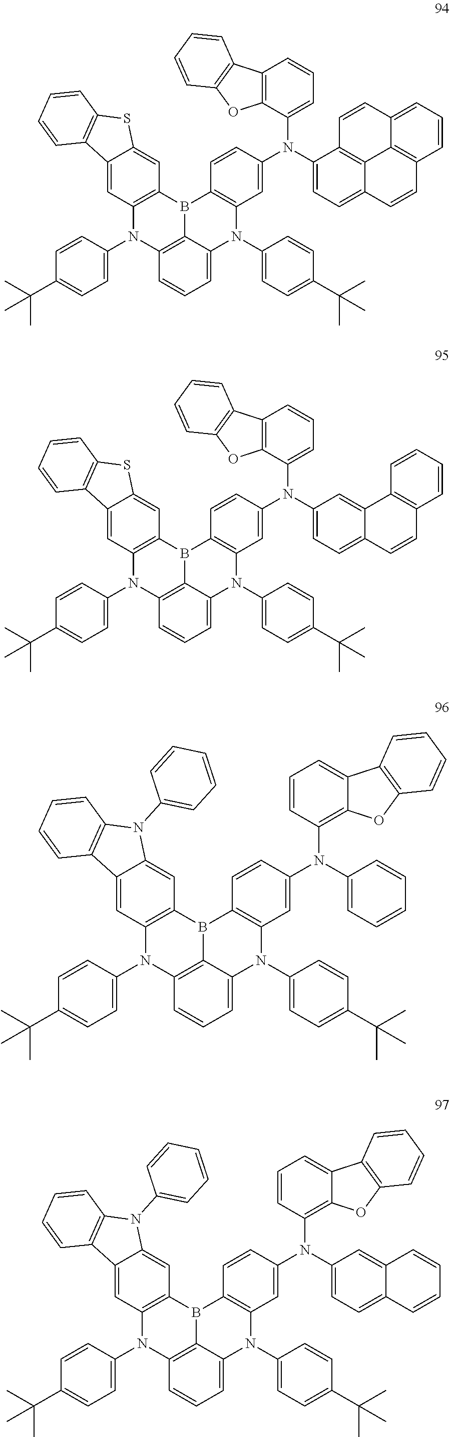

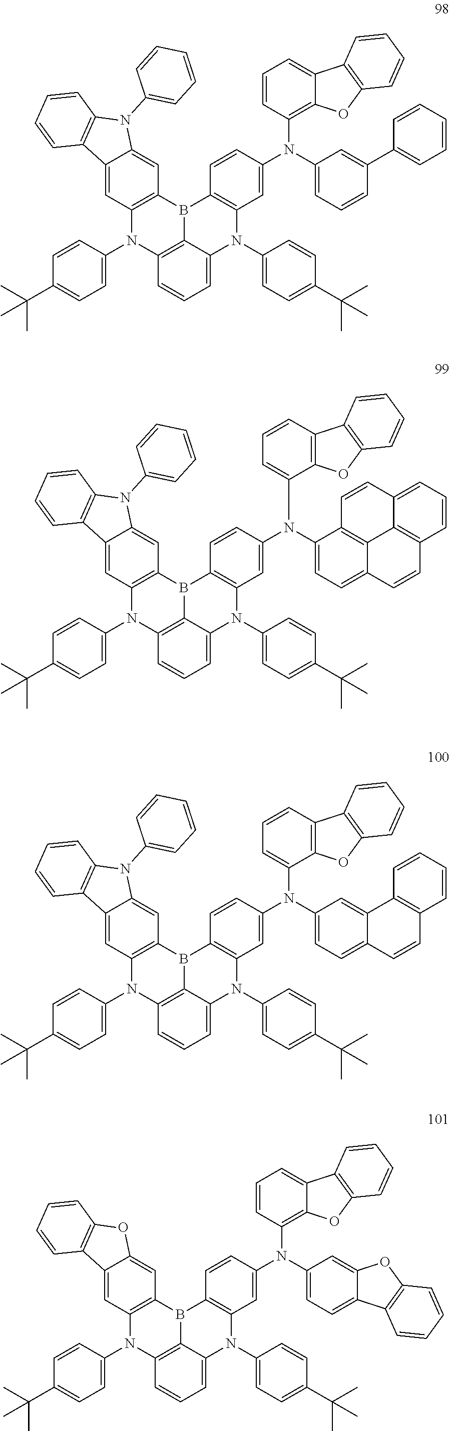

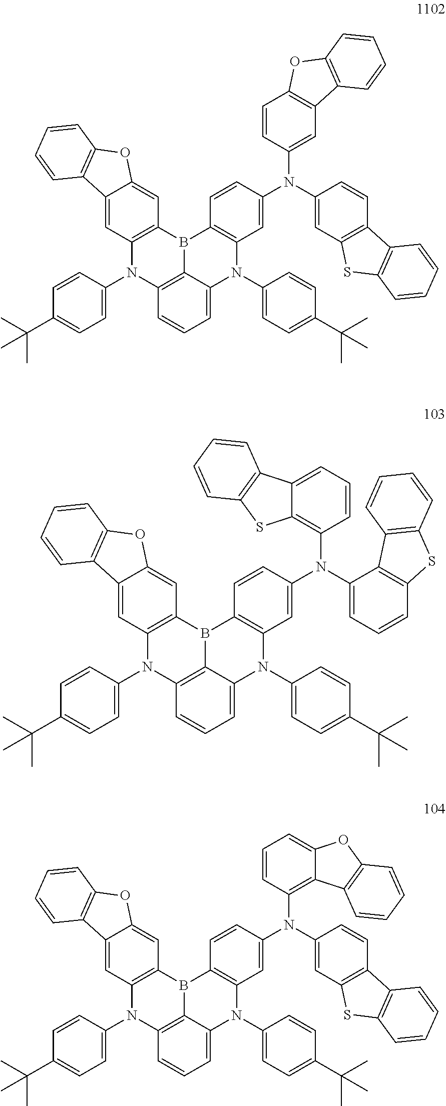 [SMILES: CC(C)(C)c1ccc(N2c3cc(N(c4ccc5c(c4)sc4ccccc45)c4ccc5oc6ccccc6c5c4)ccc3B3c4cc5oc6ccccc6c5cc4N(c4ccc(C(C)(C)C)cc4)c4cccc2c43)cc1 ; CC(C)(C)c1ccc(N2c3cc(N(c4cccc5c4sc4ccccc45)c4cccc5sc6ccccc6c45)ccc3B3c4cc5oc6ccccc6c5cc4N(c4ccc(C(C)(C)C)cc4)c4cccc2c43)cc1 ; CC(C)(C)c1ccc(N2c3cc(N(c4ccc5c(c4)sc4ccccc45)c4cccc5oc6ccccc6c45)ccc3B3c4cc5oc6ccccc6c5cc4N(c4ccc(C(C)(C)C)cc4)c4cccc2c43)cc1]

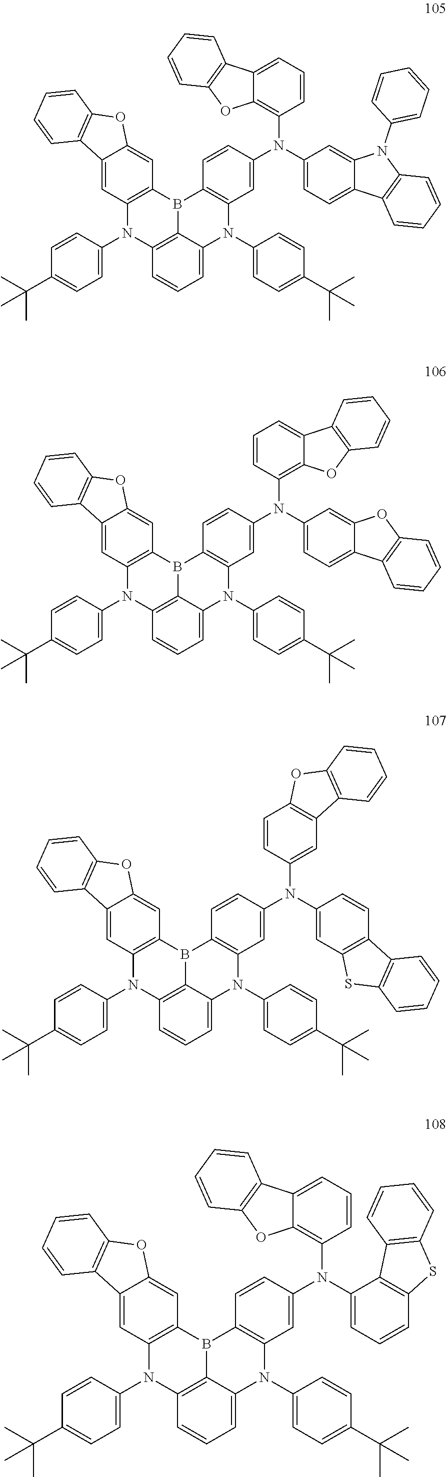

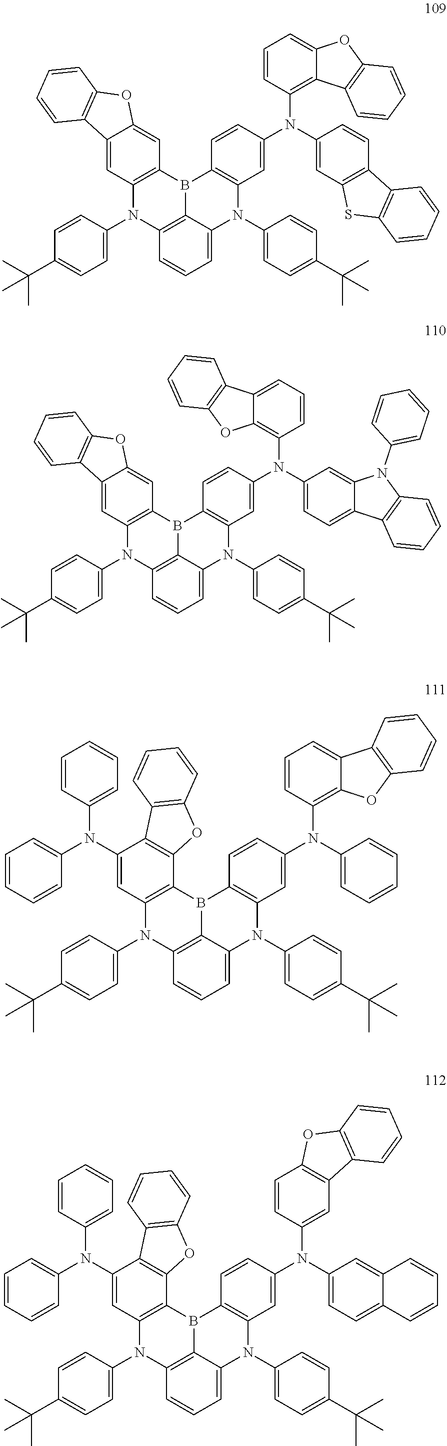

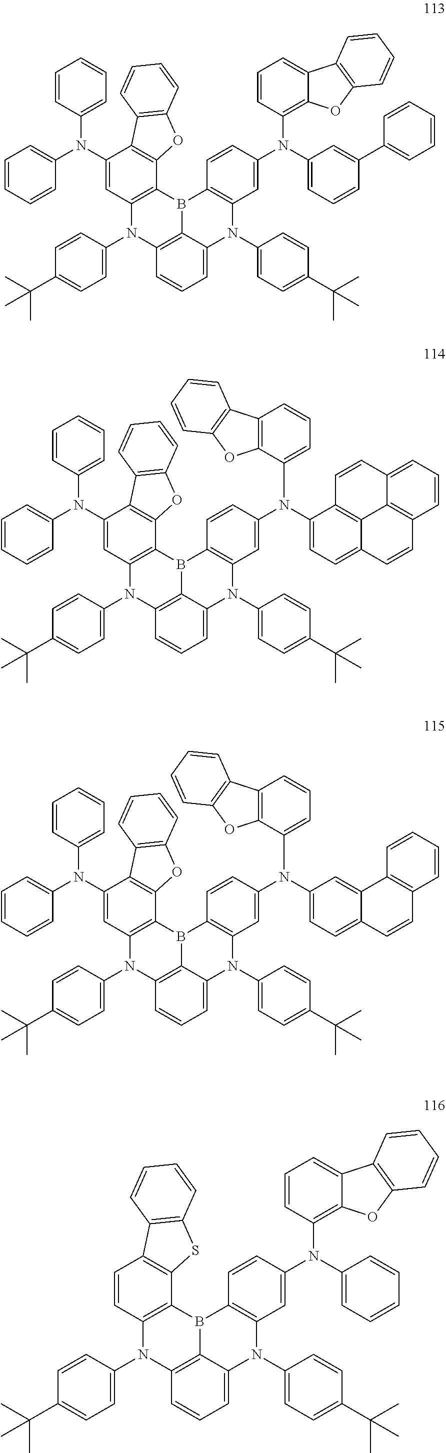

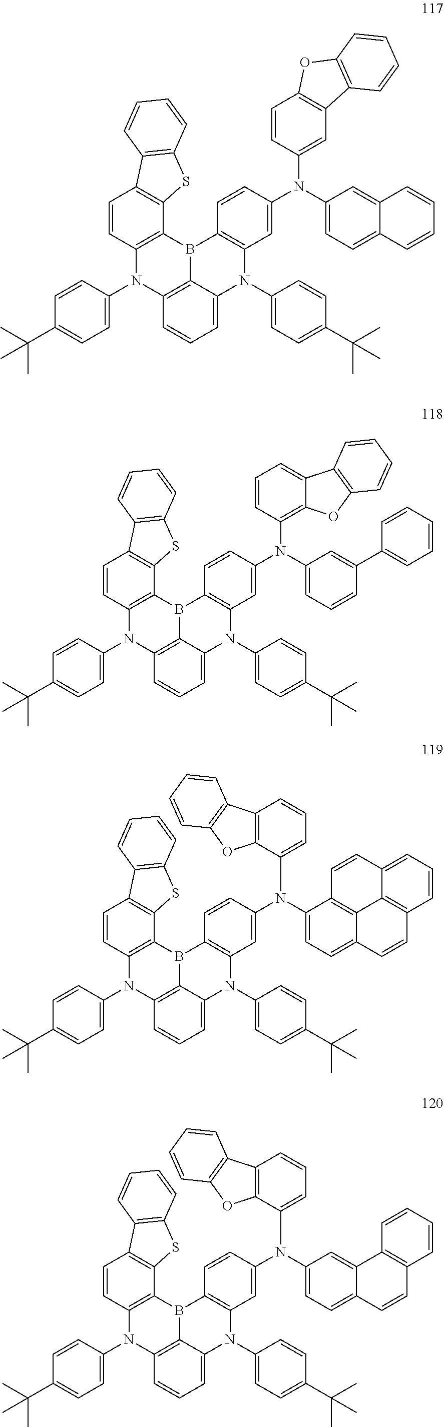

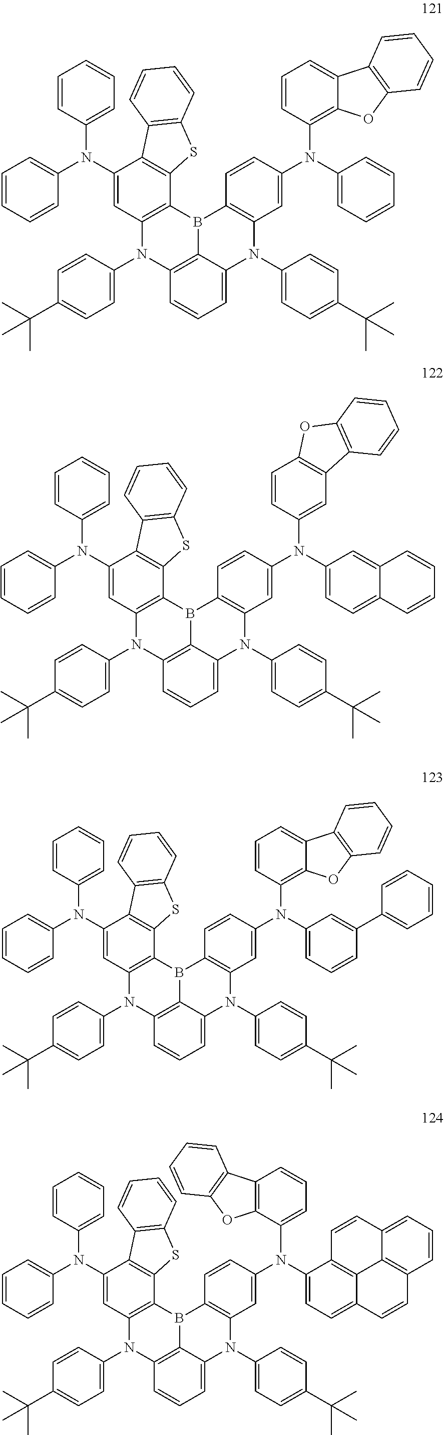

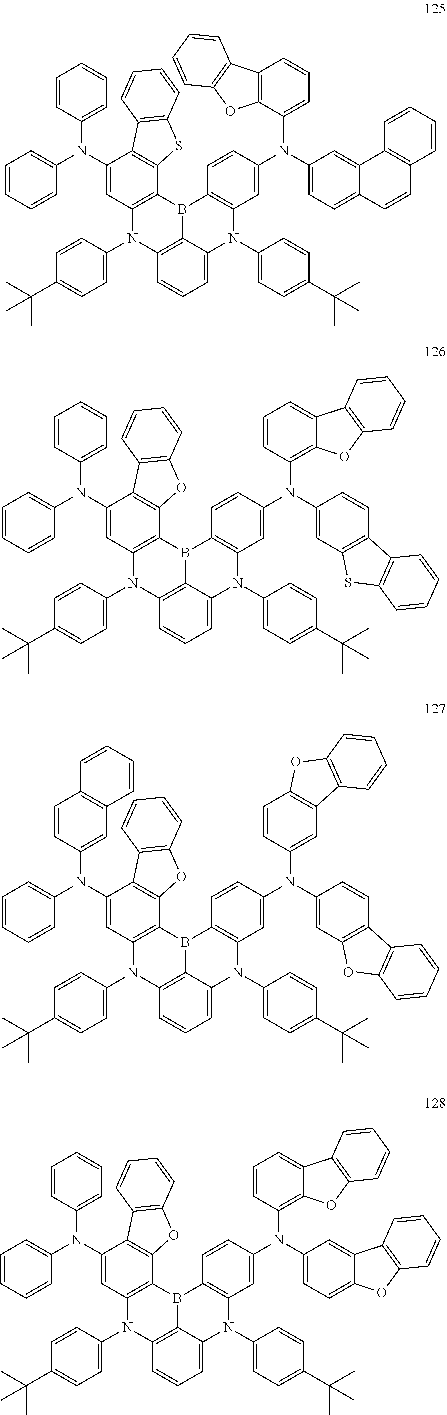

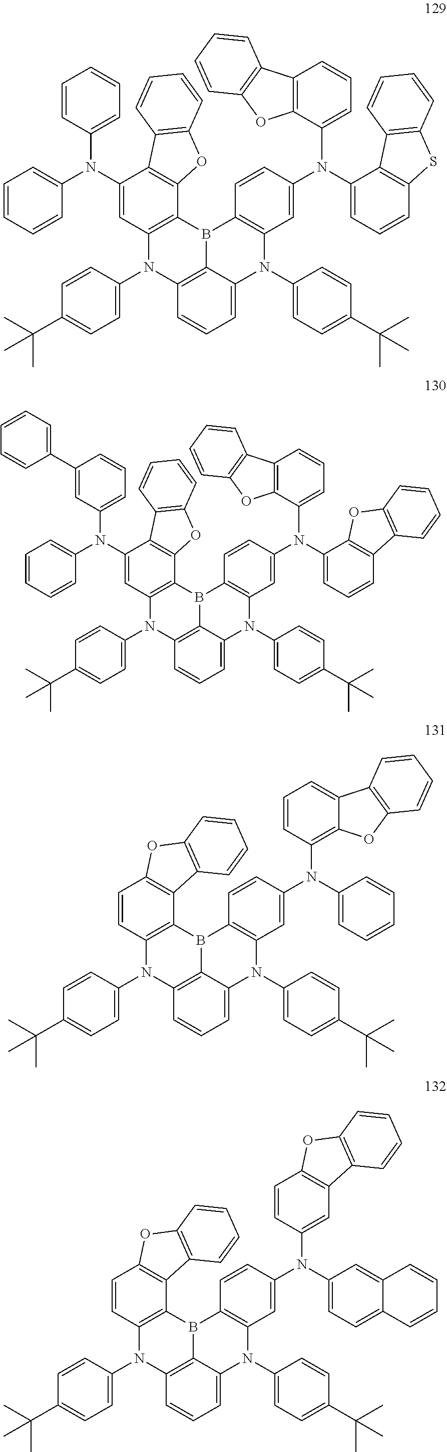

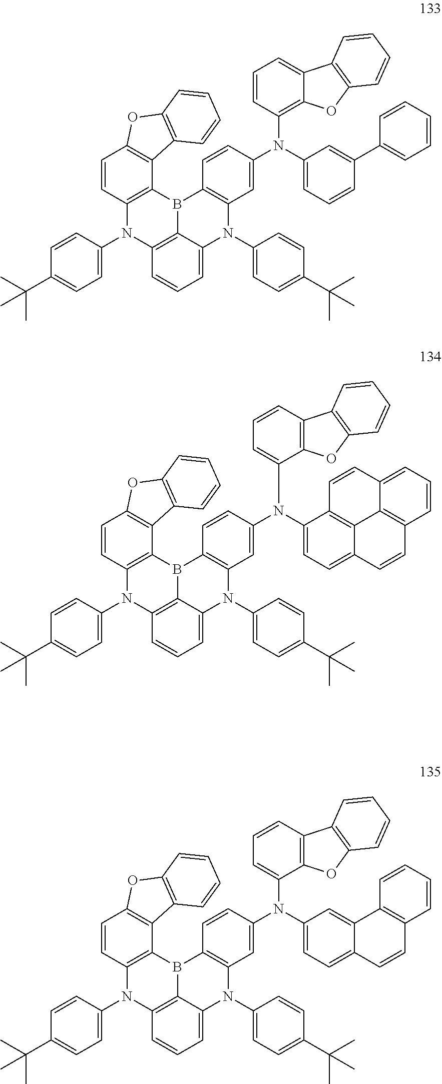 [SMILES: CC(C)(C)c1ccc(N2c3cc(N(c4cccc(-c5ccccc5)c4)c4cccc5c4oc4ccccc45)ccc3B3c4c2cccc4N(c2ccc(C(C)(C)C)cc2)c2ccc4oc5ccccc5c4c23)cc1 ; CC(C)(C)c1ccc(N2c3cc(N(c4ccc5ccc6cccc7ccc4c5c67)c4cccc5c4oc4ccccc45)ccc3B3c4c2cccc4N(c2ccc(C(C)(C)C)cc2)c2ccc4oc5ccccc5c4c23)cc1 ; CC(C)(C)c1ccc(N2c3cc(N(c4ccc5ccc6ccccc6c5c4)c4cccc5c4oc4ccccc45)ccc3B3c4c2cccc4N(c2ccc(C(C)(C)C)cc2)c2ccc4oc5ccccc5c4c23)cc1]

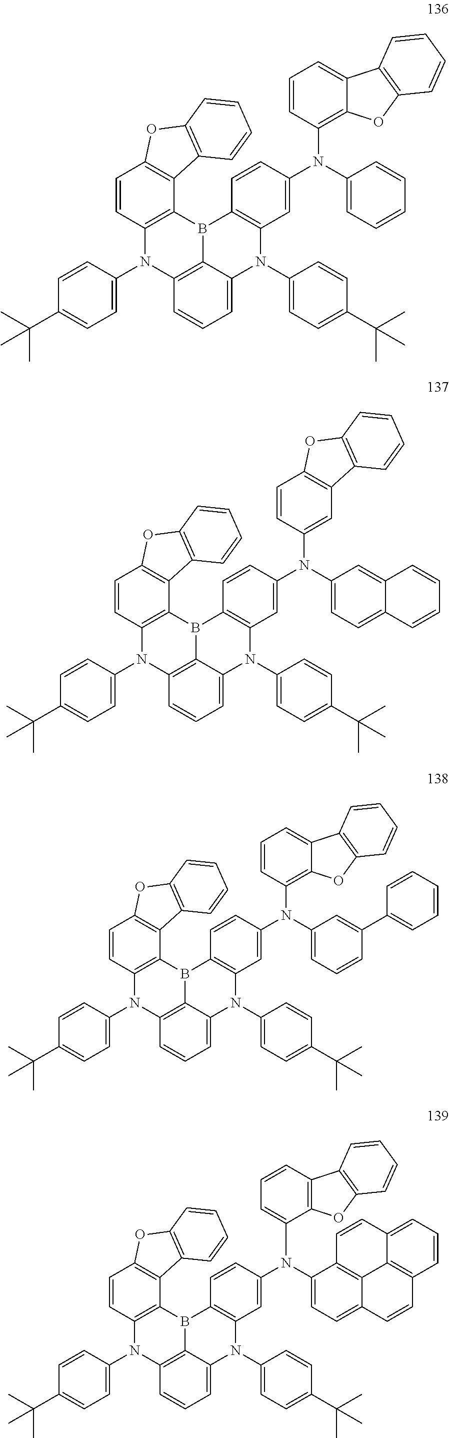 [SMILES: CC(C)(C)c1ccc(N2c3cc(N(c4ccccc4)c4cccc5c4oc4ccccc45)ccc3B3c4c2cccc4N(c2ccc(C(C)(C)C)cc2)c2ccc4oc5ccccc5c4c23)cc1 ; CC(C)(C)c1ccc(N2c3cc(N(c4ccc5ccccc5c4)c4ccc5oc6ccccc6c5c4)ccc3B3c4c2cccc4N(c2ccc(C(C)(C)C)cc2)c2ccc4oc5ccccc5c4c23)cc1 ; CC(C)(C)c1ccc(N2c3cc(N(c4cccc(-c5ccccc5)c4)c4cccc5c4oc4ccccc45)ccc3B3c4c2cccc4N(c2ccc(C(C)(C)C)cc2)c2ccc4oc5ccccc5c4c23)cc1 ; CC(C)(C)c1ccc(N2c3cc(N(c4ccc5ccc6cccc7ccc4c5c67)c4cccc5c4oc4ccccc45)ccc3B3c4c2cccc4N(c2ccc(C(C)(C)C)cc2)c2ccc4oc5ccccc5c4c23)cc1]

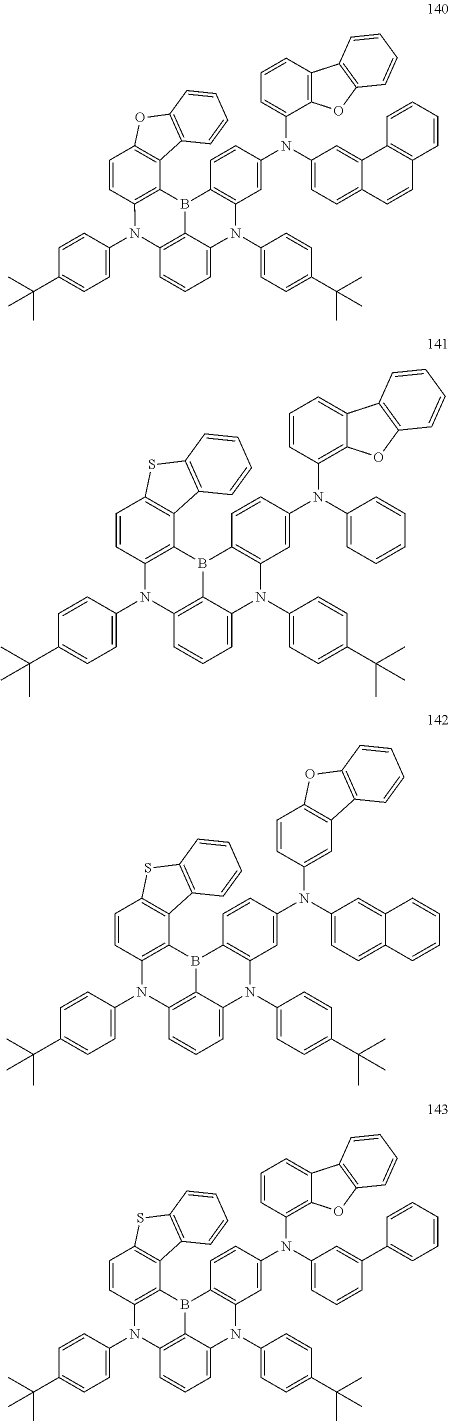 [SMILES: CC(C)(C)c1ccc(N2c3cc(N(c4ccc5ccc6ccccc6c5c4)c4cccc5c4oc4ccccc45)ccc3B3c4c2cccc4N(c2ccc(C(C)(C)C)cc2)c2ccc4oc5ccccc5c4c23)cc1 ; CC(C)(C)c1ccc(N2c3cc(N(c4ccccc4)c4cccc5c4oc4ccccc45)ccc3B3c4c2cccc4N(c2ccc(C(C)(C)C)cc2)c2ccc4sc5ccccc5c4c23)cc1 ; CC(C)(C)c1ccc(N2c3cc(N(c4ccc5ccccc5c4)c4ccc5oc6ccccc6c5c4)ccc3B3c4c2cccc4N(c2ccc(C(C)(C)C)cc2)c2ccc4sc5ccccc5c4c23)cc1 ; CC(C)(C)c1ccc(N2c3cc(N(c4cccc(-c5ccccc5)c4)c4cccc5c4oc4ccccc45)ccc3B3c4c2cccc4N(c2ccc(C(C)(C)C)cc2)c2ccc4sc5ccccc5c4c23)cc1]

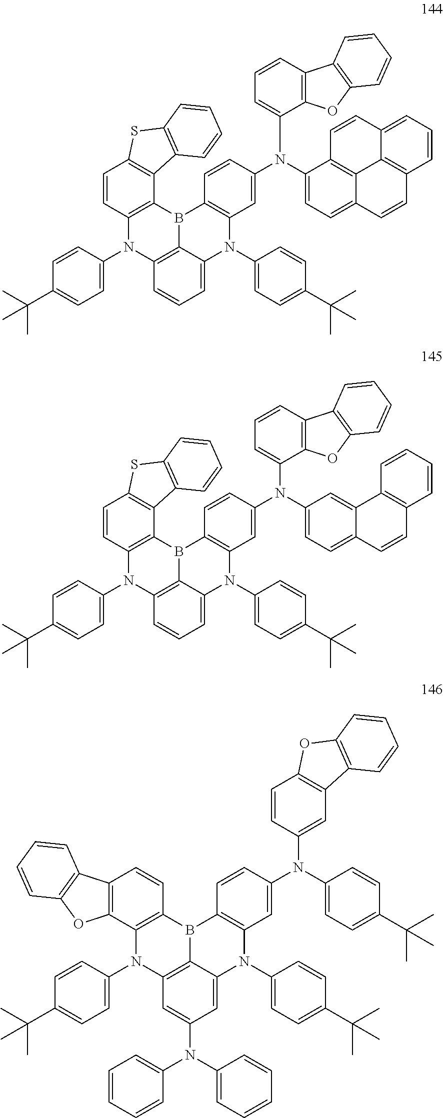 [SMILES: CC(C)(C)c1ccc(N2c3cc(N(c4ccc5ccc6cccc7ccc4c5c67)c4cccc5c4oc4ccccc45)ccc3B3c4c2cccc4N(c2ccc(C(C)(C)C)cc2)c2ccc4sc5ccccc5c4c23)cc1 ; CC(C)(C)c1ccc(N2c3cc(N(c4ccc5ccc6ccccc6c5c4)c4cccc5c4oc4ccccc45)ccc3B3c4c2cccc4N(c2ccc(C(C)(C)C)cc2)c2ccc4sc5ccccc5c4c23)cc1 ; CC(C)(C)c1ccc(N(c2ccc3c(c2)N(c2ccc(C(C)(C)C)cc2)c2cc(N(c4ccccc4)c4ccccc4)cc4c2B3c2ccc3c(oc5ccccc53)c2N4c2ccc(C(C)(C)C)cc2)c2ccc3oc4ccccc4c3c2)cc1]

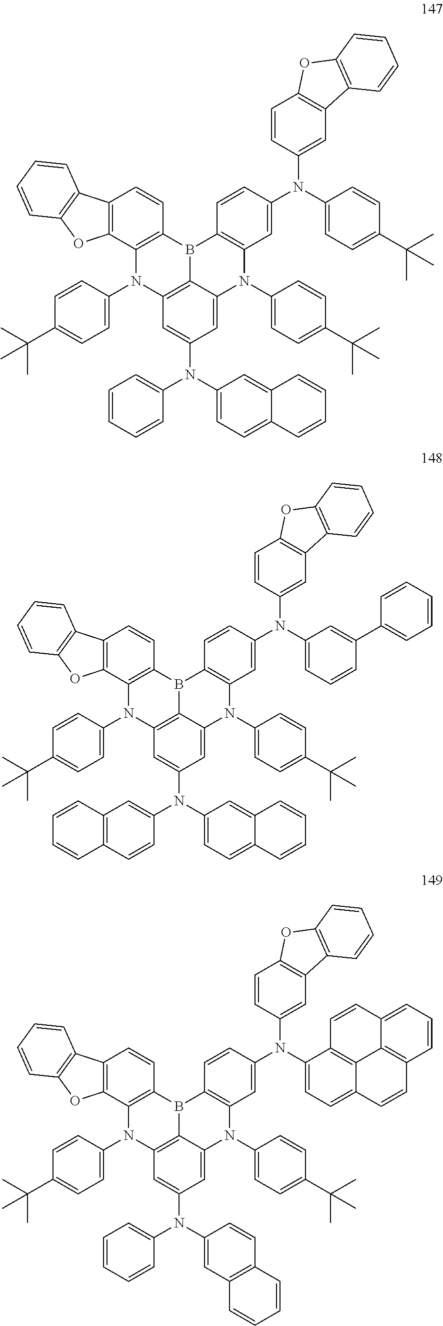

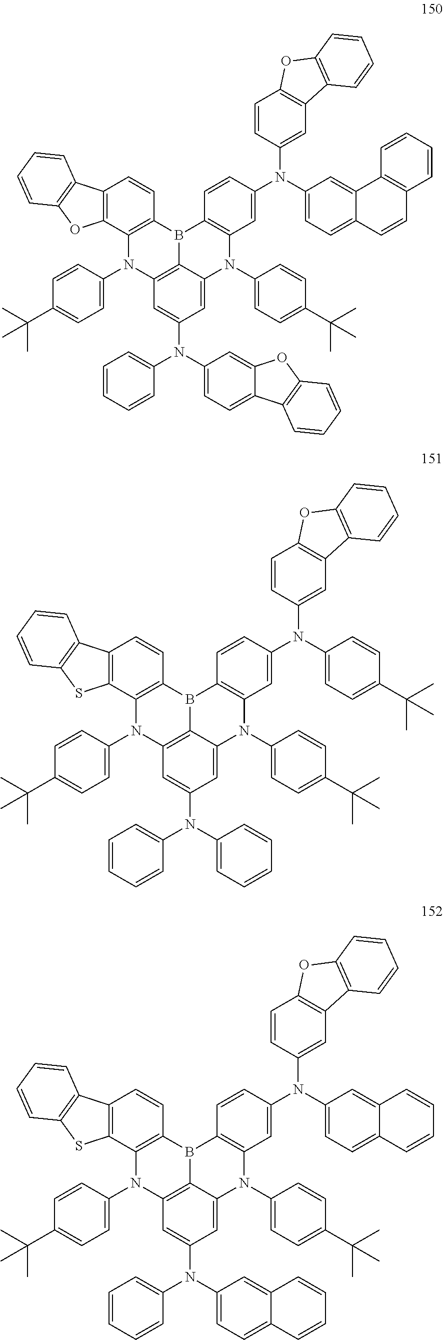

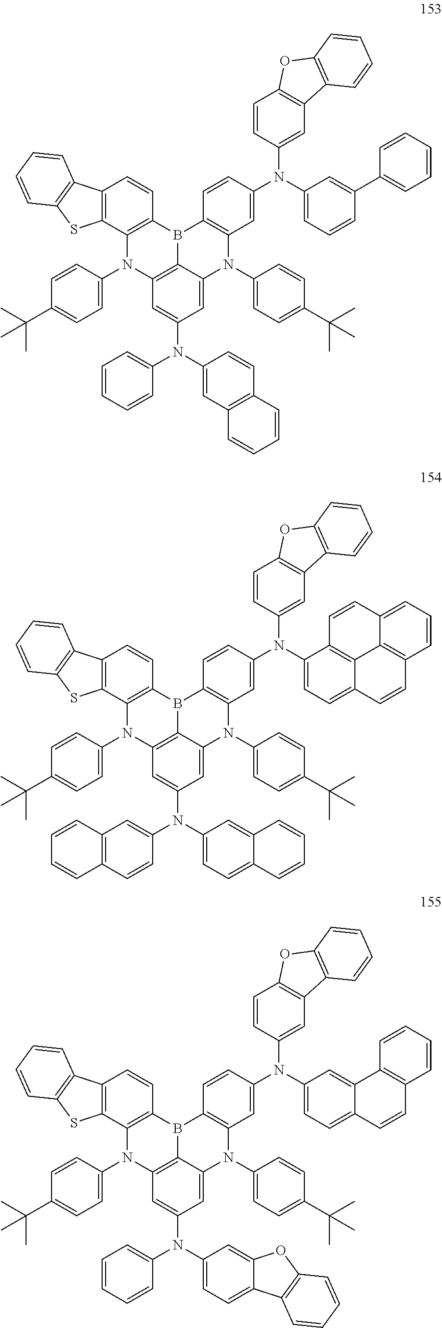 [SMILES: CC(C)(C)c1ccc(N2c3cc(N(c4cccc(-c5ccccc5)c4)c4ccc5oc6ccccc6c5c4)ccc3B3c4ccc5c(sc6ccccc65)c4N(c4ccc(C(C)(C)C)cc4)c4cc(N(c5ccccc5)c5ccc6ccccc6c5)cc2c43)cc1 ; CC(C)(C)c1ccc(N2c3cc(N(c4ccc5oc6ccccc6c5c4)c4ccc5ccc6cccc7ccc4c5c67)ccc3B3c4ccc5c(sc6ccccc65)c4N(c4ccc(C(C)(C)C)cc4)c4cc(N(c5ccc6ccccc6c5)c5ccc6ccccc6c5)cc2c43)cc1 ; CC(C)(C)c1ccc(N2c3cc(N(c4ccc5ccc6ccccc6c5c4)c4ccc5oc6ccccc6c5c4)ccc3B3c4ccc5c(sc6ccccc65)c4N(c4ccc(C(C)(C)C)cc4)c4cc(N(c5ccccc5)c5ccc6c(c5)oc5ccccc56)cc2c43)cc1]

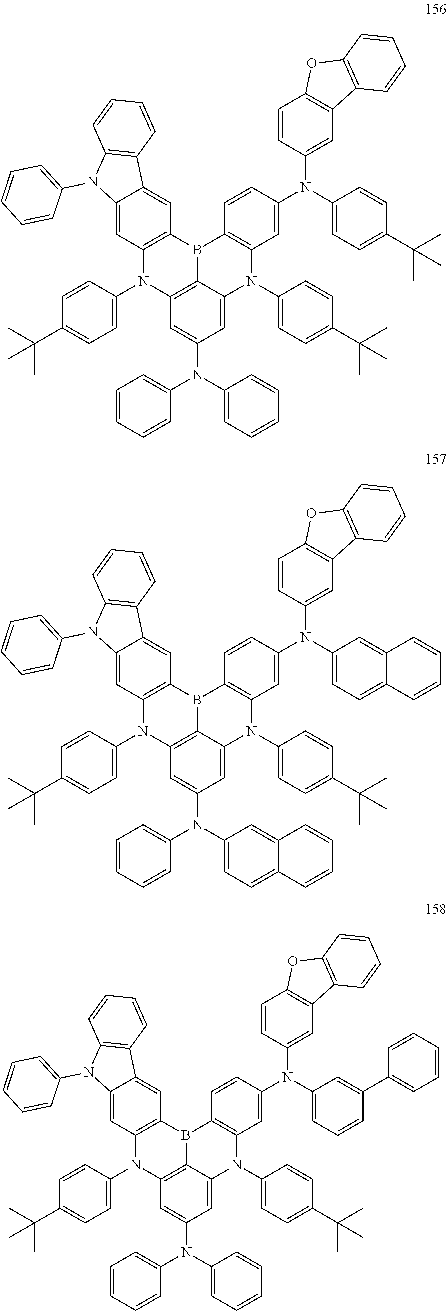 [SMILES: CC(C)(C)c1ccc(N(c2ccc3c(c2)N(c2ccc(C(C)(C)C)cc2)c2cc(N(c4ccccc4)c4ccccc4)cc4c2B3c2cc3c5ccccc5n(-c5ccccc5)c3cc2N4c2ccc(C(C)(C)C)cc2)c2ccc3oc4ccccc4c3c2)cc1 ; CC(C)(C)c1ccc(N2c3cc(N(c4ccc5ccccc5c4)c4ccc5oc6ccccc6c5c4)ccc3B3c4cc5c6ccccc6n(-c6ccccc6)c5cc4N(c4ccc(C(C)(C)C)cc4)c4cc(N(c5ccccc5)c5ccc6ccccc6c5)cc2c43)cc1 ; CC(C)(C)c1ccc(N2c3cc(N(c4cccc(-c5ccccc5)c4)c4ccc5oc6ccccc6c5c4)ccc3B3c4cc5c6ccccc6n(-c6ccccc6)c5cc4N(c4ccc(C(C)(C)C)cc4)c4cc(N(c5ccccc5)c5ccccc5)cc2c43)cc1]

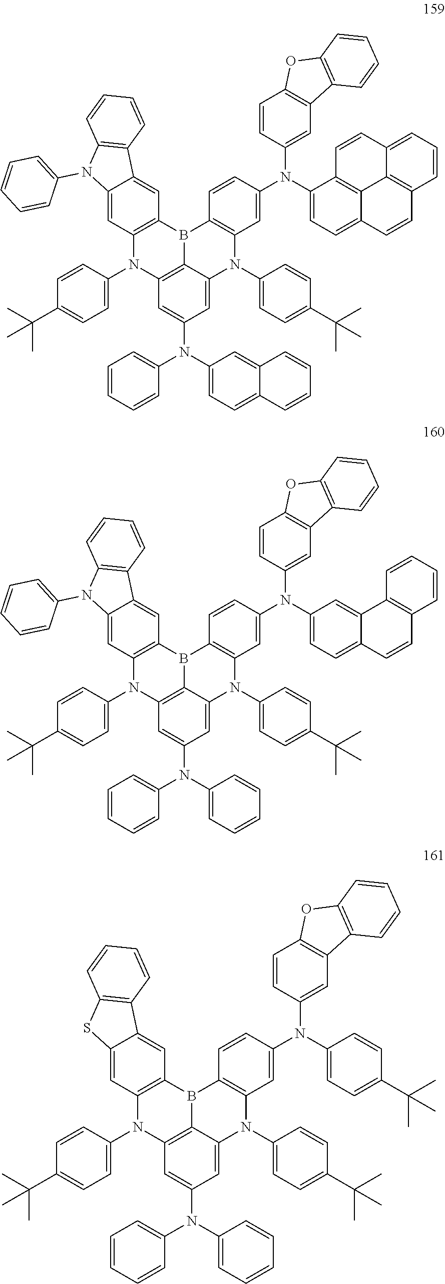 [SMILES: CC(C)(C)c1ccc(N2c3cc(N(c4ccc5oc6ccccc6c5c4)c4ccc5ccc6cccc7ccc4c5c67)ccc3B3c4cc5c6ccccc6n(-c6ccccc6)c5cc4N(c4ccc(C(C)(C)C)cc4)c4cc(N(c5ccccc5)c5ccc6ccccc6c5)cc2c43)cc1 ; CC(C)(C)c1ccc(N2c3cc(N(c4ccc5ccc6ccccc6c5c4)c4ccc5oc6ccccc6c5c4)ccc3B3c4cc5c6ccccc6n(-c6ccccc6)c5cc4N(c4ccc(C(C)(C)C)cc4)c4cc(N(c5ccccc5)c5ccccc5)cc2c43)cc1 ; CC(C)(C)c1ccc(N(c2ccc3c(c2)N(c2ccc(C(C)(C)C)cc2)c2cc(N(c4ccccc4)c4ccccc4)cc4c2B3c2cc3c(cc2N4c2ccc(C(C)(C)C)cc2)sc2ccccc23)c2ccc3oc4ccccc4c3c2)cc1]

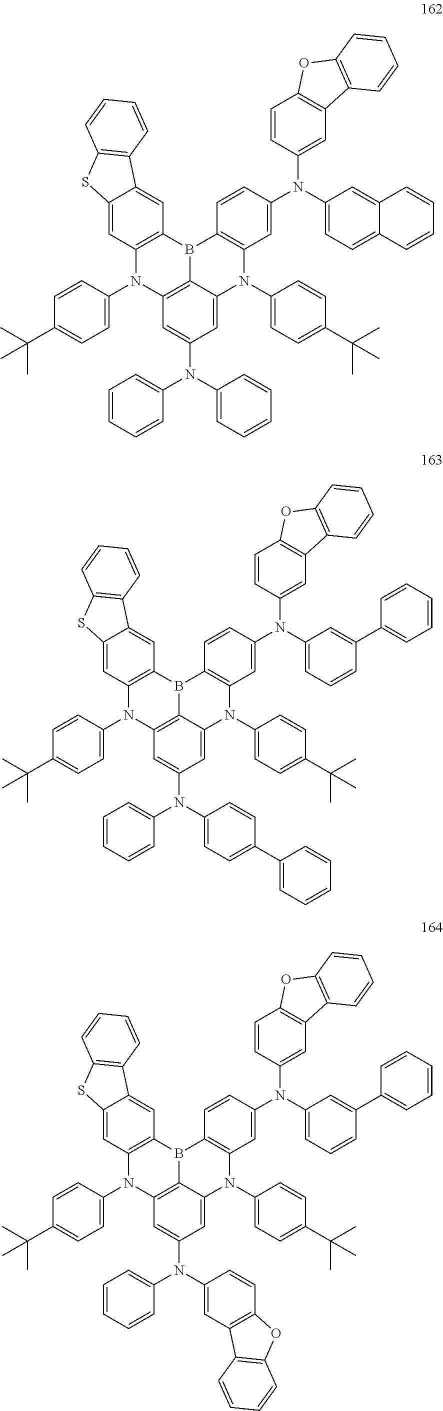 [SMILES: CC(C)(C)c1ccc(N2c3cc(N(c4ccc5ccccc5c4)c4ccc5oc6ccccc6c5c4)ccc3B3c4cc5c(cc4N(c4ccc(C(C)(C)C)cc4)c4cc(N(c6ccccc6)c6ccccc6)cc2c43)sc2ccccc25)cc1 ; CC(C)(C)c1ccc(N2c3cc(N(c4cccc(-c5ccccc5)c4)c4ccc5oc6ccccc6c5c4)ccc3B3c4cc5c(cc4N(c4ccc(C(C)(C)C)cc4)c4cc(N(c6ccccc6)c6ccc(-c7ccccc7)cc6)cc2c43)sc2ccccc25)cc1 ; CC(C)(C)c1ccc(N2c3cc(N(c4cccc(-c5ccccc5)c4)c4ccc5oc6ccccc6c5c4)ccc3B3c4cc5c(cc4N(c4ccc(C(C)(C)C)cc4)c4cc(N(c6ccccc6)c6ccc7oc8ccccc8c7c6)cc2c43)sc2ccccc25)cc1]

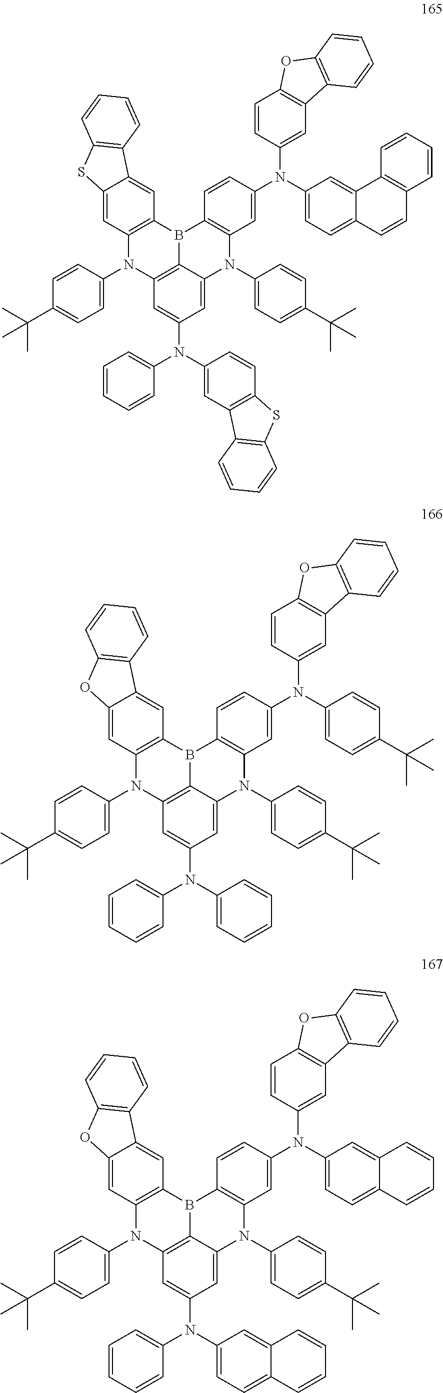

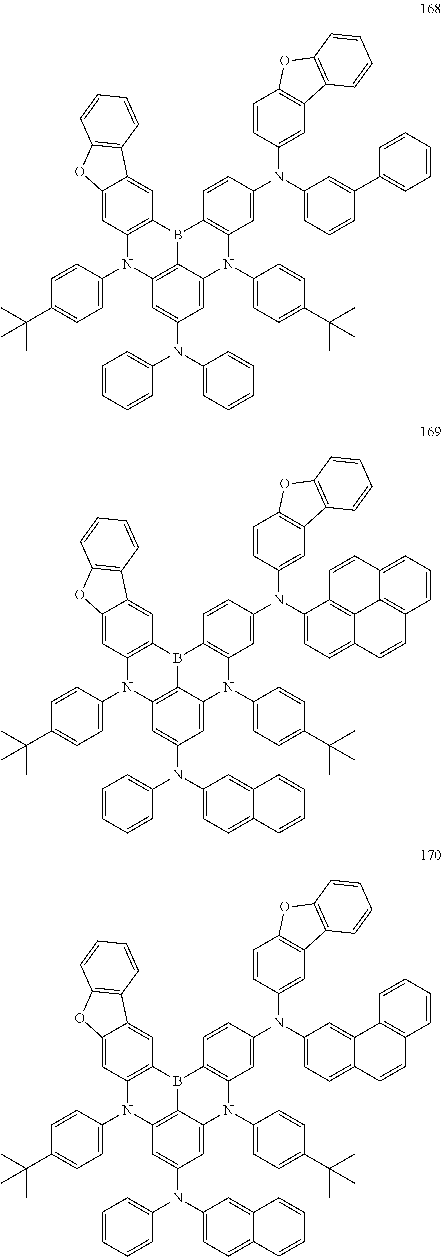 [SMILES: CC(C)(C)c1ccc(N2c3cc(N(c4cccc(-c5ccccc5)c4)c4ccc5oc6ccccc6c5c4)ccc3B3c4cc5c(cc4N(c4ccc(C(C)(C)C)cc4)c4cc(N(c6ccccc6)c6ccccc6)cc2c43)oc2ccccc25)cc1 ; CC(C)(C)c1ccc(N2c3cc(N(c4ccc5oc6ccccc6c5c4)c4ccc5ccc6cccc7ccc4c5c67)ccc3B3c4cc5c(cc4N(c4ccc(C(C)(C)C)cc4)c4cc(N(c6ccccc6)c6ccc7ccccc7c6)cc2c43)oc2ccccc25)cc1 ; CC(C)(C)c1ccc(N2c3cc(N(c4ccc5ccc6ccccc6c5c4)c4ccc5oc6ccccc6c5c4)ccc3B3c4cc5c(cc4N(c4ccc(C(C)(C)C)cc4)c4cc(N(c6ccccc6)c6ccc7ccccc7c6)cc2c43)oc2ccccc25)cc1]

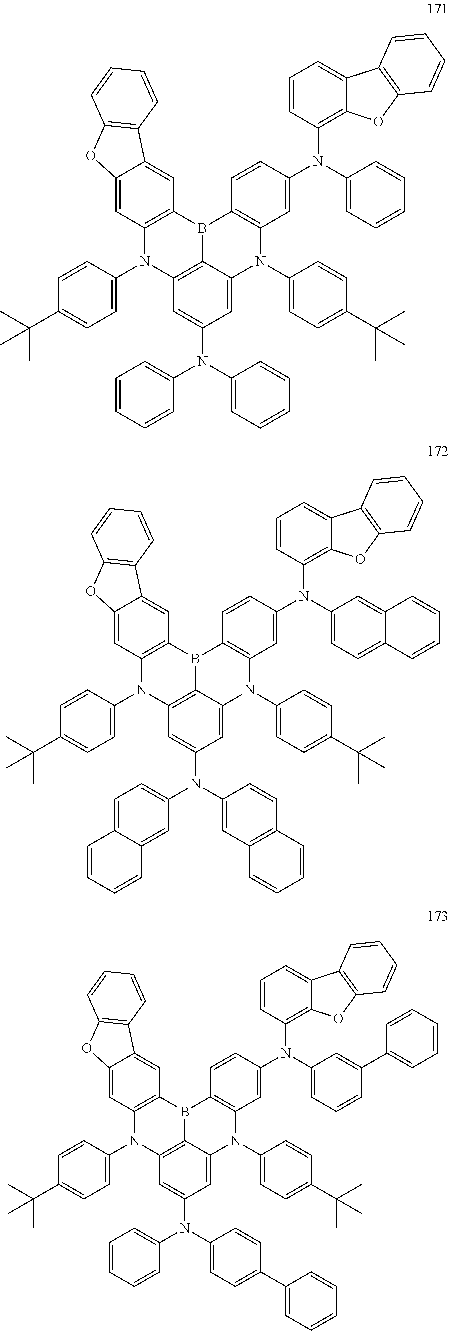 [SMILES: CC(C)(C)c1ccc(N2c3cc(N(c4ccccc4)c4cccc5c4oc4ccccc45)ccc3B3c4cc5c(cc4N(c4ccc(C(C)(C)C)cc4)c4cc(N(c6ccccc6)c6ccccc6)cc2c43)oc2ccccc25)cc1 ; CC(C)(C)c1ccc(N2c3cc(N(c4ccc5ccccc5c4)c4cccc5c4oc4ccccc45)ccc3B3c4cc5c(cc4N(c4ccc(C(C)(C)C)cc4)c4cc(N(c6ccc7ccccc7c6)c6ccc7ccccc7c6)cc2c43)oc2ccccc25)cc1 ; CC(C)(C)c1ccc(N2c3cc(N(c4cccc(-c5ccccc5)c4)c4cccc5c4oc4ccccc45)ccc3B3c4cc5c(cc4N(c4ccc(C(C)(C)C)cc4)c4cc(N(c6ccccc6)c6ccc(-c7ccccc7)cc6)cc2c43)oc2ccccc25)cc1]

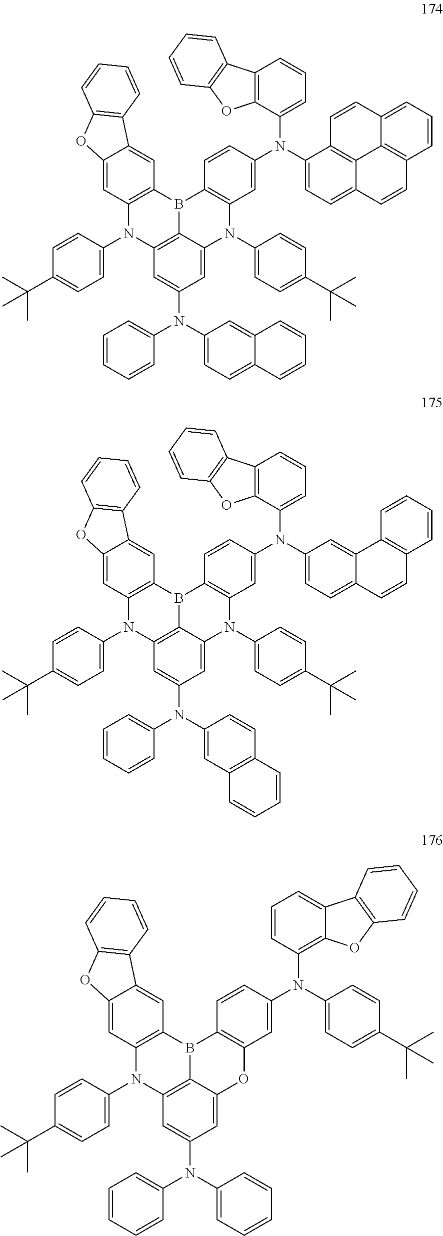 [SMILES: CC(C)(C)c1ccc(N2c3cc(N(c4ccc5ccc6cccc7ccc4c5c67)c4cccc5c4oc4ccccc45)ccc3B3c4cc5c(cc4N(c4ccc(C(C)(C)C)cc4)c4cc(N(c6ccccc6)c6ccc7ccccc7c6)cc2c43)oc2ccccc25)cc1 ; CC(C)(C)c1ccc(N2c3cc(N(c4ccc5ccc6ccccc6c5c4)c4cccc5c4oc4ccccc45)ccc3B3c4cc5c(cc4N(c4ccc(C(C)(C)C)cc4)c4cc(N(c6ccccc6)c6ccc7ccccc7c6)cc2c43)oc2ccccc25)cc1 ; CC(C)(C)c1ccc(N2c3cc4oc5ccccc5c4cc3B3c4ccc(N(c5ccc(C(C)(C)C)cc5)c5cccc6c5oc5ccccc56)cc4Oc4cc(N(c5ccccc5)c5ccccc5)cc2c43)cc1]

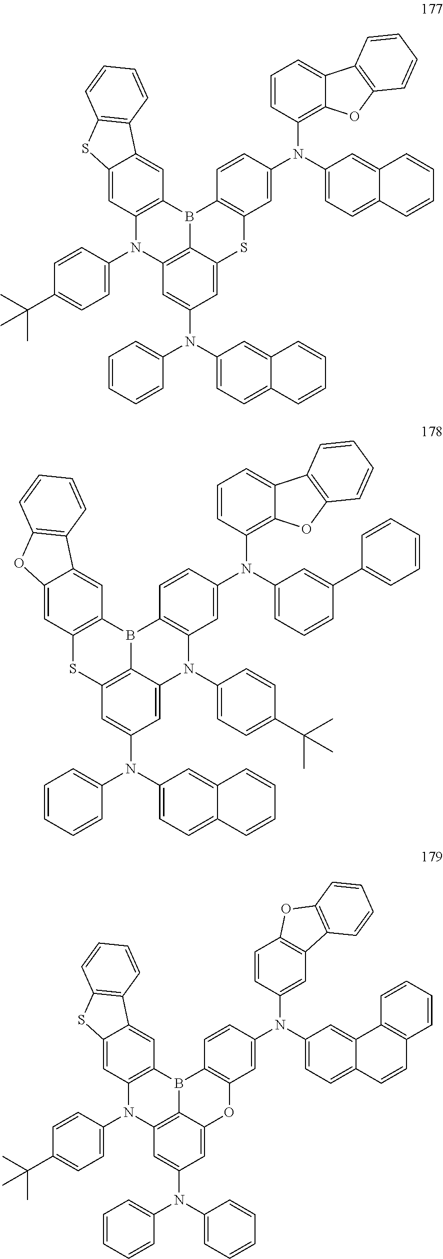 [SMILES: CC(C)(C)c1ccc(N2c3cc4sc5ccccc5c4cc3B3c4ccc(N(c5ccc6ccccc6c5)c5cccc6c5oc5ccccc56)cc4Sc4cc(N(c5ccccc5)c5ccc6ccccc6c5)cc2c43)cc1 ; CC(C)(C)c1ccc(N2c3cc(N(c4cccc(-c5ccccc5)c4)c4cccc5c4oc4ccccc45)ccc3B3c4cc5c(cc4Sc4cc(N(c6ccccc6)c6ccc7ccccc7c6)cc2c43)oc2ccccc25)cc1 ; CC(C)(C)c1ccc(N2c3cc4sc5ccccc5c4cc3B3c4ccc(N(c5ccc6ccc7ccccc7c6c5)c5ccc6oc7ccccc7c6c5)cc4Oc4cc(N(c5ccccc5)c5ccccc5)cc2c43)cc1]

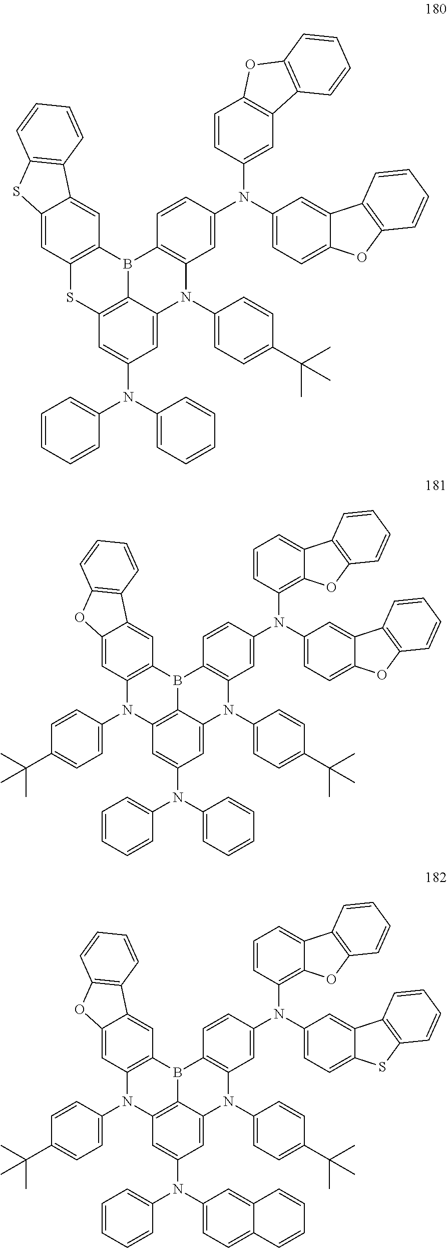 [SMILES: CC(C)(C)c1ccc(N2c3cc(N(c4ccc5oc6ccccc6c5c4)c4ccc5oc6ccccc6c5c4)ccc3B3c4cc5c(cc4Sc4cc(N(c6ccccc6)c6ccccc6)cc2c43)sc2ccccc25)cc1 ; CC(C)(C)c1ccc(N2c3cc(N(c4ccc5oc6ccccc6c5c4)c4cccc5c4oc4ccccc45)ccc3B3c4cc5c(cc4N(c4ccc(C(C)(C)C)cc4)c4cc(N(c6ccccc6)c6ccccc6)cc2c43)oc2ccccc25)cc1 ; CC(C)(C)c1ccc(N2c3cc(N(c4ccc5sc6ccccc6c5c4)c4cccc5c4oc4ccccc45)ccc3B3c4cc5c(cc4N(c4ccc(C(C)(C)C)cc4)c4cc(N(c6ccccc6)c6ccc7ccccc7c6)cc2c43)oc2ccccc25)cc1]

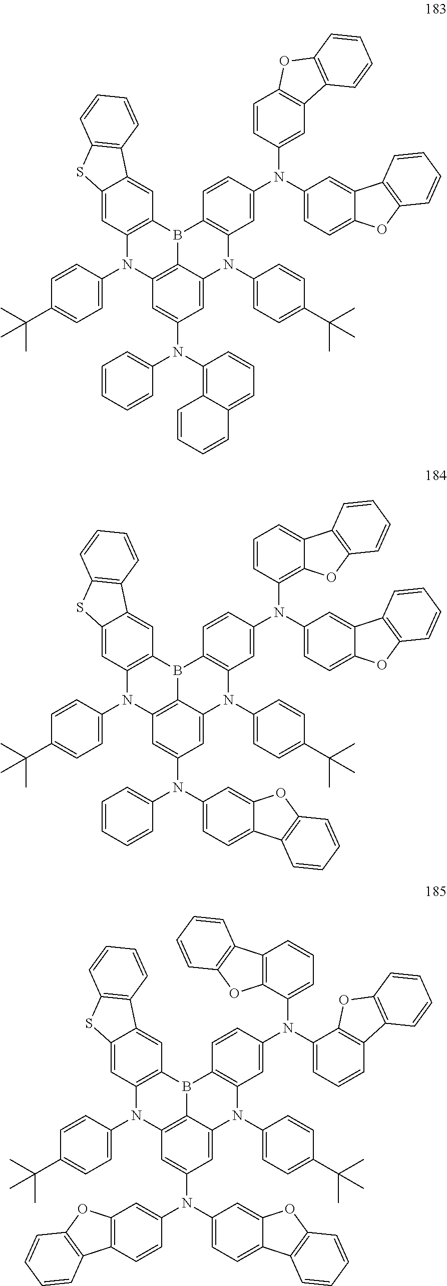 [SMILES: CC(C)(C)c1ccc(N2c3cc(N(c4ccc5oc6ccccc6c5c4)c4ccc5oc6ccccc6c5c4)ccc3B3c4cc5c(cc4N(c4ccc(C(C)(C)C)cc4)c4cc(N(c6ccccc6)c6cccc7ccccc67)cc2c43)sc2ccccc25)cc1 ; CC(C)(C)c1ccc(N2c3cc(N(c4ccc5oc6ccccc6c5c4)c4cccc5c4oc4ccccc45)ccc3B3c4cc5c(cc4N(c4ccc(C(C)(C)C)cc4)c4cc(N(c6ccccc6)c6ccc7c(c6)oc6ccccc67)cc2c43)sc2ccccc25)cc1 ; CC(C)(C)c1ccc(N2c3cc(N(c4cccc5c4oc4ccccc45)c4cccc5c4oc4ccccc45)ccc3B3c4cc5c(cc4N(c4ccc(C(C)(C)C)cc4)c4cc(N(c6ccc7c(c6)oc6ccccc67)c6ccc7c(c6)oc6ccccc67)cc2c43)sc2ccccc25)cc1]

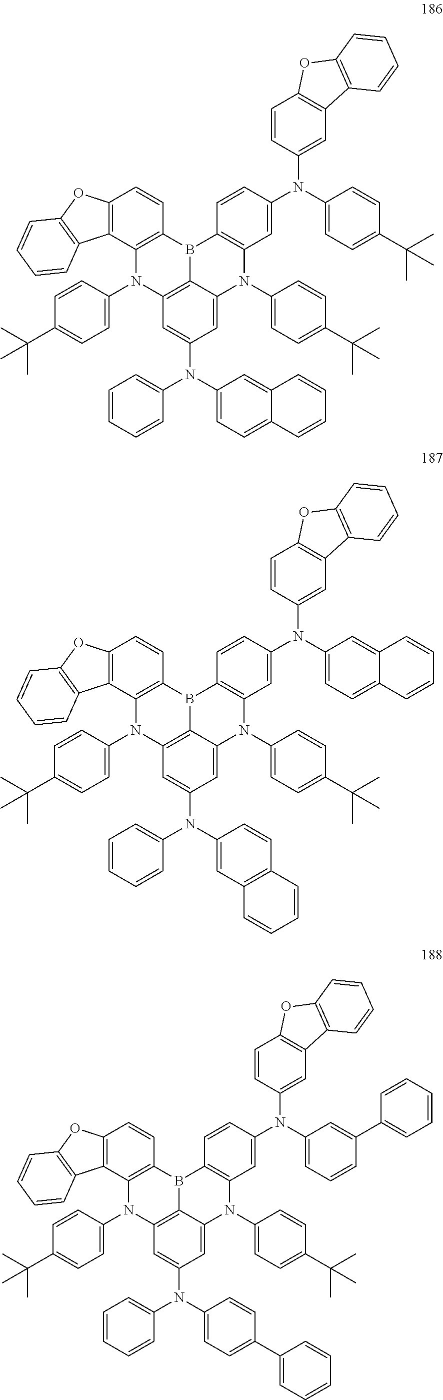

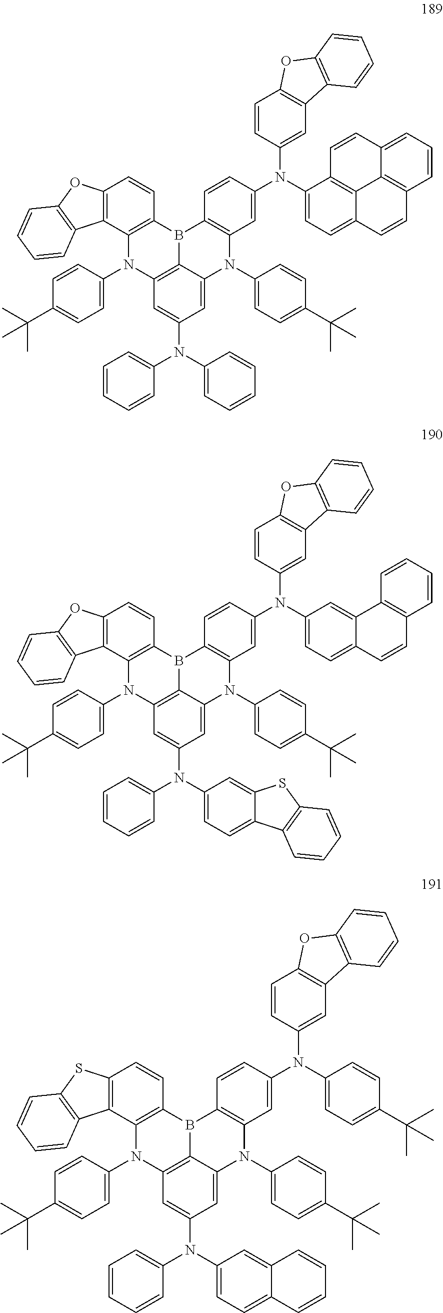 [SMILES: CC(C)(C)c1ccc(N2c3cc(N(c4ccc5oc6ccccc6c5c4)c4ccc5ccc6cccc7ccc4c5c67)ccc3B3c4ccc5oc6ccccc6c5c4N(c4ccc(C(C)(C)C)cc4)c4cc(N(c5ccccc5)c5ccccc5)cc2c43)cc1 ; CC(C)(C)c1ccc(N2c3cc(N(c4ccc5ccc6ccccc6c5c4)c4ccc5oc6ccccc6c5c4)ccc3B3c4ccc5oc6ccccc6c5c4N(c4ccc(C(C)(C)C)cc4)c4cc(N(c5ccccc5)c5ccc6c(c5)sc5ccccc56)cc2c43)cc1 ; CC(C)(C)c1ccc(N(c2ccc3c(c2)N(c2ccc(C(C)(C)C)cc2)c2cc(N(c4ccccc4)c4ccc5ccccc5c4)cc4c2B3c2ccc3sc5ccccc5c3c2N4c2ccc(C(C)(C)C)cc2)c2ccc3oc4ccccc4c3c2)cc1]

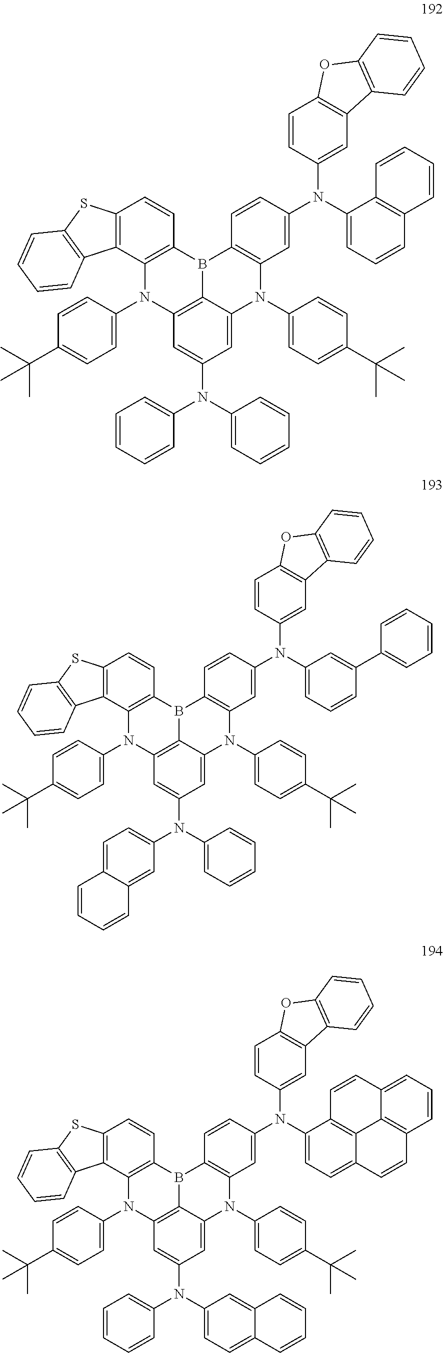 [SMILES: CC(C)(C)c1ccc(N2c3cc(N(c4ccc5oc6ccccc6c5c4)c4cccc5ccccc45)ccc3B3c4ccc5sc6ccccc6c5c4N(c4ccc(C(C)(C)C)cc4)c4cc(N(c5ccccc5)c5ccccc5)cc2c43)cc1 ; CC(C)(C)c1ccc(N2c3cc(N(c4cccc(-c5ccccc5)c4)c4ccc5oc6ccccc6c5c4)ccc3B3c4ccc5sc6ccccc6c5c4N(c4ccc(C(C)(C)C)cc4)c4cc(N(c5ccccc5)c5ccc6ccccc6c5)cc2c43)cc1 ; CC(C)(C)c1ccc(N2c3cc(N(c4ccc5oc6ccccc6c5c4)c4ccc5ccc6cccc7ccc4c5c67)ccc3B3c4ccc5sc6ccccc6c5c4N(c4ccc(C(C)(C)C)cc4)c4cc(N(c5ccccc5)c5ccc6ccccc6c5)cc2c43)cc1]

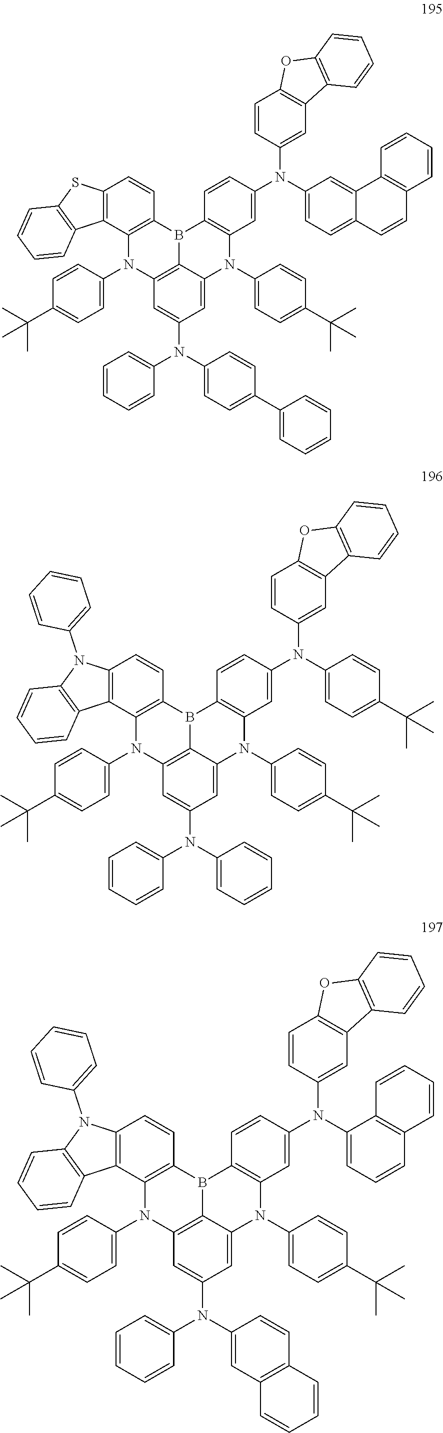

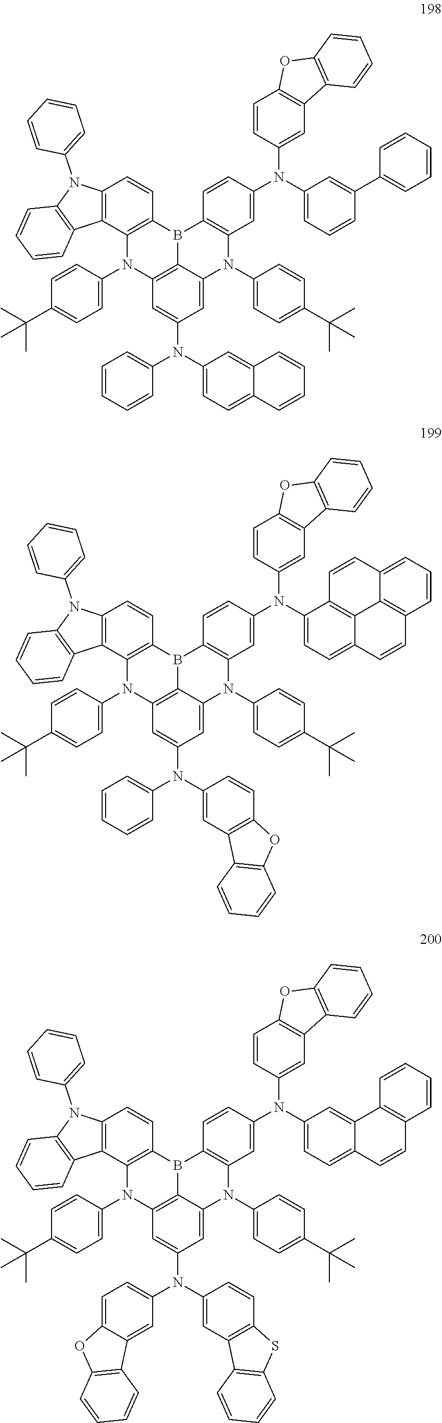

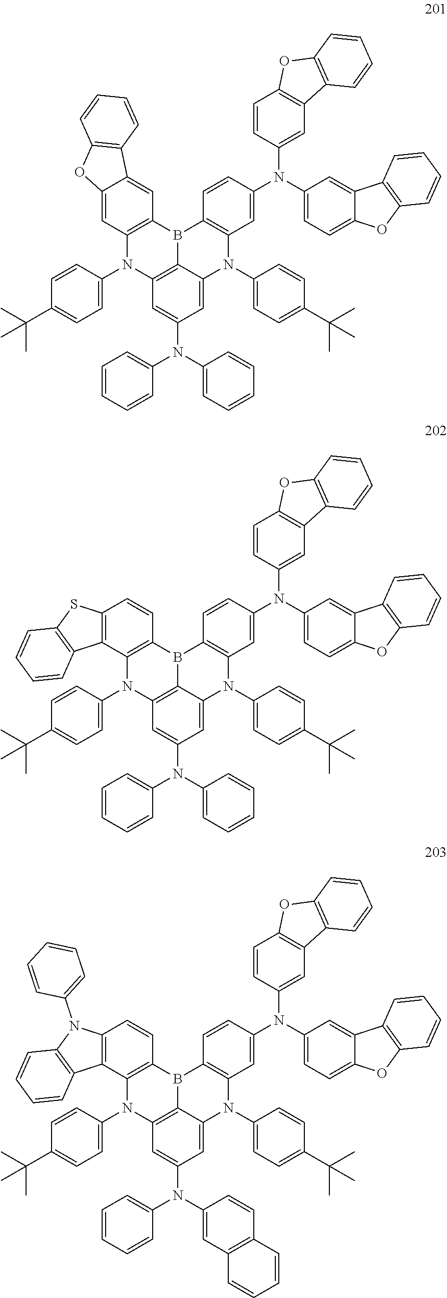 [SMILES: CC(C)(C)c1ccc(N2c3cc(N(c4ccc5oc6ccccc6c5c4)c4ccc5oc6ccccc6c5c4)ccc3B3c4cc5c(cc4N(c4ccc(C(C)(C)C)cc4)c4cc(N(c6ccccc6)c6ccccc6)cc2c43)oc2ccccc25)cc1 ; CC(C)(C)c1ccc(N2c3cc(N(c4ccc5oc6ccccc6c5c4)c4ccc5oc6ccccc6c5c4)ccc3B3c4ccc5sc6ccccc6c5c4N(c4ccc(C(C)(C)C)cc4)c4cc(N(c5ccccc5)c5ccccc5)cc2c43)cc1 ; CC(C)(C)c1ccc(N2c3cc(N(c4ccc5oc6ccccc6c5c4)c4ccc5oc6ccccc6c5c4)ccc3B3c4ccc5c(c4N(c4ccc(C(C)(C)C)cc4)c4cc(N(c6ccccc6)c6ccc7ccccc7c6)cc2c43)c2ccccc2n5-c2ccccc2)cc1]

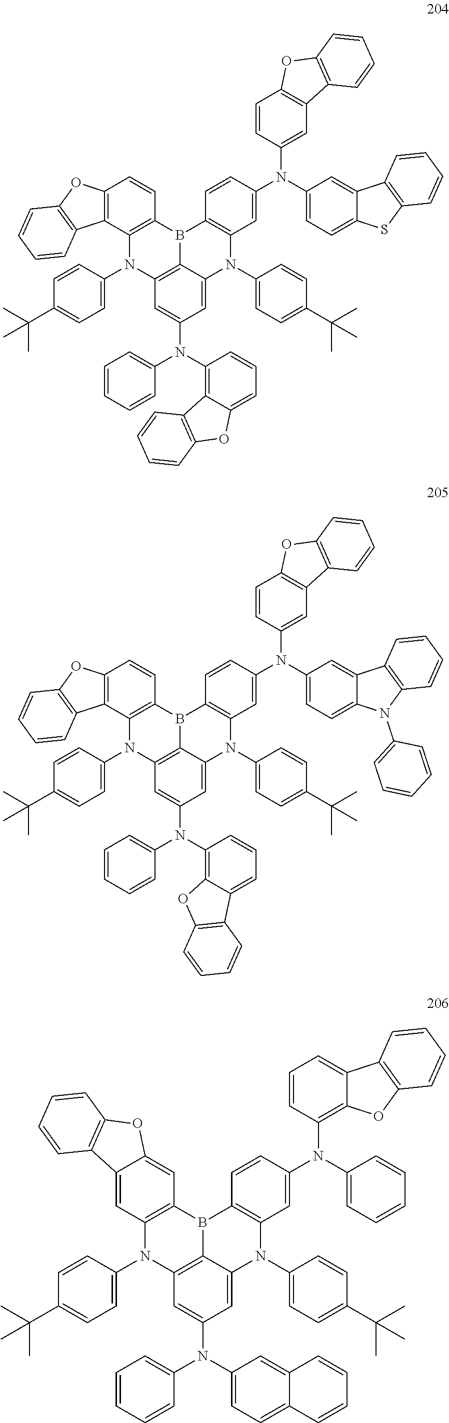 [SMILES: CC(C)(C)c1ccc(N2c3cc(N(c4ccc5oc6ccccc6c5c4)c4ccc5sc6ccccc6c5c4)ccc3B3c4ccc5oc6ccccc6c5c4N(c4ccc(C(C)(C)C)cc4)c4cc(N(c5ccccc5)c5cccc6oc7ccccc7c56)cc2c43)cc1 ; CC(C)(C)c1ccc(N2c3cc(N(c4ccc5oc6ccccc6c5c4)c4ccc5c(c4)c4ccccc4n5-c4ccccc4)ccc3B3c4ccc5oc6ccccc6c5c4N(c4ccc(C(C)(C)C)cc4)c4cc(N(c5ccccc5)c5cccc6c5oc5ccccc56)cc2c43)cc1 ; CC(C)(C)c1ccc(N2c3cc(N(c4ccccc4)c4cccc5c4oc4ccccc45)ccc3B3c4cc5oc6ccccc6c5cc4N(c4ccc(C(C)(C)C)cc4)c4cc(N(c5ccccc5)c5ccc6ccccc6c5)cc2c43)cc1]

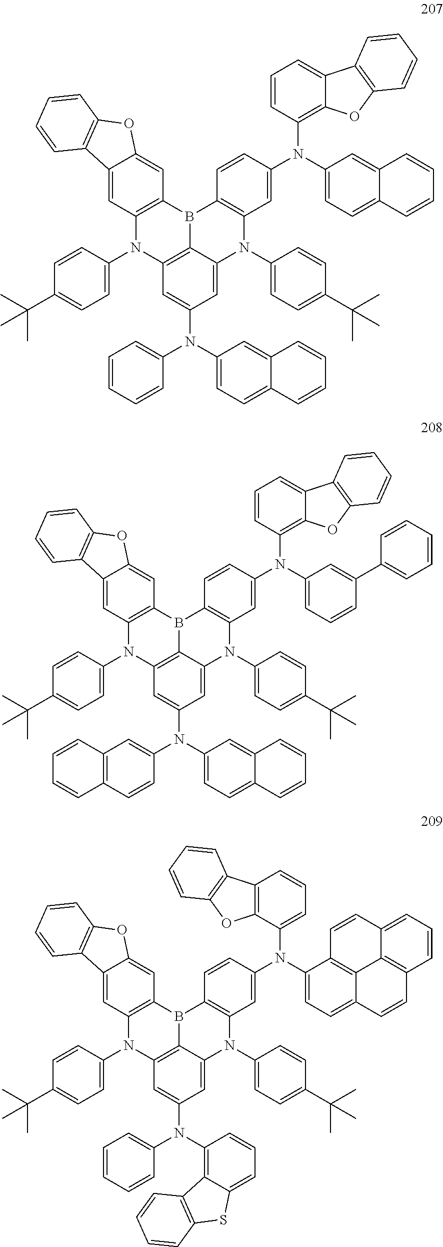 [SMILES: CC(C)(C)c1ccc(N2c3cc(N(c4ccc5ccccc5c4)c4cccc5c4oc4ccccc45)ccc3B3c4cc5oc6ccccc6c5cc4N(c4ccc(C(C)(C)C)cc4)c4cc(N(c5ccccc5)c5ccc6ccccc6c5)cc2c43)cc1 ; CC(C)(C)c1ccc(N2c3cc(N(c4cccc(-c5ccccc5)c4)c4cccc5c4oc4ccccc45)ccc3B3c4cc5oc6ccccc6c5cc4N(c4ccc(C(C)(C)C)cc4)c4cc(N(c5ccc6ccccc6c5)c5ccc6ccccc6c5)cc2c43)cc1 ; CC(C)(C)c1ccc(N2c3cc(N(c4ccc5ccc6cccc7ccc4c5c67)c4cccc5c4oc4ccccc45)ccc3B3c4cc5oc6ccccc6c5cc4N(c4ccc(C(C)(C)C)cc4)c4cc(N(c5ccccc5)c5cccc6sc7ccccc7c56)cc2c43)cc1]

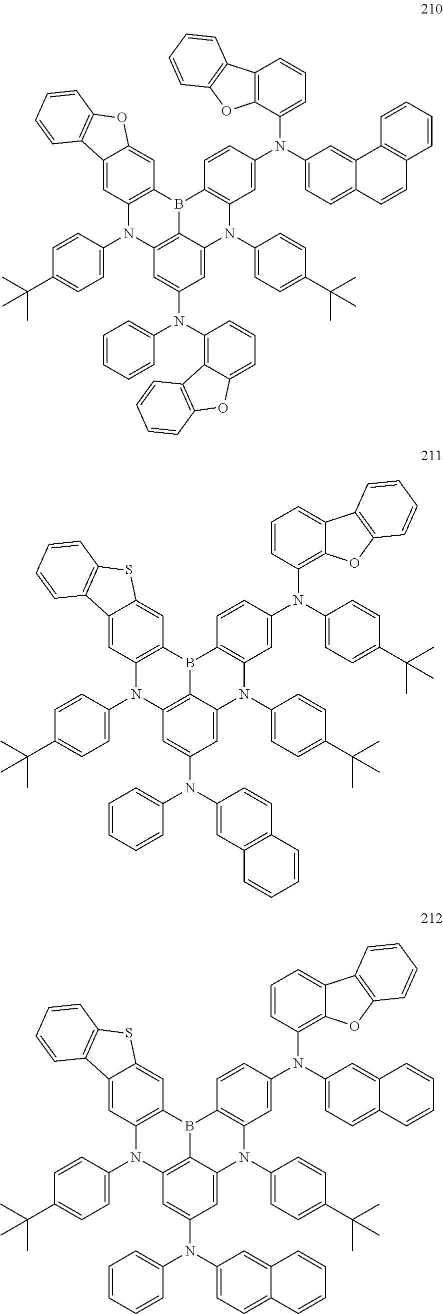

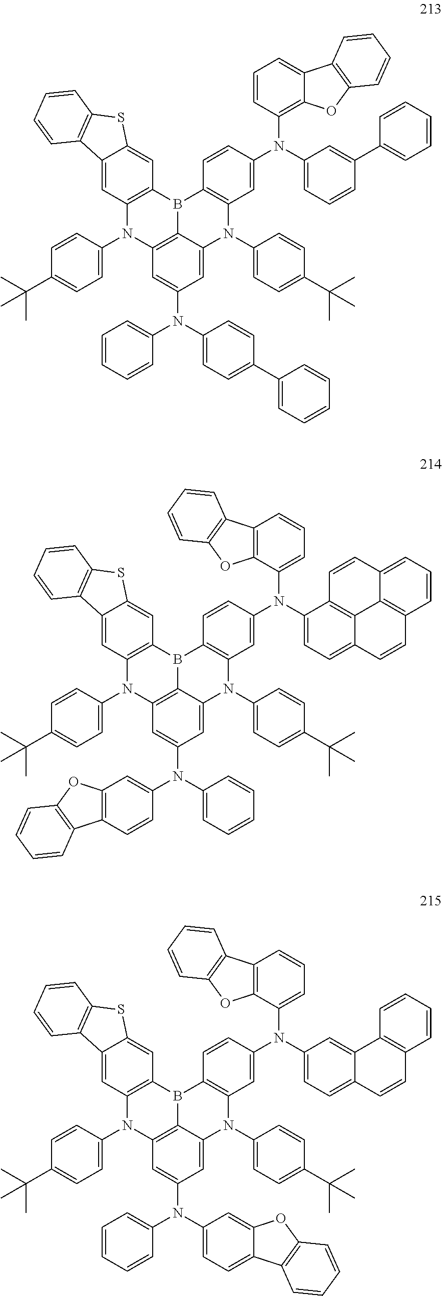 [SMILES: CC(C)(C)c1ccc(N2c3cc(N(c4cccc(-c5ccccc5)c4)c4cccc5c4oc4ccccc45)ccc3B3c4cc5sc6ccccc6c5cc4N(c4ccc(C(C)(C)C)cc4)c4cc(N(c5ccccc5)c5ccc(-c6ccccc6)cc5)cc2c43)cc1 ; CC(C)(C)c1ccc(N2c3cc(N(c4ccc5ccc6cccc7ccc4c5c67)c4cccc5c4oc4ccccc45)ccc3B3c4cc5sc6ccccc6c5cc4N(c4ccc(C(C)(C)C)cc4)c4cc(N(c5ccccc5)c5ccc6c(c5)oc5ccccc56)cc2c43)cc1 ; CC(C)(C)c1ccc(N2c3cc(N(c4ccc5ccc6ccccc6c5c4)c4cccc5c4oc4ccccc45)ccc3B3c4cc5sc6ccccc6c5cc4N(c4ccc(C(C)(C)C)cc4)c4cc(N(c5ccccc5)c5ccc6c(c5)oc5ccccc56)cc2c43)cc1]

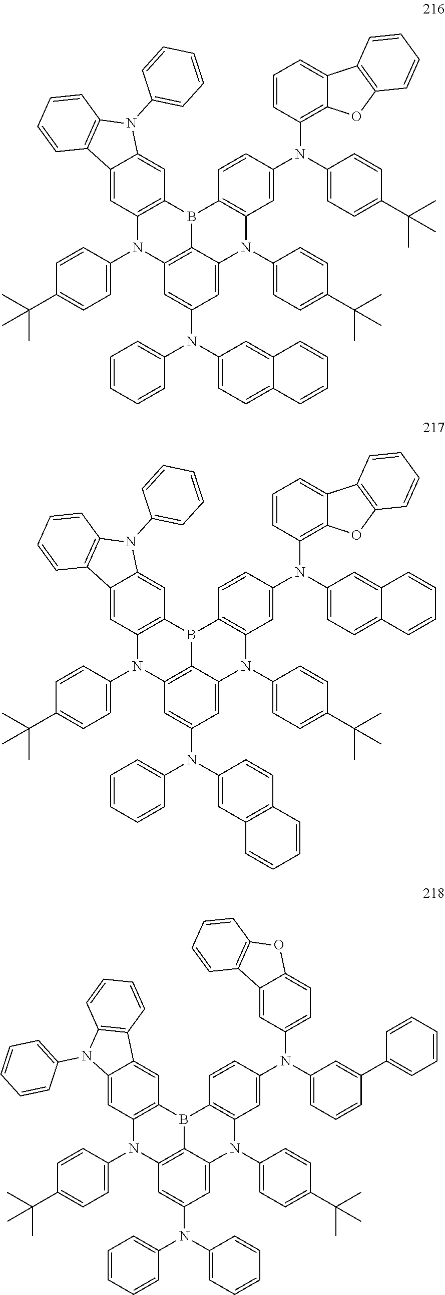

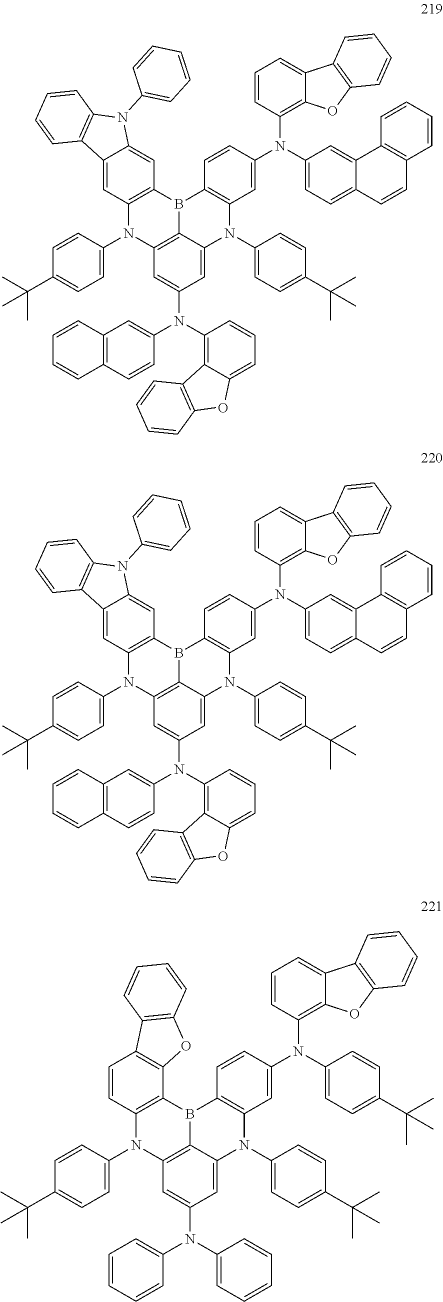 [SMILES: CC(C)(C)c1ccc(N2c3cc(N(c4ccc5ccc6ccccc6c5c4)c4cccc5c4oc4ccccc45)ccc3B3c4cc5c(cc4N(c4ccc(C(C)(C)C)cc4)c4cc(N(c6ccc7ccccc7c6)c6cccc7oc8ccccc8c67)cc2c43)c2ccccc2n5-c2ccccc2)cc1 ; CC(C)(C)c1ccc(N2c3cc(N(c4ccc5ccc6ccccc6c5c4)c4cccc5c4oc4ccccc45)ccc3B3c4cc5c(cc4N(c4ccc(C(C)(C)C)cc4)c4cc(N(c6ccc7ccccc7c6)c6cccc7oc8ccccc8c67)cc2c43)c2ccccc2n5-c2ccccc2)cc1 ; CC(C)(C)c1ccc(N2c3cc(N(c4ccc(C(C)(C)C)cc4)c4cccc5c4oc4ccccc45)ccc3B3c4c2cc(N(c2ccccc2)c2ccccc2)cc4N(c2ccc(C(C)(C)C)cc2)c2ccc4c(oc5ccccc54)c23)cc1]

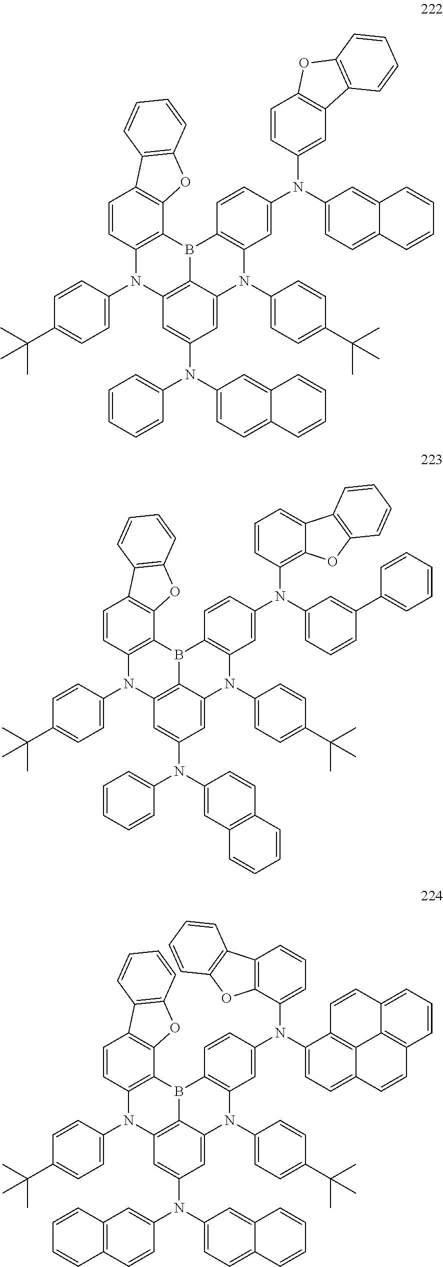 [SMILES: CC(C)(C)c1ccc(N2c3cc(N(c4ccc5ccccc5c4)c4ccc5oc6ccccc6c5c4)ccc3B3c4c2cc(N(c2ccccc2)c2ccc5ccccc5c2)cc4N(c2ccc(C(C)(C)C)cc2)c2ccc4c(oc5ccccc54)c23)cc1 ; CC(C)(C)c1ccc(N2c3cc(N(c4cccc(-c5ccccc5)c4)c4cccc5c4oc4ccccc45)ccc3B3c4c2cc(N(c2ccccc2)c2ccc5ccccc5c2)cc4N(c2ccc(C(C)(C)C)cc2)c2ccc4c(oc5ccccc54)c23)cc1 ; CC(C)(C)c1ccc(N2c3cc(N(c4ccc5ccc6cccc7ccc4c5c67)c4cccc5c4oc4ccccc45)ccc3B3c4c2cc(N(c2ccc5ccccc5c2)c2ccc5ccccc5c2)cc4N(c2ccc(C(C)(C)C)cc2)c2ccc4c(oc5ccccc54)c23)cc1]

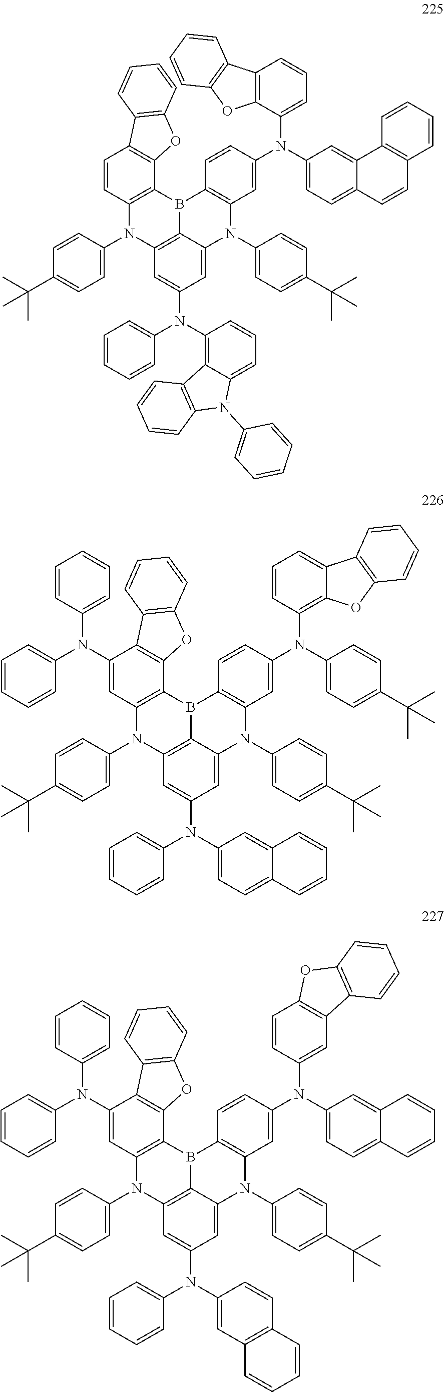

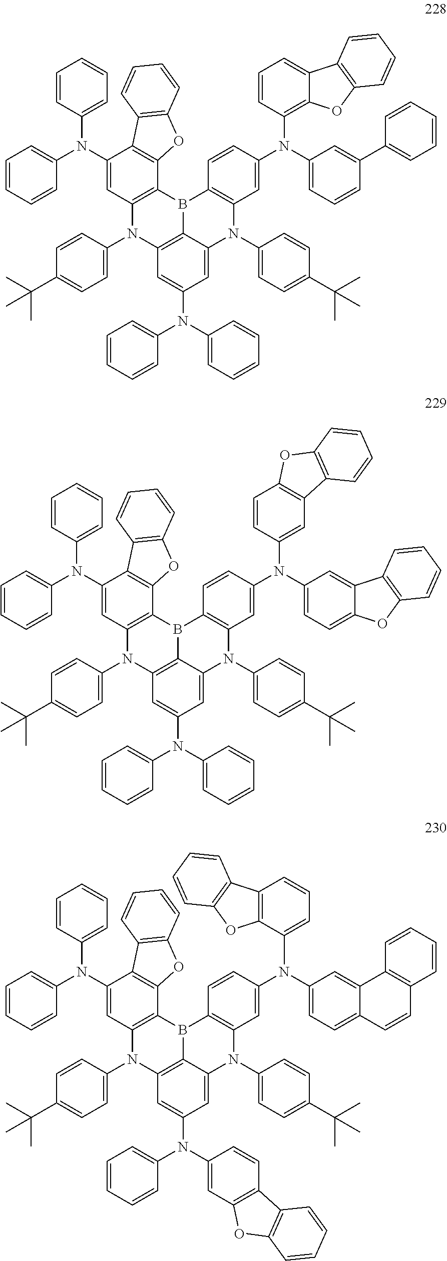

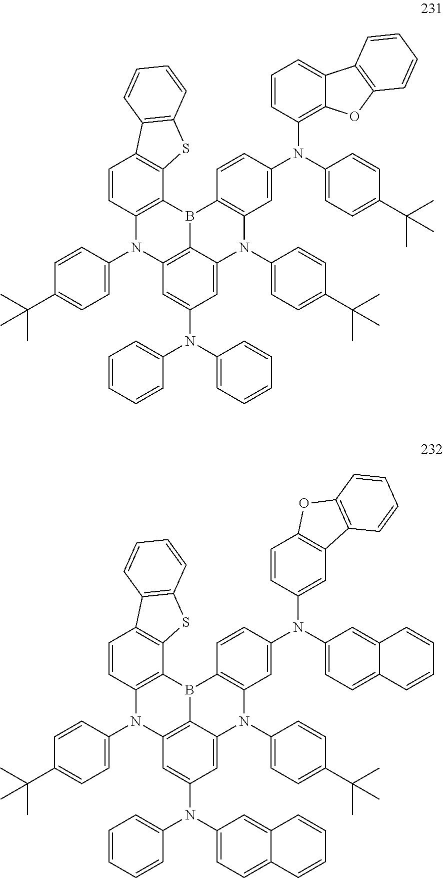

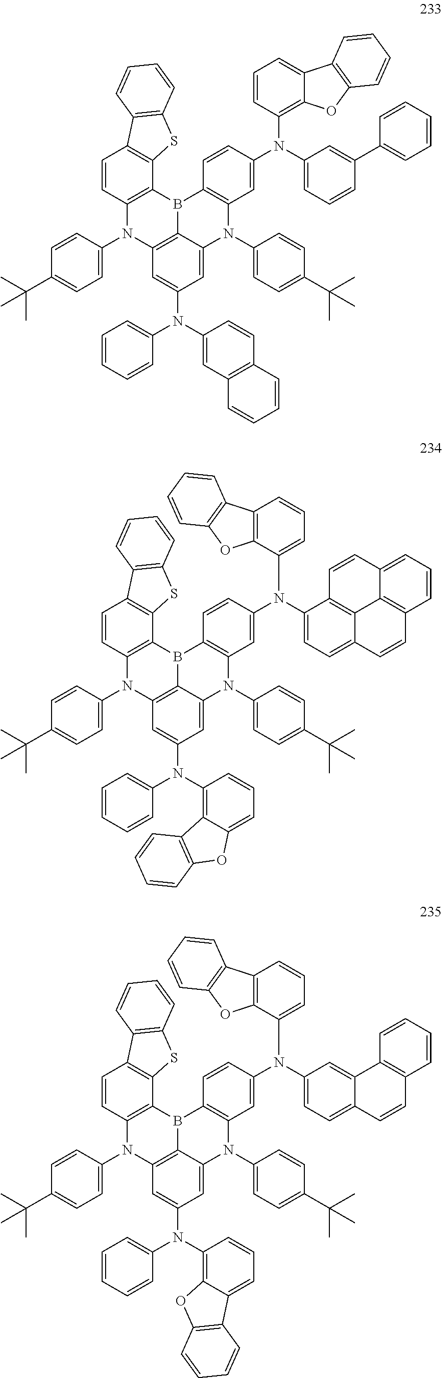 [SMILES: CC(C)(C)c1ccc(N2c3cc(N(c4cccc(-c5ccccc5)c4)c4cccc5c4oc4ccccc45)ccc3B3c4c2cc(N(c2ccccc2)c2ccc5ccccc5c2)cc4N(c2ccc(C(C)(C)C)cc2)c2ccc4c(sc5ccccc54)c23)cc1 ; CC(C)(C)c1ccc(N2c3cc(N(c4ccc5ccc6cccc7ccc4c5c67)c4cccc5c4oc4ccccc45)ccc3B3c4c2cc(N(c2ccccc2)c2cccc5oc6ccccc6c25)cc4N(c2ccc(C(C)(C)C)cc2)c2ccc4c(sc5ccccc54)c23)cc1 ; CC(C)(C)c1ccc(N2c3cc(N(c4ccc5ccc6ccccc6c5c4)c4cccc5c4oc4ccccc45)ccc3B3c4c2cc(N(c2ccccc2)c2cccc5c2oc2ccccc25)cc4N(c2ccc(C(C)(C)C)cc2)c2ccc4c(sc5ccccc54)c23)cc1]

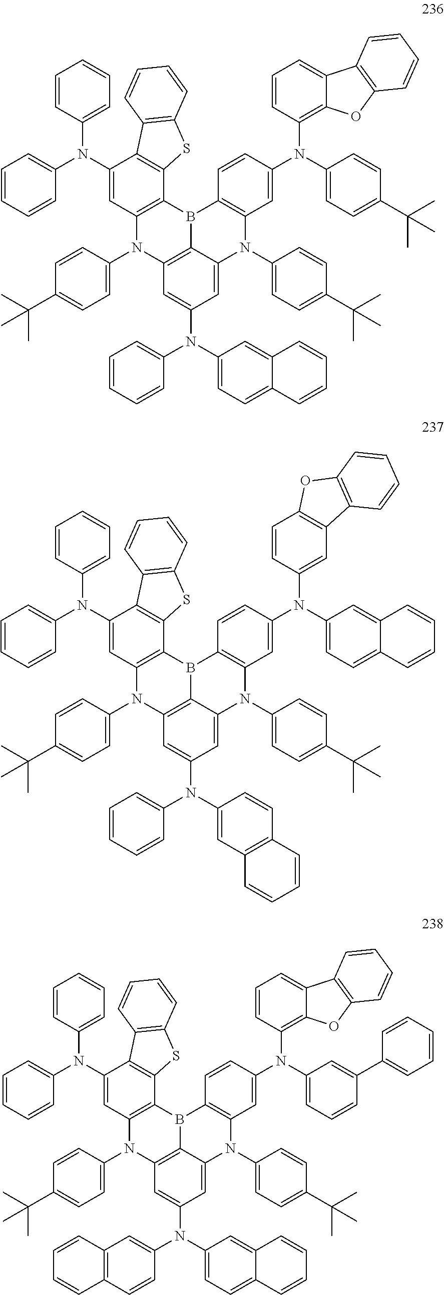

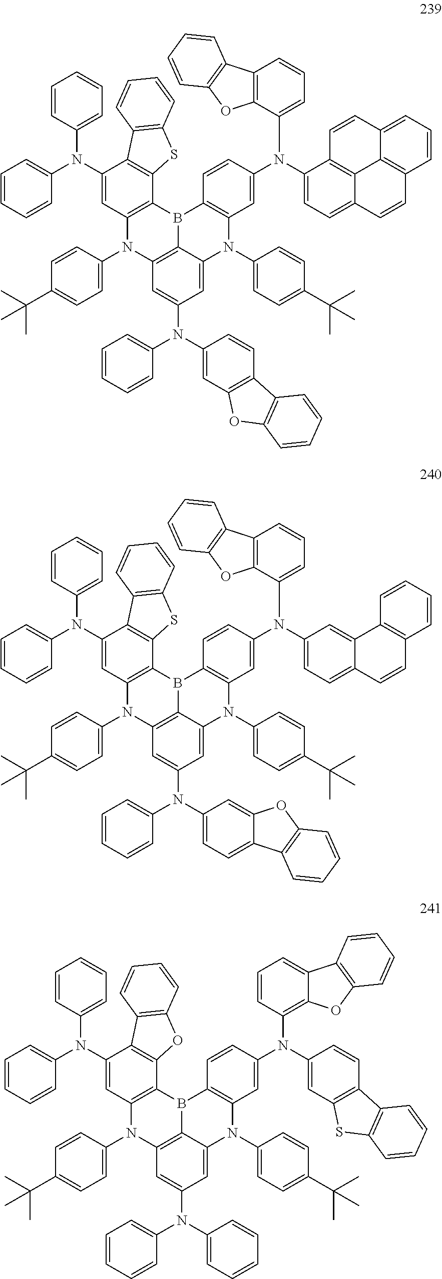

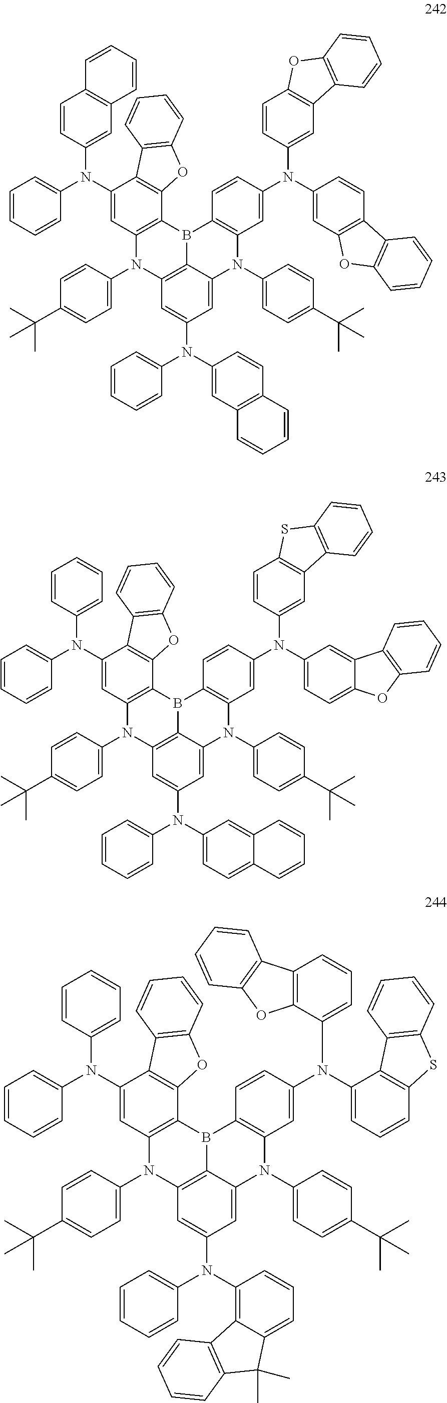

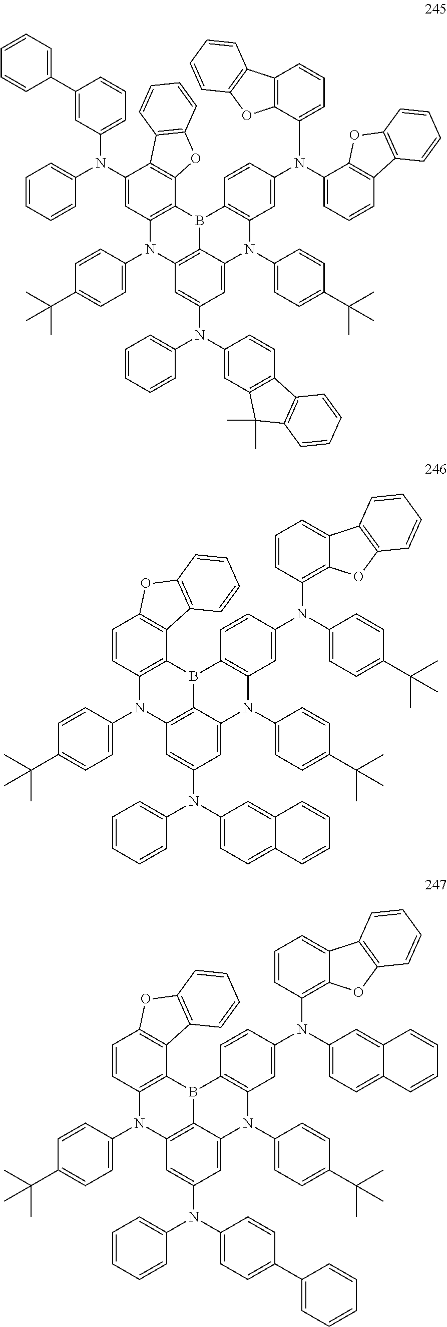

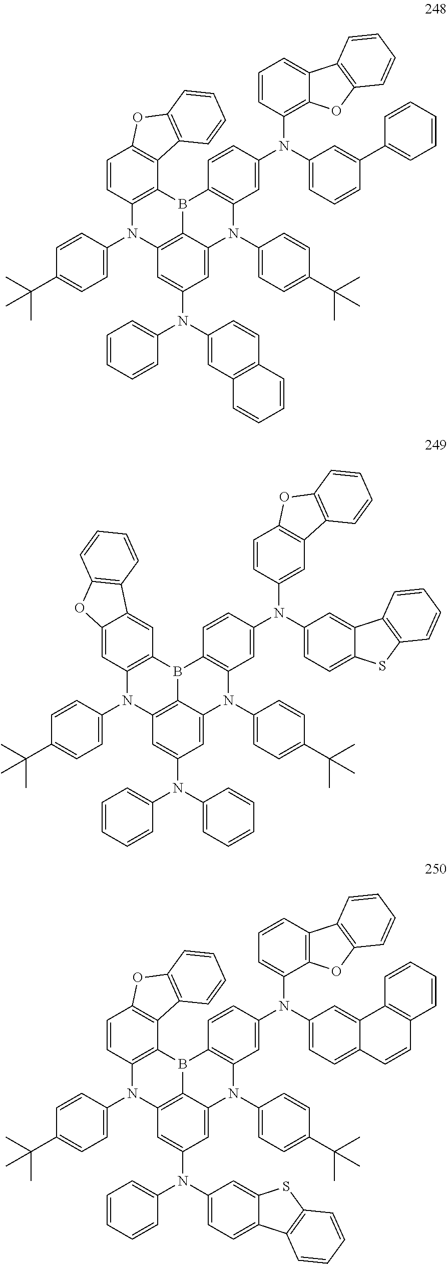 [SMILES: CC(C)(C)c1ccc(N2c3cc(N(c4cccc(-c5ccccc5)c4)c4cccc5c4oc4ccccc45)ccc3B3c4c2cc(N(c2ccccc2)c2ccc5ccccc5c2)cc4N(c2ccc(C(C)(C)C)cc2)c2ccc4oc5ccccc5c4c23)cc1 ; CC(C)(C)c1ccc(N2c3cc(N(c4ccc5oc6ccccc6c5c4)c4ccc5sc6ccccc6c5c4)ccc3B3c4cc5c(cc4N(c4ccc(C(C)(C)C)cc4)c4cc(N(c6ccccc6)c6ccccc6)cc2c43)oc2ccccc25)cc1 ; CC(C)(C)c1ccc(N2c3cc(N(c4ccc5ccc6ccccc6c5c4)c4cccc5c4oc4ccccc45)ccc3B3c4c2cc(N(c2ccccc2)c2ccc5c(c2)sc2ccccc25)cc4N(c2ccc(C(C)(C)C)cc2)c2ccc4oc5ccccc5c4c23)cc1]

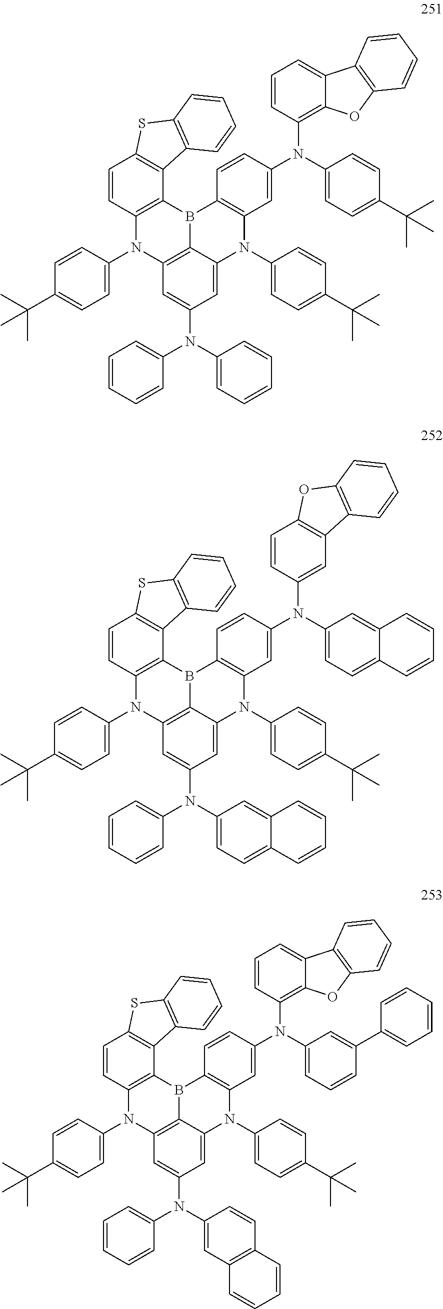

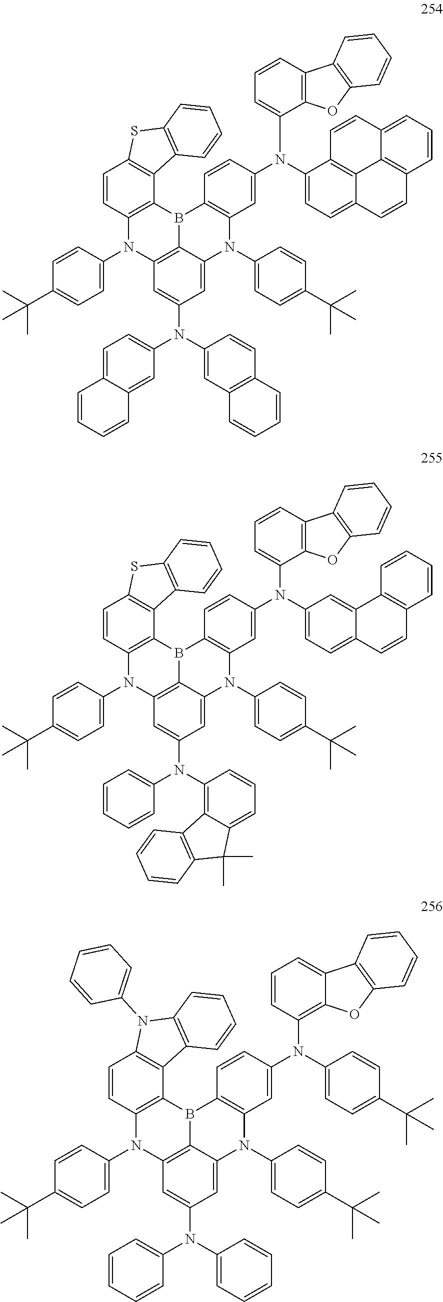 [SMILES: CC(C)(C)c1ccc(N2c3cc(N(c4ccc5ccc6cccc7ccc4c5c67)c4cccc5c4oc4ccccc45)ccc3B3c4c2cc(N(c2ccc5ccccc5c2)c2ccc5ccccc5c2)cc4N(c2ccc(C(C)(C)C)cc2)c2ccc4sc5ccccc5c4c23)cc1 ; CC(C)(C)c1ccc(N2c3cc(N(c4ccc5ccc6ccccc6c5c4)c4cccc5c4oc4ccccc45)ccc3B3c4c2cc(N(c2ccccc2)c2cccc5c2-c2ccccc2C5(C)C)cc4N(c2ccc(C(C)(C)C)cc2)c2ccc4sc5ccccc5c4c23)cc1 ; CC(C)(C)c1ccc(N2c3cc(N(c4ccc(C(C)(C)C)cc4)c4cccc5c4oc4ccccc45)ccc3B3c4c2cc(N(c2ccccc2)c2ccccc2)cc4N(c2ccc(C(C)(C)C)cc2)c2ccc4c(c23)c2ccccc2n4-c2ccccc2)cc1]

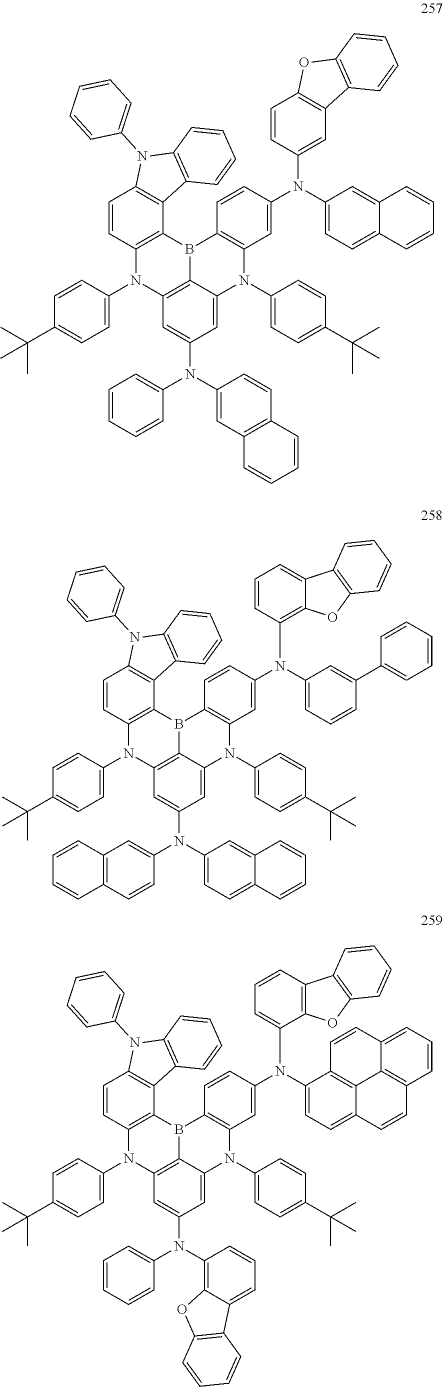 [SMILES: CC(C)(C)c1ccc(N2c3cc(N(c4ccc5ccccc5c4)c4ccc5oc6ccccc6c5c4)ccc3B3c4c2cc(N(c2ccccc2)c2ccc5ccccc5c2)cc4N(c2ccc(C(C)(C)C)cc2)c2ccc4c(c23)c2ccccc2n4-c2ccccc2)cc1 ; CC(C)(C)c1ccc(N2c3cc(N(c4cccc(-c5ccccc5)c4)c4cccc5c4oc4ccccc45)ccc3B3c4c2cc(N(c2ccc5ccccc5c2)c2ccc5ccccc5c2)cc4N(c2ccc(C(C)(C)C)cc2)c2ccc4c(c23)c2ccccc2n4-c2ccccc2)cc1 ; CC(C)(C)c1ccc(N2c3cc(N(c4ccc5ccc6cccc7ccc4c5c67)c4cccc5c4oc4ccccc45)ccc3B3c4c2cc(N(c2ccccc2)c2cccc5c2oc2ccccc25)cc4N(c2ccc(C(C)(C)C)cc2)c2ccc4c(c23)c2ccccc2n4-c2ccccc2)cc1]

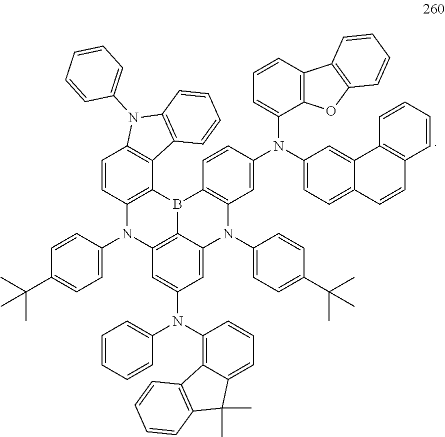 [SMILES: CC(C)(C)c1ccc(N2c3cc(N(c4ccc5ccc6ccccc6c5c4)c4cccc5c4oc4ccccc45)ccc3B3c4c2cc(N(c2ccccc2)c2cccc5c2-c2ccccc2C5(C)C)cc4N(c2ccc(C(C)(C)C)cc2)c2ccc4c(c23)c2ccccc2n4-c2ccccc2)cc1]

8. The organic compound according to claim 1, wherein a first excited singlet state of the organic compound has an energy level greater than or equal to 2.93 eV, and a first excited triplet state of the organic compound has an energy level greater than or equal to 2.48 eV.

9. A light-emitting element comprising:
a first electrode and a second electrode; and
an organic functional layer between the first electrode and the second electrode,
wherein a material of the organic functional layer comprises one or more than one organic compound having a structure represented by formula (1): 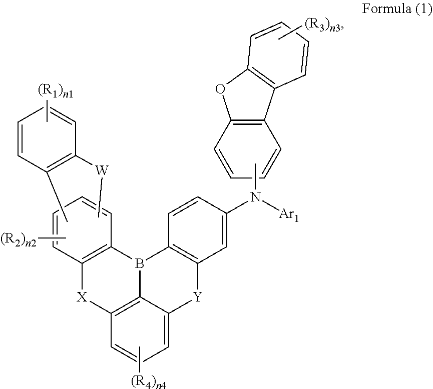
wherein Ar₁ is selected from the group consisting of a substituted or unsubstituted aromatic group having 6 to 60 ring atoms, and a substituted or unsubstituted heteroaromatic group having 5 to 60 ring atoms;
X and Y are each independently selected from the group consisting of O, S, CR₅R₆, and NR₇;
W is selected from the group consisting of O, S, CR₈R₉, and NR₁₀;
R₁, R₂, R₃, R₄, R₅, R₆, R₇, R₈, R₉, and R₁₀, at each occurrence, are each independently selected from the group consisting of —H, a linear alkyl group having 1 to 20 carbon atoms, a branched alkyl group having 3 to 20 carbon atoms, and a substituted or unsubstituted aromatic group having 6 to 30 ring atoms; and
n1 is selected from 0, 1, 2, 3, or 4; n2 is selected from 0, 1, or 2; n3 is selected from 0, 1, 2, 3, or 4; n4 is selected from 0, 1, 2, or 3.

10. The light-emitting element according to claim 9, wherein the organic functional layer at least comprises a light-emitting layer having a host material and a guest material, the guest material comprising one or more than one organic compound of formula (1), and a mass ratio of the host material to the guest material is 99:1 to 70:30.

11. The light-emitting element according to claim 9, R₁, R₂, R₃, and R₄, at each occurrence, are each independently selected from the group consisting of —H, methyl, 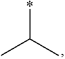 [SMILES: *C(C)C]
tert-butyl, 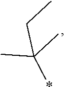 [SMILES: *C(C)(C)CC]
phenyl, 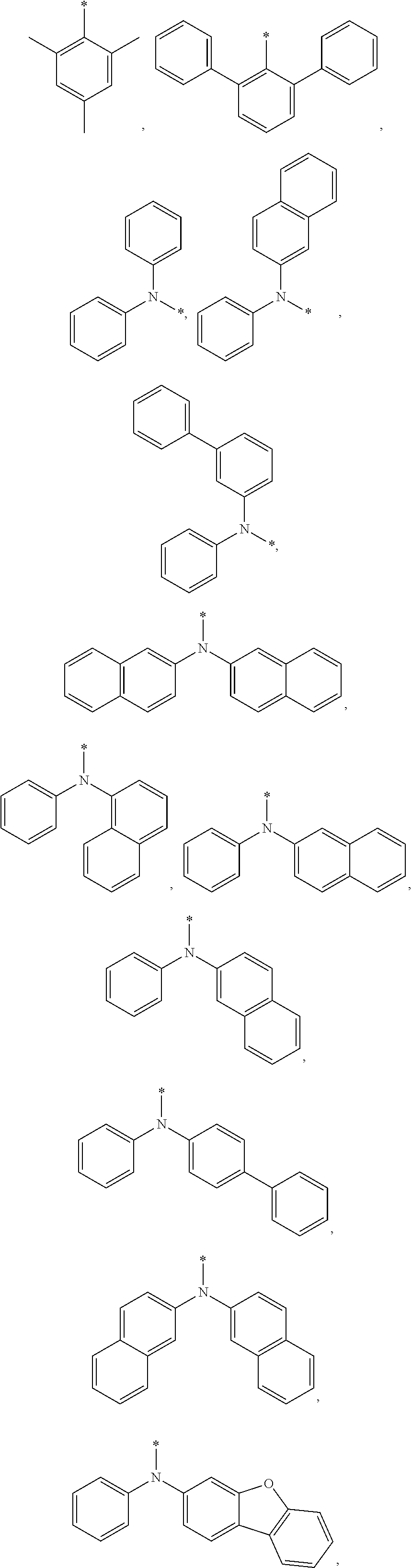 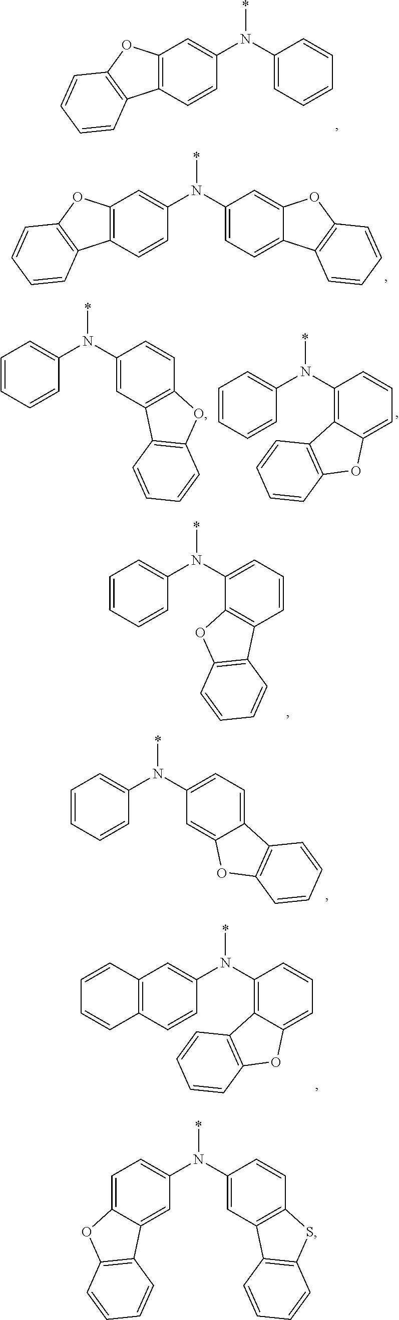 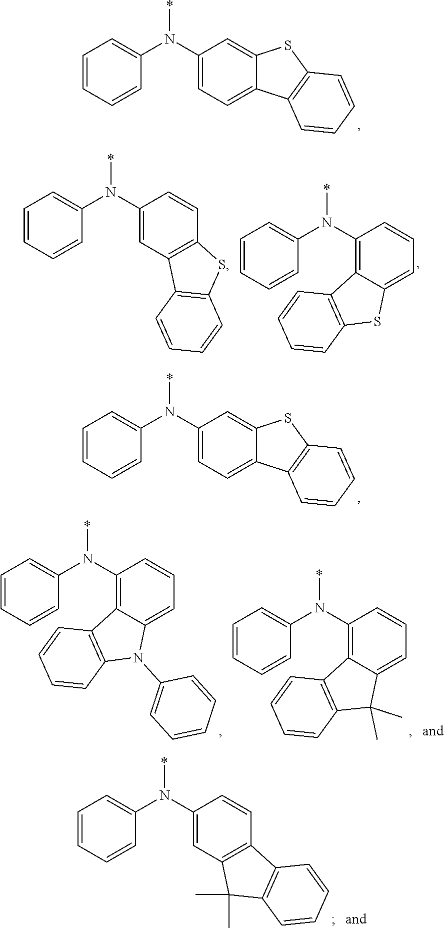
R₅, R₆, R₇, R₈, R₉ and R₁₀, at each occurrence, are each independently selected from the group consisting of —H, methyl, tert-butyl, phenyl,

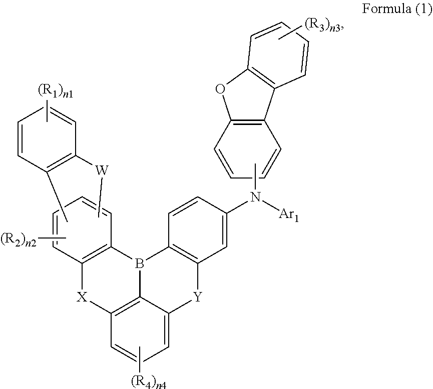

12. The light-emitting element according to claim 9, wherein a first excited singlet state of the organic compound has an energy level greater than or equal to 2.93 eV, and a first excited triplet state of the organic compound has an energy level greater than or equal to 2.48 eV.

13. The light-emitting element according to claim 9, wherein the light-emitting element has a luminous efficiency of 5.1 cd/A-6.2 cd/A.

14. The light-emitting element according to claim 9, wherein time taken for decreasing luminance of the light-emitting element from an initial luminance to 90% of the initial luminance is in a range of 141 h-168 h.

15. A display panel comprising a light-emitting element, wherein the light-emitting element comprises an organic compound having a structure represented by formula (1): 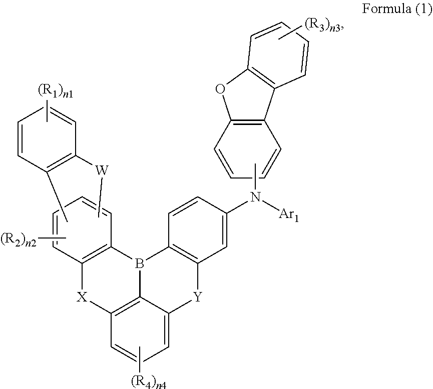
wherein Ar₁ is selected from the group consisting of a substituted or unsubstituted aromatic group having 6 to 60 ring atoms, and a substituted or unsubstituted heteroaromatic group having 5 to 60 ring atoms;
X and Y are each independently selected from the group consisting of O, S, CR₅R₆, and NR₇;
W is selected from the group consisting of O, S, CR₈R₉, and NR₁₀;
R₁, R₂, R₃, R₄, R₅, R₆, R₇, R₈, R₉, and R₁₀, at each occurrence, are each independently selected from the group consisting of —H, a linear alkyl group having 1 to 20 carbon atoms, a branched alkyl group having 3 to 20 carbon atoms, and a substituted or unsubstituted aromatic group having 6 to 30 ring atoms; and
n1 is selected from 0, 1, 2, 3, or 4; n2 is selected from 0, 1, or 2; n3 is selected from 0, 1, 2, 3, or 4; n4 is selected from 0, 1, 2, or 3.

16. The display panel according to claim 15, wherein a first excited singlet state of the organic compound has an energy level greater than or equal to 2.93 eV, and a first excited triplet state of the organic compound has an energy level greater than or equal to 2.48 eV.

17. The display panel according to claim 15, wherein the light-emitting element has a luminous efficiency of 5.1 cd/A-6.2 cd/A.

18. The display panel according to claim 15, wherein time taken for decreasing luminance of the light-emitting element from an initial luminance to 90% of the initial luminance is in a range of 141 h-168 h.
